(19) United States
(12) Patent Application Publication
(10) Pub. No.: US 2014/0151615 A1
(43) Pub. Date: Jun. 5, 2014

(54) COLORING COMPOSITION, COLORED CURED FILM, COLOR FILTER, MANUFACTURING METHOD OF THE SAME, AND SOLD STATE IMAGING DEVICE

(71) Applicant: FUJIFILM Corporation, Tokyo (JP)

(72) Inventors: Seiichi HITOMI, Haibara-gun (JP); Yuzo NAGATA, Haibara-gun (JP); Hiroaki IDEI, Haibara-gun (JP); Kazuya OOTA, Haibara-gun (JP); Yousuke MURAKAMI, Haibara-gun (JP)

(73) Assignee: FUJIFILM Corporation, Tokyo (JP)

(21) Appl. No.: 14/176,568

(22) Filed: Feb. 10, 2014

Related U.S. Application Data
(63) Continuation of application No. PCT/JP2012/075282, filed on Sep. 24, 2012.

(30) Foreign Application Priority Data
Sep. 28, 2011 (JP) 2011-213220

(51) Int. Cl. G02B 5/22; G03F 7/00; G03F 7/038

(52) U.S. Cl. CPC G02B 5/223; G03F 7/038; G03F 7/0005
USPC 252/586; 526/241; 528/73; 526/284; 430/7

(57) ABSTRACT

A coloring composition which suppresses color loss of the colored pattern to be formed, and may form a colored pattern which has excellent developability and heat resistance is provided. A colored cured film which suppresses color loss of the colored pattern to be formed, and may form a colored pattern which has excellent developability and heat resistance, a color filter which is provided with the colored pattern, and a manufacturing method thereof are provided. A solid state imaging device which has excellent color loss resistance and heat resistance is provided. A coloring composition of the present invention includes a resin (A) having a dye structure in which a peak area occupied by a component having a molecular weight of 2000 or less is below 10% in respect to a peak area of a total molecular weight distribution of the resin (A) which is measured using gel permeation chromatography.

### BACKGROUND OF THE INVENTION

1. Field of the Invention

The present invention relates to a coloring composition which contains a resin having a dye structure, which is suitable for manufacturing a color filter that may be used in a solid state imaging device, a liquid crystal display device or the like, a colored cured film, a color filter, a manufacturing method of the same, and a solid state imaging device.

2. Description of the Related Art

There is a pigment dispersion method as one of the methods of manufacturing a color filter used in liquid crystal display devices, solid state imaging devices, or the like, and as a pigment dispersion method, there is a method where a radiation-sensitive coloring composition in which pigments are dispersed in various photosensitive compositions is used, and a color filter is manufactured using photolithography. In detail, a radiation-sensitive coloring composition is coated onto a substrate using a spin coater, a roll coater, or the like, is dried to form a coated film, and a colored pixel is obtained by pattern exposing and developing the coated film. A color filter is manufactured by repeating this operation for all of the desired colors.

The above described method is stable in regard to light and heat due to using pigment, positional accuracy is sufficiently secured due to performing patterning using the photolithography method, and has been used widely as a favorable method of manufacturing color filters for color displays and the like.

Meanwhile, in color filters for solid state imaging devices such as CCDs and the like, in recent years further high definition is desired. With this high definition, there is a tendency for the size of a pattern to be made more minute, however, in the pigment dispersion method widely used in the related art, further increasing the resolution by further refining the size of the pattern is considered to be difficult. One reason for this is that in a fine pattern, coarse particles made by pigment particles aggregating are a cause of color irregularity occurrence. Therefore, in recent years, in the present situation, the general pigment dispersion method which has been used hitherto is not necessarily suitable for the applications in which fine patterns are demanded such as solid state imaging devices.

In the related art, color filters have been manufactured using pigment as the coloring agent, however, using dye instead of pigment is being considered. When dye is used, the points shown below become a problem, in particular. (1) Dyes are generally inferior in light resistance and heat resistance compared to pigments. In particular, there is a problem in that the optical characteristics change due to the high temperature step when film forming of ITO (indium tin oxide) which is used frequently as an electrode of liquid crystal displays and the like.

(2) In dyes, due to there being a tendency to suppress a radical polymerization reaction, there are problems in the design of the radiation-sensitive coloring composition in systems which use radical polymerization as means for curing.

(3) Dyes normally have low solubility in either an aqueous alkali solution or an organic solvent (below also referred to as simply solvent), therefore, it is difficult to obtain a radiation-sensitive coloring composition of a desired spectrum.

(4) Dyes often exhibit interaction with other components in a radiation-sensitive coloring composition, therefore, it is difficult to adjust the solubility (developability) of the exposed area and non-exposed area.

(5) When the molar extinction coefficient (ε) of the dye is low, a large amount of dye needs to be added. Therefore, polymerizable compounds (monomers), binders, and other components of photopolymerization initiators in the radiation-sensitive coloring composition and the like need to be reduced relatively, and the curability of the composition, the heat resistance, the developability and the like after curing are reduced.

Due to these problems, forming a colored pattern with dye which is configured to be fine and of a thin film for a high definition color filter, and which also has excellent durability has been difficult. Also, in a case of a color filter for a solid state imaging device, there is a demand to make the colored layer a thin film of 1 μm or less. Therefore, in order to obtain a desired absorption, it is necessary to add a large amount of dye to the radiation-sensitive coloring composition, resulting in the previously described problem occurring.

Also, in the radiation-sensitive coloring composition which contains a dye, when heat processing is performed after film formation, it has been noted that a phenomenon in which color migration occurs easily between neighboring colored patterns of different colors, or between layers which are laminated and overlap. Besides color migration, there are also other problems such as that the pattern becomes easily exfoliated in a low exposure amount region due to a reduction in sensitivity, since the amount of photosensitive components which contribute to a photolithographic property decreases relatively, a desired shape or color density may not be obtained due to thermal sagging or elution during developing or the like.

As a method of solving such problems, a method has been disclosed (for example, refer to JP2007-139906A, JP2007-138051A, JP3736221B, and JP2011-95732A) which solves these problems by making a dye a resin having a dye structure by polymerization.

### SUMMARY OF THE INVENTION

However, when using a resin having a dye structure as a component containing a radiation-sensitive coloring composition, the present inventors have discovered that the following problems occur. In other words, if there is 10% or more of a low molecular weight component (in particular, a component having a molecular weight of 2000 or less) of the resin is present in relation to a peak area of the total molecular weight distribution of the resin, the molecular mobility of the low molecular weight component (in particular, a component having a molecular weight of 2000 or less) is large, and may therefore manifest as a cause of color loss of the colored pattern and a cause of degradation of heat resistance. Also, since there is a tendency for the hydrophobicity of the low molecular weight component to increase, the problems may manifest as a cause of residue during developing after the pattern exposure.

The present invention is made in consideration of the above described problems and in order to achieve the below objects.

In other words, the first object of the present invention is to provide a coloring compound which suppresses color loss of the colored pattern to be formed, and may form a colored pattern which has excellent developability and heat resistance. Also, the second object of the present invention is to provide a colored cured film which may form a colored pattern which suppresses color loss of the colored pattern to be formed, and may form a colored pattern which has excellent developability and heat resistance, a color filter which is provided with the colored pattern, and a manufacturing method thereof. Furthermore, the third object of the present invention is to provide a solid state imaging device which has excellent developability and heat resistance due to being provided with the color filter.

The means for accomplishing the above problems are as follows.

[1] A coloring composition which includes a resin (A) having a dye structure, in which a peak area occupied by a component having a molecular weight of 2000 or less is below 10% in respect to a peak area of a total molecular weight distribution of the resin (A) which is measured using gel permeation chromatography.

[2] The coloring composition according to [1], in which a weight average molecular weight of the resin (A) is from 4000 to 15000.

[3] The coloring composition according to [1] or [2], further including a pigment (B).

[4] The coloring composition according to [3], in which the pigment (B) is an anthraquinone pigment, a diketopyrrolopyrrole pigment, a phthalocyanine pigment, a quinophthalone pigment, an isoindoline pigment, an azomethine pigment, or a dioxazine pigment.

[5] The coloring composition according to any one of [1] to [4], further including a polymerizable compound (C), and a photopolymerization initiator (D).

[6] The coloring composition according to [5], in which the photopolymerization initiator (D) is an oxime initiator.

[7] The coloring composition according to any one of [1] to [6], further including an alkaline soluble resin (E).

[8] The coloring composition according to any one of [1] to [7], in which the dye structure of the resin (A) is a structure derived from a dye selected from a dipyrromethene dye, an azo dye, an anthraquinone dye, a triphenylmethane dye, a xanthene dye, a cyanine dye, a squarylium dye, a quinophthalone dye, a phthalocyanine dye, and a sub-phthalocyanine dye.

[9] The coloring composition according to any one of [1] to [8], in which the resin (A) further has a polymerizable group.

[10] The coloring composition according to [9], in which the polymerizable group is a polymerizable group selected from a group consisting of a group that includes an ethylenic unsaturated bond, an epoxy group, an oxetane group, and a methylol group.

[11] The coloring composition according to any one of [1] to [10], in which the resin (A) is a resin obtained by subjecting a monomer, which has an ethylenic unsaturated bond and a dye structure, to a radical polymerization reaction.

[12] The coloring composition according to any one of [1] to [11], in which the resin (A) further has an alkaline soluble group.

[13] The coloring composition according to any one of [1] to [12], in which an acid value of the resin (A) is from 0.5 mmol/g to 1.0 mmol/g.

[14] The coloring composition according to any one of [1] to [13], in which the coloring composition is used to form a colored layer of a color filter.

[15] A colored cured film obtained by curing the coloring composition according to any one of [1] to [14].

[16] A color filter which is provided with the colored cured film according to [15].

[17] A manufacturing method of a color filter including forming a colored layer by coating the coloring composition according to claim 11 onto a support, performing pattern exposure on the colored layer, and developing the colored layer after exposure to form a colored pattern.

[18] A solid state imaging device provided with the color filter according to [16].

[19] A solid state imaging device provided with the color filter obtained using the manufacturing method of a color filter according to [17].

### Advantageous Effects of Invention

According to the coloring compound of the present invention, it is possible to suppress color loss of the colored pattern to be formed, and form a colored pattern which has excellent developability and heat resistance.

Also, according to the present invention, it is possible to provide a colored cured film which may form a colored pattern which suppresses color loss of the colored pattern to be formed, and may form a colored pattern which has excellent developability and heat resistance, a color filter which is provided with the colored pattern, and a manufacturing method thereof.

Furthermore, according to the present invention, it is possible to provide a solid state imaging device and an image display device (a liquid crystal display device, an organic EL display device and the like) which has excellent color loss resistance and heat resistance due to being provided with the color filter.

### DESCRIPTION OF THE PREFERRED EMBODIMENTS

The description of the constituent components in the present invention described below is sometimes given based on representative embodiments of the present invention, however, the present invention is not limited to such embodiments. In the notation of a group (atomic group) in the present specification, the notation in which substituted or unsubstituted is not denoted includes not only groups (atomic groups) which have no substituents but also groups (atomic groups) which have substituents. For example, “an alkyl group” includes not only an alkyl group which has no substituents (an unsubstituted alkyl group) but also an alkyl group which has a substituent (a substituted alkyl group).

Also, here, “actinic rays” or “radiation” has the meaning of, for example, a bright line spectrum of a mercury lamp, far ultraviolet rays which are typified by an excimer laser, extreme-ultraviolet rays (EUV light), X-rays, an electron beam, or the like. Also, the term light as used herein means actinic rays or radiation. Unless otherwise specifically indicated, the term “exposure” as used herein includes not only exposure by a mercury lamp, far ultraviolet rays which are typified by an excimer laser, X-rays, EUV light or the like but also drawing using a particle beam such as an electron beam or an ion beam.

In the present specification, the numeric value range represented using “(from) xx to yy” means a range including the numeric value xx as the lower limit value, and the numeric value yy as the upper limit value.

In the present specification, the term total solid means the total mass of the components of the total composition of the coloring composition except the solvent.

Also, in the present specification, “(meth)acrylate” represents both or one of acrylate and methacrylate, “(meth)acryl” represents both or one of acryl and methacryl, and “(meth)acryloyl” represents both or one of acryloyl and methacryloyl.

Also, the monomer in the present specification is distinguished from an oligomer and a polymer, and refers to a compound of a weight average molecular weight of 2000 or less. In the present specification, a polymerizable compound is a compound which has a polymerizable functional group, and may be a monomer or a polymer. A polymerizable functional group is a group which is involved in a polymerization reaction.

In the present specification, the term “colored layer” means the pixel and/or the black matrix which is used in the color filter. In the present specification, the term “step” is not just an independent step, but even in a case where a clear distinction may not be made with other steps, if the anticipated effect of the step is achieved, it is included in the present term.

Coloring Composition

The coloring composition of the present invention includes a resin (A) having a dye structure, the peak area occupied by the component having a molecular weight of 2000 or less is below 10% in respect to the peak area of the total molecular weight distribution of the resin (A) which is measured using gel permeation chromatography (GPC).

A coloring compound of the present invention in which the peak area of the component having a molecular weight of 2000 or less is below 10% in regard to the peak area of the total molecular weight distribution of the resin (A) measured by the GPC of the resin (A), suppresses color loss of the colored pattern to be formed, and may form a colored pattern which has excellent developability and heat resistance. The reason for this is not clear, however it is estimated to be as shown below. When manufacturing a color filter, a low component having a molecular weight of 2000 or less in the resin having a dye structure, by having a great molecular mobility, is easily eluted in the solvent contained in the neighboring colored layers and the developing fluid in the patterning. Therefore, when there is 10% or more of a low molecular weight component of the resin in regard to the peak area of the total molecular weight distribution, it may manifest as a cause of color loss of the colored pattern. Also, as described above, a nucleophilic reaction may occur in the resin molecules which have another dye structure when performing heating such as prebaking due to the molecular mobility of the low molecular weight component being great. Therefore, when there is 10% or more of a low molecular weight component of the resin in regard to the peak area of the total molecular weight distribution, it may manifest as a degradation of the heat resistance of the colored pattern.

Furthermore, the component having a low molecular weight of 2000 or less in the resin having a dye structure has a tendency for the hydrophobicity thereof to increase, and when there is 10% or more in regard to the peak area of the total molecular weight distribution of the resin, it may manifest as a cause of residues when performing developing after pattern exposure from a viewpoint of solubility in respect to the developing fluid.

Conversely, it is estimated that the present invention may suppresses color loss, and form a colored pattern which has excellent developability and heat resistance by setting the peak area of the component having a molecular weight of 2000 or less to below 10% in regard to the peak area of the total molecular weight distribution of the resin (A) which is measured using GPC with regard to the resin (A).

It is preferable that the coloring composition of the present invention be a radiation-sensitive coloring composition which has radiation sensitivity.

It is preferable that the coloring composition of the present invention further contains (B) a pigment, even more preferable that, as well as (A) and (B), it also contains (C) a polymerizable compound, and (D) a photopolymerization initiator, and it is particularly preferable that, as well as (A) to (D), it contains (E) an alkali soluble resin, and, as necessary, may also contain other components such as a cross-linking agent.

Each of the components contained in the coloring composition of the present invention will be described below in detail.

[A resin (A) which has dye structure where a peak area of the molecular weight component of a weight average molecular weight of 2000 or less measured using gel permeation chromatography (GPC) is less than 10% in regard to the peak area of the total molecular weight distribution of the resin (Below, this will also be referred to simply as “resin (A) having a dye structure” or “resin (A)”).]

In the present invention, measurement of the weight average molecular weight using GPC may be performed under the conditions described below, and this may be set to a substituent value based on polystyrene.

Measuring Apparatus: HLC-8120 GPC (manufactured by TOSOH Corporation)
Guard Column: TSKguardcolumn MP (XL) (6.0 mm ID×40 mm L) (manufactured by TOSOH Corporation)
Column: TSKgel Multipore HXL-M (7.8 mm ID×300 mm L)×3 (manufactured by TOSOH Corporation)
Eluent: tetrahydrofuran
Flow rate: Sample pump: 1.0 mL/min, Reference pump: 0.3 mL/min
Temp: Inlet oven: 40° C., Column oven: 40° C., RI detector: 40° C.
Measuring sample injection Amount: After diluting 5 mg of sample with 5 mL of tetrahydrofuran followed by filtering with 0.5 μm of PTFE (polytetrafluoroethylene) membrane filter, inject 100 μL.

In the present invention, the peak area of the component having a molecular weight of 2000 or less is below 10% in regard to the peak area of the total molecular weight distribution of the resin (A) which is measured using GPC with regard to the resin (A), it is preferable that it be 7% or less in regard to the peak area of the total molecular weight of the resin (A), and it is even more preferable that it be 5% or less.

The weight average molecular weight of the resin (A) having a dye structure is preferably from 4000 to 15000, and is further preferably from 5000 to 10000. If the weight average molecular weight is excessively small, it becomes a cause of color loss of the colored pattern which is to be formed, and also becomes a cause of degradation of developability and heat resistance. Also, if the weight average molecular weight is excessively large, the degradation of the color irregularity increases.

In the present invention, as the weight average molecular weight and the numeric average molecular weight, a value which is measured by a polystyrene substituent using the GPC method is used.

Also, the ratio of weight average molecular weight (Mw)/number-average molecular weight (Mn) of the resin (A) having a dye structure is preferably from 1.0 to 3.0, is more preferably from 1.6 to 2. 5 and is most preferably 1.6 to 2.0.

As a method of setting the peak area occupied by the component having a molecular weight of 2000 or less which is measured using GPC with regard to the resin having a dye structure to be less than 10% in respect to the peak area of the total molecular weight distribution of the resin, for example, the resin having a dye structure which was manufactured using a polymerization reaction is provided to a purification method according to the specific reprecipitation method below, thereby setting the peak area may be favorably achieved.

The reprecipitation method is a purification method in which a residual monomer or the like is removed by coagulating a resin, which has the dye structure, in a poor solvent by dropping the polymer reaction solution, which contains a resin having a dye structure after a polymer reaction, into the poor solvent.

For example, the resin which has the dye structure is precipitated as a solid by bringing the solution, which contains a resin which has the dye structure, into contact with a poor solvent, in which the resin which has the dye structure is sparingly insoluble or insoluble, and which is present in a volumetric amount of 10 times or less, preferably from 10 to 5 times, in comparison with the reaction solution, while stirring.

In the present invention, the reprecipitation operation may be performed one time, however, it is preferable to repeat the reprecipitation operation a plurality of times. Specifically, it is preferable that an operation is repeated a plurality of times in which, after the resin is once precipitated and separated, the resin may be dissolved again in a solvent and then bought into contact with a solvent in which the resin is sparingly soluble or insoluble. In other words, it is preferable to repeat a reprecipitation operation a plurality of times, as in a method including, after the completion of a polymerization reaction, bringing the resin into contact with a solvent in which the resin is sparingly soluble or insoluble, to precipitate a resin (step a), separating the resin from the solution (step b), dissolving the resin again in a solvent to prepare a resin solution A (step c), after which the resin solution A is brought into contact with a solvent in which the resin is sparingly soluble or insoluble and which is present in a volumetric amount of less than 10 times (preferably 5 times or less) the resin solution A, precipitating a resin solid (step d), and separating the precipitated resin (step e).

In the present invention, it is more preferable to repeat the reprecipitation operation from 2 to 5 times, even more preferable to repeat the reprecipitation operation from 2 to 4 times, and particularly preferable to repeat the reprecipitation operation 2 or 3 times.

In the reprecipitation operation, it is preferable to perform the operation of bringing the resin into contact with the poor solvent while stirring, and although there is no particular limit to the stirring time, it is preferable to be from 5 to 120 minutes, more preferable to be from 20 to 100 minutes, and even more preferable to be from 30 to 60 minutes. Although there are no particular limits to the rotation speed when stirring, it is preferable to be from 140 to 260 rpm, and even more preferable to be from 180 to 260 rpm.

As the poor solvent (reprecipitation solvent) used when performing the reprecipitation operation with the reaction solution containing a resin which has the dye structure, there are no limits as long as it is a poor solvent of a resin which has the dye structure is favorable, water, an n-hexane, or the like may be exemplified, and it is preferable to be water.

The amount of the reprecipitation solvent used may be appropriately selected by taking into consideration the efficiency, yield and the like, and the amount used is preferably from 100 to 10000 parts by mass, more preferably from 200 to 2000 parts by mass, and further preferably from 300 to 1000 parts by mass, in regard to 100 parts by mass of the polymer solution.

Also, as the reprecipitation solvent, a mixed solvent of the poor solvent and a solvent (good solvent) in which the resin which has the dye structure is soluble or is easily soluble may be used. As the good solvent, acetonitrile, methanol, tetrahydrofuran, N-methyl pyrrolidone, 1-methoxy-2-propanol, ethanol and the like may be exemplified, it is preferable to use acetonitrile, methanol, N-methylpyrrolidone, 1-methoxy-2-propanol, or ethanol and even more preferable to use acetonitrile, methanol, N-methylpyrrolidone, or 1-methoxy-2-propanol.

When using a mixed solvent of a poor solvent and a good solvent as the reprecipitation solvent, the mixing ratio (mass ratio) of the good solvent/the poor solvent is preferably 90/10 to 0/100, more preferably 70/30 to 0/100, and further preferably 50/50 to 20/80.

The temperature when performing the reprecipitation may be appropriately selected by taking into consideration the efficiency or operability, and is preferably from 0 to 50° C., and more preferably in the vicinity of room temperature (for example, approximately from 20 to 35° C.). The reprecipitation operation may be performed using a commonly employed mixing vessel such as stirring tank by a known method such as a batch system or a continuous system.

It is preferable for the resin (A) having a dye structure, more specifically, to be a resin which has a partial structure which has a dye skeleton which is present in the molecular structure at a range where the maximum absorption wavelength is from 400 nm to 780 nm. The resin (A) having a dye structure, for example, functions as a coloring agent in the coloring composition of the present invention.

Hereinafter, the resin (A) having a dye structure (a partial structure derived from dye in the resin (A) having a dye structure, a preferred structure of the resin (A) having a dye structure, a functional group or the like which the resin (A) having a dye structure may have) will be described in detail.

Here, the term “partial structure derived from dye” represents a structure which can connect directly or indirectly to a connecting unit (a polymer chain) of the resin having a dye structure in which hydrogen atoms have been removed from the specific dye (hereinafter also referred to as a dye compound) which may form the dye structure described later.

(Partial Structure Derived from Dye)

As the partial structure (hereinafter, also referred to as “dye structure”) derived from dye in the resin (A) having a dye structure, there is no particular limitation, and various dyes including well-known dye structures may be applied. As well-known dye structures, for example, dye structures derived from azo dyes, azomethine dyes (indoaniline dyes, indophenol dyes or the like), dipyrromethene dyes, quinone-based dyes (benzoquinone dyes, naphthoquinone dyes, anthraquinone dyes, anthrapyridone dyes or the like), carbonium dyes (diphenylmethane dyes, triphenylmethane dyes, xanthene dyes, acridine dyes or the like), quinoneimine dyes (oxazine dyes, thiazine dyes or the like), azine dyes, polymethine dyes (oxonol dyes, merocyanine dyes, arylidene dyes, styryl dyes, cyanine dyes, squarylium dyes, croconium dyes or the like), quinophthalone dyes, phthalocyanine dyes, sub-phthalocyanine dyes, perinone dyes, indigo dyes, thioindigo dyes, quinoline dyes, nitro dyes, nitroso dyes, and dyes selected from metal complex dyes of the above may be exemplified. The resin (A) of the present invention may have one type of the dye structure described above, and may also have two or more types.

Among these dye structures, from a viewpoint of color properties such as color hue, color isolation, and color uneveness, a dye structure derived from a dye which is selected from azo dyes, dipyrromethene dyes, anthraquinone dyes, triphenylmethane dyes, xanthene dyes, cyanine dyes, squarylium dyes, quinophthalone dyes, phthalocyanine dyes, and sub-phthalocyanine dyes is preferable, and a dye structure derived from a dye which is selected from anthraquinone dyes, triphenylmethane dyes, xanthene dyes, cyanine dyes, squarylium dyes, quinophthalone dyes, phthalocyanine dyes, and sub-phthalocyanine dyes is most preferable. Specific dye compounds which can form dye structures are described in “Dye Handbook, new edition” (The Society of Synthetic Organic Chemistry, Japan; Maruzen Company, Limited, 1970), “Color Index” (The Society of Dyers and Colourists), “A Dye Handbook (Ookawara et al; Kodansha Ltd, 1986) and the like.

For the resin (A) having a dye structure of the present invention, a hydrogen atom in the dye structure may be replaced with a substituent selected from the following Substituent Group A.

<Substituent Group A>

As the substituents the resin which may have a dye structure, a halogen atom, an alkyl group, a cycloalkyl group, an alkenyl group, a cycloalkenyl group, an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxy carbonyloxy group, an amino group (including an alkylamino group and an anilino group), an acylamino group, an aminocarbonylamino group, an alkoxycarbonylamino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heterocyclic azo group, an imido group, a phosphino group, a phosphinyl group, a phosphinyloxy group, a phosphinylamino group, a silyl group or the like may be exemplified. Further specific details are described as below.

There may be exemplified by halogen atoms (For example, a fluorine atom, a chlorine atom, a bromine atom and an iodine atom), linear or branched alkayl groups (linear or branched substituted or non-substituted alkyl groups, preferably alkyl groups having 1 to 30 carbon atoms, for example, methyl, ethyl, n-propyl, isopropyl, t-butyl, n-octyl, 2-chloroethyl, 2-cyanoetyl and 2-ethylhexyl), cycloalkyl groups (Preferably, substituted or non-substituted cycloalkyl groups having 3 to 30 carbon atoms, examples include cyclohexyl and cyclopentyl, and groups with polycyclic structure such as multicycloalkyl groups, for example, bicycloalkyl groups (preferably, substituted or non-substituted bicycloalkyl groups having 5 to 30 carbon atoms, for example, bicyclo[1,2,2]heptan-2-yl and bicyclo[2,2,2]octan-3-yl) and tricycloakyl groups. Preferred are monocyclic cycloalkyl groups and bicycloakyl groups, and particularly preferred are monocyclic cycloalkyl groups.)

linear or branched alkenyl groups (linear or branched substituted or non-substituted alkenyl groups, preferably alkenyl groups having 2 to 30 carbon atoms, for example, vinyl, allyl, prenyl, geranyl and oreyl), cycloalkenyl groups (Preferably, substituted or non-substituted cycloalkenyl groups having 3 to 30 carbon atoms, examples include 2-cyclopenten-1-yl and 2-cyclohexen-1-yl, and multicycloalkenyl groups, for example, bicycloalkenyl groups (preferably, substituted or non-substituted bicycloalkenyl groups having to 30 carbon atoms, for example bicyclo[2,2,1]hept-2-en-1-yl and bicyclo[2,2,2]oct-2-en-4-yl) and tricycloakyl groups. Particularly preferred are monocyclic cycloalkenyl groups.), alkynyl groups (preferably, substituted or non-substituted alkynyl groups having 2 to 30 carbon atoms, for example, ethynyl, propalgyl, and trimethylsilylethynyl groups),

aryl groups (preferably, substituted or non-substituted aryl groups having 6 to 30 carbon atoms, for example, phenyl, p-tolyl, naphthyl, m-chlorophenyl, o-hexadecanoyl aminophenyl), heterocyclic groups (preferably, five- to seven-membered, substituted or non-substituted, saturated or unsaturated, aromatic or non-aromatic, monocyclic or fused heterocyclic groups, more preferably, heteroncyclic groups wherein ring constituting atoms are selected from a carbon atom, a nitrogen atom and a sulfur atom and at least one hetero atom of a nitrogen atom, an oxygen atom and a sulfur atom is included, and even more preferably five- or fix-membered aromatic heterocyclic groups having 3 to 30 carbon atoms. For example, 2-furyl, 2-thienyl, 2-pyridyl, 4-pyridyl, 2-pyrimidinyl or 2-benzothiazolyl.), cyano groups, hydroxyl groups, nitro groups, carboxyl groups,

alkoxy groups (preferably, substituted or non-substituted alkoxy groups having 1 to 30 carbon atoms, for example, methoxy, ethoxy, isopropoxy, t-butoxy, n-octyloxy or 2-methoxyethoxy), aryloxy groups (preferably, substituted or unsubstituted aryloxy groups having 6 to 30 carbon atoms, for example, phenoxy, 2-methylphenoxy, 2,4-di-t-amylphenoxy, 4-t-butylphenoxy, 3-nitrophenoxy, or 2-tetradecanoylaminophenoxy), silyloxy groups (preferably silyloxy groups having 3 to 20 carbon atoms, for example, trimethylsilyloxy or t-butyl di methyl silyl oxy), heterocyclic-oxy groups (preferably, substituted or unsubstituted heterocyclic oxy groups having 2 to 30 carbon atoms, while a hetero ring moiety is preferably those explained above for the heterocyclic groups, for example, 1-phenyltetrazole-5-oxy or 2-tetrahydropyranyloxy),

acyloxy groups (preferably, formyloxy groups, substituted or unsubstituted alkylcarbonyloxy groups having 2 to 30 carbon atoms, or substituted or unsubstituted arylcarbonyloxy groups having 6 to 30 carbon atoms, for example, formyloxy, acetyloxy, pivaloyloxy, stearoyloxy, benzoyloxy or p-methoxyphenylcarbonyloxy), carbamoyloxy groups (preferably, substituted or unsubstituted carbamoyloxy groups having 1 to 30 carbon atoms, for example, N,N-dimethylcarbamoyloxy, N,N-diethylcarbamoyloxy, morpholinocarbonyloxy, N,N-di-n-octylaminocarbonyloxy or N-n-octylcarbamoyloxy), alkoxycarbonyloxy groups (preferably, substituted or unsubstituted alkoxycarbonyloxy groups having 2 to 30 carbon atoms, for example, methoxycarbonyloxy, ethoxycarbonyloxy, t-butoxycarbonyloxy or n-octylcarbonyloxy), aryloxycarbonyloxy groups (preferably, substituted or unsubstituted aryloxycarbonyloxy groups having 7 to 30 carbon atoms, for example, phenoxycarbonyloxy, p-methoxyphenoxycarbonyloxy, or p-n-hexadecyloxy-phenoxycarbonyloxy),

amino groups (preferably, amino groups, substituted or unsubstituted alkylamino groups having 1 to 30 carbon atoms, substituted or unsubstituted arylamino groups having 6 to 30 carbon atoms or heterocyclic amino groups having 0 to 30 carbon atoms, for example, amino, methylamino, dimethylamino, anilino, N-methyl-anilino, diphenylamino, or N-1,3,5-triazin-2-ylamino), acylamino groups (preferably, formylamino groups, substituted or unsubstituted alkylcarbonylamino groups having 1 to 30 carbon atoms, substituted or unsubstituted arylcarbonylamino groups having 6 to 30 carbon atoms, for example, formylamino, acetylamino, pivaloylamino, lauroylamino, benzoylamino, 3,4,5-tri-n-octyl oxyphenyl carbonylamino), aminocarbonylamino groups (preferably, substituted or unsubstituted aminocarbonylamino groups having 1 to 30 carbon atoms, for example, carbamoylamino, N,N-dimethylaminocarbonylamino, N,N-diethylaminocarbonylamino or morpholinocarbonylamino), alkoxycarbonylamino groups (preferably, substituted or unsubstituted alkoxycarbonylamino groups having 2 to 30 carbon atoms, for example, methoxycarbonylamino, ethoxycarbonylamino, t-butoxycarbonylamino, n-octadecyloxycarbonylamino or N-methyl-methoxycarbonylamino),

aryloxycarbonylamino groups (preferably, substituted or unsubstituted aryloxycarbonylamino groups having 7 to 30 carbon atoms, for example, phenoxycarbonylamino, p-chlorophenoxycarbonylamino, or m-n-octyloxyphenoxycarbonylamino), sulfamoylamino groups (preferably, substituted or unsubstituted sulfamoylamino groups having 0 to 30 carbon atoms, for example, sulfamoylamino, N,N-dimethylaminosulfonylamino or N-n-octylaminosulfonylamino), alkyl- or aryl-sulfonylamino groups (preferably, substituted or unsubstituted alkylsulfonylamino groups having 1 to 30 carbon atoms, substituted or unsubstituted arylsulfonylamino groups having 6 to 30 carbon atoms, for example, methylsulfonylamino, butylsulfonylamino, phenylsulfonylamino, 2,3,5-trichlorophenylsulfonylamino or p-methylphenylsulfonylamino), mercapto groups,

alkylthio groups (preferably, substituted or unsubstituted alkylthio groups having 1 to 30 carbon atoms, for example, methylthio, ethylthio or n-hexadecylthio), arylthio groups (preferably, substituted or unsubstituted arylthio groups having 6 to 30 carbon atoms, for example, phenylthio, p-chlorophenylthio, m-methoxyphenylthio), heterocyclic thio groups (preferably, substituted or unsubstituted heterocyclic thio groups having 2 to 30 carbon atoms, while a hetero ring moiety is preferably those explained above for the heterocyclic groups, for example, 2-benzothiazolylthio or 1-phenyltetrazol-5-ylthio), sulfamoyl groups (preferably, substituted or unsubstituted sulfamoyl groups having 0 to 30 carbon atoms, for example, N-ethyl sulfamoyl, N-(3-dodecyloxypropyl)sulfamoyl, N,N-dimethylsulfamoyl, N-acetyl sulfamoyl, N-benzoylsulfamoyl or N—(N′-phenylcarbamoyl)sulfamoyl), sulfo groups,

alkyl- or arylsulfinyl groups (preferably, substituted or unsubstituted alkylsulfinyl groups having 1 to 30 carbon atoms, substituted or unsubstituted arylsulfinyl groups having 6 to 30 carbon atoms, for example, methylsulfinyl, ethylsulfinyl, phenylsulfinyl or p-methylphenylsulfinyl), alkyl- or arylsulfonyl groups (preferably, substituted or unsubstituted alkylsulfonyl groups having 1 to 30 carbon atoms, substituted or unsubstituted arylsulfonyl groups having 6 to 30 carbon atoms, for example, methylsulfonyl, ethylsulfonyl phenylsulfonyl or p-methylphenylsulfonyl), acyl groups (preferably, formyl groups, substituted or unsubstituted alkylcarbonyl groups having 2 to 30 carbon atoms, substituted or unsubstituted arylcarbonyl groups having 7 to 30 carbon atoms, for example, acetyl, pivaloyl, 2-chloroacetyl, stearoyl, benzoyl, p-n-octyloxyphenylcarbonyl), aryloxycarbonyl groups (preferably, substituted or unsubstituted aryloxycarbonyl groups having 7 to 30 carbon atoms, for example, phenoxycarbonyl, o-chlorophenoxycarbonyl, m-nitrophenoxycarbonyl or p-t-butylphenoxycarbonyl),

alkoxycarbonyl groups (preferably, substituted or unsubstituted alkoxycarbonyl groups having 2 to 30 carbon atoms, for example, methoxycarbonyl, ethoxycarbonyl t-butoxycarbonyl or n-octadecyloxycarbonyl), carbamoyl groups (preferably, substituted or unsubstituted carbamoyl having 1 to 30 carbon atoms, for example, carbamoyl, N-methylcarbamoyl, N,N-dimethylcarbamoyl, or N,N-di-n-octylcarbamoyl, N-(methylsulfonyl)carbamoyl), aryl- or heterocyclic azo groups (preferably, substituted or unsubstituted arylazo groups having 6 to 30 carbon atoms, substituted or unsubstituted heterocyclic azo groups having 3 to 30 carbon atoms (while a hetero ring moiety is preferably those explained above for the heterocyclic groups), for example, phenylazo, p-chlorophenylazo, 5-ethylthio-1,3,4-thiadiazol-2-ylazo), imide groups (preferably, substituted or unsubstituted imide groups having 2 to 30 carbon atoms, for example, N-succinimide or N-phthalimide), phosphino groups (preferably, substituted or unsubstituted phosphino groups having 2 to 30 carbon atoms, for example, dimethylphosphino, diphenylphosphino or methylphenoxyphosphino), phosphinyl groups (preferably, substituted or unsubstituted phosphinyl groups having 2 to 30 carbon atoms, for example, phosphinyl, dioctyloxyphosphinyl or diethoxyphosphinyl),

phosphinyloxy groups (preferably, substituted or unsubstituted phosphinyloxy groups having 2 to 30 carbon atoms, for example, diphenoxyphosphinyloxy or dioctyloxyphosphinyloxy), phosphinylamino groups (preferably, substituted or unsubstituted phosphinylamino groups having 2 to 30 carbon atoms, for example, dimethoxyphosphinylamino or dimethylaminophosphinylamino), and silyl groups (preferably, substituted or unsubstituted silyl groups having 3 to 30 carbon atoms, for example, trimethylsilyl, t-butyldimethylsilyl or phenyldimethylsilyl).

For those having a hydrogen atom among the functional groups, the portion of the hydrogen atoms among the functional groups may be substituted with any of the groups described above. As examples of the functional groups which can be introduced as the substituents, an alkylcarbonylaminosulfonyl group, an arylcarbonylaminosulfonyl group, an alkylsulfonylaminocarbonyl group, or an arylsulfonylaminocarbonyl group may be exemplified and specifically, a methylsulfonylaminocarbonyl, a p-methylsulfonylaminocarbonyl, an acetylaminosulfonyl, or a benzoylaminosulfonyl group may be exemplified.

Regarding the resin (A) having a dye structure, particularly preferred dyes (dye compound) which form a partial structure derived from dyes will be described in details.

(Dipyrromethene Dye)

An aspect of the resin (A) having a dye structure according to the invention is a resin having a dye structure in which a partial structure derived from dipyrromethene dyes mentioned below is included as a partial structure of dye moiety.

As the dipyrromethene dye according to the invention, preferred are dipyrromethene compounds and dipyrromethene metal complex compounds that can be obtained from a dipyrromethene compound and metal or a metal compound.

Hereinafter, in the present invention, a compound including a dipyrromethene structure is referred to as a dipyrromethene compound and a complex in which the compound including a dipyrromethene structure is coordinated to a metal or a metal complex is referred to as a dipyrromethene metal complex compound.

As the dipyrromethene metal complex compound, a dipyrromethene metal complex compound obtained from a dipyrromethene compound represented by following General Formula (M) and a metal or a metal compound and a tautomer thereof are preferable and among these, the dipyrromethene metal complex compound represented by following General Formula (7) or the dipyrromethene metal complex compound represented by following General Formula (8) may be included as the preferable aspect, the dipyrromethene metal complex compound represented by following General Formula (8) is the most preferable.

[Dipyrromethene Metal Complex Compound Obtained from Dipyrromethene Compound and Metal or Metal Compound Represented by General Formula (M) and Tautomer Thereof]

One of the preferable aspects of the dye structure in the resin (A) having a dye structure is a dye structure including a complex in which the compound (the dipyrromethene compound) represented by following General Formula (M) or the tautomer thereof is coordinated to a metal or a metal compound (hereinafter, appropriately referred to as “a specific complex”) as a dye moiety.

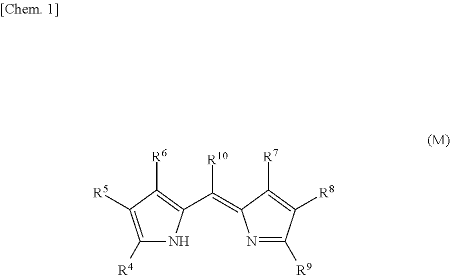

In General Formula (M), R⁴ to R¹⁰ each independently represent a hydrogen atom or a monovalent substituent. However, there are no cases in which R⁴ and R⁹ are bonded to each other to form a ring.

When the compound represented by General Formula (M) is bonded and introduced to a structural unit represented by General Formula (A) to General Formula (C) described below, the bonding site is not particularly limited, however, bonding and introducing at any one site of R⁴ to R⁹ is preferable in terms of synthesis suitability, bonding and introducing at any one of R⁴, R⁶, R⁷ and R⁹ is more preferable, and introducing and bonding at any one of R⁴ and R⁹ is even more preferable.

As the monovalent substituent in a case in which R⁴ to R⁹ in General Formula (M) represent monovalent substituents, substituents described in the above section of the Substituent Group A may be exemplified.

If the monovalent substituent represented as R⁴ to R⁹ in General Formula (M) is a group which can be further substituted, it may have further substituents described in R⁴ to R⁹ and when there are two or more substituents, those substituents may be the same as or different from each other.

R⁴ and R⁵, R⁵ and R⁶, R⁷ and R⁸, and, R⁸ and R⁹ in General Formula (M), each independently, are bonded to each other and may form a five-membered, a six-membered, or a seven-membered saturated ring or unsaturated ring. However, there are no cases in which R⁴ and R⁹ are bonded to each other to form a ring. If the five-membered, the six-membered, or the seven-membered ring which are formed are a group which can be further substituted, they may be substituted with substituents described in R⁴ to R⁹ and when they are substituted by two or more substituents, those substituents may be the same as or different from each other.

When R⁴ and R⁵, R⁵ and R⁶, R⁷ and R⁸, and, R⁵ and R⁹ in General Formula (M), each independently, are bonded to each other and form a five-membered, a six-membered, or a seven-membered saturated ring or unsaturated ring with no substituents, as the five-membered, the six-membered, or the seven-membered saturated ring or unsaturated ring with no substituents, for example, a pyrrole ring, a furan ring, a thiophene ring, a pyrazole ring, an imidazole ring, a triazole ring, an oxazole ring, a thiazole ring, a pyrrolidine ring, a piperidine ring, a cyclopentene ring, a cyclohexene ring, a benzene ring, a pyridine ring, a pyrazine ring, a pyridazine ring or the like may be exemplified, and preferably, a benzene ring or a pyridine ring may be exemplified.

If the alkyl group, the aryl group, and the heterocyclic group in a case in which R10 represents an alkyl group, an aryl group, or a heterocyclic group can be further substituted, they may be substituted with substituents described in Substituent Group A and when they are substituted by two or more substituents, those substituents may be the same as or different from each other.

Metal or Metal Compound

The specific complex in the present invention is a complex in which the dipyrromethene compound represented by General Formula (M) described above or the tautomer thereof is coordinated to a metal or a metal compound.

Here, as the metal or the metal compound, any metal or metal complex which can form a complex can be used and a divalent metal atom, a divalent metal oxide, a divalent metal hydroxide, or a divalent metal chloride is included. As the metal or the metal compound, for example, in addition to metals of Zn, Mg, Si, Sn, Rh, Pt, Pd, Mo, Mn, Pb, Cu, Ni, Co, Fe or the like, a metal chloride such as AlCl, InCl, FeCl, TiCl₂, SnCl₂, SiCl₂ or GeCl₂, a metal oxide such as TiO or VO, or a metal hydroxide such as Si(OH)₂ is included.

Among these, from the viewpoint of stability, spectral characteristics, heat resistance, light resistance, preparation suitability and the like of a complex, Fe, Zn, Mg, Si, Pt, Pd, Mo, Mn, Cu, Ni, Co, TiO or VO is preferable, Zn, Mg, Si, Pt, Pd, Cu, Ni, Co, or VO is even more preferable, and Zn is the most preferable.

Next, more preferable ranges of the specific complex of the compound represented by General Formula (M) in the present invention will be described.

As preferable ranges of the specific complex in the present invention, in General Formula (M), R⁴ and R⁹, are each independently a hydrogen atom, an alkyl group, alkenyl group, an aryl group, a heterocyclic group, a silyl group, a hydroxyl group, a cyano group, an alkoxy group, an aryloxy group, a heterocyclic oxy group, an acyl group, an alkoxycarbonyl group, a carbamoyl group, an amino group, an anilino group, a heterocyclic amino group, a carbonamide group, a ureide group, an imide group, an alkoxycarbonylamino group, an aryloxycarbonylamino group, a sulfonamide group, an azo group, an alkylthio group, an arylthio group, a heterocyclic thio group, an alkylsulfonyl group, an arylsulfonyl group or a phosphinoylamino group, R⁵ and R⁸, are each independently a hydrogen atom, a halogen atom, an alkyl group, alkenyl group, an aryl group, a heterocyclic group, a hydroxyl group, a cyano group, nitro group, an alkoxy group, an aryloxy group, a heterocyclic oxy group, an acyl group, an alkoxycarbonyl group, an aryloxycarbonyl group, a carbamoyl group, an imide group, an alkoxycarbonylamino group, a sulfonamide group, an azo group, an alkylthio group, an arylthio group, a heterocyclic thio group, an alkylsulfonyl group, an arylsulfonyl group or a sulfamoyl group, R⁶ and R⁷, are each independently a hydrogen atom, a halogen atom, an alkyl group, an alkenyl group, an aryl group, a heterocyclic group, a silyl group, a hydroxyl group, a cyano group, an alkoxy group, an aryloxy group, a heterocyclic oxy group, an acyl group, an alkoxycarbonyl group, a carbamoyl group, an anilino group, a carbonamide group, a ureide group, an imide group, a alkoxycarbonylamino group, a sulfonamide group, an azo group, an alkylthio group, an arylthio group, a heterocyclic thio group, an alkylsulfonyl group, an arylsulfonyl group, a sulfamoyl group or a phosphinoylamino group, R¹⁰ are a hydrogen atom, a halogen atom, an alkyl group, an aryl group or a heterocyclic group and the metal or the metal compound is in the range of Zn, Mg, Si, Pt, Pd, Mo, Mn, Cu, Ni, Co, TiO or VO.

As more preferable ranges of the specific complex in the present invention, in General Formula (M), R⁴ to R⁹, are each independently, a hydrogen atom, an alkyl group, alkenyl group, an aryl group, a heterocyclic group, a cyano group, an acyl group, an alkoxycarbonyl group, a carbamoyl group, an amino group, a heterocyclic amino group, a carbonamide group, a ureide group, an imide group, an alkoxycarbonylamino group, an aryloxycarbonylamino group, a sulfonamide group, an azo group, an alkylsulfonyl group, an arylsulfonyl group or a phosphinoylamino group, R⁵ and R⁸, are each independently, an alkyl group, alkenyl group, an aryl group, a heterocyclic group, a cyano group, nitro group, an acyl group, an alkoxycarbonyl group, an aryloxycarbonyl group, a carbamoyl group, an imide group, an alkylsulfonyl group, an arylsulfonyl group or a sulfamoyl group, R⁶ and R⁷, are each independently, a hydrogen atom, an alkyl group, an alkenyl group, an aryl group, a heterocyclic group, a cyano group, an acyl group, an alkoxycarbonyl group, a carbamoyl group, a carbonamide group, a ureide group, an imide group, a alkoxycarbonylamino group, a sulfonamide group, an alkylthio group, an arylthio group, a heterocyclic thio group, an alkylsulfonyl group, an arylsulfonyl group or a sulfamoyl group, R¹⁰ is a hydrogen atom, a halogen atom, an alkyl group, an aryl group or a heterocyclic group, and the metal or the metal compound is in the range of Zn, Mg, Si, Pt, Pd, Cu, Ni, Co or VO.

As particularly preferable ranges of the specific complex in the present invention, in General Formula (M), R⁴ to R⁹, are each independently, a hydrogen atom, an alkyl group, an aryl group, a heterocyclic group, an amino group, a heterocyclic amino group, a carbonamide group, a ureide group, an imide group, an alkoxycarbonylamino group, a sulfonamide group, an azo group, an alkylsulfonyl group, an arylsulfonyl group or a phosphinoylamino group, R⁵ and R⁸, are each independently, an alkyl group, an aryl group, a heterocyclic group, a cyano group, an acyl group, an alkoxycarbonyl group, a carbamoyl group, an alkylsulfonyl group or an arylsulfonyl group, R⁶ and R⁷, are each independently, a hydrogen atom, an alkyl group, an aryl group or a heterocyclic group, R¹⁰ is a hydrogen atom, an alkyl group, an aryl group or a heterocyclic group, and the metal or the metal compound is in the range of Zn, Cu, Co or VO.

Also, dipyrromethene metal complex compounds represented by General Formula (7) or General Formula (8) described below in detail are also particularly preferable aspects.

[Dipyrromethene Metal Complex Compound Represented by General Formula (7)]

A preferred aspect of a dye structure for the resin (A) having a dye structure is a dye structure derived from the dipyrromethene metal complex compound represented by General Formula (7).

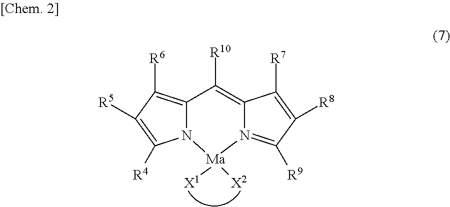

In General Formula (7), R⁴ to R⁹, each independently, represent a hydrogen atom or a monovalent substituent and R¹⁰ represents a hydrogen atom, a halogen atom, an alkyl group, an aryl group or a heterocyclic group. Ma represents a metal atom or a metal compound. X¹ represents a group which can bind to Ma, X² represents a group which neutralizes the charge of Ma, and X¹ and X² are bonded to each other and may form a five-membered, a six-membered, or a seven-membered ring with Ma. However, there are no cases in which R⁴ and R⁹ are bonded to each other to form a ring.

Also, the dipyrromethene metal complex compound represented by following General Formula (7) includes a tautomer.

When the structure including the dipyrromethene metal complex compound represented by General Formula (7) is bonded and introduced to a structural unit represented by General Formula (A) to General Formula (C), the introduction site is not particularly limited, however, introducing at any one site of R⁴ to R⁹ is preferable in terms of synthesis suitability, bonding and introducing at any one of R⁴, R⁶, R⁷ and R⁹ is more preferable, and bonding and introducing at any one of R⁴ and R⁹ is even more preferable.

In a case where the resin (A) having a dye structure has an alkaline-soluble group, as a method to introduce the alkaline-soluble group, a method may be used in which any one, or two or more substituents among R⁴ to R¹⁰, X¹, and X² in the General Formula (7) may have the alkaline-soluble group. Among these substituents, any of R⁴ to R⁹ and X¹ is preferable, any of R⁴, R⁶, R⁷ and R⁹ is more preferable, and any of R⁴ and R⁹ is even more preferable.

The dipyrromethene metal complex compound represented by General Formula (7) may have other functional groups in addition to the alkaline-soluble group as long as the effects of the present invention are not impaired.

R⁴ to R⁹ in General Formula (7) are the same as R⁴ to R⁹ in General Formula (M) and so are the preferable aspects.

In General Formula (7), Ma represents a metal atom or a metal compound. As the metal atom or the metal compound, any metal atom or metal complex which can form a complex can be used and a divalent metal atom, a divalent metal oxide, a divalent metal hydroxide, or a divalent metal chloride is included.

For example, Zn, Mg, Si, Sn, Rh, Pt, Pd, Mo, Mn, Pb, Cu, Ni, Co, Fe or the like, a metal chloride such as AlCl, InCl, FeCl, TiCl₂, SnCl₂, SiCl₂ or GeCl₂, a metal oxide such as TiO or VO, or a metal hydroxide such as Si(OH)₂ is included.

Among these, from the viewpoint of a complex stability, spectral characteristics, heat resistance, light resistance, preparation suitability and the like, as the metal atom or the metal compound, Fe, Zn, Mg, Si, Pt, Pd, Mo, Mn, Cu, Ni, Co, TiO or VO is preferable, Zn, Mg, Si, Pt, Pd, Cu, Ni, Co, or VO is more preferable, Zn, Co, VO and Cu is particularly preferable, and Zn is the most preferable.

Also, in General Formula (7), R¹⁰ represents a hydrogen atom, a halogen atom, an alkyl group, an aryl group or a heterocyclic group and preferably a hydrogen atom.

In General Formula (7), X¹ may be any group which can bind to Ma and specifically, water, alcohols, (for example, methanol, ethanol or propanol), or the like, moreover, compounds described in “Metal Chelates” ([1] Sakaguchi Takeichi, Ueno Keihei (1995, Nankodo Co., Ltd.), [2] (1996), [3] (1997) and the like) may be exemplified. Among these, from the viewpoint of preparation, water, a carboxylic acid compound or alcohols is preferable and water or carboxylic acid compound is more preferable.

In General Formula (7), as the “group which neutralizes the charge of Ma” represented by X², for example, a halogen atom, a hydroxyl group, a carboxylic acid group, a phosphoric acid group, a sulfonic acid group or the like may be included and among these, from the viewpoint of preparation, a halogen atom, a hydroxyl group, a carboxylic acid group, or a sulfonic acid group is preferable, and a hydroxyl group, or a carboxylic acid group is more preferable.

In General Formula (7), X¹ and X² are bonded to each other and may form a five-membered, a six-membered, or a seven-membered ring with Ma. The five-membered, the six-membered, or the seven-membered ring formed may be a saturated ring or an unsaturated ring. Also, the five-membered, the six-membered, or the seven-membered ring may be composed of only carbon atoms, or may form a heterocyclic ring having at least one atom selected from a nitrogen atom, an oxygen atom, or/and a sulfur atom.

As the preferable aspect of the compound represented by General Formula (7), an aspect in which R⁴ to R⁹, each independently, are as described in the description of R⁴ to R⁹ is preferable, an aspect in which R¹⁰ is as described in the description of R¹⁰ is preferable, Ma is Zn, Cu, Co or VO, X¹ is water or a carboxylic acid compound, X² is a hydroxyl group or a carboxylic acid group, and X¹ and X² are bonded to each other and may form a five-membered or a six-membered ring.

[Dipyrromethene Metal Complex Compound Represented by General Formula (8)]

Another preferred aspect of a dye structure for the resin (A) having a dye structure is a dye structure derived from the dipyrromethene metal complex compound represented by General Formula (8).

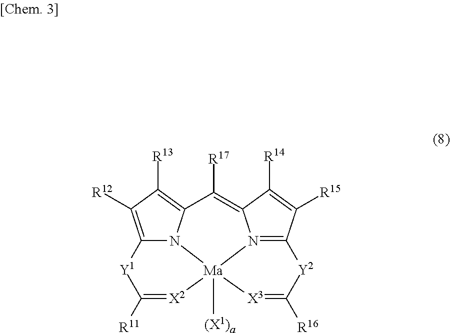

In General Formula (8), R¹¹ and R¹⁶, each independently, represent an alkyl group, an alkenyl group, an aryl group, a heterocyclic group, an alkoxy group, an aryloxy group, an alkylamino group, an arylamino group or a heterocyclic amino group. R¹² to R¹⁵, each independently, represent a hydrogen atom or a substituent. R¹⁷ represents a hydrogen atom, a halogen atom, an alkyl group, an aryl group or a heterocyclic group. Ma represents a metal atom or a metal compound. X² and X³, each independently, represent NR(R represents a hydrogen atom, an alkyl group, an alkenyl group, an aryl group, a heterocyclic group, an acyl group, an alkylsulfonyl group or an arylsulfonyl group), a nitrogen atom, an oxygen atom or a sulfur atom. Y¹ and Y², each independently, represent NR^{c} (R^{c} represents a hydrogen atom, an alkyl group, an alkenyl group, an aryl group, a heterocyclic group, an acyl group, an alkylsulfonyl group or a arylsulfonyl group), a nitrogen atom or a carbon atom. R¹¹ and Y¹ are bonded to each other and may form a five-membered, a six-membered, or a seven-membered ring and R¹⁶ and Y² are bonded to each other and may form a five-membered, a six-membered, or a seven-membered ring. X¹ is a group which can bind to Ma and a represents 0, 1, or 2.

Furthermore, the dipyrromethene metal complex compound represented by General Formula (8) includes a tautomer.

When the structure including the dipyrromethene metal complex represented by General Formula (8) is bonded and introduced to a structural unit represented by General Formula (A) to General Formula (C) which are described later, the introduction site is not particularly limited as long as the effects of the present invention are not impaired, and introducing at any one of R¹¹ to R¹⁷, X¹, Y¹ to Y² is preferable. Among these, in terms of synthesis suitability, bonding and introducing at any one of R¹¹ to R¹⁶ and X¹ is preferable, an aspect bonding and introducing at any one of R¹¹, R¹³, R¹⁴ and R¹⁶ is more preferable, and an aspect bonding and introducing at any one of R¹¹ and R¹⁶ is even more preferable.

In a case where the resin (A) having a dye structure has an alkaline-soluble group, as a method to introduce the alkaline-soluble group, in a case where a dye monomer having an alkaline soluble group or a structural unit is used, a method may be used in which any one, or two or more substituents among R¹¹ to R¹⁷, X¹, and Y¹ to Y² represented by General Formula (8) may have the alkaline-soluble group. Among these substituents, any of R¹¹ to R¹⁶ and X¹ is preferable, any of R¹¹, R¹³, R¹⁴ and R¹⁶ is more preferable, and any of R¹¹ and R¹⁶ is even more preferable.

The structure including the dipyrromethene metal complex compound represented by General Formula (8) may have other functional groups in addition to the alkaline-soluble group as long as the effects of the present invention are not impaired.

The R¹² to R¹⁵ in General Formula (8) are the same as R⁵ to R⁸ in General Formula (M) and so are the preferable aspects. The R¹⁷ is the same as R¹⁰ in General Formula (M) and so are the preferable aspects. Ma is the same as Ma in General Formula (7) and so are the preferable ranges.

More specifically, as the R¹² and R¹⁵ among R¹² to R¹⁵ in General Formula (8), an alkoxycarbonyl group, an aryloxycarbonyl group, a carbamoyl group, an alkylsulfonyl group, an arylsulfonyl group, a nitrile group, an imide group, or a carbamoylsulfonyl group is preferable, an alkoxycarbonyl group, an aryloxycarbonyl group, a carbamoyl group, an alkylsulfonyl group, a nitrile group, an imide group, or a carbamoylsulfonyl group is more preferable, an alkoxycarbonyl group, an aryloxycarbonyl group, a carbamoyl group, a nitrile group, an imide group, or a carbamoylsulfonyl group is even more preferable, and an alkoxycarbonyl group, an aryloxycarbonyl group, a carbamoyl group is particularly preferable.

As the R¹³ and R¹⁴, a substituted or unsubstituted alkyl group, a substituted or unsubstituted aryl group, or a substituted or unsubstituted heterocyclic group is preferable and a substituted or unsubstituted alkyl group or a substituted or unsubstituted aryl group is more preferable. Here, specific examples of more preferable an alkyl group, an aryl group, and a heterocyclic group are the same as the specific examples listed for the R⁶ and R⁷ in General Formula (M).

In General Formula (8), R¹¹ and R¹⁶ represent an alkyl group (a linear, branched, or cyclic alkyl group preferably having 1 to 36 carbon atoms, more preferably having 1 to 12 carbon atoms, and, for example, a methyl group, an ethyl group, a propyl group, an isopropyl group, a butyl group, an isobutyl group, a t-butyl group, a hexyl group, an 2-ethylhexyl group, a dodecyl group, a cyclopropyl group, a cyclopentyl group, a cyclohexyl group, or an 1-adamantyl group), an alkenyl group (an alkenyl group preferably having 2 to 24 carbon atoms, more preferably having 2 to 12 carbon atoms, and, for example, a vinyl group, an allyl group, or a 3-buten-1-yl group), an aryl group (an aryl group preferably having 6 to 36 carbon atoms, more preferably having 6 to 18 carbon atoms, and, for example, a phenyl group or a naphthyl group), a heterocyclic group (a heterocyclic group preferably having 1 to 24 carbon atoms, more preferably having 1 to 12 carbon atoms, and for example, a 2-thienyl group, a 4-pyridyl group, a 2-furyl group, a 2-pyrimidinyl group, a 2-pyridyl group, a 2-benzothiazolyl group, an 1-imidazolyl group, a 1-pyrazolyl group, or a benzotriazol-1-yl group), an alkoxy group (an alkoxy group preferably having 1 to 36 carbon atoms, more preferably having 1 to 18 carbon atoms, and, for example, a methoxy group, an ethoxy group, a propyloxy group, a butoxy group, a hexyloxy group, an 2-ethylhexyloxy group, a dodecyloxy group, or a cyclohexyloxy group), an aryloxy group (an aryloxy group preferably having 6 to 24 carbon atoms, more preferably having 1 to 18 carbon atoms, and, for example, a phenoxy group or a naphthyloxy group), an alkylamino group (an alkylamino group preferably having 1 to 36 carbon atoms, more preferably having 1 to 18 carbon atoms, and, for example, a methylamino group, an ethylamino group, a propylamino group, a butylamino group, a hexylamino group, an 2-ethylhexylamino group, an isopropylamino group, a t-butylamino group, a t-octylamino group, a cyclohexylamino group, an N,N-diethylamino group, an N,N-dipropylamino group, an N,N-dibutylamino group, or an N-methyl-N-ethylamino group), an arylamino group (an arylamino group preferably having 6 to 36 carbon atoms, more preferably having 6 to 18 carbon atoms, and, for example, a phenylamino group, a naphthylamino group, an N,N-diphenylamino group, or an N-ethyl-N-phenylamino group), or a heterocyclic amino group (a heterocyclic amino group preferably having 1 to 24 carbon atoms, more preferably having 1 to 12 carbon atoms, and, for example, a 2-aminopyrrole group, a 3-aminopyrazole group, a 2-aminopyridine group, or a 3-aminopyridine group).

As R¹¹ and R¹⁶, among the above, an alkyl group, an alkenyl group, an aryl group, a heterocyclic group, an alkylamino group, an arylamino group, or a heterocyclic amino group is preferable, an alkyl group, an alkenyl group, an aryl group, or a heterocyclic group is more preferable, an alkyl group, an alkenyl group, or an aryl group is even more preferable, and an alkyl group is particularly preferable.

If an alkyl group, an alkenyl group, an aryl group, a heterocyclic group, an alkoxy group, an aryloxy group, an alkylamino group, an arylamino group, or a heterocyclic amino group of and R¹⁶ in General Formula (8) is a group which can be further substituted, it may be substituted with substituents described as the substituents in the section of the substituent A described before and when there are two or more substituents, those substituents may be the same as or different from each other.

In General Formula (8), X² and X³, each independently, represent NR, a nitrogen atom, an oxygen atom or a sulfur atom. Here, R represents a hydrogen atom, an alkyl group (a linear, branched, or cyclic alkyl group preferably having 1 to 36 carbon atoms, more preferably having 1 to 12 carbon atoms, and, for example, a methyl group, an ethyl group, a propyl group, an isopropyl group, a butyl group, an isobutyl group, a t-butyl group, a hexyl group, an 2-ethylhexyl group, a dodecyl group, a cyclopropyl group, a cyclopentyl group, a cyclohexyl group, or an 1-adamantyl group), an alkenyl group (an alkenyl group preferably having 2 to 24 carbon atoms, more preferably having 2 to 12 carbon atoms, and, for example, a vinyl group, an allyl group, or a 3-buten-1-yl group), an aryl group (an aryl group preferably having 6 to 36 carbon atoms, more preferably having 6 to 18 carbon atoms, and, for example, a phenyl group or a naphthyl group), a heterocyclic group (a heterocyclic group preferably having 1 to 24 carbon atoms, more preferably having 1 to 12 carbon atoms, and, for example, a 2-thienyl group, a 4-pyridyl group, a 2-furyl group, a 2-pyrimidinyl group, a 1-pyridyl group, a 2-benzothiazolyl group, an 1-imidazolyl group, a 1-pyrazolyl group, or a benzotriazol-1-yl group), an acyl group (an acyl group preferably having 1 to 24 carbon atoms, more preferably having 2 to 18 carbon atoms, and, for example, an acetyl group, a pivaloyl group, an 2-ethylhexyl group, a benzoyl group, or a cyclohexanoyl group), an alkylsulfonyl group (an alkylsulfonyl group preferably having 1 to 24 carbon atoms, more preferably having 1 to 18 carbon atoms, and, for example, a methylsulfonyl group, an ethylsulfonyl group, an isopropylsulfonyl group, or a cyclohexylsulfonyl group), or an arylsulfonyl group (an arylsulfonyl group preferably having 6 to 24 carbon atoms, more preferably having 6 to 18 carbon atoms, and, for example, a phenylsulfonyl group or a naphthylsulfonyl group).

In General Formula (8), Y¹ and Y², each independently, represent NR^{c}, a nitrogen atom or a carbon atom, R^{c} is the same as R of X² and X³ and so are the preferable aspects.

In General Formula (8), R¹¹ and Y¹ are bonded to each other and a five-membered ring (for example, a cyclopentane ring, a pyrrolidine ring, a tetrahydrofuran ring, a dioxolane ring, a tetrahydrothiophene ring, a pyrrole ring, a furan ring, a thiophene ring, an indole ring, a benzofuran ring, or a benzothiophene ring), a six-membered ring (for example, a cyclohexane ring, a piperidine ring, a piperazine ring, a morpholine ring, a tetrahydropyran ring, a dioxane ring, a pentamethylene sulfide ring, a dithiane ring, a benzene ring, a piperidine ring, a piperazine ring, a pyridazine ring, a quinoline ring, or a quinazoline ring) or a seven-membered ring (for example, a cycloheptane ring or a hexamethylene imine ring) may be formed with carbon atoms.

In General Formula (8), R¹⁶ and Y² are bonded to each other and a five-membered ring (for example, a cyclopentane ring, a pyrrolidine ring, a tetrahydrofuran ring, a dioxolane ring, a tetrahydrothiophene ring, a pyrrole ring, a furan ring, a thiophene ring, an indole ring, a benzofuran ring, or a benzothiophene ring), a six-membered ring (for example, a cyclohexane ring, a piperidine ring, a piperazine ring, a morpholine ring, a tetrahydropyran ring, a dioxane ring, a pentamethylene sulfide ring, a dithiane ring, a benzene ring, a piperidine ring, a piperazine ring, a pyridazine ring, a quinoline ring, or a quinazoline ring) or a seven-membered ring (for example, a cycloheptane ring or a hexamethylene imine ring) may be formed with carbon atoms.

If a five-membered, a six-membered, and a seven-membered ring formed from R¹¹ and Y¹, and R¹⁶ and Y² bonding in General Formula (8) are rings which can be further substituted, they may be substituted with substituents in the section of the Substituant Group A described above and when there are two or more substituents, those substituents may be the same as or different from each other.

In General Formula (8), R¹¹ and R¹⁶, each independently, is a monovalent substituent with −Es′ value which is a steric parameter of preferably 1.5 or more, more preferably 2.0 or more, even more preferably 3.5 or more, and particularly preferably 5.0 or more. Here, the term steric parameter −Es′ value is a parameter which represents a steric bulkiness of a substituent and −Es′ value described in literatures (J. A. Macphee, et al., Tetrahedron, Vol. 34, pp 3553-3562, Chemistry Special Edition 107, Chemical Structure-Activity Correlation and Drug Design, Edited by Fujita Minorubu, Published on Feb. 20, 1986 (Kagaku Dojin)) is used.

In General Formula (8), X¹ is a group which can bind to Ma and specifically, is the same group as X¹ in General Formula (7) and so are the preferable aspects. a represents 0, 1, or 2.

As the preferable aspect of the compound represented by General Formula (8), an aspect in which R¹² to R¹⁵, each independently, are as described in the description of R⁵ to R⁸ in General Formula (M) is preferable, an aspect in which R¹⁷ is as described in the description or R¹⁰ in General Formula (M) is preferable, Ma is Zn, Cu, Co or VO, X² is NR(R is a hydrogen atom or an alkyl group), a nitrogen atom, or an oxygen atom, X³ is NR(R is a hydrogen atom or an alkyl group) or an oxygen atom, Y¹ is NR^{c} (R^{c} represents a hydrogen atom or an alkyl group), a nitrogen atom or a carbon atom, Y² is a nitrogen atom or a carbon atom, R¹¹ and R¹⁶, each independently, represent an alkyl group, an aryl group, a heterocyclic group, an alkoxy group, or an alkylamino group, X¹ is a group bonding through an oxygen atom, a is 0 or 1, and R¹¹ and Y¹ are bonded to each other and may form a five-membered or a six-membered ring or R¹⁶ and Y² are bonded to each other and may form a five-membered or a six-membered ring.

As the more preferable aspect of the compound represented by General Formula (8), an aspect in which R¹² to R¹⁵, each independently, are as described in the description of R⁵ to R⁸ in the compound represented by General Formula (M) is preferable, an aspect in which R¹⁷ is as described in the description or R¹⁰ in General Formula (M) is preferable, Ma is Zn, X² and X³ are oxygen atoms, Y¹ is NH, Y² is a nitrogen atom, R¹¹ and R¹⁶, each independently, represent an alkyl group, an aryl group, a heterocyclic group, an alkoxy group, or an alkylamino group, X¹ is a group bonding through an oxygen atom, a is 0 or 1, and R¹¹ and Y¹ are bonded to each other and may form a five-membered or a six-membered ring or R¹⁶ and Y² are bonded to each other and may form a five-membered or a six-membered ring.

[100] A molar extinction coefficient of the dipyrromethene metal complex compound represented by General Formula (7) and General Formula (8) is preferably as high as possible from the viewpoint of coloring power. Also, λmax which is a maximum absorption wavelength is preferably 520 nm to 580 nm and more preferably 530 nm to 570 nm from the viewpoint of color purity improvements. Using the coloring composition of the present invention, a color filter with satisfactory color reproducibility may be produced.

Furthermore, in a resin (A) having a dye structure derived from a dipyrromethene dye, with regard to the absorbance at 450 nm, a maximum absorption wavelength (λmax) of greater than or equal to 1000 times is preferable, greater than or equal to 10000 times is more preferable, greater than or equal to 100000 times is even more preferable. By maintaining the ratio in this range, using the coloring composition of the present invention, particularly when a blue color filter is produced, a color filter with higher transmittance may be formed. A maximum absorption wavelength and a molar extinction coefficient are also measured using a spectrophotometer cary 5 (manufactured by Varian, Inc.).

Melting point of the dipyrromethene metal complex represented by General Formula (7) and General Formula (8) may not be excessively high from the viewpoint of solubility.

The dipyrromethene metal complex compound represented by General Formula (7) and General Formula (8) may be synthesized by a method disclosed in U.S. Pat. No. 4,774,339A, U.S. Pat. No. 5,433,896A, JP2001-240761A, JP2002-155052A, JP3614586B, Aust. J. Chem., 1965, 11, 1835-1845, J. H. Boger et al., Heteroatom Chemistry, Vol 1, No. 5, 389 (1990) or the like. Specifically, a method disclosed in paragraphs [0131] to [0157] of JP2008-292970A may be applied.

Specific examples of the dipyrromethene dyes are shown below, however, the present invention is not limited to these.

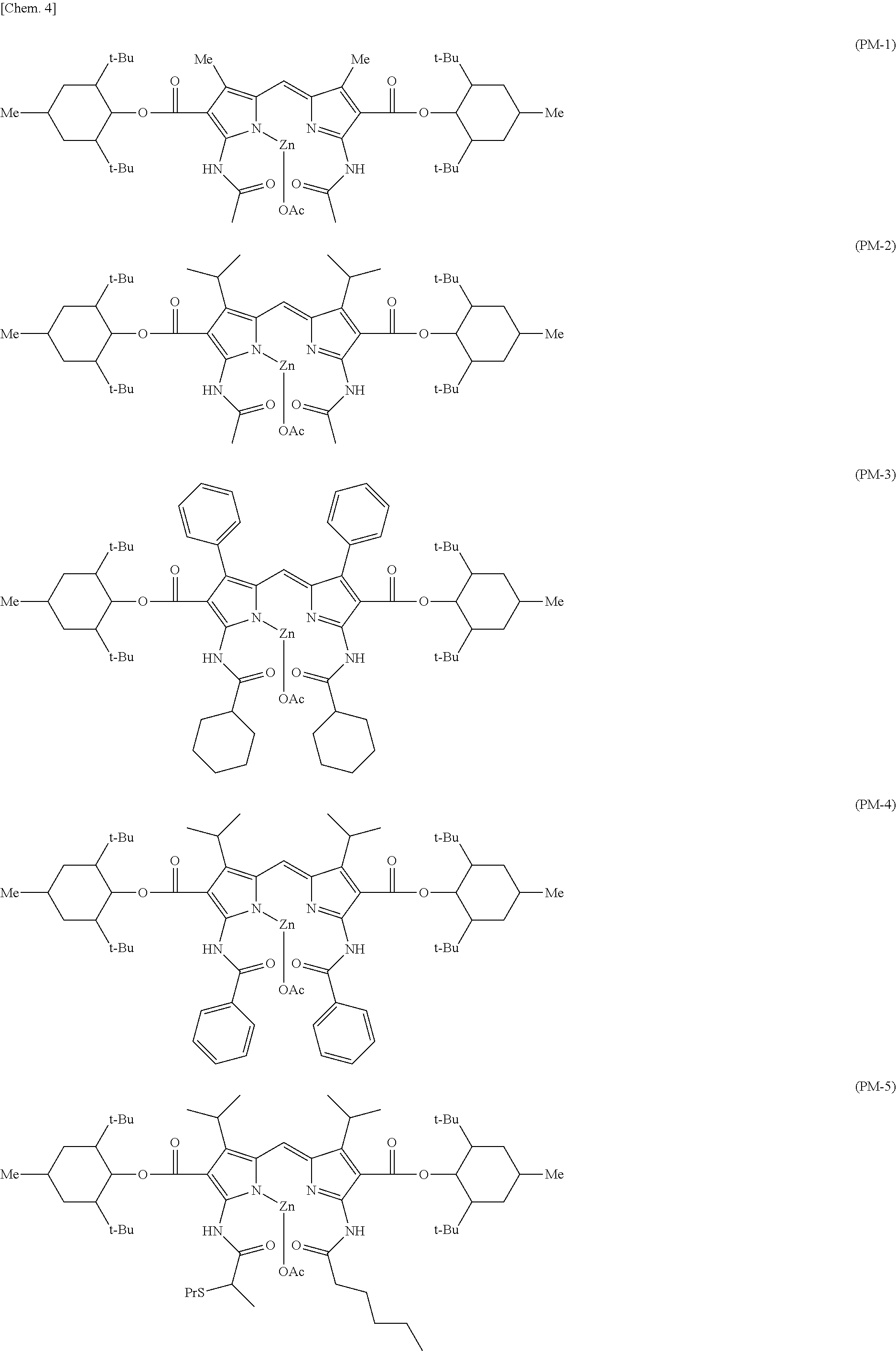

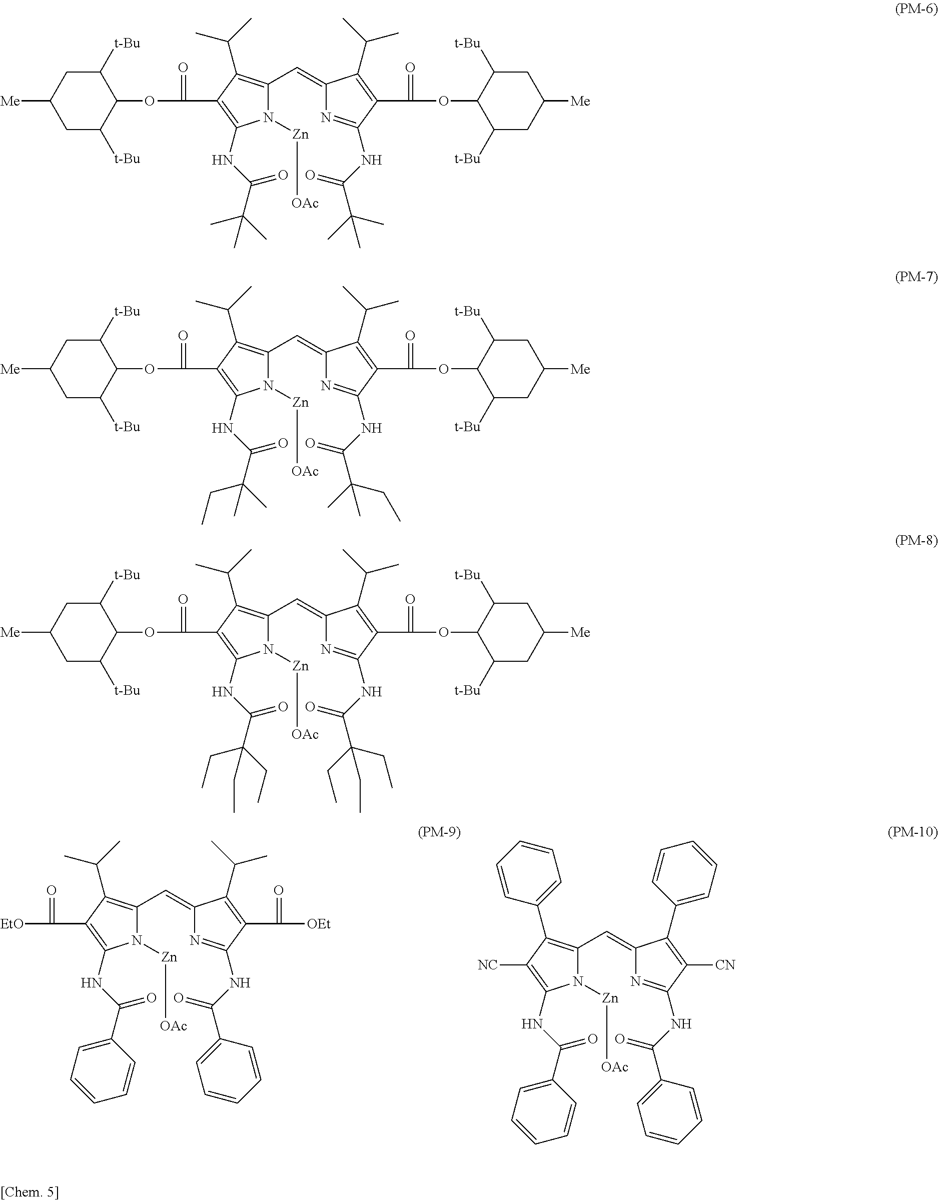

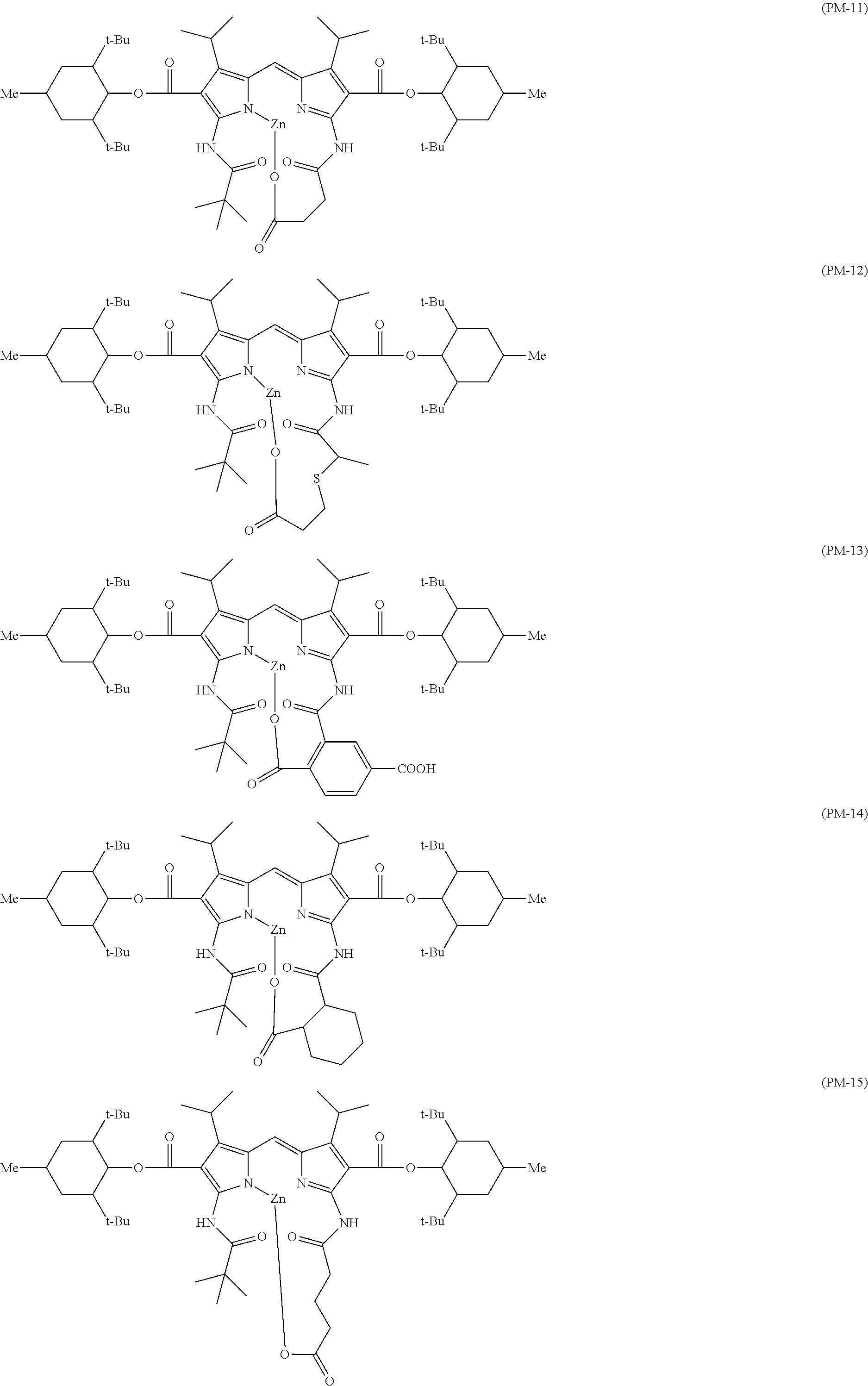

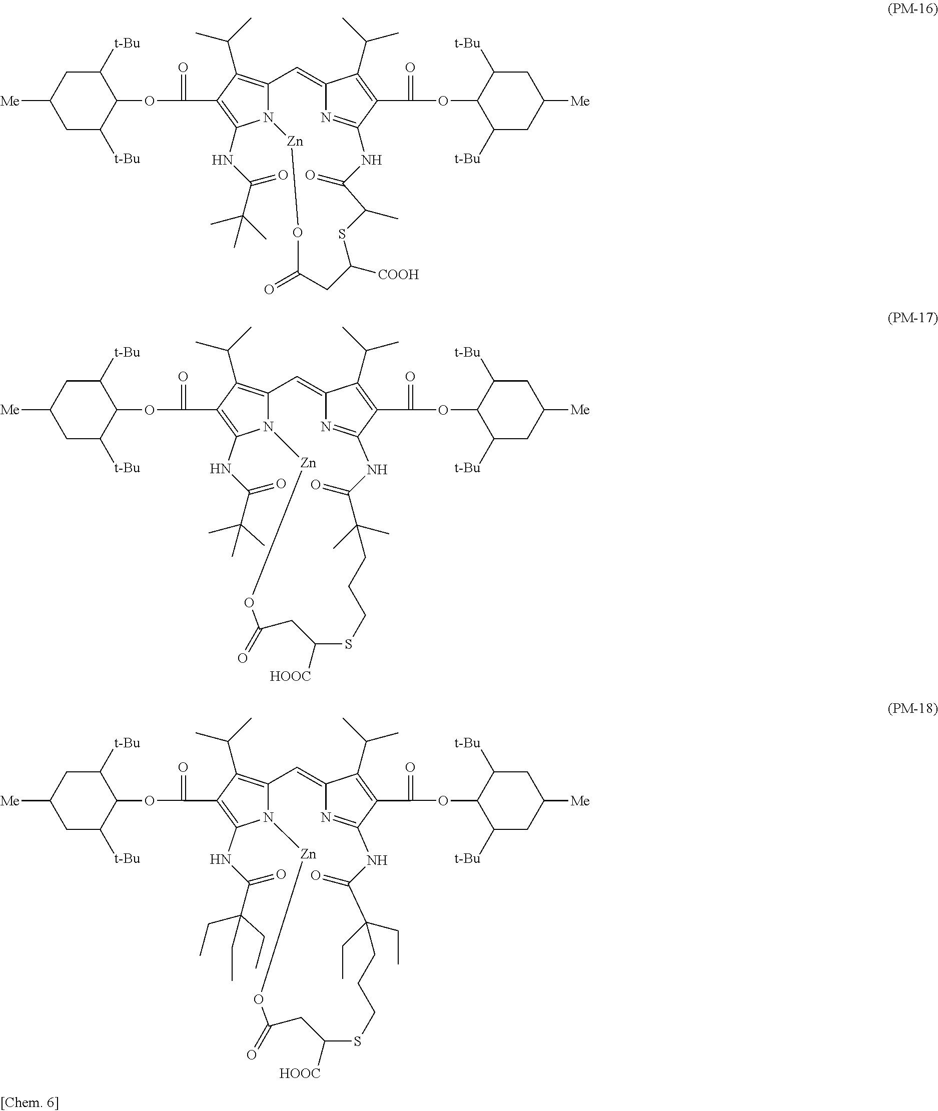

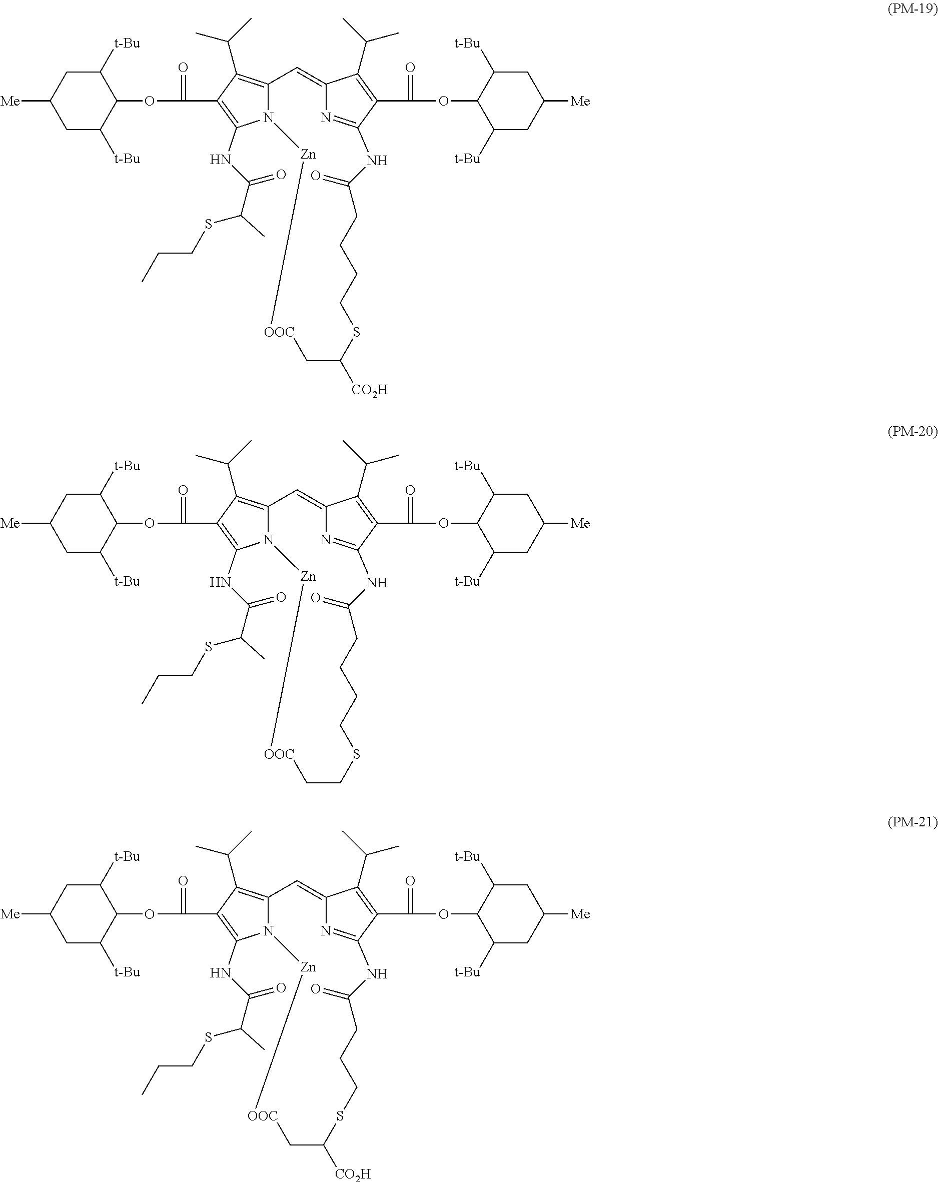

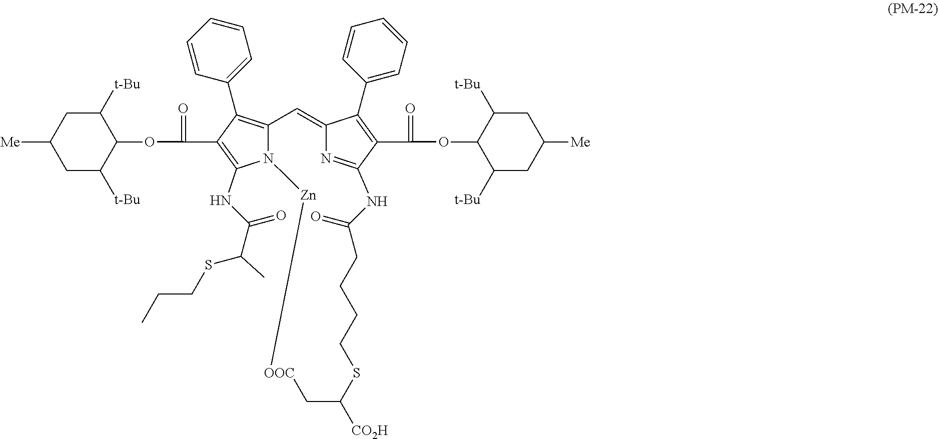

Among the above-mentioned specific examples, particularly (PM-16) to (PM-22) are preferable and (PM-18) is most preferable from the viewpoint of color characteristic, developability and heat resistance.

[Azo Dye]

An aspect of the resin (A) having a dye structure according to the present invention is a resin having a dye structure in which a partial structure derived from azo dyes (azo compound) is included as a partial structure of the dye moiety. The azo compound in the present invention is a collective term of compounds having a dye moiety including an N═N group within the molecule.

As the azo dye, well-known azo dyes (for example, a substituted azobenzene (as specific examples, (AZ-4) to (AZ-6) or the like described later) may be appropriately used.

As the azo dye, azo dyes known as magenta dye and yellow dye can be used, and among these, azo dyes represented by the following General Formulae (d), (e), (g), (I-1), (I-2) and (V) are particularly preferable.

[Magenta Dye]

As the azo dye, an azo dye represented by following General Formula (d) which is a magenta dye is suitably used.

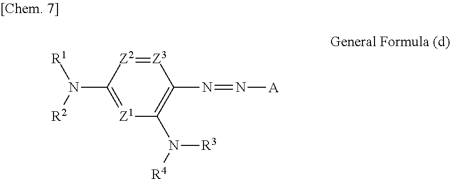

In General Formula (d), R¹ to R⁴, each independently, represent a hydrogen atom, an alkyl group, an alkenyl group, an aryl group, a heterocyclic group, an acyl group, an alkoxycarbonyl group, an aryloxycarbonyl group, a carbamoyl group, an alkylsulfonyl group, or an arylsulfonyl group, A represents an aryl group or an aromatic heterocyclic group, Z¹ to Z³, each independently, represent —C(R⁵)═, or —N═, and R⁵ represents a hydrogen atom or a substituent.

Each substituent of General Formula (d) is described in detail.

In General Formula (d), R¹ to R⁴, each independently, represent a hydrogen atom, an alkyl group (a linear, branched, or cyclic alkyl group preferably having 1 to 36 carbon atoms, more preferably having 1 to 12 carbon atoms, and, for example, methyl, ethyl, propyl, isopropyl, butyl, isobutyl, t-butyl, hexyl, 2-ethylhexyl, dodecyl, cyclopropyl, cyclopentyl, cyclohexyl, or 1-adamantyl), an alkenyl group (an alkenyl group preferably having 2 to 24 carbon atoms, more preferably having 2 to 12 carbon atoms, and, for example, vinyl, allyl, or 3-buten-1-yl), an aryl group (an aryl group preferably having 6 to 36 carbon atoms, more preferably having 6 to 18 carbon atoms, and for example, phenyl or naphthyl), a heterocyclic group (a heterocyclic group preferably having 1 to 24 carbon atoms, more preferably having 1 to 12 carbon atoms, and, for example, 2-thienyl, 4-pyridyl, 2-furyl, 2-pyrimidinyl, 1-pyridyl, 2-benzothiazolyl, 1-imidazolyl, 1-pyrazolyl, or benzotriazol-1-yl), an acyl group (an acyl group preferably having 1 to 24 carbon atoms, more preferably having 2 to 18 carbon atoms, and for example, acetyl, pivaloyl, 2-ethylhexyl, benzoyl, or cyclohexanoyl) an alkoxycarbonyl group (an alkoxycarbonyl group preferably having 1 to 10 carbon atoms, more preferably having 1 to 6 carbon atoms, and, for example, methoxycarbonyl or ethoxycarbonyl), an aryloxycarbonyl group (an aryloxycarbonyl group preferably having 6 to 15 carbon atoms, more preferably having 6 to 10 carbon atoms, and, for example, phenoxycarbonyl), a carbamoyl group (a carbamoyl group preferably having 1 to 8 carbon atoms, more preferably having 2 to 6 carbon atoms, and, for example, dimethylcarbamoyl), an alkylsulfonyl group (an alkylsulfonyl group preferably having 1 to 24 carbon atoms, more preferably having 1 to 18 carbon atoms, and, for example, methylsulfonyl, ethylsulfonyl, isopropylsulfonyl, or cyclohexylsulfonyl), or an arylsulfonyl group (an arylsulfonyl group preferably having 6 to 24 carbon atoms, more preferably having 6 to 18 carbon atoms, and, for example, phenylsulfonyl or naphthyl sulfonyl).

R¹ and R³, preferably, each independently, represent an alkyl group, an alkenyl group, an aryl group, or a heterocyclic group. R² and R⁴, preferably, each independently, represent a hydrogen atom or an alkyl group.

If R¹ to R⁴ are groups which can be substituted, for example, they may be substituted with substituents described in the above section of the Substituent Group A and when there are two or more substituents, those substituents may be the same as or different from each other.

R¹ and R², R¹ and R⁵ (when Z¹ or Z² is —C(R⁵)═), R³ and R⁴, and R³ and R⁵ (when Z¹ is —C(R⁵)═) are bonded to each other and may form a five-membered or a six-membered ring.

Z¹ to Z³, each independently, represent —C(R⁵)═, or —N═, and R⁵ represents a hydrogen atom or a substituent. As the substituents of R⁵, for example, substituents described in the above section of the substituents may be included. If the substituents of R⁵ are groups which can be further substituted, they may be substituted with substituents described in the above section of the Substituent Group A and when there are two or more substituents, those substituents may be the same as or different from each other.

As Z¹ to Z³, it is preferable that Z¹ is —N═, Z² is —C(R⁵)═ or —N═, and Z³ is —C(R⁵)═. More preferably, Z¹ is —N═, and Z² and Z³ are —C(R⁵)═.

A represents an aryl group or an aromatic heterocyclic group. The aryl group and the aromatic heterocyclic group of A may also have, for example, substituents described in the above section of the substituents and when there are two or more substituents, those substituents may be the same as or different from each other.

In General Formula (d), the bonding site when introducing by bonding with structural units represented by General Formulae (A) to (C) which will be described later is not particularly limited, however, introducing by bonding with any one, or two or more of R² and A, and bonding with R1 and/or A is more preferable.

The azo dye represented by General Formula (d) is more preferably an azo dye represented by General Formula (d′).

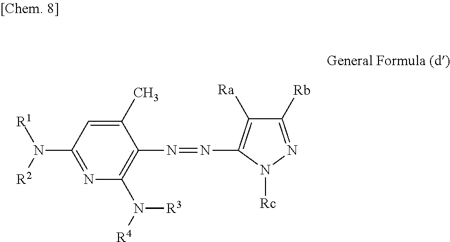

In General Formula (d′), R¹ to R⁴ is the same as those in General Formula (d), and so are the preferable ranges. Ra represents an electron withdrawing group with σp value which is a Hammett substituent constant of 0.2 or more and Rb represents a hydrogen atom or a monovalent substituent. Rc represents an alkyl group, an alkenyl group, an aryl group, a heterocyclic group, an acyl group, an alkoxycarbonyl group, a carbamoyl group, an alkylsulfonyl group or an arylsulfonyl group.

As the substituents of Rb, for example, substituents described in the above section of the Substituent Group A may be exemplified.

As the azo dye, an azo dye represented by following General Formula (e) which is a magenta dye can be suitably exemplified.

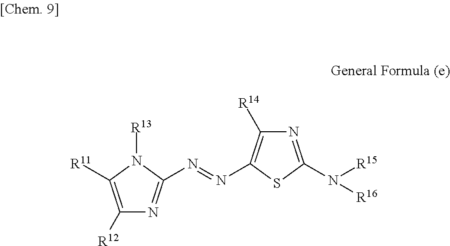

In General Formula (e), R¹¹ to R¹⁶, each independently, represent a hydrogen atom or a monovalent substituent. R¹¹ and R¹², and R¹⁵ and R¹⁶, each independently, are bonded to each other and may form a ring.

Each substituent in General Formula (e) is described in detail.

R¹¹ to R¹⁶, each independently, represent a hydrogen atom or a monovalent substituent. The monovalent substituent may include, for example, a halogen atom, an alkyl group having 1 to 30 carbon atoms (here, meaning a saturated aliphatic group including a cycloalkyl group and a bicycloalkyl group), an alkenyl group having 2 to 30 carbon atoms (here, meaning an unsaturated aliphatic group having a double bond including a cycloalkenyl group and a bicycloalkenyl group), an alkynyl group having 2 to 30 carbon atoms, an aryl group having 6 to 30 carbon atoms, a heterocyclic group having 3 to 30 carbon atoms, a cyano group, an aliphatic oxy group having 1 to 30 carbon atoms, an aryloxy group having 6 to 30 carbon atoms, an acyloxy group having 2 to 30 carbon atoms, a carbamoyloxy group having 1 to 30 carbon atoms, an aliphatic oxycarbonyloxy group having 2 to 30 carbon atoms, an aryloxycarbonyloxy group having 7 to 30 carbon atoms, an amino group having 0 to 30 carbon atoms (including an alkylamino group, an aniline group, and a heterocyclic amino group), an acylamino group having 2 to 30 carbon atoms, an aminocarbonylamino group having 1 to 30 carbon atoms, an aliphatic oxycarbonylamino group having 2 to 30 carbon atoms, an aryloxycarboxylamino group having 7 to 30 carbon atoms, a sulfamoylamino group having 0 to 30 carbon atoms, an alkyl- or arylaminosulfonylamino group having 1 to 30 carbon atoms, an alkylthio group having 1 to 30 carbon atoms, an arylthio group having 6 to 30 carbon atoms, a sulfamoyl group having 0 to 30 carbon atoms, an alkyl- or an arylsulfinyl group having 1 to 30 carbon atoms, an alkyl- or arylsulfonyl group having 1 to 30 carbon atoms, an acyl group having 2 to 30 carbon atoms, an aryloxycarbonyl group having 6 to 30 carbon atoms, an aliphatic oxycarbonyl group having 2 to 30 carbon atoms, a carbamoyl group having 1 to 30 carbon atoms, an aryl- or heterocyclic azo group having 3 to 30 carbon atoms, or an imide group, and each group may have further substituents.

R¹¹ and R¹², preferably, each independently, are a hydrogen atom, a heterocyclic group, a cyano group, and more preferably a cyano group.

R¹³ and R¹⁴, preferably, each independently, are a hydrogen atom, a substituted or unsubstituted alkyl group, a substituted or unsubstituted aryl group, and more preferably a substituted or unsubstituted alkyl group.

R¹⁵ and R¹⁶, preferably, each independently, are a hydrogen atom, a substituted or unsubstituted alkyl group, a substituted or unsubstituted aryl group, and more preferably a substituted or unsubstituted alkyl group.

In General Formula (e), the bonding site when introducing by bonding with structural units represented by General Formulae (A) to (C) which will be described later is not particularly limited, however, introducing by bonding with any one, two or more of R¹³, R¹⁵, and R¹⁶ is preferable in terms of synthesis suitability, bonding with R¹³ and/or R¹⁵ is more preferable, and bonding with R¹³ is even more preferable.

Among the azo dyes mentioned above, the azo dye represented by General Formula (e) is more preferable as a magenta dye.

Yellow Dye

As the azo dye, azo dyes represented by following General Formulae (g), (I-1), (I-2), and (V) which are yellow dyes are suitable (the tautomers thereof are also included).

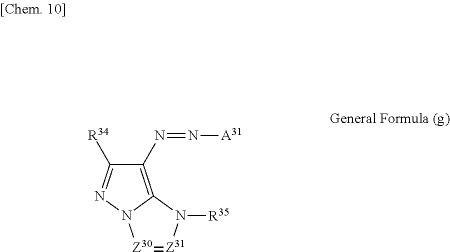

In General Formula (g), R³⁴ represents a hydrogen atom or a substituent, R³⁵ represents a hydrogen atom, an alkyl group, an alkenyl group, an aryl group, a heterocyclic group, an acyl group, an alkoxycarbonyl group, or a carbamoyl group. Z³⁰ and Z³¹, each independently, represent —C(R³⁶)═, or —N═, and R³⁶ represents a hydrogen atom or a substituent. A³¹ represents an aryl group or an aromatic heterocyclic group.

Each substituent in General Formula (g) will be described in details.

R³⁴ represents a hydrogen atom or a monovalent substituent, where substituents mentioned in Substituent Group A described before can be exemplified, and preferred are an aryl group and a heterocyclic group and more preferred is a phenyl group.

R³⁵ represents a hydrogen atom, an alkyl group (a linear, branched, or cyclic alkyl group preferably having the number of carbon atom 1 to 36, more preferably having 1 to 12 carbon atoms, and for example, methyl, ethyl, propyl, isopropyl, butyl, isobutyl, t-butyl, hexyl, 2-ethylhexyl, dodecyl, cyclopropyl, cyclopentyl, cyclohexyl, or 1-adamantyl), an alkenyl group (an alkenyl group preferably having 2 to 24 carbon atoms, more preferably having 2 to 12 carbon atoms, and, for example, vinyl, allyl, or 3-buten-1-yl), an aryl group (an aryl group preferably having 6 to 36 carbon atoms, more preferably having 6 to 18 carbon atoms, and for example, phenyl or naphthyl), a heterocyclic group (a heterocyclic group preferably having 1 to 24 carbon atoms, more preferably having 1 to 12 carbon atoms, and, for example, 2-thienyl, 4-pyridyl, 2-furyl, 2-pyrimidinyl, 1-pyridyl, 2-benzothiazolyl, 1-imidazolyl, 1-pyrazolyl or benzotriazol-1-yl), an acyl group (an acyl group preferably having 1 to 24 carbon atoms, more preferably having 2 to 18 carbon atoms, and, for example, acetyl, pivaloyl, 2-ethylhexyl, benzoyl, or cyclohexanoyl), an alkoxycarbonyl group (an alkoxycarbonyl group preferably having 1 to 10 carbon atoms, more preferably having 1 to 6 carbon atoms, and, for example, methoxycarbonyl group or ethoxycarbonyl group), or a carbamoyl group (a carbamoyl group preferably having 1 to 10 carbon atoms, more preferably having 1 to 6 carbon atoms, and for example, N,N-dimethylcarbamoyl).

Z³⁰ and Z³¹, each independently, represent —C(R³)═ or —N═, and R³⁶ represents a hydrogen atom or a substituent. As the substituent of R³⁶, for example, substituents described in the above section of the Substituent Group A may be included. If the substituents of R³⁶ are groups which can be further substituted, they may be substituted with substituents described in the above section of the Substituent Group A and when there are two or more substituents, those substituents may be the same as or different from each other.

As Z³⁰ and Z³¹, preferably, Z³⁰ is —N═ and Z³¹ is —C(R³⁶)═.

A³¹ is the same as A in General Formula (d) and so are the preferable aspects.

In General Formula (g), the bonding site when introducing by bonding with structural units represented by General Formulae (A) to (C) which will be described later is not particularly limited, however, R³⁴ and/or A³¹ is preferable from a viewpoint of synthesis suitability.

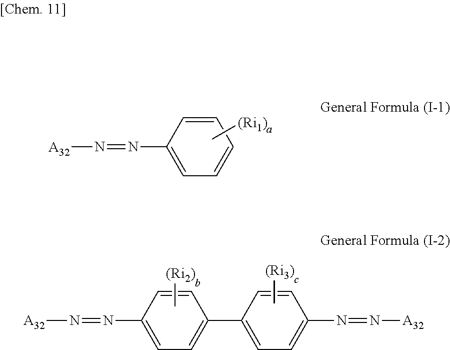

In General Formulae (I-1) and (I-2), Ri₁, Ri₂ and Ri₃ each independently represent a monovalent substituent. a represents an integer of 0 to 5. When a is equal to or greater than 2, two adjacent Ri₁ may link together to form a condensed ring. b and c each independently represent an integer of 0 to 4. When b and c are equal to or greater than 1, two adjacent Ri₁ may link together to form a condensed ring. A₃₂ represents General Formulae (IA), (IB) or (IC) shown below.

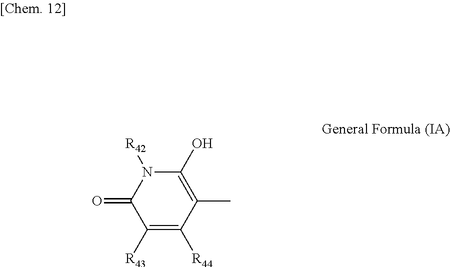

In General Formula (IA), R₄₂ represents a hydrogen atom, an alkyl group or an aryl group. R₄₃ represents a monovalent substituent. R₄₄ represents a hydrogen atom, an alkyl group or an aryl group.

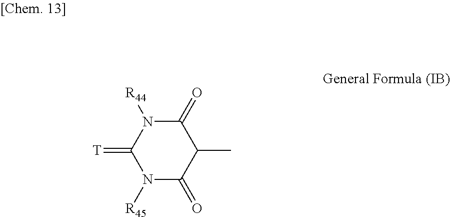

In General Formula (IB), R₄₄ and R₄₅, each independently, represent a hydrogen atom, an alkyl group or an aryl group. T represents an oxygen atom or a sulfur atom.

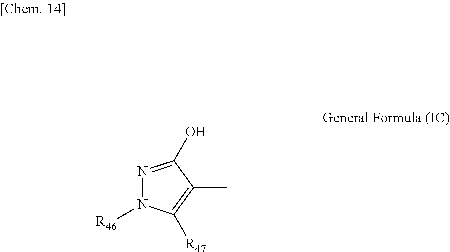

In General Formula (IC), R₄₆ represents a hydrogen atom, an alkyl group or an aryl group. R₄₇ represents a monovalent substituent.

As the monovalent substituents represented by Rᵢ₁, Rᵢ₂, and Rᵢ₃ of General Formula (I-1) and General Formula (I-2), represent, substituents described in the above section of the Substituent Group A may be exemplified. As the monovalent substituent, more specifically, an alkyl group (a linear, branched, or cyclic alkyl group preferably having 1 to 10 carbon atoms, more preferably having 1 to 5 carbon atoms, and for example, methyl, ethyl, propyl, isopropyl, butyl, isobutyl, t-butyl, hexyl, 2-ethylhexyl, dodecyl, cyclopropyl, cyclopentyl, cyclohexyl, or 1-adamantyl), an aryl group (an aryl group preferably having 6 to 36 carbon atoms, more preferably having 6 to 18 carbon atoms, and for example, phenyl or naphthyl sulfonamide groups), an alkenyl group (a linear, branched, or cyclic alkenyl group preferably having 1 to 10 carbon atoms, more preferably having 1 to 5 carbon atoms, and, for example, vinyl, allyl, prenyl, geranyl, or oleyl), a sulfa group, a sulfamoyl group (an alkylsulfamoyl group having preferably 1 to 10 carbon atoms) may be exemplified, and particularly, an alkyl group having 1 to 5 carbon atoms and an alkylsulfamoyl group having 1 to 10 carbon atoms are preferable. a is preferably 1 to 3. b and c are preferably 1 to 3.

In General Formula (IA), R₄₂ represents a hydrogen atom, an alkyl group or an aryl group, and particularly, an alkyl group having the number of carbon atoms 1 to 5 and a phenyl group is preferable. As the monovalent substituent represented by R₄₃, the substituents described in the above section of the Substituent Group A may be exemplified, and particularly, a cyano group or a carbamoyl group is preferable. R₄₄ represents a hydrogen atom, an alkyl group or an aryl group, and particularly, an alkyl group having the number of 1 to 5 carbon atoms and a phenyl group are preferable.

In General Formula (IB), T represents an oxygen atom or a sulfur atom, and an oxygen atom is preferable. R₄₄ and R₄₅, each independently, represent a hydrogen atom, an alkyl group or an aryl group, and particularly, an alkyl group having the number of carbon atoms 1 to 5 and a phenyl group are preferable.

In General Formula (IC), R₄₆ represents a hydrogen atom, an alkyl group or an aryl group, and particularly, an alkyl group having the number of carbon atoms 1 to 5 and a phenyl group is preferable. As the monovalent substituent represented by R₄₇, the substituents described in the section of the Substituent Group A may be exemplified, and a hydrogen atom, an alkyl group, and an aryl group are preferable, and particularly, an alkyl group and a phenyl group having the number of carbon atoms 1 to 5 are preferable.

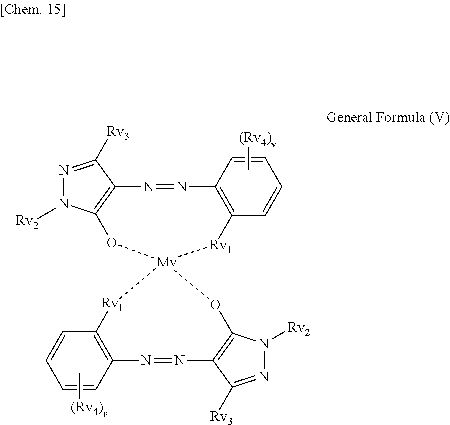

In General Formula (V), My represents Cr or Co. Rv₁ represents an oxygen atom or —COO—. Rv₂ and Rv₃, each independently represent a hydrogen atom, an alkyl group or an aryl group v represents an integer of 0 to 4. Rv₄ represents a monovalent substituent. If v is greater than or equal to 2, the adjacent Rv₄s are bonded and may form a ring.

Rv₂ and Rv₃ is particularly preferably an alkyl group having the number of carbon atoms 1 to 5 and a phenyl group. As the monovalent substituent represented by Rv₄, the substituents described in the above section of the Substituent Group A may be exemplified, and particularly, an alkyl group, or an aryl group, a nitro group, a sulfamoyl group, and a sulfo group are preferable, and an alkyl group having the number of carbon atoms 1 to 5, a phenyl group, and a nitro group is the most preferable.

Among the azo dyes, azo dyes represented by General Formula (I-1), General Formula (I-2), and General Formula (V) are preferable as yellow dyes.

Specific examples of the azo dyes are shown below, however, the present invention is not limited to these

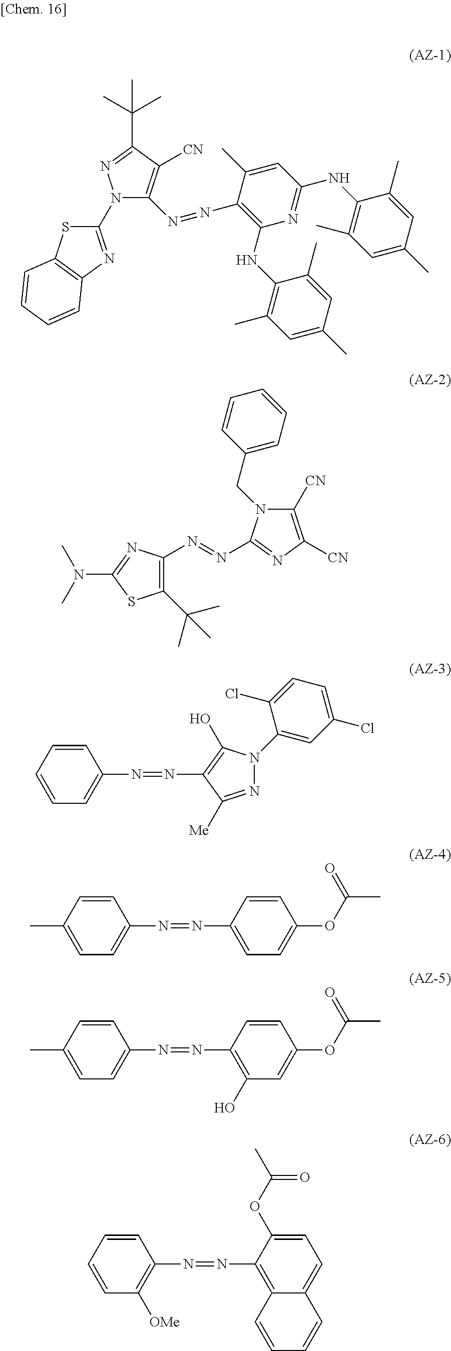

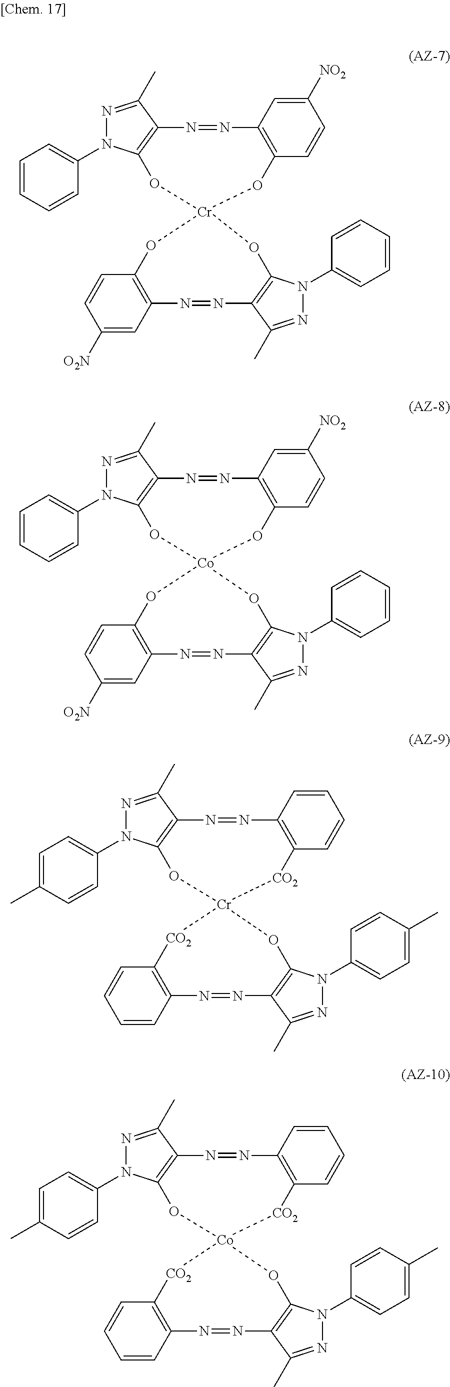

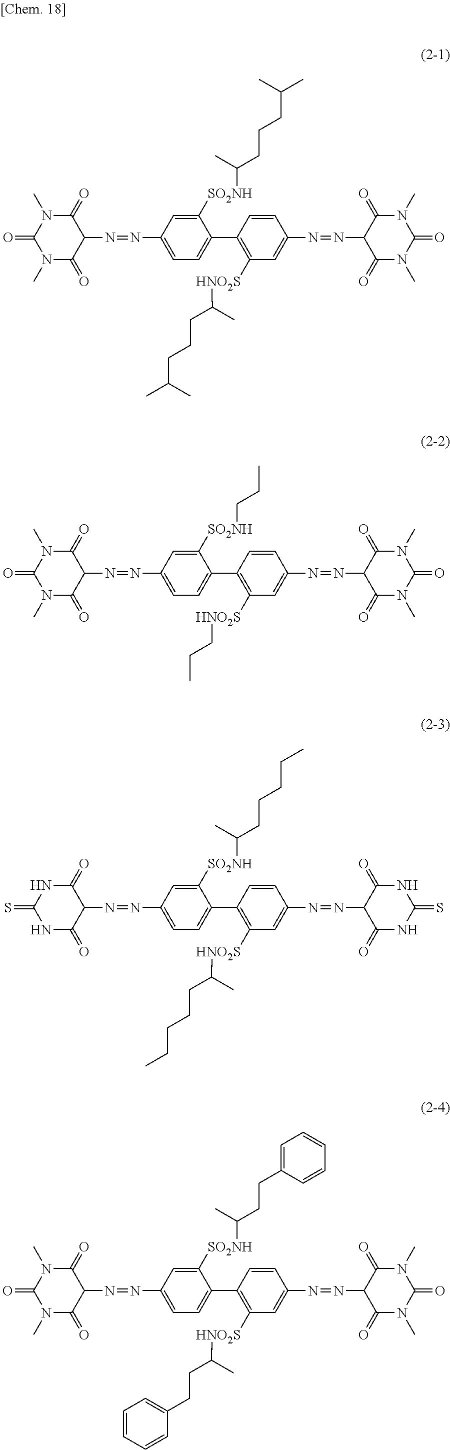

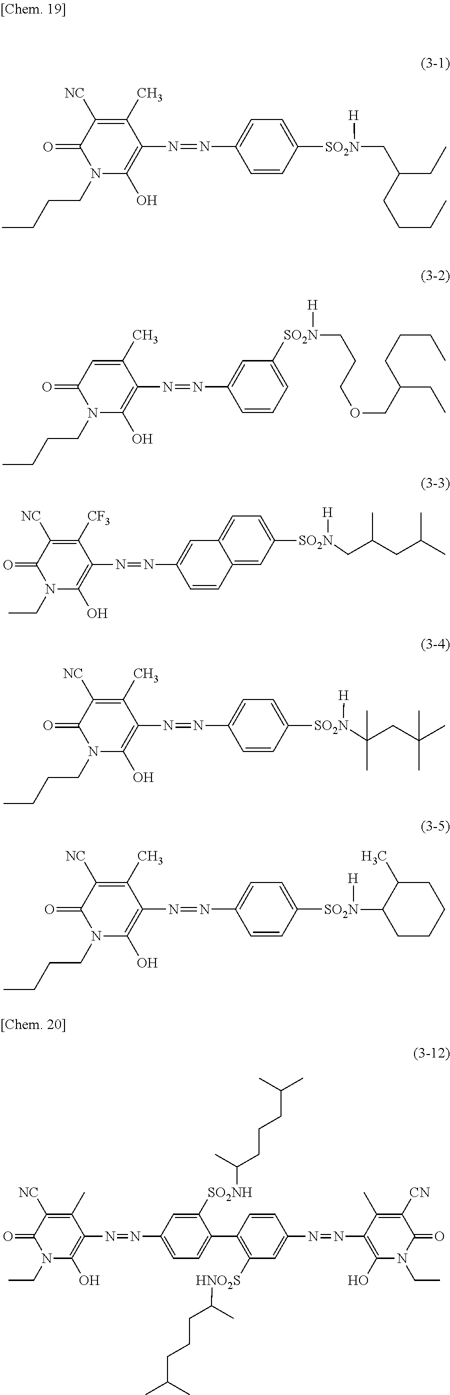

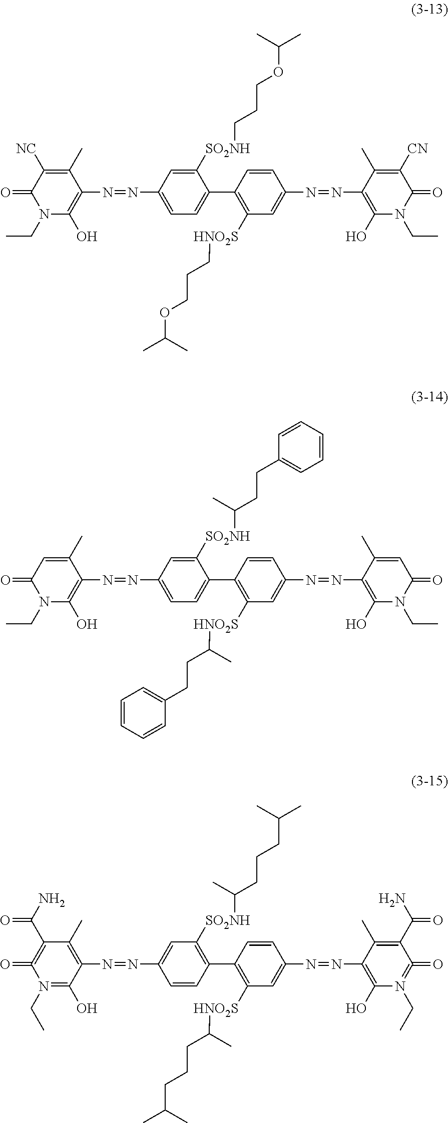

Among the specific examples, from a viewpoint of color properties and heat resistance, in particular, (AZ-7) to (AZ-8), (2-1), (2-2), (2-4), (3-1) to (3-5), and (3-12) to (3-15) are preferable.

(Anthraquinone Dye)

An aspect of the resin (A) having a dye structure according to the present invention, is that it has a partial structure derived from an anthraquinone dye (anthraquinone compound). As the resin (A) having a dye structure, a resin having a dye structure which, as a partial structure of a dye portion, has a partial structure derived from the compound (anthraquinone compound) represented by General Formulas (AQ-1) to (AQ-3) described below is included. The anthraquinone compound in the present invention is a collective term of compounds having a dye portion including an anthraquinone skeleton within the molecule.

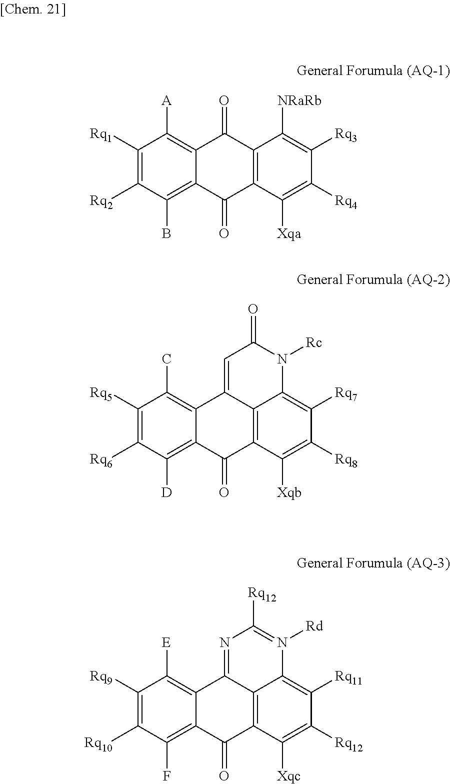

In General Formula (AQ-1), A and B, each independently represent an amino group, a hydroxyl group, an alkoxy group, or a hydrogen atom. Xqa represents ORqa₁ or NRqa₂Rqa₃. Rqa₁ to Rqa₃, each independently represent a hydrogen atom, an alkyl group, or an aryl group. Rq₁ to Rq₄ represent substituents. The substituents which Rq₁ to Rq₄ may take are the same as the substituents described in the above section of the Substituent Group A. Ra and Rb, each independently represent a hydrogen atom, an alkyl group or an aryl group.

In General Formula (AQ-2), C and D are the same as A and B in General Formula (AQ-1). Xqb represents ORqb₁ or NRqb₂Rqb₃. Rqb₁ to Rqb₃, each independently represent a hydrogen atom, an alkyl group, or an aryl group. Rq₅ to Rq₈ represent substituents. Rq₅ to Rq₈ are the same as Rq₁ to Rq₄ in General Formula (AQ-1). Rc is the same as Ra or Rb in General Formula (AQ-1).

In General Formula (AQ-3), E and F are the same as A and B in General Formula (AQ-1). Xqc represents ORqc₁ or NRqc₂Rqc₃. Rqc₁ to Rqc₃, each independently, represent a hydrogen atom, an alkyl group, or an aryl group. Rq₉ to Rq₁₂ are the same as Rq₁ to Rq₄ in General Formula (AQ-1). Rd is the same as Ra or Rb in General Formula (AQ-1).

In General Formula (AQ-1), A and B are preferably hydrogen atoms. Xqa is preferably ORqa₁ (Rqa₁ is a hydrogen atom, an alkyl group having the number of carbon atoms 1 to 5, or a phenyl group), or NRqa₂Rqa₃ (Rqa₂ is a hydrogen atom, Rqa₃ is an alkyl group having the number of carbon atoms 1 to 5, or a phenyl group). Rq₁ to Rq₄ are preferably a hydrogen atom, a halogen atom or an alkoxy group. Ra is preferably a hydrogen atom. Rb is preferably a hydrogen atom, an alkyl group having the number of carbon atoms 1 to 5, or a phenyl group.

In General Formula (AQ-2), C and D are preferably hydrogen atoms. Xqb is preferably ORqb₁ (Rqb₁ is a hydrogen atom, an alkyl group having the number of carbon atoms 1 to 5, or a phenyl group), or NRqb₂Rbq₃ (Rqb₂ is a hydrogen atom, Rqb₃ is an alkyl group having the number of carbon atoms 1 to 5, or a phenyl group). Rq₅ to Rq₈ are preferably a hydrogen atom, a halogen atom or an alkoxy group. Rc is preferably a hydrogen atom, an alkyl group having the number of carbon atoms 1 to 5, or a phenyl group.

In General Formula (AQ-3), E and F are preferably hydrogen atoms. Xqc is preferably ORqc₁ (Rqc₁ is a hydrogen atom, an alkyl group having the number of carbon atoms 1 to 5, or a phenyl group), or NRqc₂Rcq₃ (Rqc₂ is a hydrogen atom, Rqc₃ is an alkyl group having the number of carbon atoms 1 to 5, or a phenyl group). Rq₉ to Rq₁₂ are preferably a hydrogen atom, a halogen atom or an alkoxy group. Rd is preferably a hydrogen atom, an alkyl group having the number of carbon atoms 1 to 5, or a phenyl group.

Specific examples of the anthraquinone dyes are shown below, however, the present invention is not limited to these.

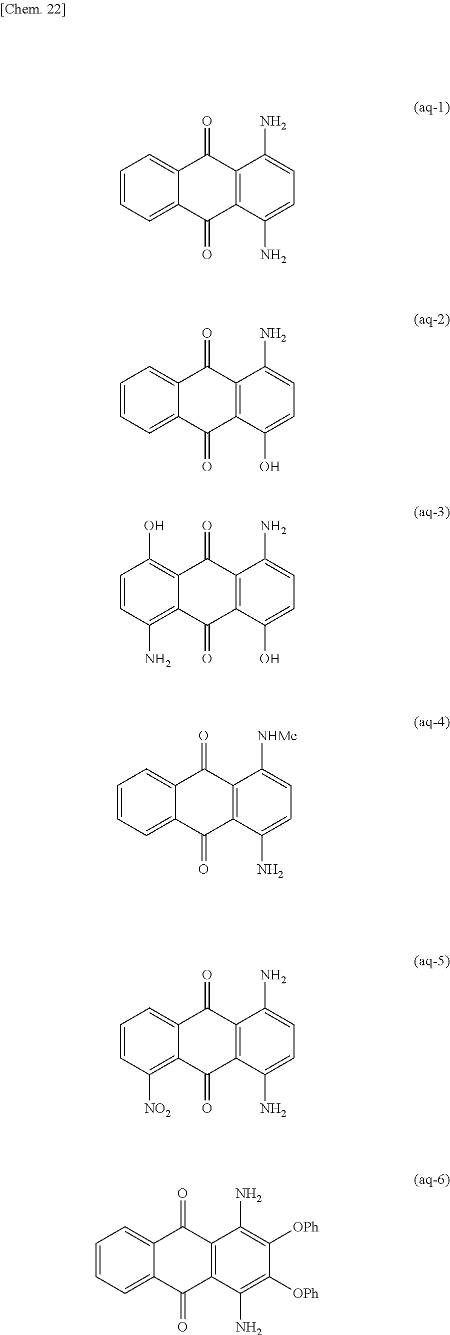 [SMILES: Nc1ccc(N)c2c1C(=O)c1ccccc1C2=O ; Nc1ccc(O)c2c1C(=O)c1ccccc1C2=O ; Nc1ccc(O)c2c1C(=O)c1c(O)ccc(N)c1C2=O ; CNc1ccc(N)c2c1C(=O)c1ccccc1C2=O ; Nc1ccc(N)c2c1C(=O)c1cccc([N+](=O)[O-])c1C2=O ; Nc1c(Oc2ccccc2)c(Oc2ccccc2)c(N)c2c1C(=O)c1ccccc1C2=O]

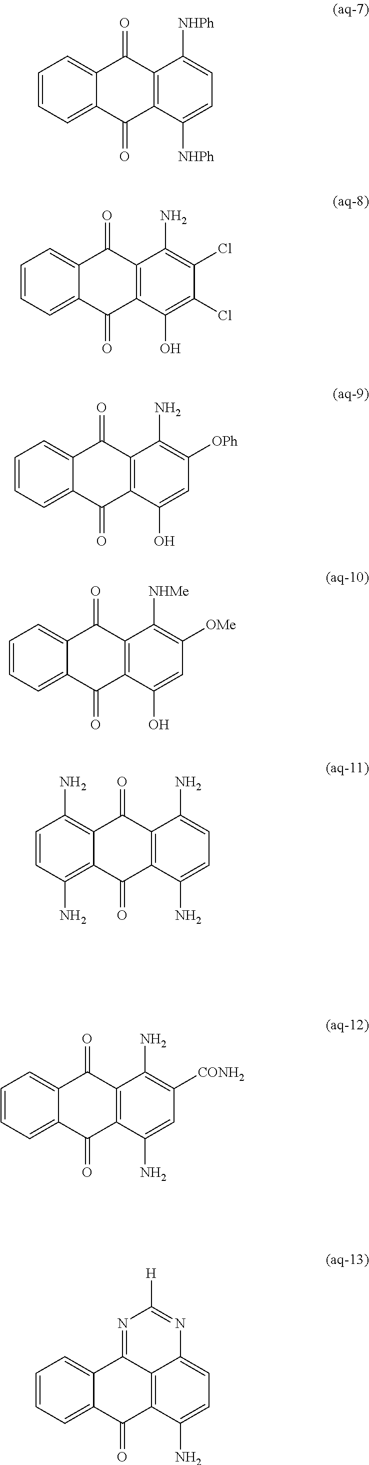

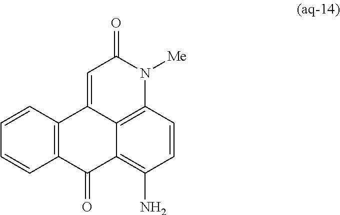 [SMILES: Cn1c(=O)cc2c3c(c(N)ccc31)C(=O)c1ccccc1-2]

Among the specific examples above, from a viewpoint of color properties and heat resistance, in particular, (aq-1) to (aq-4), (aq-13), and (aq-14) are preferable.

(Triphenylmethane Dye)

An aspect of the resin having a dye structure according to the present invention, is that it has a partial structure derived from a triphenylmethane dye (triphenylmethane compound). As the resin (A) having a dye structure, a resin having a dye structure which, as a partial structure of a dye portion, has a partial structure derived from the compound (triphenylmethane compound) represented by General Formula (TP) described below is included. The triphenylmethane compound in the present invention is a collective term of compounds having a dye portion including a triphenylmethane skeleton within the molecule.

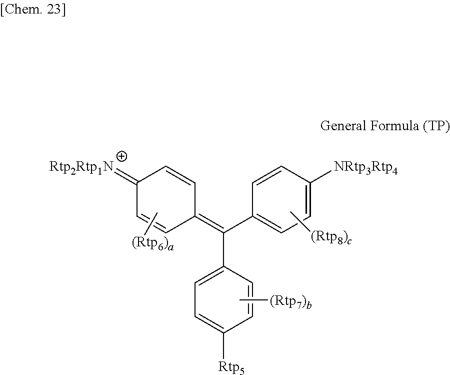

In General Formula (TP), Rtp₁ to Rtp₄ each independently represent a hydrogen atom, an alkyl group, or an aryl group. Rtp₅ represents a hydrogen atom, an alkyl group, an aryl group, or NRtp₉Rtp₁₀ (Rtp₉ and Rtp₁₀ represent a hydrogen atom, an alkyl group, an aryl group). Rtp₆, Rtp₇, and Rtp₈ represent substituents. a, b, and c represent integers of 0 to 4. If a, b, and c are greater than or equal to 2, Rtp₆, Rtp₇, and Rtp₈ may be bonded to each other and may form a ring. X⁻ represents an anion.

As Rtp₁ to Rtp₆, a hydrogen atom, a linear or branched alkyl group having the number of carbon atoms 1 to 5 and a phenyl group are preferable. Rtp₅ is preferably a hydrogen atom or NRtp₉Rtp₁₀, NRtp₉Rtp₁₀ is the most preferable. Rtp₉ and Rtp₁₀ are preferably a hydrogen atom, a linear or branched alkyl group having the number of carbon atoms 1 to 5 and a phenyl group. As the substituents represented by Rtp₆, Rtp₇ and Rtp₈, substituents described in the above section of the Substituent Group A may be used, however, particularly, a linear or branched alkyl group having the number of carbon atoms 1 to 5, an alkenyl group having the number of carbon atoms 1 to 5, an aryl group having the number of carbon atoms 6 to 15, a carboxyl group, or a sulfo group are preferable, and a linear or branched alkyl group having the number of carbon atoms 1 to 5, an alkenyl group having the number of carbon atoms 1 to 5, a phenyl group or a carboxylic group are more preferable. Particularly, as Rtp₆ and Rtp₈, an alkyl group having the number of carbon atoms 1 to 5 is preferable and as Rtp₇, an alkenyl group (particularly, a phenyl group in which adjacent two alkenyl groups are bonded is preferable), a phenyl group or a carboxyl group are preferable.

a, b, or c each independently represent integers of 0 to 4. In particular, a and b are preferably 0 to 1, and c is preferably 0 to 2.

X⁻ represents an anion. As X⁻, specifically, an inorganic anion such as a fluorine anion, a chlorine anion, a bromine anion, an iodine anion, a perchlorate anion, a thiocyanate anion, a hexafluoride phosphate anion, a hexafluoride antimonate anion, or a tetrafluoride borate anion, a carboxylate anion such as an acetate anion or a benzoate anion, an organic sulfonate anion such as a benzene sulfonate anion, a toluene sulfonate anion, a trifluoromethane sulfonate anion, an organic phosphate anion such as an octylphosphate anion, a dodecylphosphate anion, an octadecylphosphate anion, a phenylphosphate anion, or a nonylphenyl phosphate anion or the like may be exemplified. X⁻ is preferably ion bonded to the dye structure, and may also be bonded to part of the resin having a dye structure (a polymer chain and the like).

X⁻ is preferably a fluorine anion, a chlorine anion, a bromine anion, an iodine anion, a perchlorate anion, or a carboxylate anion and a perchlorate anion, or a carboxylate anion is the most preferable.

Specific examples of the compound represented by General Formula (TP) are described below, however, the present invention is not limited to these.

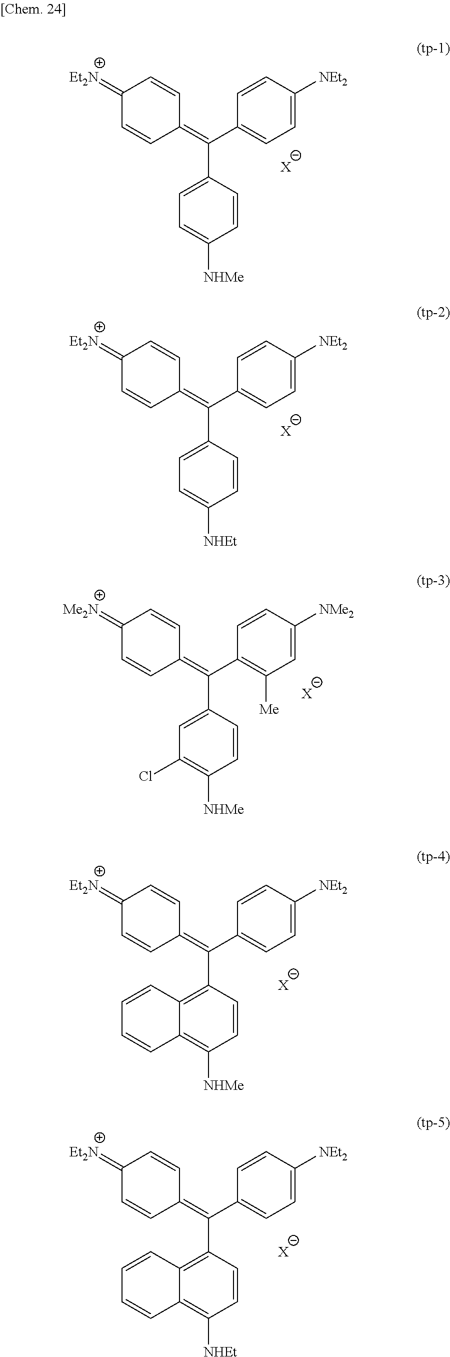

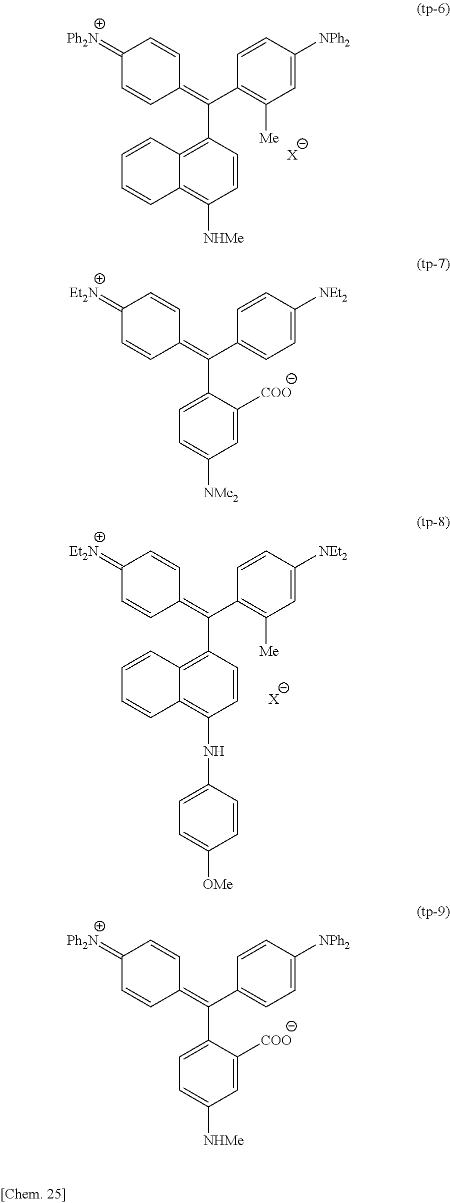

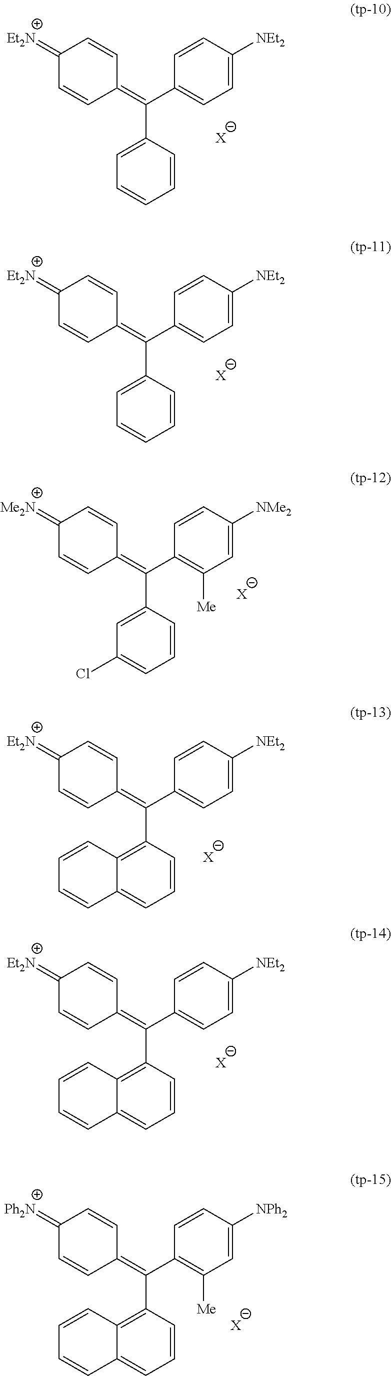

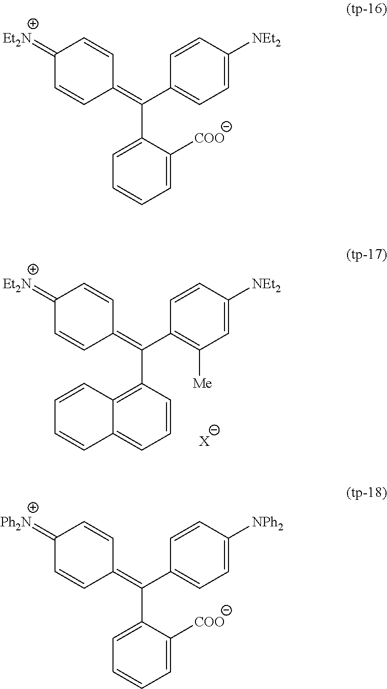

Among the specific examples, from a viewpoint of color properties and heat resistance, in particular, (tp-4), (tp-5), (tp-6), and (tp-8) are preferable.

(Xanthene Dye)

A preferable aspect of the resin having a dye structure according to the present invention, is that it has a partial structure derived from a xanthene dye (xanthene compound). As the resin (A) having a dye structure, a resin having a dye structure which, as a partial structure of a dye portion, has a partial structure derived from the xanthene compound represented by General Formula (J) described below is included.

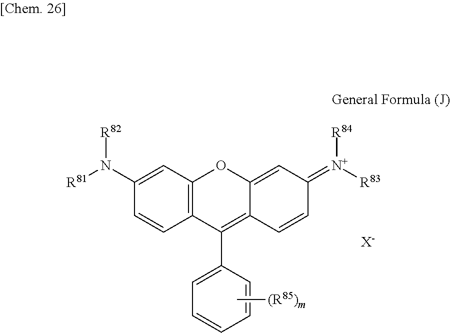

In General Formula (J), R⁸¹, R⁸², R⁸³, and R⁸⁴, each independently, represent a hydrogen atom or a monovalent substituent. R⁸⁵s, each independently, represent a monovalent substituent and m represents an integer of 0 to 5. X⁻ represents an anion.

The substituents R⁸¹ to R⁸⁴ and R⁸⁵ may take in General Formula (J) are the same as the substituents described in the above section of the Substituent Group A.

When R⁸¹ and R⁸², R⁸³ and R⁸⁴, and R⁸⁵s when m are greater than or equal to 2 in General Formula (J), each independently, are bonded to each other and may form a five-membered, a six-membered or a seven-membered saturated ring, or a five-membered, a six-membered or a seven-membered unsaturated ring. If the five-membered, the six-membered, or the seven-membered ring formed are groups which can be further substituted, they may be substituted with substituents described in R⁸¹ to R⁸⁵ and when they are substituted by two or more substituents, those substituents may be the same as or different from each other.

In a case in which, when R⁸¹ and R⁸², R⁸³ and R⁸⁴, and R⁸⁵s when m are greater than or equal to 2 in General Formula (J), each independently, are bonded to each other and form a five-membered, a six-membered and a seven-membered saturated ring, or a five-membered, a six-membered or a seven-membered unsaturated ring which has no substituent, a pyrrole ring, a furan ring, a thiophene ring, a pyrazole ring, an imidazole ring, a triazole ring, an oxazole ring, a thiazole ring, a pyrrolidine ring, a piperidine ring, a cyclopentene ring, a cyclohexene ring, a benzene ring, a pyridine ring, a pyrazine ring, a pyridazine ring may be exemplified, and preferably, a benzene ring or a pyridine ring may be exemplified as the five-membered, the six-membered, or the seven-membered saturated ring or the five-membered, the six-membered or the seven-membered unsaturated ring which has no substituent.

Particularly, R⁸² and R⁸³ are hydrogen atoms and R⁸¹ and R⁸⁴ are preferably substituted or unsubstituted phenyl groups. Also, R⁸⁵ is preferably a halogen atom, a linear or branched alkyl group having the number of carbon atoms 1 to 5, a sulfo group, a sulfonamide group, or a carboxyl group. The phenyl groups of R⁸¹ and R⁸⁴ which have substituents are most preferably a hydrogen atom, a halogen atom, a linear or branched alkyl group having the number of carbon atoms 1 to 5, a sulfo group, a sulfonamide group, or a carboxyl group.

X⁻ represents an anion. As X⁻, specifically, an inorganic anion such as a fluorine anion, a chlorine anion, a bromine anion, an iodine anion, a perchlorate anion, a thiocyanate anion, a hexafluoride phosphate anion, a hexafluoride antimonate anion, or a tetrafluoride borate anion, a carboxylate anion such as an acetate anion or a benzoate anion, an organic sulfonate anion such as a benzene sulfonate anion, a toluene sulfonate anion, a trifluoromethane sulfonate anion, an organic phosphate anion such as an octylphosphate anion, a dodecylphosphate anion, an octadecylphosphate anion, a phenylphosphate anion, or a nonylphenyl phosphate anion or the like may be exemplified. X⁻ may be bonded to the dye skeleton or to part of the resin having a dye structure (a polymer chain and the like).

X⁻ is preferably a fluorine anion, a chlorine anion, a bromine anion, an iodine anion, a perchlorate anion, or a carboxylate anion and a perchlorate anion, or a carboxylate anion is the most preferable.

Compounds having xanthene skeletons represented by General Formula (J) may be synthesized using the method disclosed in literatures. Specifically, methods disclosed in Tetrahedron Letters, 2003, vol. 44, No. 23, pp 4355 to 4360 and Tetrahedron, 2005, vol. 61, No. 12, pp 3097 to 3106, and the like may be applied.

Specific examples of the xanthene compounds are shown below, however, the present invention is not limited to these.

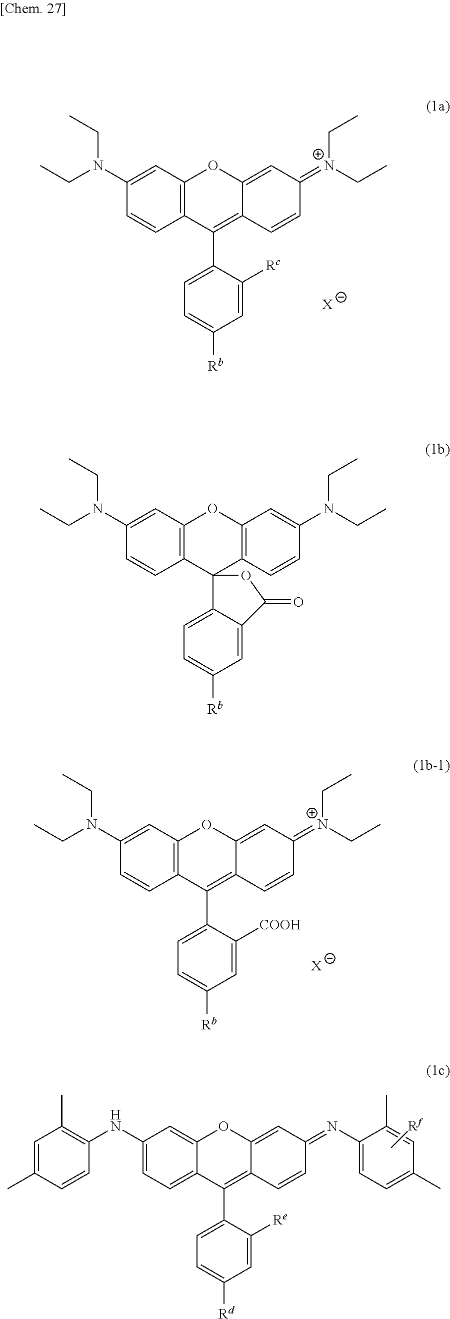

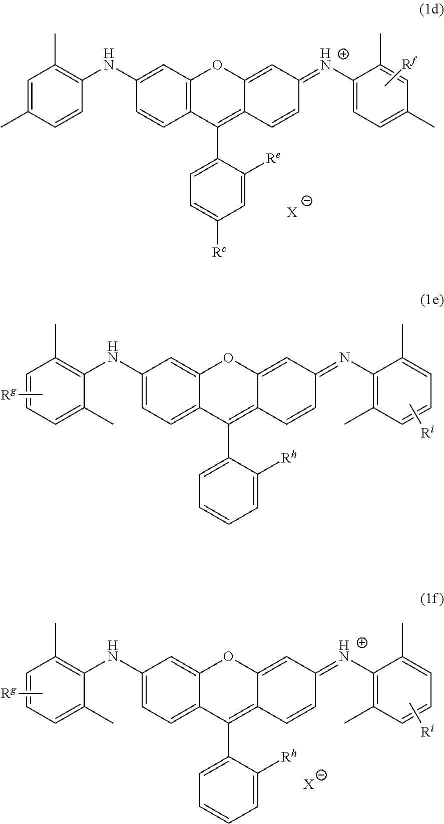

In Formulas (1a) to (1f), R^{b} and R^{c} each independently represent a hydrogen atom, —SO₃—, CO₂H or —SO₂NHR^{a}. R^{d}, R^{e}, and R^{f} each independently represent —SO₃—, —SO₃Na or —SO₂NHR^{a}.

R^{g}, and R^{h}, each Rⁱ independently represent a hydrogen atom, —SO₃—, SO₃H or —SO₂NHRa.

R^{a} represents an alkyl group of 1 to 10 and preferably represents a 2-ethylhexyl group. X represents the same meaning as above.

Compounds represented by Formula (1b) are tautomers of the compounds represented by Formula (1b-1).

Among these, from a viewpoint of color properties and heat resistance, in particular, Formula (1e) and Formula (1f) are preferable.

(Cyanine Dye)

An aspect of the resin having a dye structure according to the present invention, is that it has a partial structure derived from a cyanine dye (cyanine compound). As the resin (A) having a dye structure, a resin having a dye structure which, as a partial structure of a dye portion, has a partial structure derived from the compound (cyanine compound) represented by General Formula (PM) described below is included. The cyanine compound in the present invention is a collective term of compounds having a dye portion including a cyanine skeleton within the molecule.

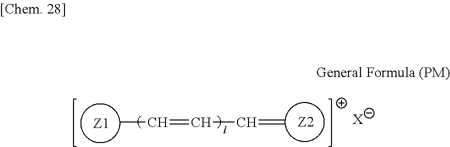

In General Formula (PM), Ring Z1 and Ring Z2 each independently represent a heterocyclic ring which may have substituents. 1 represents an integer of from 0 to 3. X⁻ represents an anion.

Ring Z1 and Ring Z2, each independently, include oxazole, benzoxazole, oxazoline, thiazole, thiazoline, benzothiazole, indolenine, benzoindolenine, or 1,3-thiadiazine. The substituents Ring Z1 and Ring Z2 may take are the same as the substituents described in the above section of the Substituent Group A. X⁻ represents an inorganic anion such as a fluorine anion, a chlorine anion, a bromine anion, an iodine anion, a perchlorate anion, a thiocyanate anion, a hexafluoride phosphate anion, a hexafluoride antimonate anion, or a tetrafluoride borate anion, a carboxylate anion such as an acetate anion or a benzoate anion, an organic sulfonate anion such as a benzene sulfonate anion, a toluene sulfonate anion, a trifluoromethane sulfonate anion, an organic phosphate anion such as an octylphosphate anion, a dodecylphosphate anion, an octadecylphosphate anion, a phenylphosphate anion, or a nonylphenyl phosphate anion or the like may be included. X is preferably ion bonded to the dye structure, and may also be bonded to part of the resin having a dye structure (a polymer chain and the like).

The compound represented by General Formula (PM) is preferably a compound represented by following General Formula (PM-2).

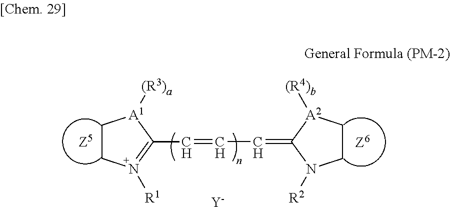

In General Formula (PM-2), ring Z⁵ and Ring Z⁶, each independently, represent a benzene ring which may have substituents or a naphthalene ring which may have substituents. Y⁻ represents Cl⁻, Br⁻, I⁻, ClO₄⁻, OH⁻, a monovalent organic carboxylate anion, a monovalent organic sulfonate anion, a monovalent borate anion, or a monovalent organic metal complex anion. Y⁻ is preferably ion bonded to the dye structure, and may also be bonded to part of the resin having a dye structure (a polymer chain and the like).

n represents an integer of from 0 to 3.

A¹ and A², each independently, represent an oxygen atom, a sulfur atom, a selenium atom, a carbon atom, or a nitrogen atom.

R¹ and R², each independently, represent a monovalent aliphatic hydrocarbon group having the number of carbon atoms 1 to 20 which may have substituents.

R³ and R⁴, each independently, either represent a hydrogen atom or monovalent aliphatic hydrocarbon group having the number of carbon atoms 1 to 6, or represent a divalent aliphatic hydrocarbon group having the number of carbon atoms 2 to 6 formed from the joint of one R³ and one R⁴. a and b, each independently, represent an integer of from 0 to 2.

In General Formula (PM-2), Y⁻ is preferably a fluorine anion, a chlorine anion, a bromine anion, an iodine anion, a perchlorate anion, or a carboxylate anion and most preferably a chlorine anion, a perchlorate anion, or a carboxylate anion. n is preferably 1. A¹ and A² are each individually preferably an oxygen atom, a sulfur atom and a carbon atom, and are most preferably a carbon atom.

Specific examples of the cyanine compounds are shown below, however, the present invention is not limited to these.

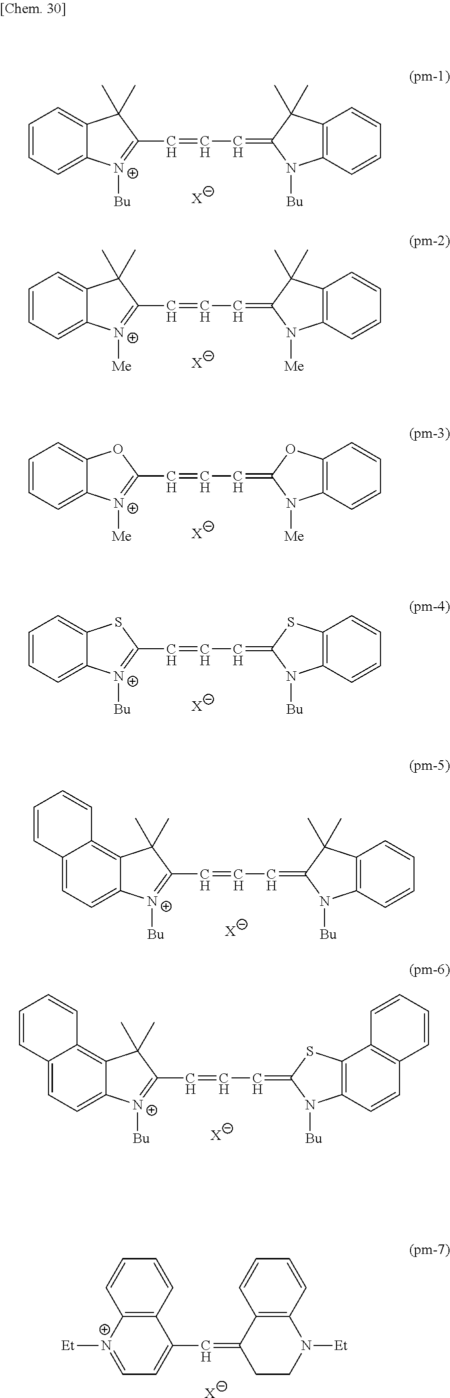

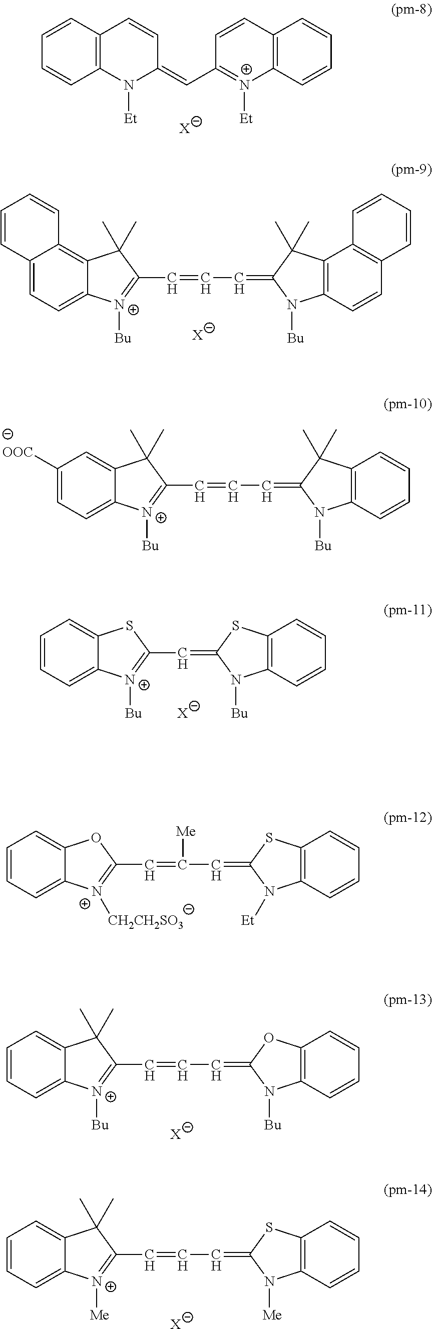

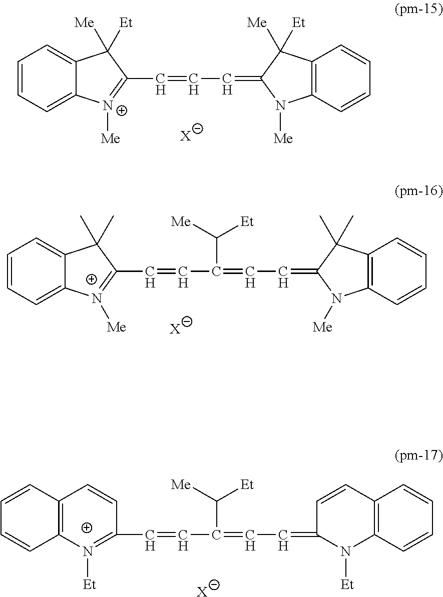

Among the specific examples, structures represented by (pm-1) to (pm-6), (pm-9) and (pm-10) are preferable and from a viewpoint of color properties and heat resistance, dye structures represented by (pm-1), (pm-2) and (pm-10) are particularly preferable.

(Squarylium Dye)

An aspect of the resin having a dye structure according to the present invention, is that it has a partial structure derived from a squarylium dye (squarylium compound). As the resin (A) having a dye structure, a resin having a dye structure which, as a partial structure of a dye portion, has a partial structure derived from the compound (squarylium compound) represented by General Formula (K) described below is included. The squarylium compound in the present invention is a collective term of compounds having a dye portion including a squarylium skeleton within the molecule.

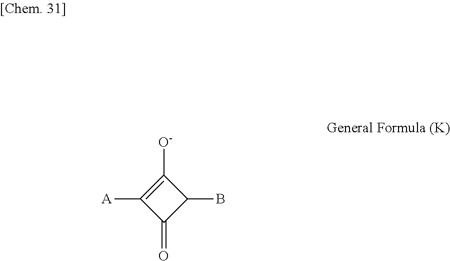

In General Formula (K), A and B, each independently, represent an aryl group or a heterocyclic group. As the aryl group, an aryl group preferably having the number of carbon atoms 6 to 48, more preferably having the number of carbon atoms 6 to 24, and, for example, phenyl or naphthyl may be included. As the heterocyclic group, a five-membered ring or six-membered ring is preferable, for example, pyrrolyl, imidazoyl, pyrazoyl, thienyl, pyridyl, pyrimidyl, pyridazyl, triazol-1-yl, thienyl, furyl, thiadiazoyl or the like may be exemplified.

As the compounds represented by General Formula (K), particularly, compounds represented by General Formula (K-1), General Formula (K-2), General Formula (K-3), or General Formula (K-4) are preferable.

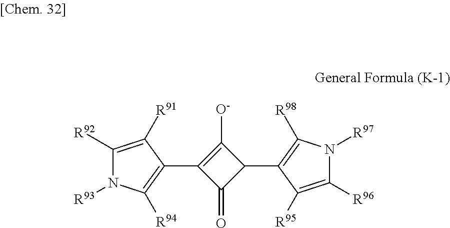

In General Formula (K-1), R⁹¹, R⁹², R⁹⁴, R⁹⁵, R⁹⁶, and R⁹⁸, each independently, represent a hydrogen atom, a halogen atom, a linear or branched alkyl group, a cycloalkyl group, a linear or branched alkenyl group, a cycloalkenyl group, an alkynyl group, an aryl group, a heterocyclic group, a cyano group, a hydroxyl group, a nitro group, a carboxyl group, an alkoxy group, an aryloxy group, a silyloxy group, a heterocyclic oxy group, an acyloxy group, a carbamoyloxy group, an amino group (including an alkylamino group and an anilino group), an acylamino group, an aminocarbonylamino group, an alkoxycarbonylamino group, an aryloxycarbonylamino group, a sulfamoylamino group, an alkyl- or arylsulfonylamino group, a mercapto group, an alkylthio group, an arylthio group, a heterocyclic thio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heterocyclic azo group, an imide group, a phosphino group, a phosphinyl groups, a phosphinyloxy group, a phosphinylamino group, or a silyl group.

R⁹³ and R⁹⁷, each independently, represent a hydrogen atom, a linear or branched alkyl group, a cycloalkyl group, a cycloalkenyl group, an alkynyl group, an aryl group or a heterocyclic group.

R⁹¹ and R⁹² and R⁹⁵ and R⁹⁶, respectively, are bonded to each other and may form a ring.

The substituents R⁹¹, R⁹², R⁹⁴, R⁹⁵, R⁹⁶, and R⁹⁸ in General Formula (K-1) may take are the same as the substituents described in the above section of the Substituent Group A.

It is preferable that R⁹¹ to R⁹⁸, each independently, be a hydrogen atom, an alkyl group, a hydroxyl group, an amino group, an aryl group, or a heterocyclic ring, it is more preferable that R⁹³, R⁹⁴, R⁹⁷ and R⁹⁸ be alkyl groups, or, R⁹¹ and R⁹², and R⁹⁵ and R⁹⁶ be bonded to each other and form an aryl ring, it is the most preferable that R⁹³, R⁹⁴, R⁹⁷ and R⁹⁸ be alkyl groups having the number of carbon atoms 1 to 20, or, R⁹¹ and R⁹², and R⁹⁵ and R⁹⁶ be bonded to each other and form a benzene ring.

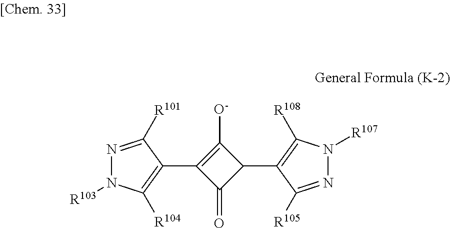

In General Formula (K-2), R¹⁰¹, R¹⁰³, R¹⁰⁴, R¹⁰⁵, R¹⁰⁷, and R¹⁰⁸ are the same as R⁹¹, R⁹³, R⁹⁴, R⁹⁵, R⁹⁷, and R⁹⁸ in General Formula (K-1). R¹⁰³ and R¹⁰⁷ are the same as R⁹³ and R⁹⁷ in General Formula (K-1).

In General Formula (K-2), it is preferable that R¹⁰¹, R¹⁰³, R¹⁰⁴, R¹⁰⁵, R¹⁰⁷ and R¹⁰⁸ be a hydrogen atom, an alkyl group, a hydroxy group, an amino group, an aryl group or a heterocyclic group, it is more preferable that R¹⁰¹, R¹⁰³, R¹⁰⁵ and R¹⁰⁷ be an alkyl group or an aryl group, and, R¹⁰⁴ and R¹⁰⁸ be a hydroxy group or an amino group, and it is more preferable that R¹⁰¹, R¹⁰³, R¹⁰⁵ and R¹⁰⁷ be an alkyl group having the number of carbon atoms 1 to 20, or, R¹⁰⁴ and R¹⁰⁸ be a hydroxy group. It is preferable that R¹⁰³ and R¹⁰⁷ be a hydrogen atom, a linear or branched alkyl group, and an aryl group and it is more preferable that R¹⁰³ and R¹⁰⁷ be an alkyl group having the number of carbon atoms 1 to 5 and a phenyl group.

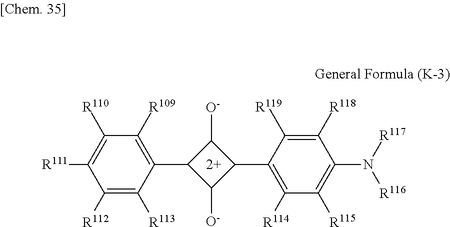

In General Formula (K-3), R¹⁰⁹, R¹¹⁰, R¹¹¹, R¹¹², R¹¹³, R¹¹⁴, R¹¹⁵, R¹¹⁸, and R¹¹⁹ are the same as R⁹¹, R⁹³, R⁹⁴, R⁹⁵, R⁹⁷, and R⁹⁸ in General Formula (K-1). R¹¹⁶ and R¹¹⁷ are the same as R⁹³ and R⁹⁷ in General Formula (K-1).

In General Formula (K-3), it is preferable that R¹⁰⁹, R¹⁰⁹, R¹⁰⁹, R¹⁰⁹, R¹¹³, R¹¹⁴, R¹¹⁵, R¹¹⁸, and R¹¹⁹ be a hydrogen atom, a halogen atom, a linear, or branched alkyl group, a hydroxy group, or an alkoxy group. Particularly, it is the most preferable that R¹⁰⁹, R¹¹³, R¹¹⁵, R¹¹⁸, and R¹¹⁹ be hydrogen atoms, R¹¹⁰, R¹¹¹, and R¹¹² be a hydrogen atom or an alkoxy group, R¹¹⁴ be a hydrogen atom, a halogen atom, a hydroxy group, an alkyl group having 1 to 5 carbon atoms, an alkoxy group having 1 to 5 carbon atoms.

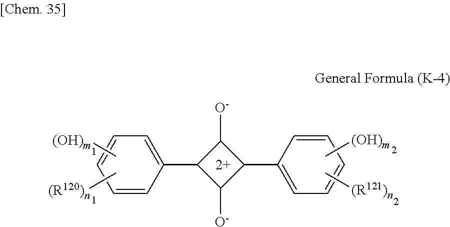

In General Formula (K-4), R¹²⁰ and R¹²¹ each independently represent a halogen atom, an alkyl group, an alkoxy group or an alkenyl group. m1 and m2 each independently represent an integer of 1 to 4. n1 and n2 each independently represent an integer of 0 to 4.

As R¹²⁰ and R¹²¹, particularly, an alkyl group having the number of carbon atoms 1 to 5 or an alkoxy group having the number of carbon atoms 1 to 5 is preferable. As m1 and m2, 1 to 3 is preferable, and it is the most preferable for m1 and m2 to be 3. As n1 and n2, 0 to 3 is preferable, and 0 or 1 is preferable.

As the dye compounds which may form the dye structure in the present invention, a squarylium compound represented by General Formula (K-1) is preferable from the viewpoint of color.

The squarylium compounds represented by General Formula (K-1) to General Formula (K-4) may be synthesized applying methods disclosed in J. Chem. Soc., Perkin Trans. 1, 2000, 599.

Specific examples of squarylium compounds represented by General Formulas (K-1) to (K-4) are described below, however, the present invention is not limited to these.

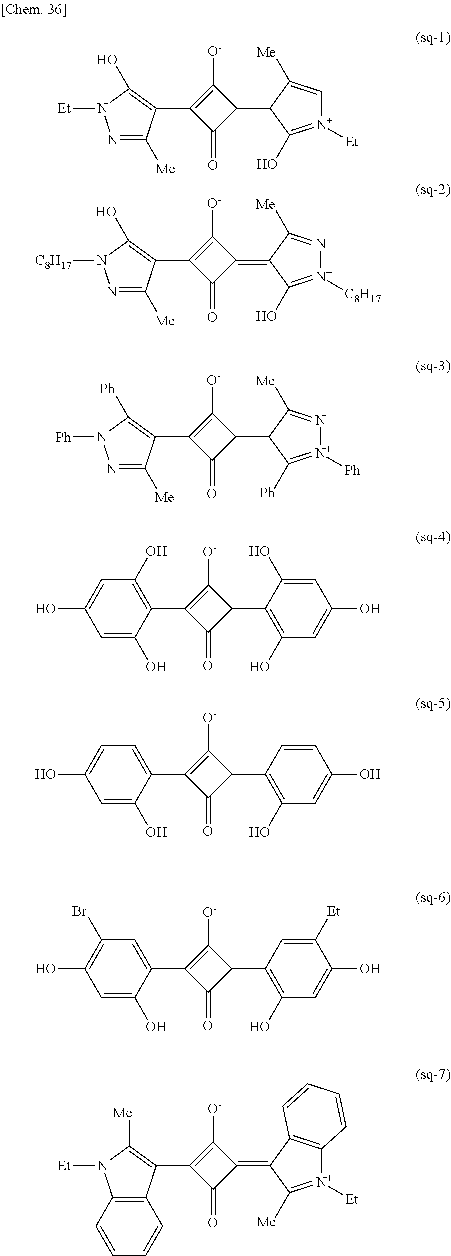

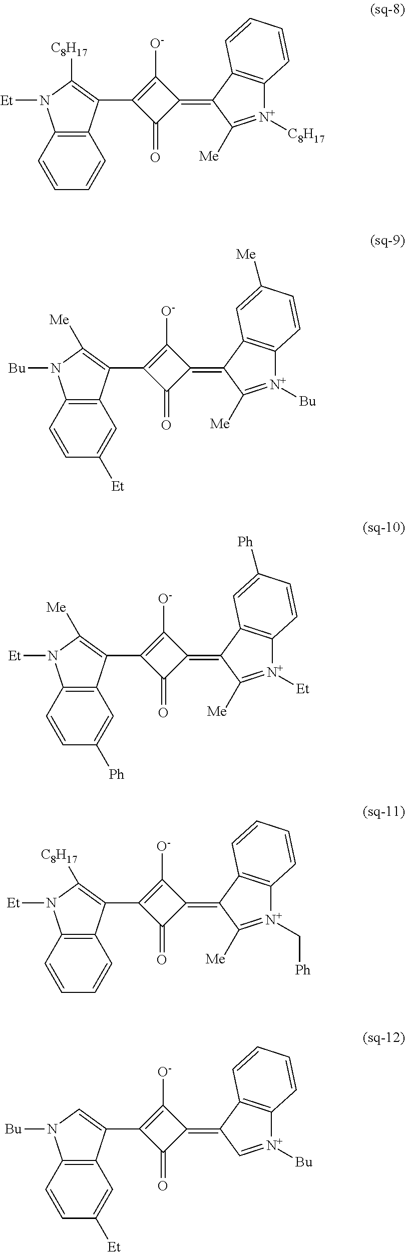

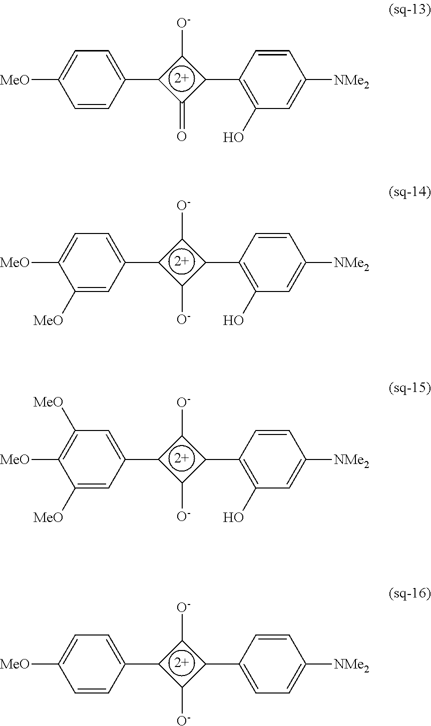

Among the specific examples above, from a viewpoint of color properties and heat resistance, (sq-1), (sq-2), (sq-3), (sq-7), (sq-8), (sq-9), (s9-9), (sq-10), (sq-11) and (sq-12) are preferable.

(Quinophthalone Dyes)

An aspect of the resin having a dye structure according to the present invention, is that it has a partial structure derived from a quinophthalone dye (quinophthalone compound). As the resin (A) having a dye structure, a resin having a dye structure which, as a partial structure of a dye portion, has a partial structure derived from the compound (quinophthalone compound) represented by General Formula (QP) described below is included. The quinophthalone compound in the present invention is a collective term of compounds having a dye portion including a quinophthalone skeleton within the molecule.

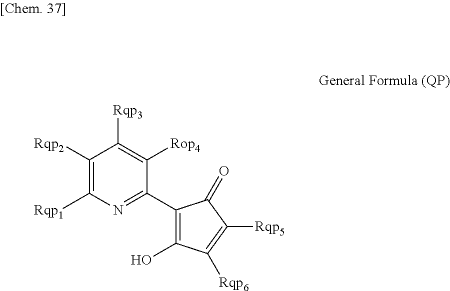

In General Formula (QP), Rqp₁ to Rqp₆, each independently, represent a hydrogen atom and a substituent. When at least two of Rqp₁ to Rqp₆ are adjacent, they are bonded to each other and may form a ring, and the ring may have further substituents.

The substituents Rqp₁ to Rqp₆ represent are substituents described in the above section of the Substituent Group A. As the substituents Rqp₁ to Rqp₆ represent, a halogen atom, an alkyl group, an alkenyl group, and an aryl group are preferable. Particularly, it is preferable that Rqp₁ and Rqp₂, and Rqp₅ and Rqp₆ be bonded to each other and form a substituted or unsubstituted phenyl group. Rqp₃ and Rqp₄ are preferably a hydrogen atom, a chlorine atom, or a bromine atom.

As the substituents the phenyl group formed by Rqp₁ and Rqp₂, and Rqp₅ and Rqp₆ bonded to each other, substituents described in the above section of the substituents may be included, however, a halogen atom, a carbamoyl group, an amino group, an alkoxy group, an aryloxy group, an alkylthio group, an arylthio group and an alkoxycarbonyl group are preferable.

Specific examples of the compound represented by General Formula (QP) are shown below, however, the present invention is not limited to these.

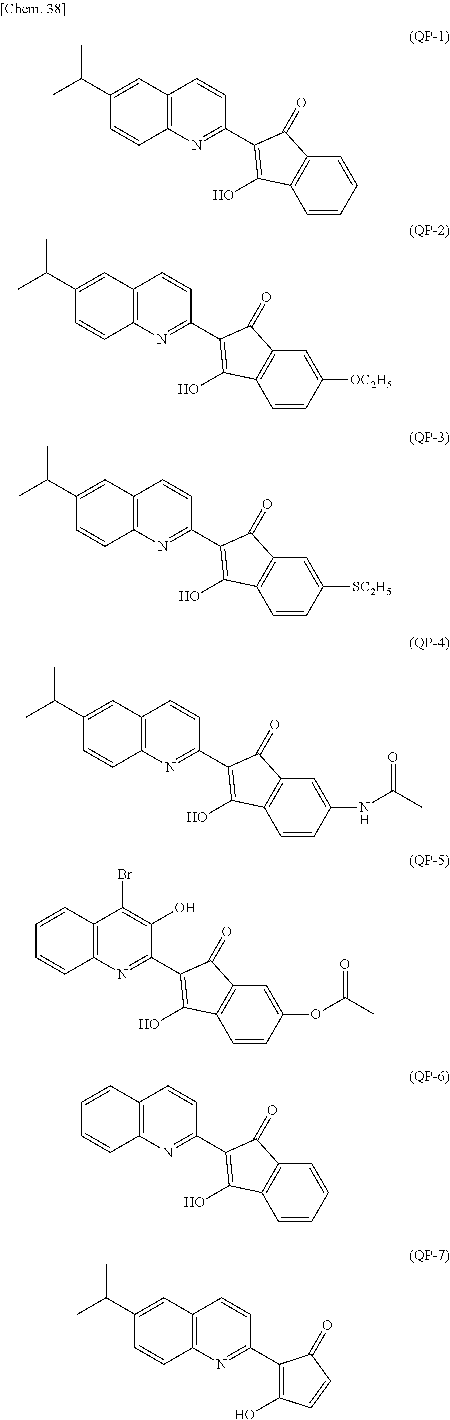

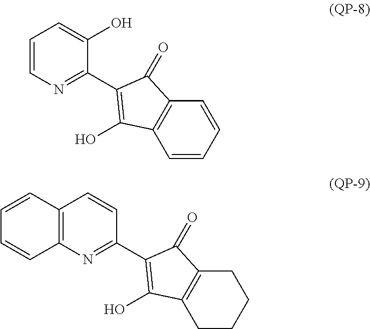

Among the specific examples above, from a viewpoint of color properties and heat resistance, (QP-1) to (QP-5) are preferable.

(Phthalocyanine Dye)

An aspect of the resin having a dye structure according to the present invention, is that it has a partial structure derived from a phthalocyanine dye (phthalocyanine compound). As the resin (A) having a dye structure, a resin having a dye structure which, as a partial structure of a dye portion, has a partial structure derived from the compound (phthalocyanine compound) represented by General Formula (F) described below is included. The phthalocyanine compound in the present invention is a collective term of compounds having a dye portion including a phthalocyanine skeleton within the molecule.

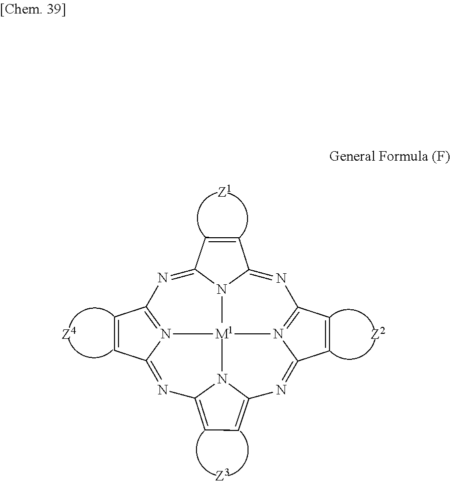

In General Formula (F), M¹ represents a type of metal, Z¹, Z² Z³, and Z⁴, each independently, represent an atomic group required to form a six-membered ring configured to include atoms selected from a hydrogen atom, a carbon atom and a nitrogen atom.

General Formula (F) is described in detail.

In General Formula (F), as the type of metal represented by M¹, for example, a metal atom such as Zn, Mg, Si, Sn, Rh, Pt, Pd, Mo, Mn, Pb, Cu, Ni, Co, and Fe, a metal chloride such as AlCl, InCl, FeCl, TiCl₂, SnCl₂, SiCl₂, and GeCl₂, a metal oxide such as TiO and VO, and a metal hydroxide such as Si(OH)₂ may be included, however, Cu and Zn are particularly preferable.

In General Formula (F), Z¹, Z² Z³, and Z⁴, each independently, represent an atomic group required to form a six-membered ring configured to include atoms selected from a hydrogen atom, a carbon atom and a nitrogen atom. The six-membered ring may be a saturated ring or an unsaturated ring, and may be unsubstituted or have a substituent. As the substituents, substituents described in the above section of the Substituent Group A may be included. In addition, when the six-membered ring has two or more substituents, those substituents may be the same as or different from each other. Moreover, the six-membered ring may be condensed with other five-membered or six-membered rings. The six-membered ring includes a benzene ring, a cyclohexane ring and the like. Among the phthalocyanine dye remnant represented by General Formula (F), the remnant derived from the phthalocyanine dye represented by General Formula (F-1) is particularly preferable.

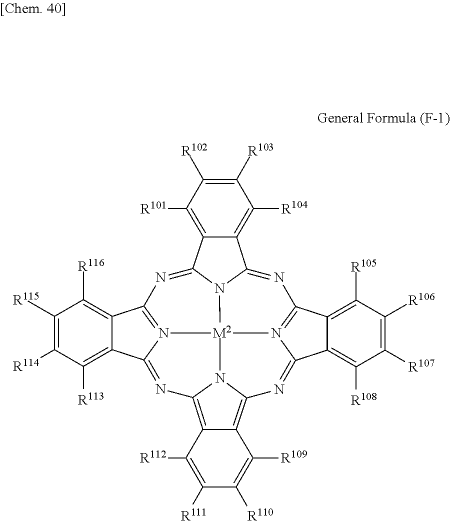

In General Formula (F-1), M² is the same as M¹ in General Formula (F), and so are the preferable aspects.

In General Formula (F-1), R¹⁰¹ to R¹¹⁶, each independently, represent a hydrogen atom or a substituent, and if the substituents represented by R¹⁰¹ to R¹¹⁶ are groups which can be further substituted, they may be substituted with groups described as the Substituent Group A above and when they are substituted with two or more substituents, those substituents may be the same as or different from each other.

Among these, the substituents represented by R¹⁰¹ to R¹¹⁶ are preferably a hydrogen atom, SO₂NR¹¹⁷R¹¹⁸ (R¹¹⁷ and R¹¹⁸ are a hydrogen atom or a linear or branched alkyl group which may have substituents having the number of carbon atoms 3 to 20), SR¹¹⁹ (R¹¹⁹ is a linear or branched alkyl group which may have substituents having the number of carbon atoms 3 to 20).

Specific examples of compounds represented by General Formula (F) are shown below, however, the present invention is not limited to these.

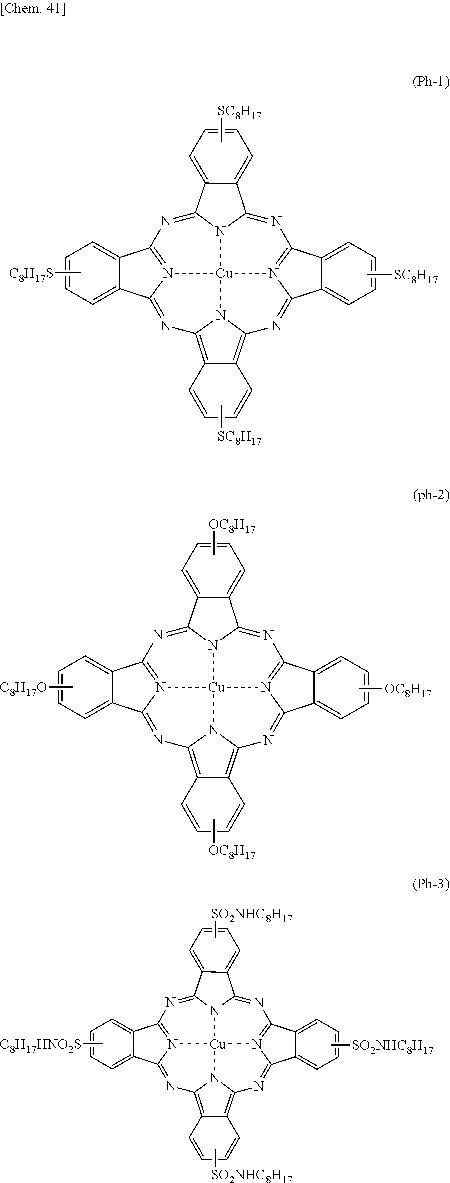

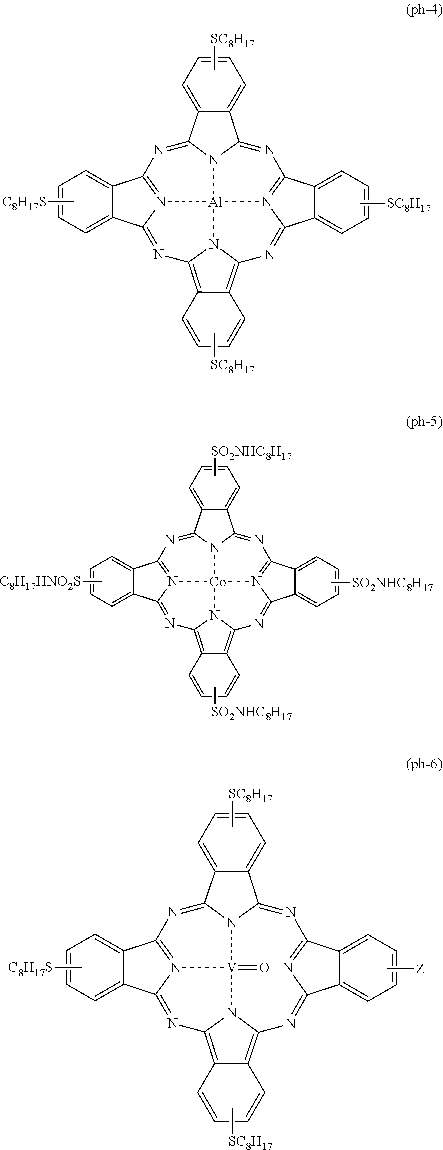

Among the specific examples, from a viewpoint of color properties and heat resistance, in particular, (Ph-1) to (Ph-3) are preferable.

(Sub-Phthalocyanine Compound)

An aspect of the resin having a dye structure according to the present invention, is that it has a partial structure derived from a sub-phthalocyanine dye (sub-phthalocyanine compound). As the resin (A) having a dye structure, a resin having a dye structure which, as a partial structure of a dye portion, has a partial structure derived from the compound (sub-phthalocyanine compound) represented by General Formula (SP) described below is included. The sub-phthalocyanine compound in the present invention is a collective term of compounds having a dye portion including a sub-phthalocyanine skeleton within the molecule.

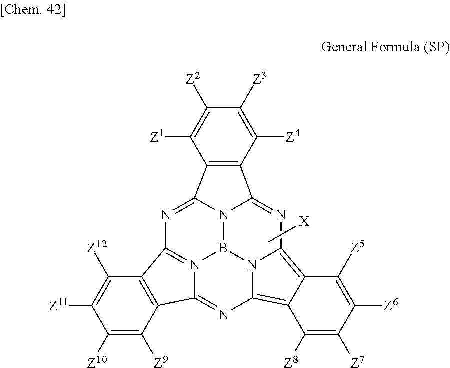

In General Formula (SP), Z¹ to Z¹², each independently, represent a hydrogen atom, an alkyl group, an aryl group, a hydroxy group, a mercapto group, an amino group, an alkoxy group, an aryloxy group, or a thioether group. X represents an anion.

General Formula (SP) is described in detail.

The alkyl groups Z¹ to Z¹² may have in General Formula (SP) represent a substituted or unsubstituted alkyl group with straight chain or branched chain. As Z¹ to Z¹², particularly, having 1 to 20 carbon atoms is preferable and having 1 to 10 carbon atoms is more preferable. As the substituents Z¹ to Z¹² may have, substituents described in the above section of the Substituent Group A may be included, however, particularly, a fluorine atom, a hydroxy group, and a mercapto group are preferable.

X in General Formula (SP) represents an anion. As X, specifically, an inorganic anion such as a fluorine anion, a chlorine anion, a bromine anion, an iodine anion, a perchlorate anion, a thiocyanate anion, a hexafluoride phosphate anion, a hexafluoride antimony anion, or a tetrafluoride borate anion, a carboxylate anion such as an acetate anion or a benzoate anion, an organic sulfonate anion such as a benzene sulfonate anion, a toluene sulfonate anion, a trifluoromethane sulfonate anion, an organic phosphate anion such as an octylphosphate anion, a dodecylphosphate anion, an octadecylphosphate anion, a phenylphosphate anion, or a nonylphenyl phosphate anion or the like may be included. X⁻ may be bonded to the dye skeleton or to part of the resin having a dye structure (a polymer chain and the like).

X⁻ is preferably a fluorine anion, a chlorine anion, a bromine anion, an iodine anion, a perchlorate anion, a carboxylate anion, or a phosphate anion, and a perchlorate anion, or a carboxylate anion is the most preferable.

Specific examples of the sub-phthalocyanine compounds are shown below, however, the present invention is not limited to these.

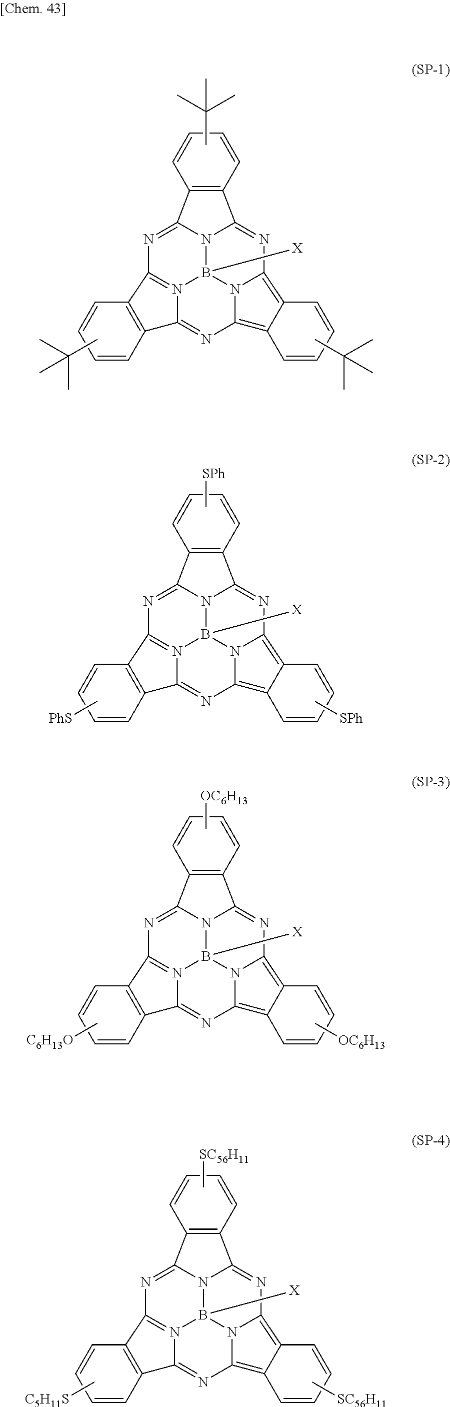

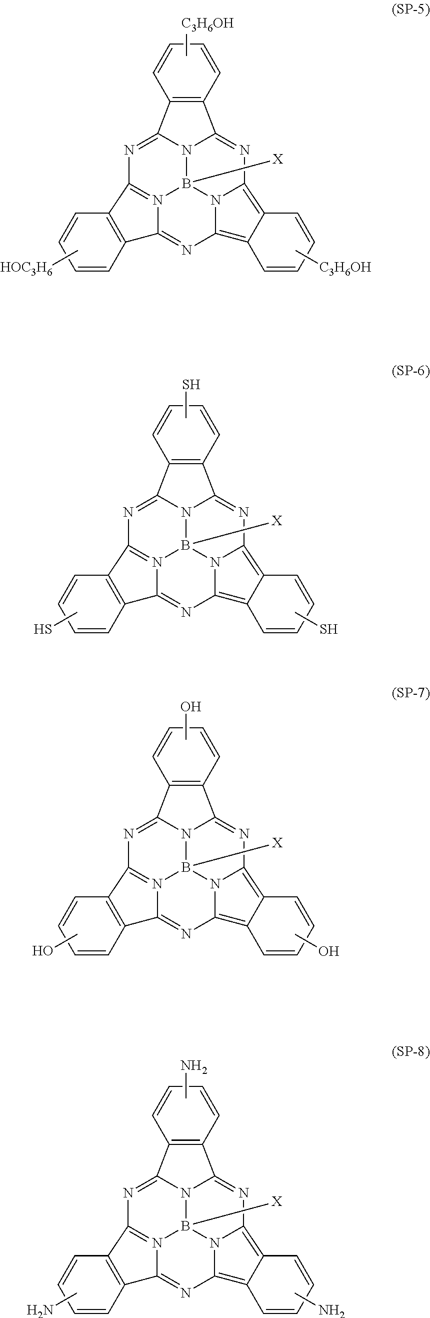

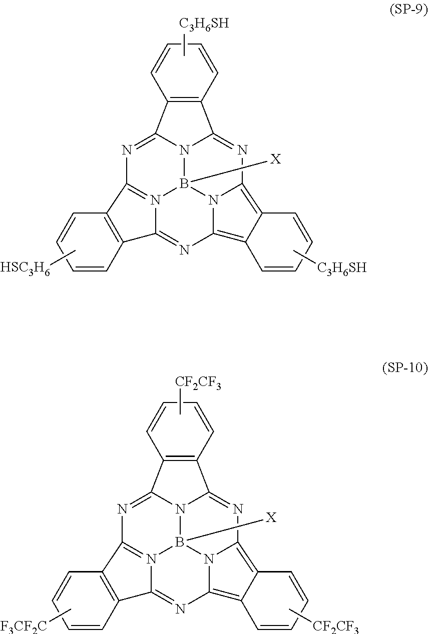

Among the specific examples, from a viewpoint of color properties and heat resistance, in particular, (SP-2), (SP-3), (SP-4), (SP-5), (SP-6), and (SP-7) are preferable.

(Structure of Resin which has Dye Structure Used in Coloring Composition of Present Invention)

The resin (A) having a dye structure and is used in a coloring composition of the present invention is preferably a resin having a dye structure and includes at least one of the structure units represented by following General Formula (A), General Formula (B), and General Formula (C). These will be described sequentially.

<Unit Structure Represented by General Formula (A)>

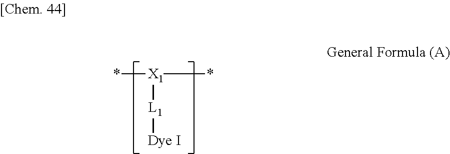

In General Formula (A), represents a linking group formed by polymerization, L¹ represents a single bonding or a divalent linking group, Dye I represents a dye structure.

The general formula (A) will be described in more detail below.

In General Formula (A), X₁ represents a linking group formed by polymerization. In other words, X₁ represents a part in which a repeating unit corresponding to a main chain formed from a polymerization reaction is formed. Also, a portion represented by two *s becomes the repeating unit. X₁ is not particularly limited as long as it is a linking group formed from well-known monomers capable of polymerization, however, particularly, linking groups represented by following (XX-1) to (XX-24) are preferable, (meth)acryl-based linking chains represented by (XX-1) and (XX-2), styrene-based linking chains represented by (XX-10) to (XX-17) and a vinyl-based linking chain represented by (XX-24) are the most preferable. In (XX-1) to (XX-24), the site represented by * represents a linking site to L₁ Me represents a methyl group. Also R in (XX-18) and (XX-19) represents a hydrogen atom, an alkyl group having 1 to 5 carbon atoms or a phenyl group.

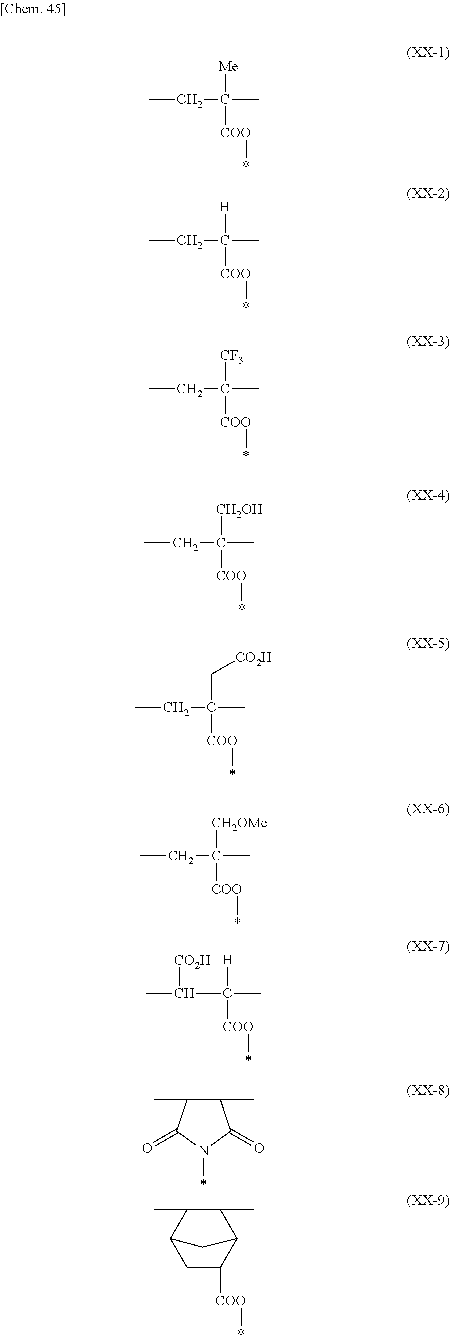

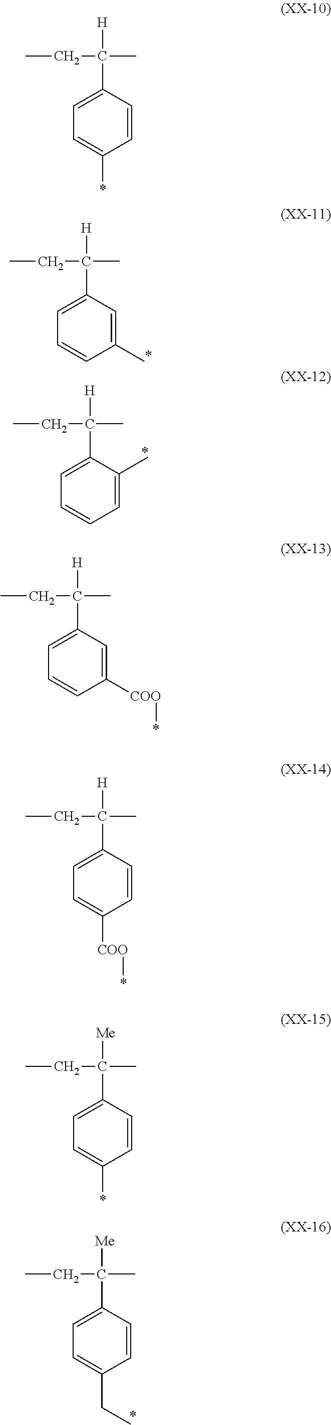

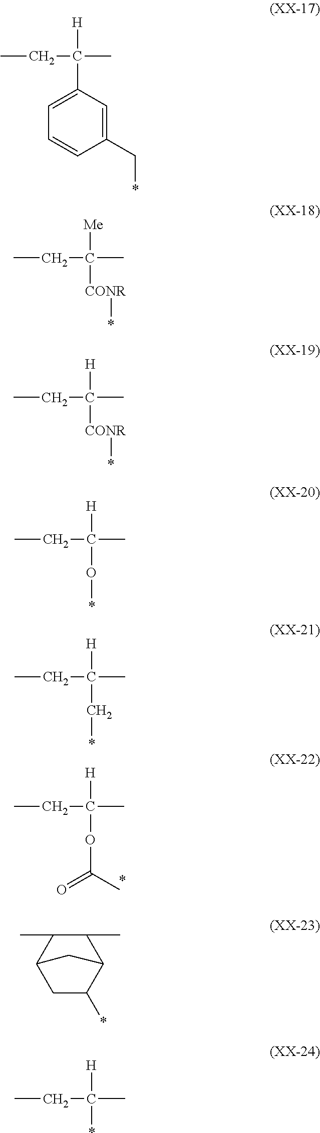

In General Formula (A), L¹ represents a single bond or a divalent linking group. As the divalent linking group when L¹ represents the divalent linking group, a substituted or unsubstituted alkylene group having 1 to 30 carbon atoms (for example, a methylene group, an ethylene group, a trimethylene group, a propylene group, a butylene group or the like), a substituted or unsubstituted arylene group having 6 to 30 carbon atoms (for example, a phenylene group, a naphthalene group or the like), a substituted or unsubstituted heterocyclic linking group, —CH═CH—, —O—, —S—, —C(—O)—, —CO₂—, —NR—, —CONR—, —O₂C—, —SO—, —SO₂— and a linking group formed by linking two or more of these are represented. Here, Rs each individually represent a hydrogen atom, an alkyl group, an aryl group or a heterocyclic group.

In General Formula (A), Dye I represents a dye structure derived from the dye compound mentioned above.

The resin having a dye structure having the structural unit represented by General Formula (A) may be synthesized by (1) a method in which a monomer having a dye structure is synthesized by an addition polymerization, (2) a method in which a polymer having a highly reactive functional group such as an isocyanate group, an acid anhydride group or an epoxy group is reacted with a dye having a functional group (a hydroxyl group, a primary or secondary amino group, a carboxyl group or the like) capable of reacting with the highly reactive group.

As the addition polymerization, well-known addition polymerizations (a radical polymerization, an anionic polymerization, a cationic polymerization) may be applied, however, among these, synthesizing by the radical polymerization is particularly preferable since it makes the reaction condition mild and does not degrade the dye structure. Well-known reaction conditions may be applied to the radical polymerization.

Among these, the resin having a dye structure having a structural unit represented by General Formula (A) in the present invention, from a viewpoint of developability, heat resistance, and color loss resistance, is preferably a radical polymer obtained by radical polymerization using a dye monomer (a monomer which has a dye structure) which has an ethylenic unsaturated bond. By providing a resin having a dye structure to a purification method by the above described specific reprecipitation after the polymerization reaction, the peak area occupied by the component of molecular weight of 2000 or less which is measured using GPC may be favorably achieved at less than 10% in respect to the peak area of the total molecular weight distribution of the resin.

Specific examples of the structural unit represented by General Formula (A) are shown below, however the present invention is not limited to these.

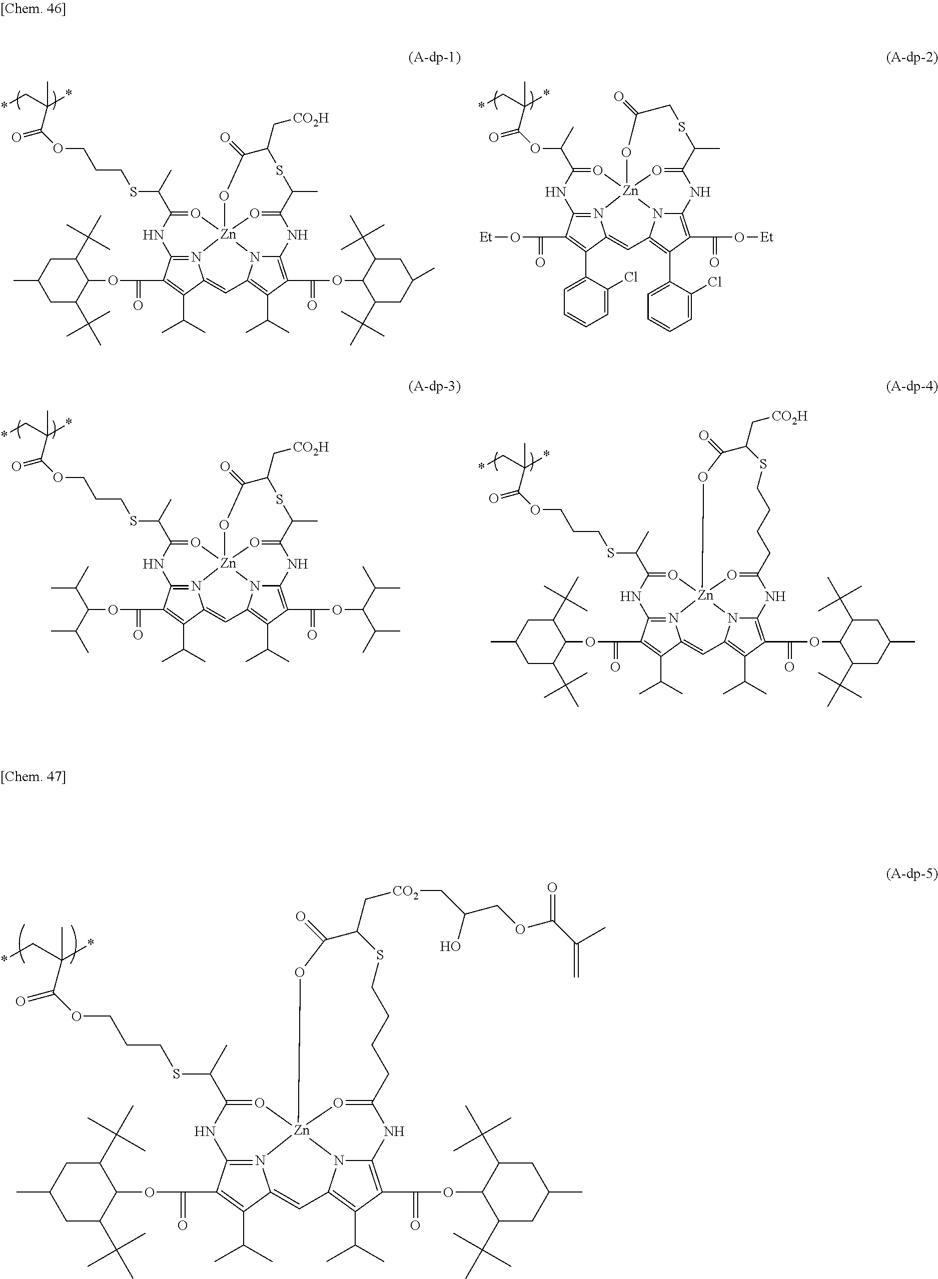

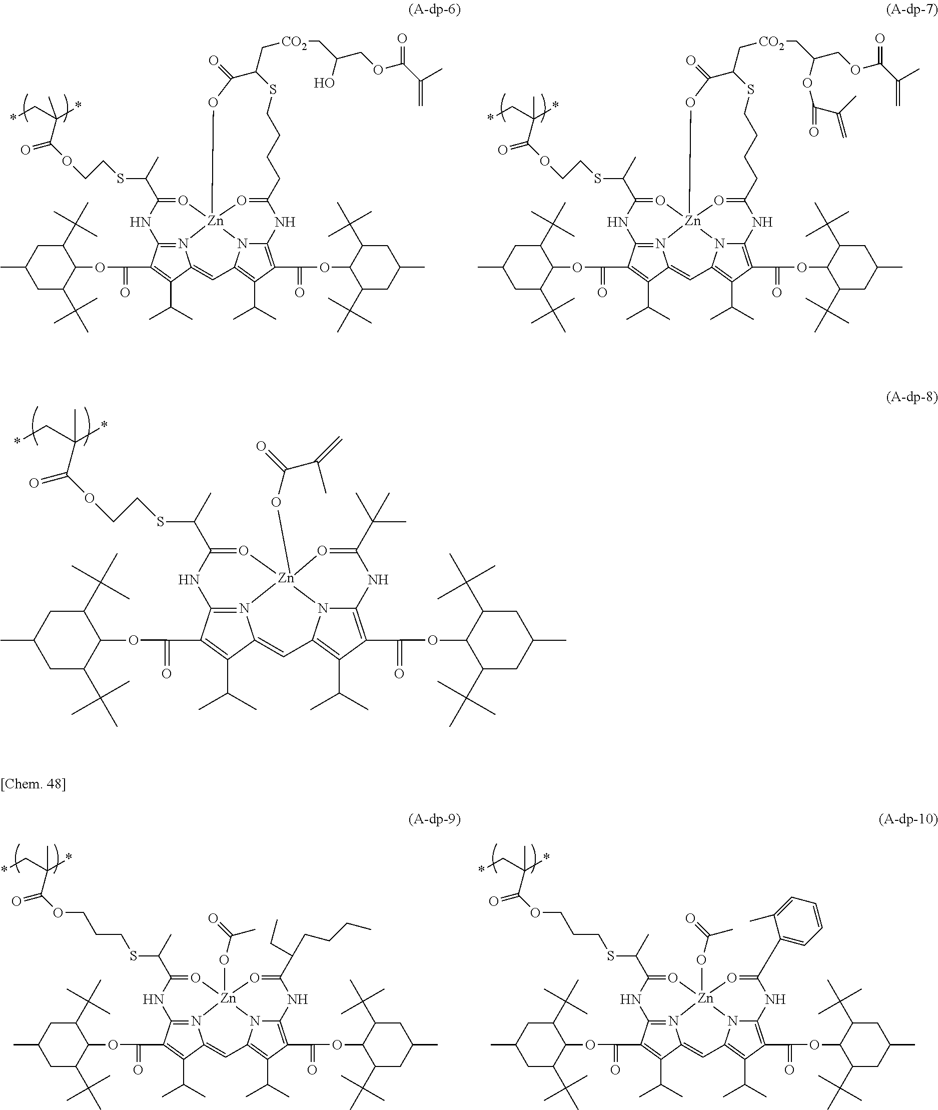

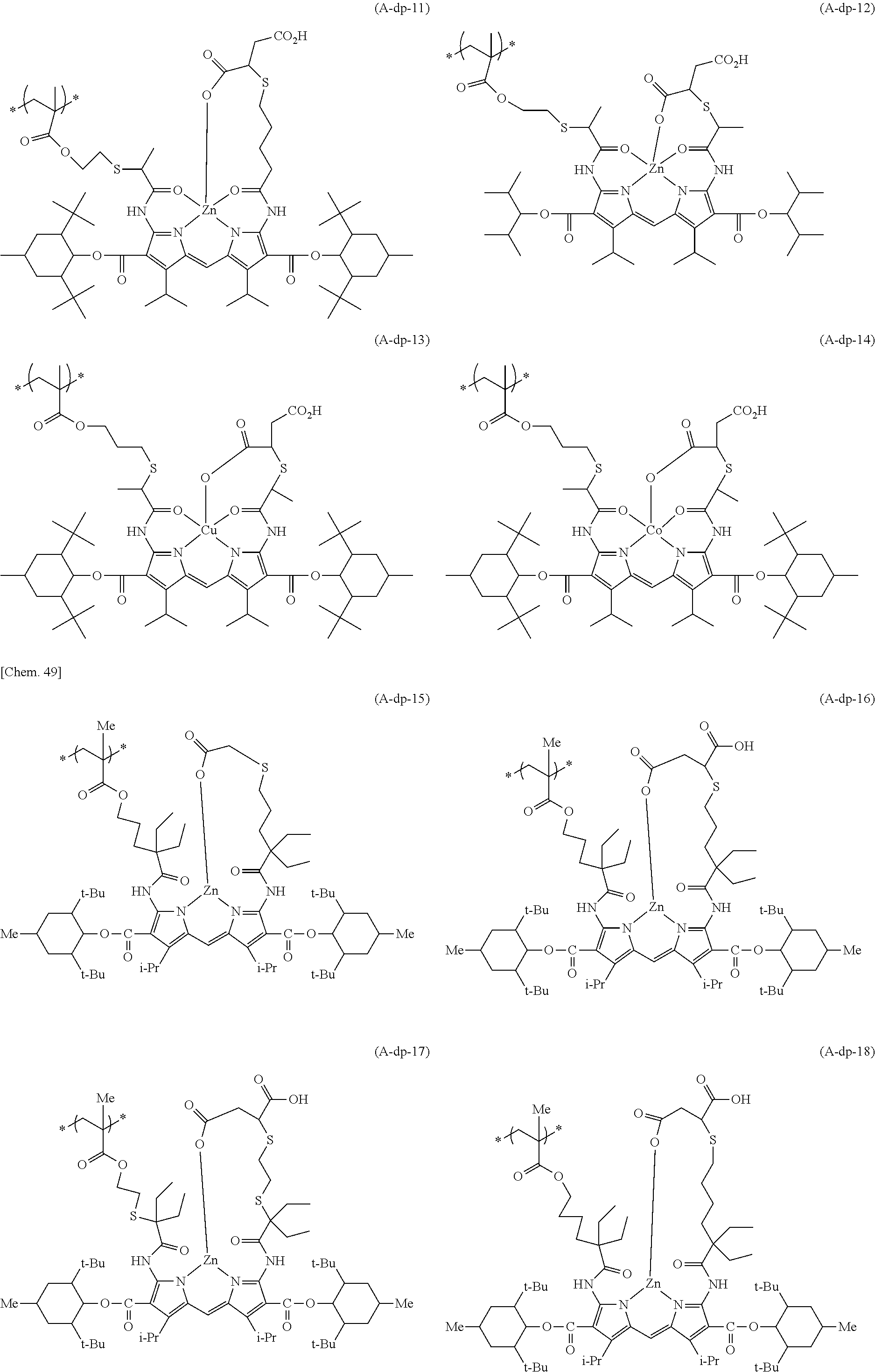

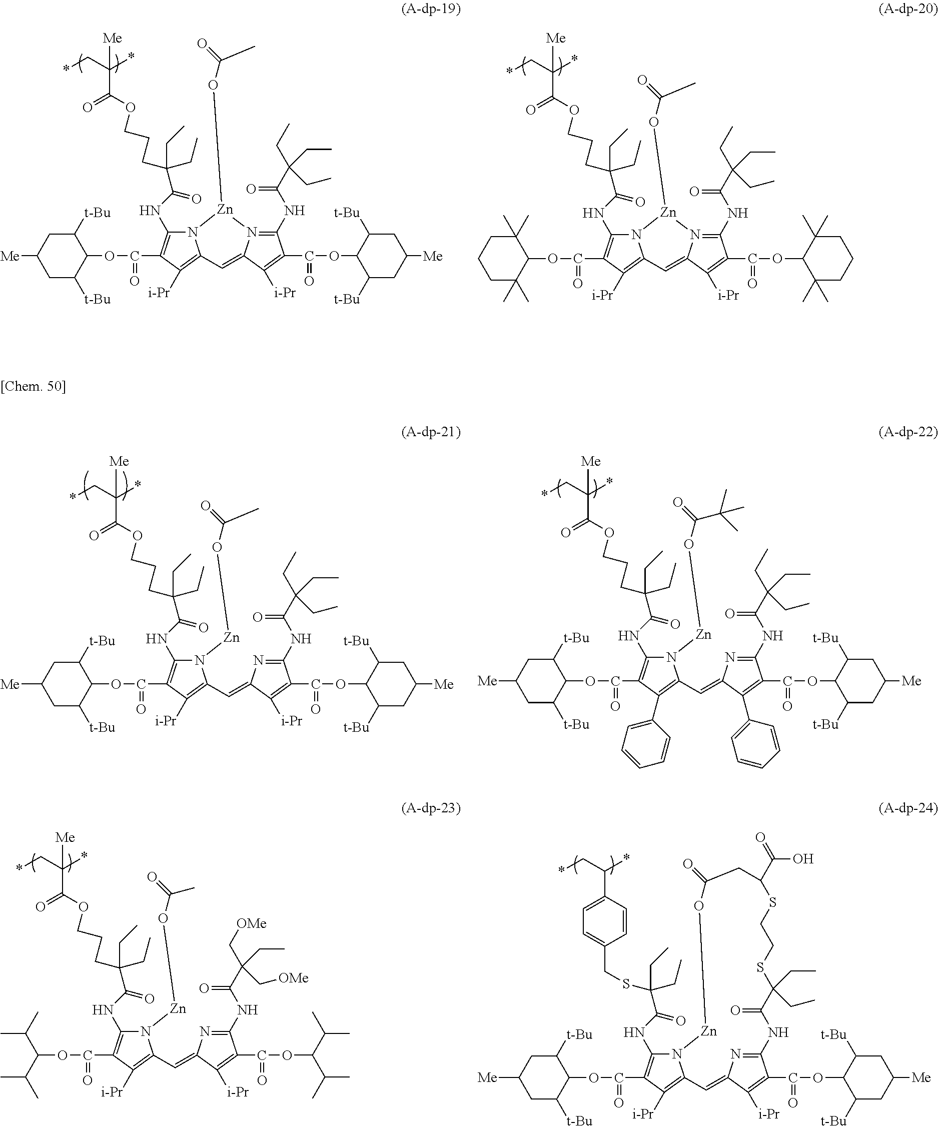

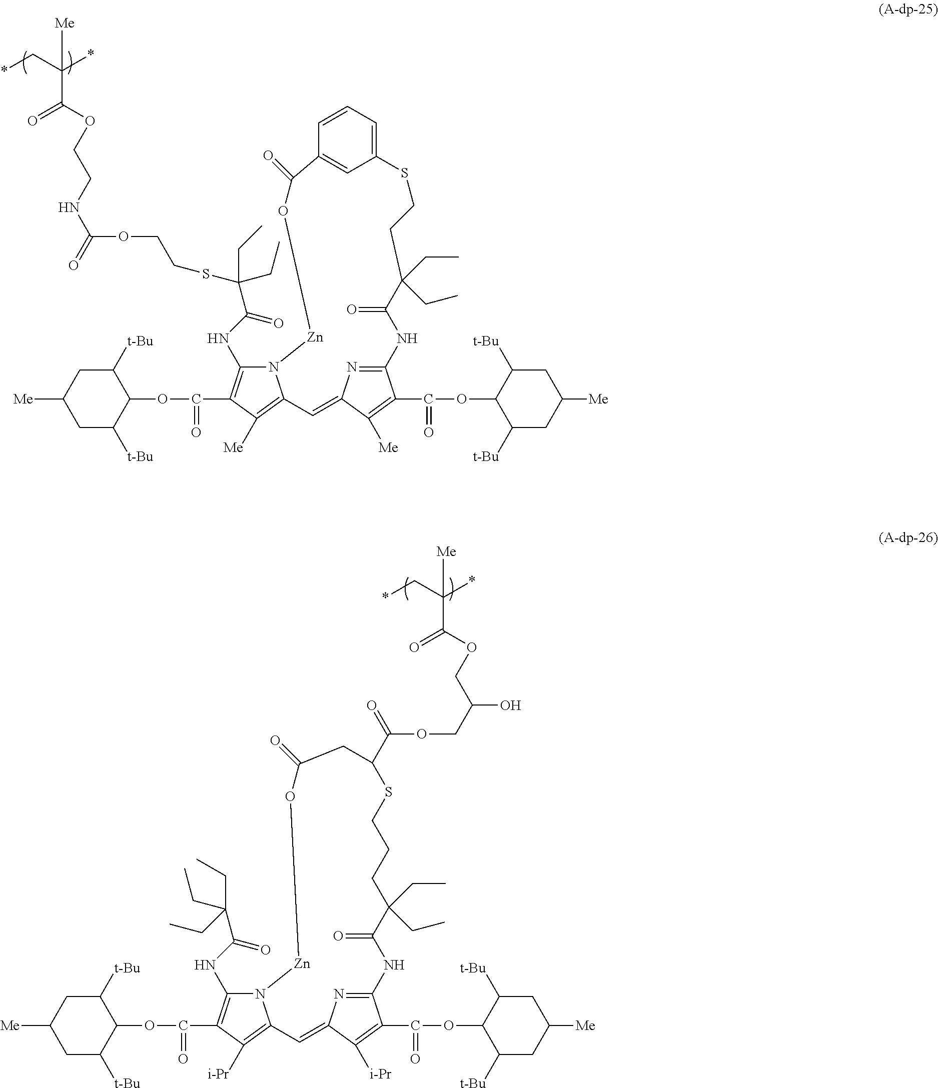

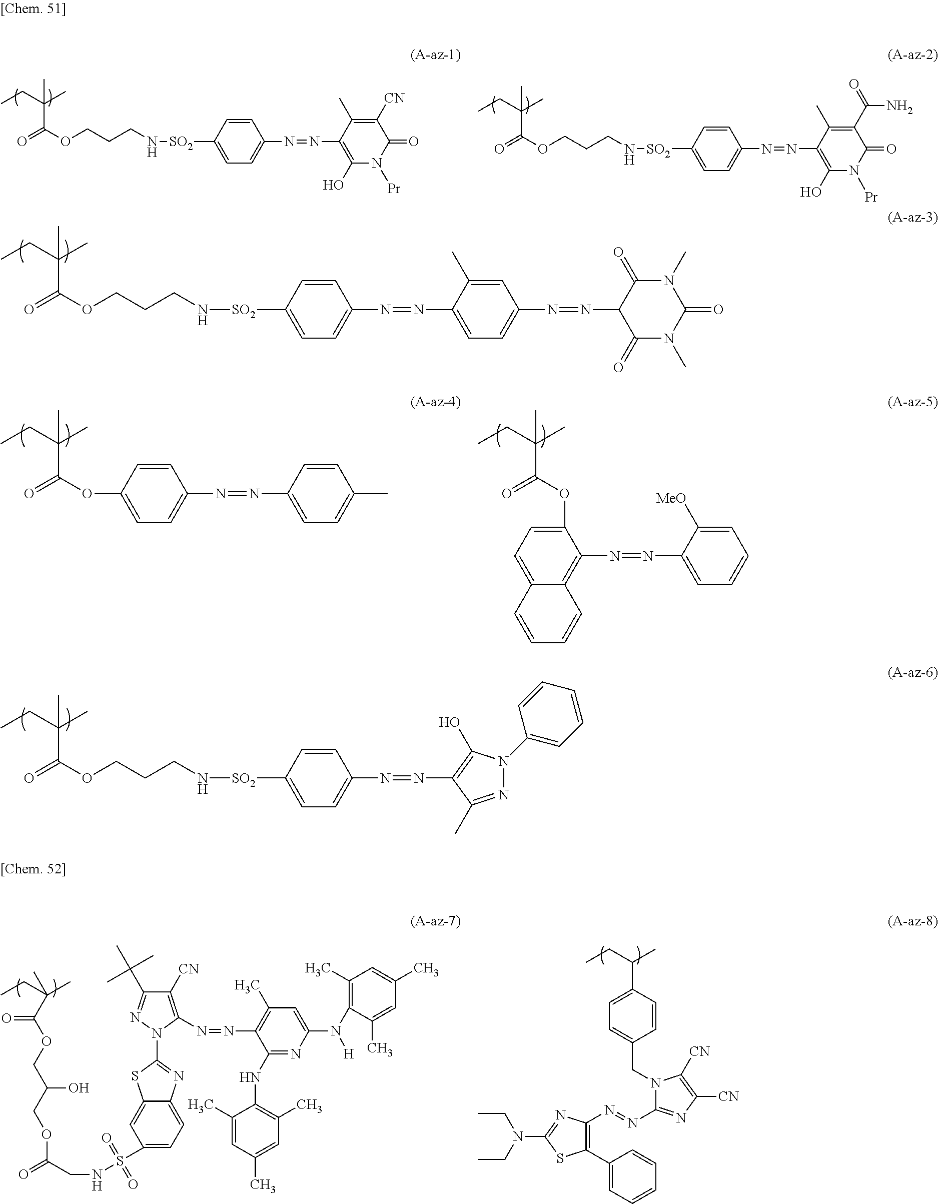

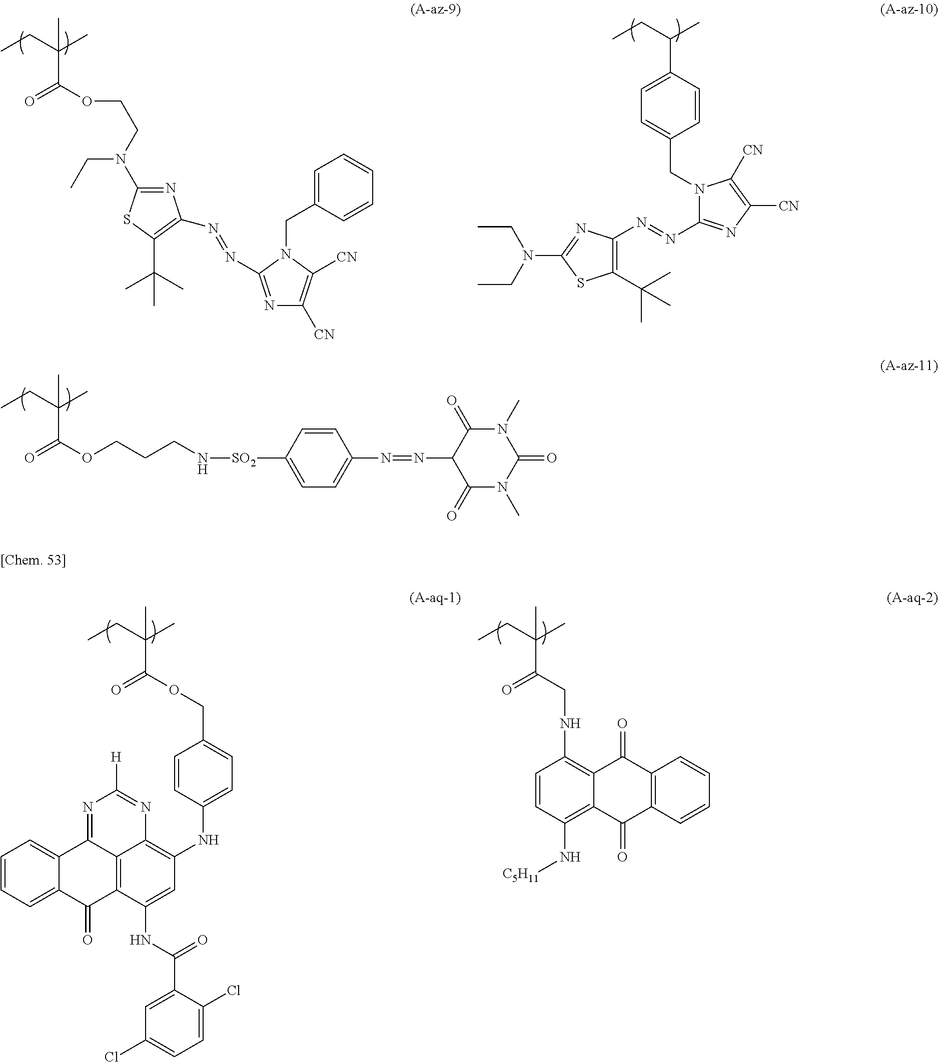

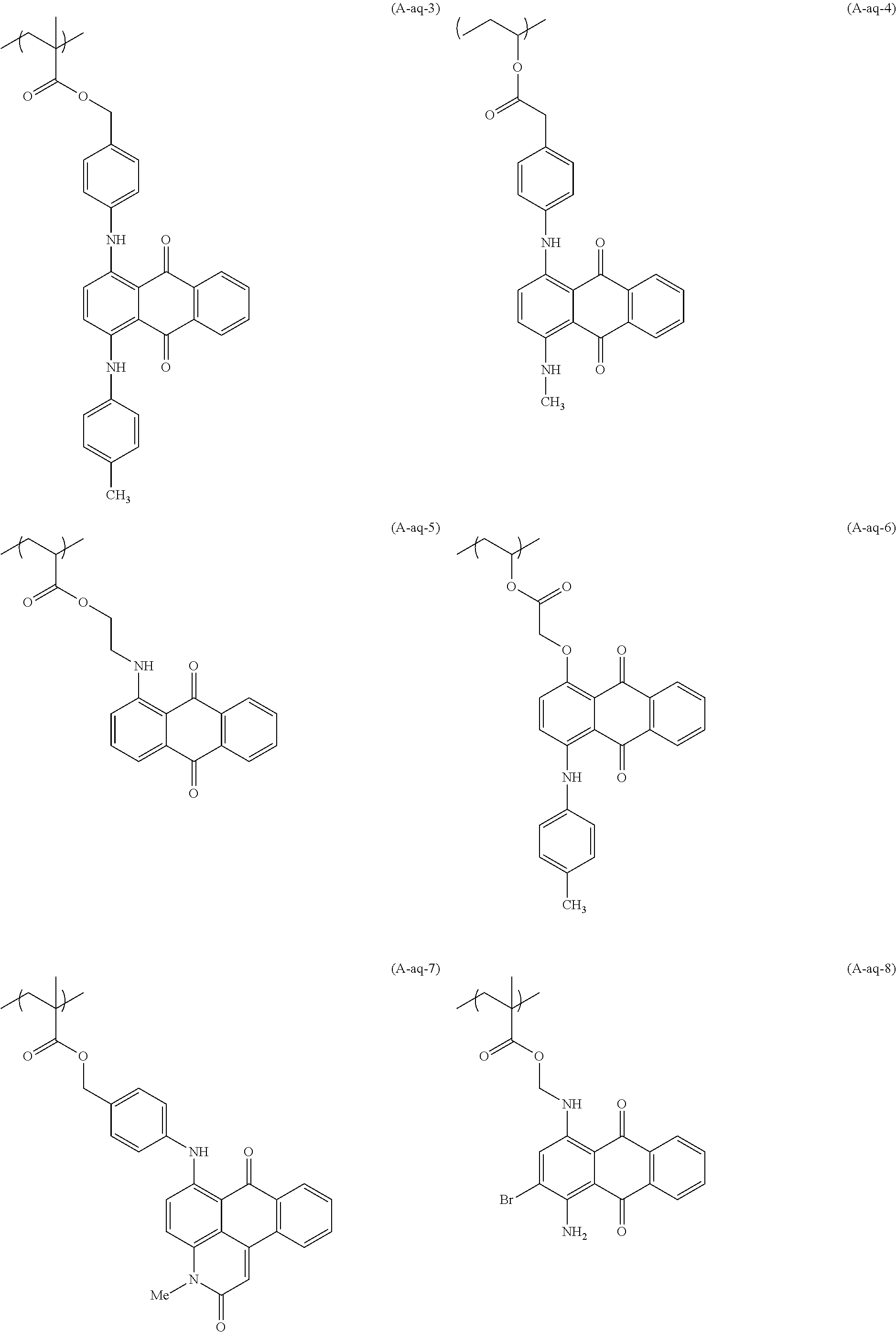

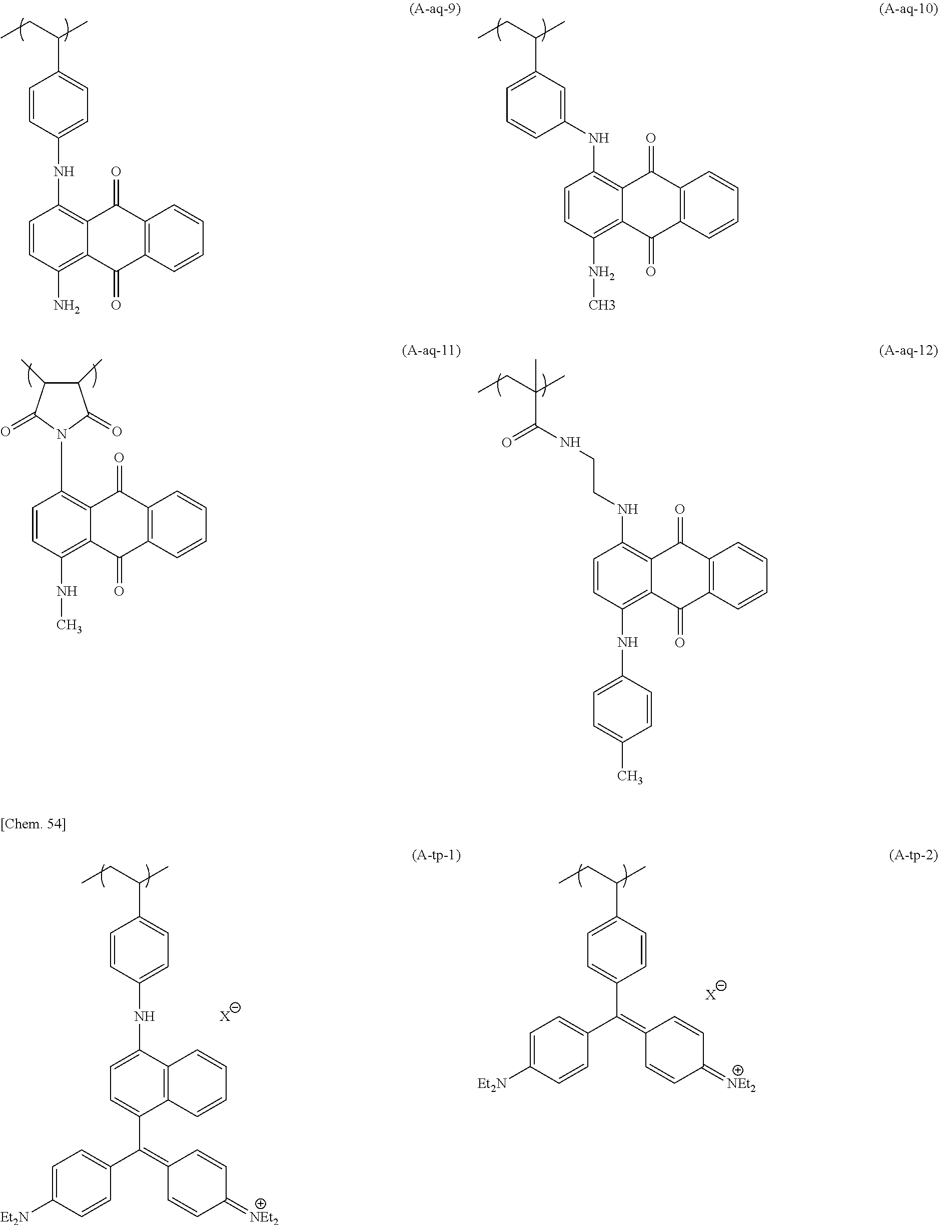

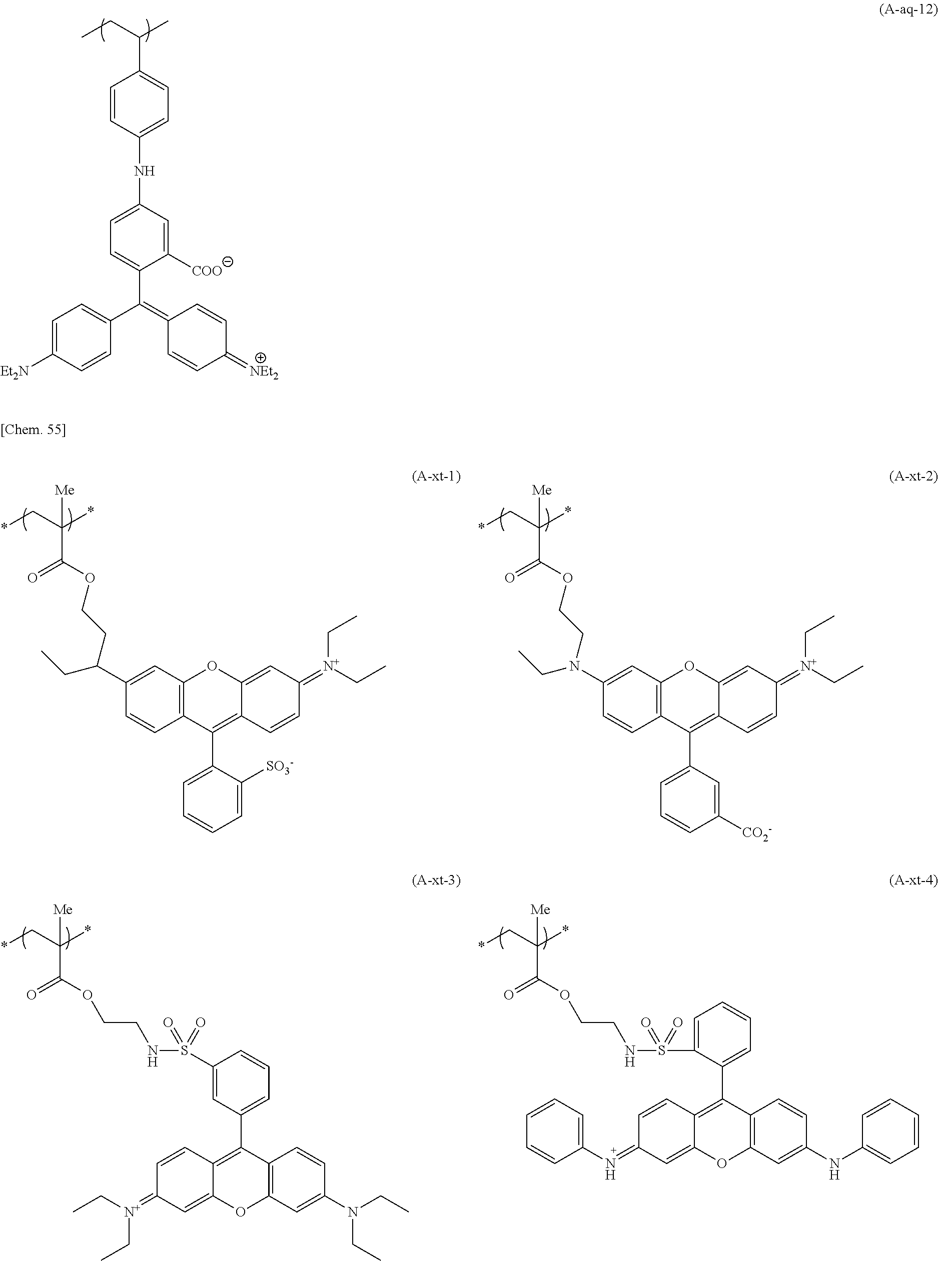

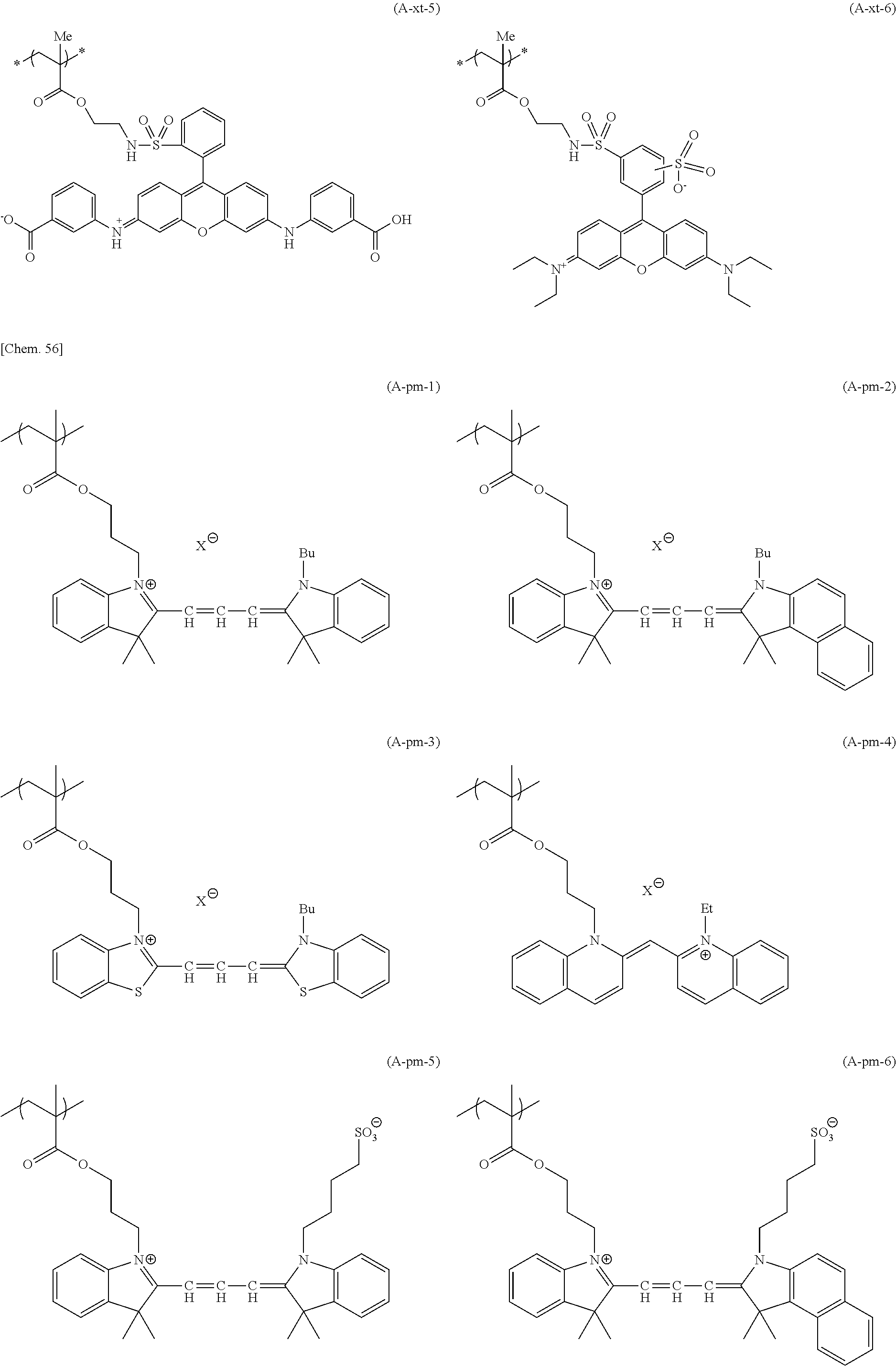

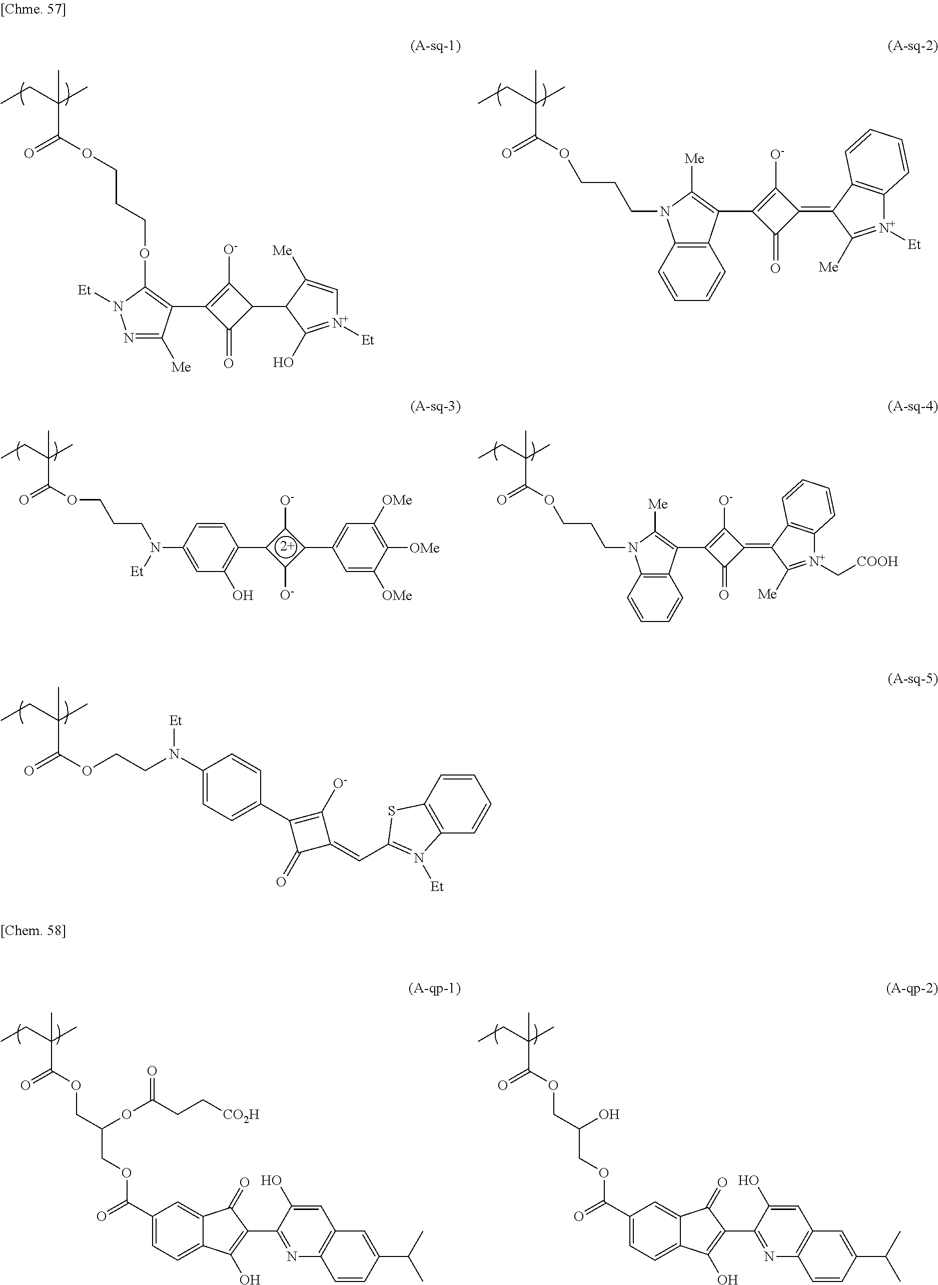

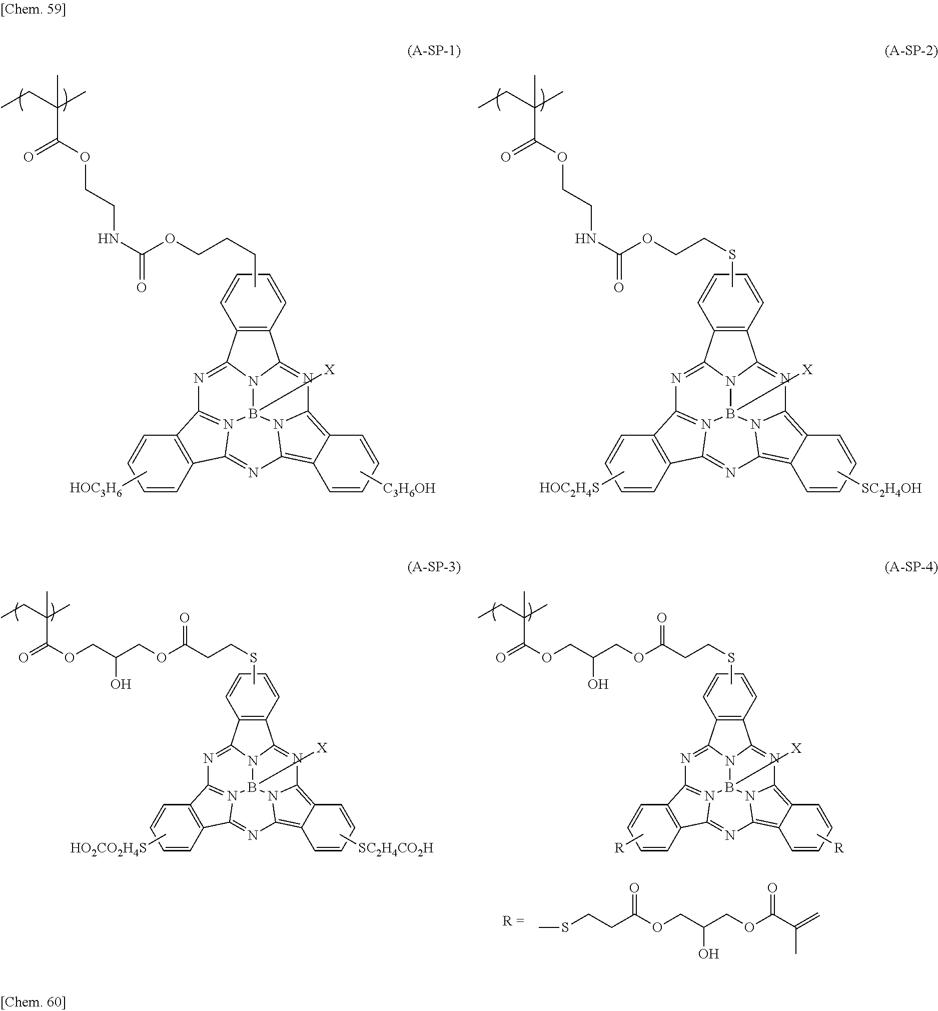

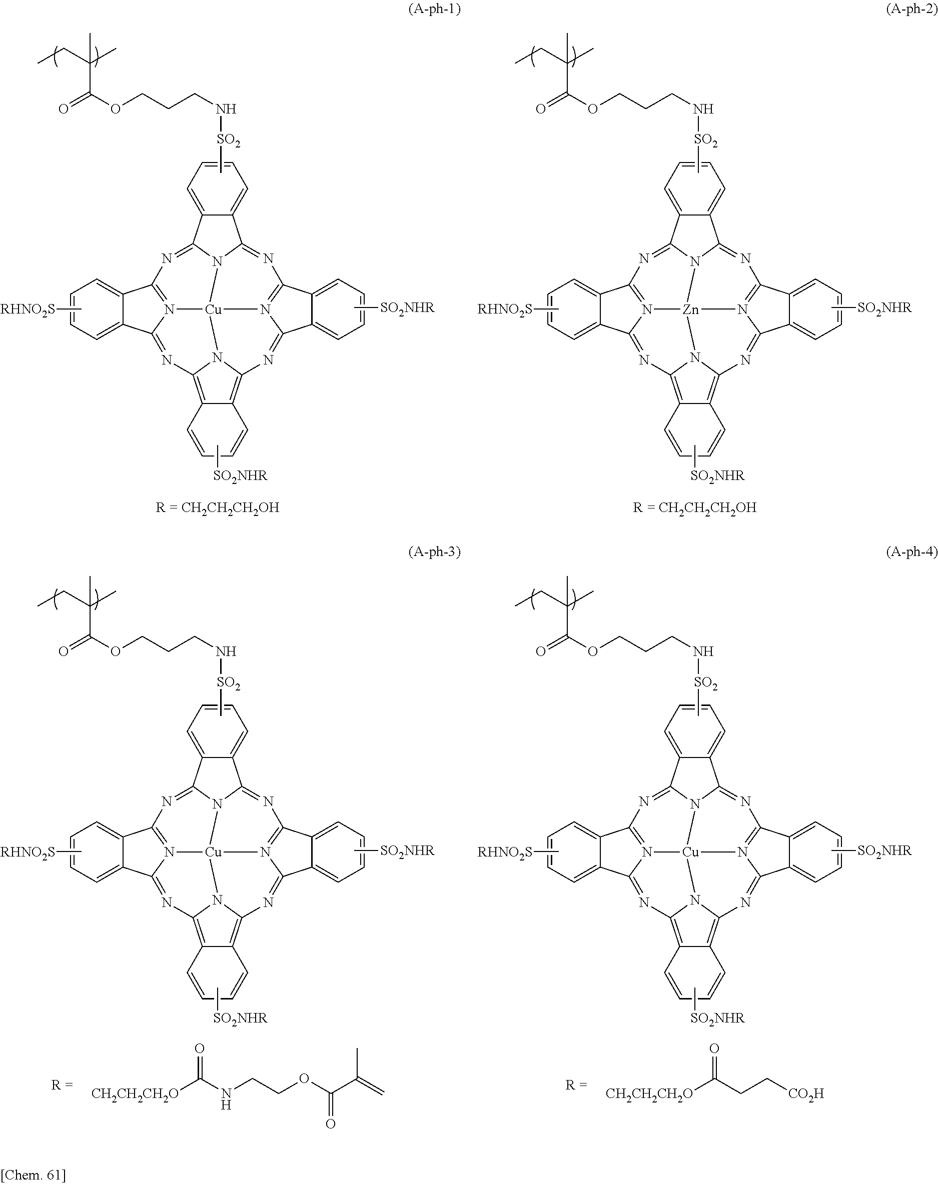

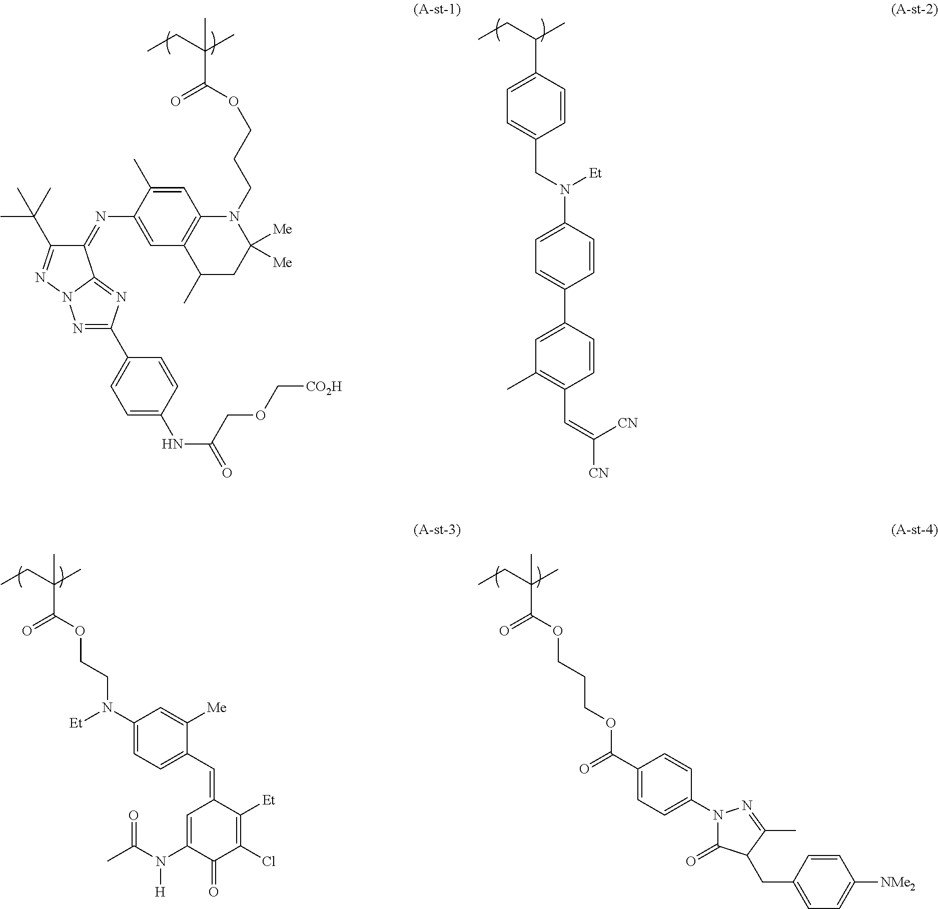

<Structural Unit Represented by General Formula (B)>

Next, the structural unit represented by General Formula (B) is described in detail

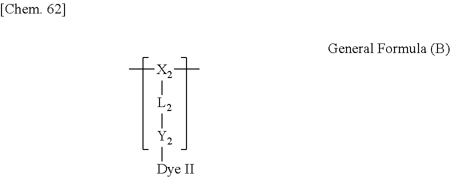

In General Formula (B), X₂ is the same as X₁ in General Formula (A). L₂ is the same as L₁ in General Formula (A). Y₂ represents a group capable of forming an ionic bonding or a coordinate bonding with Dye II. Dye II represents a dye structure.

Hereinafter, they will be described in detail.

In General Formula (B), X₂ is the same as X₁ in General Formula (A) and so are the preferable ranges L₂ is the same as L₁ in General Formula (A) and so are the preferable ranges Y₂ is a group capable of forming an ionic bonding or a coordinate bonding with Dye II and may be any group between an anionic group or a cationic group. As the anionic group, COO⁻, PO₃H⁻, SO₃⁻, —SO₃NH⁻, —SO₃N⁻CO— or the like may be included, however, COO⁻, PO₃H⁻, or SO₃⁻ is preferable.

As the cationic group, a substituted or unsubstituted onium cation (for example, ammonium, pyridinium, imidazolium, phosphonium and the like) may be included and particularly, an ammonium cation is preferable.

Y₂ may be bonded to the anion part (COO⁻, SO₃⁻, O⁻ or the like) or the cation part (the onium cation or a metal cation) contained in Dye II.

The resin having a dye structure having the structural unit represented by General Formula (B) may be synthesized in the same manner as the resin having a dye structure having the structural unit represented by General Formula (A). Especially, the resin having a dye structure having the structural unit represented by General Formula (B) in the present invention, from a viewpoint of color loss resistance, developability, and heat resistance, is preferably a radical polymer obtained by radical polymerization using a dye monomer (a monomer which has a dye structure) which has an ethylenic unsaturated bond. By providing a resin having a dye structure after the polymerization reaction to a purification method by the above described specific reprecipitation, the peak area occupied by the component having a molecular weight of 2000 or less which is measured using GPC may be favorably achieved at less than 10% in respect to the peak area of the total molecular weight distribution of the resin.

Specific examples of the structural unit represented by General Formula (B) are shown below, however the present invention is not limited to these.

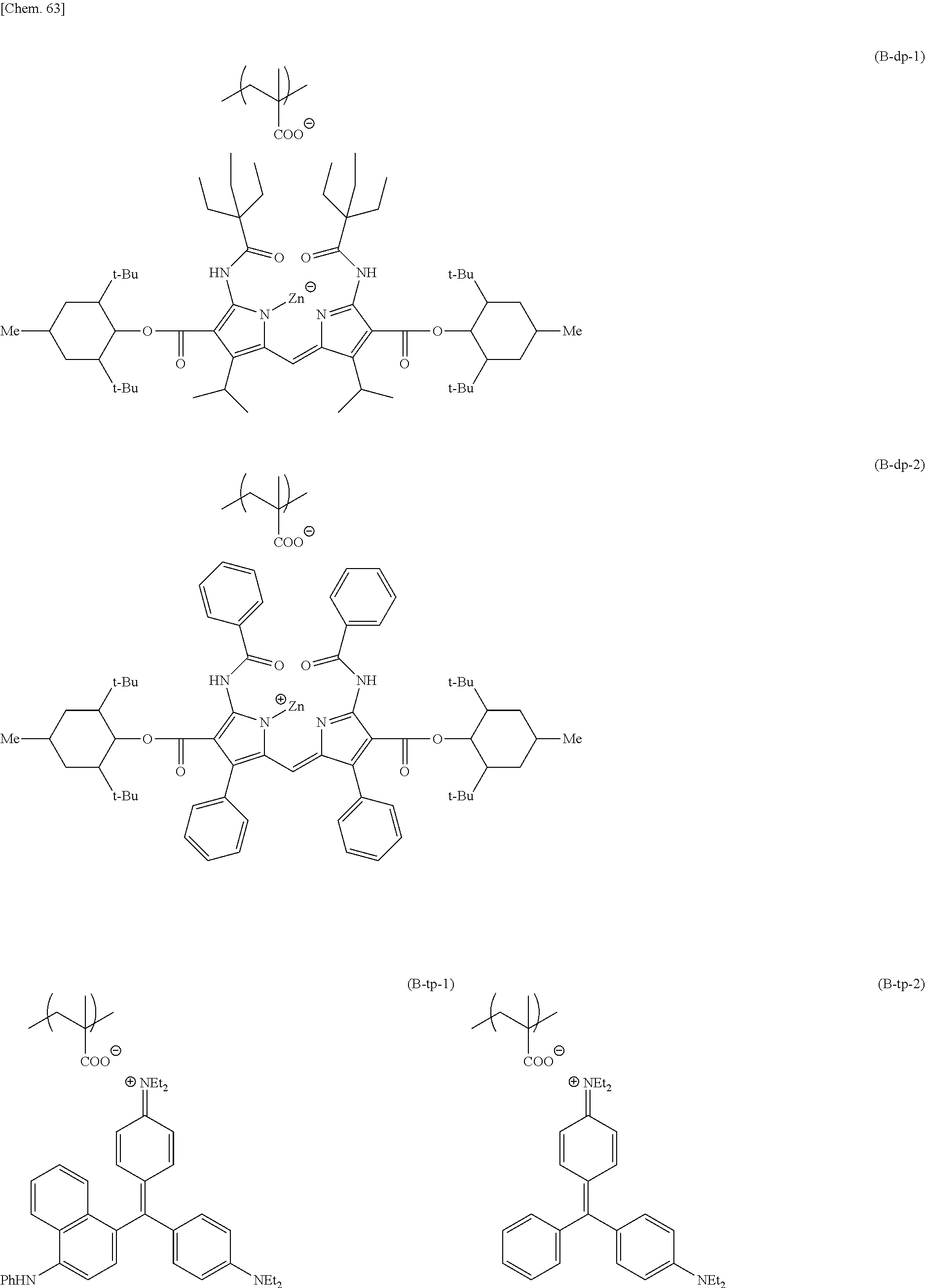

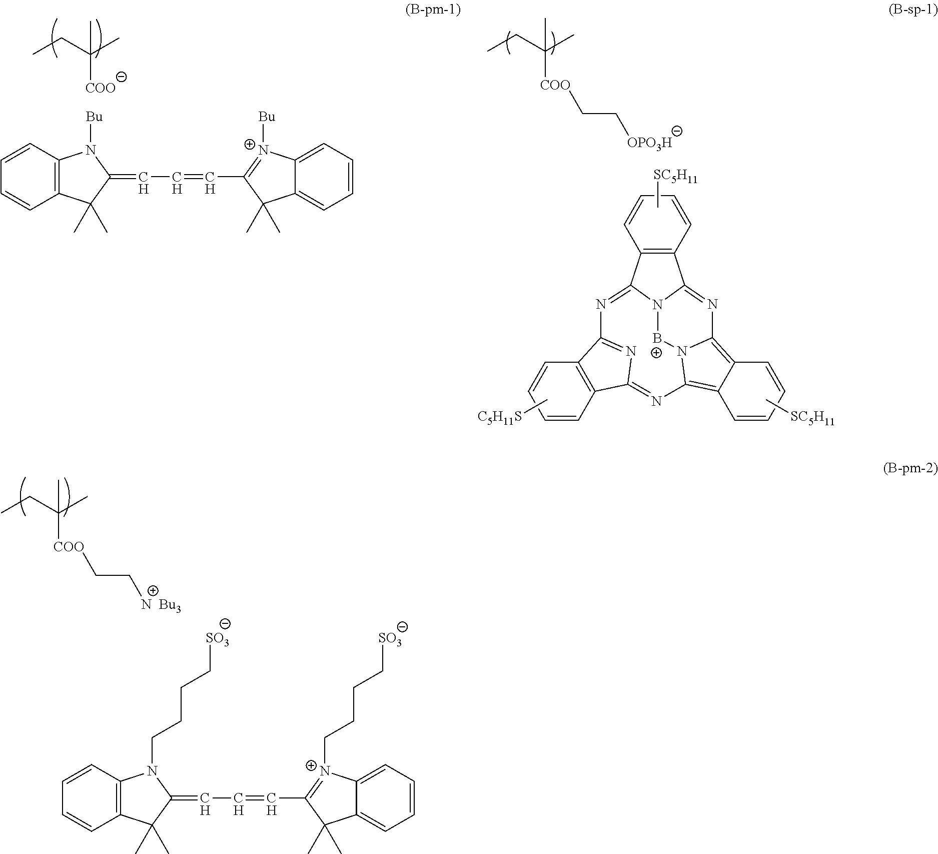

<Structural Unit Represented by General Formula (C)>

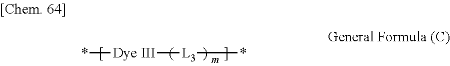

In the above General Formula (C), L₃ represents a singe bond or a divalent linking group. Dye III represents a dye partial structure m represents 0 or 1. Hereinafter, specific descriptions will be explained.

In General Formula (C), as the divalent linking group when represented by L₃, a substituted or unsubstituted linear branched, or cyclic alkylene group having 1 to 30 carbon atoms (for example, a methylene group, an ethylene group, a trimethylene group, a propylene group, a butylene group or the like), a substituted or unsubstituted arylene group having 6 to 30 carbon atoms (for example, a phenylene group, a naphthalene group or the like), a substituted or unsubstituted heterocyclic linking group, —CH═CH—, —O—, —S—, —NR— (R each independently represent a hydrogen atom, an alkyl group, an aryl group, or a heterocyclic group), —C(═O)—, —SO—, —SO₂— and a linking group formed by linking two or more of these are suitably exemplified. m represents 0 or 1, however, 1 is preferable.

Specific examples of the divalent linking group represented by L₃ in General Formula (C) are shown below, however, L₃ of the present invention is not limited to these.

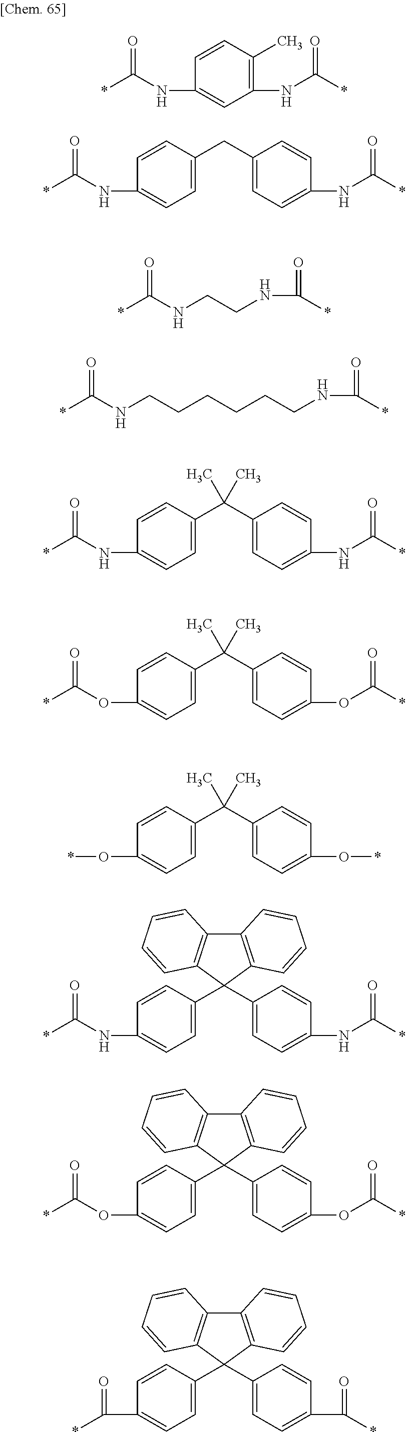

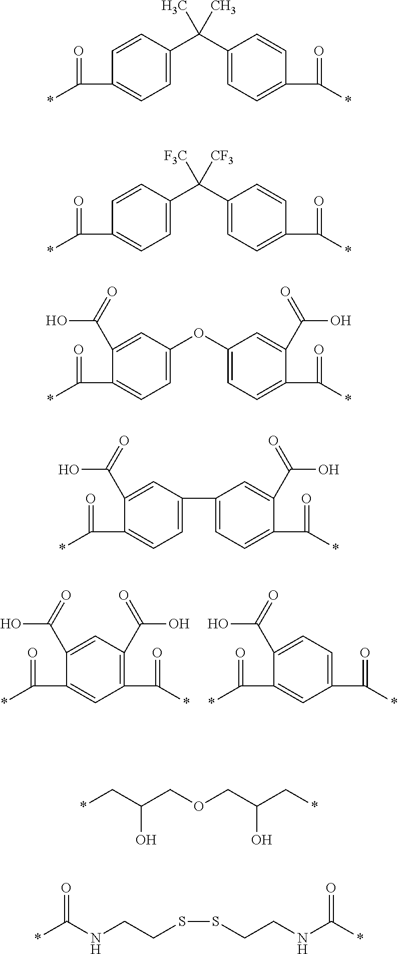

The resin having a dye structure having the structural unit in General Formula (C) is synthesized by sequential polymerization. The sequential polymerization includes polyaddition (for example, a reaction of a diisocyanate compound with diol, a reaction of a di epoxy compound with dicarboxylic acid, a reaction of tetracarboxylic acid dianhydride with diol or the like) and polycondensation (for example, a reaction of dicarboxylic acid with diol, a reaction of dicarboxylic acid and diamine or the like). Among these, particularly, synthesizing by the polyaddition reaction is preferable since it makes the reaction condition mild and does not degrade the dye structure.

As the sequential polymerization, well-known reaction conditions may be applied.

By providing a resin having a dye structure after the polymerization reaction to a purification method by the above described specific reprecipitation, the peak area occupied by the component having a molecular weight of 2000 or less which is measured using GPC may be favorably achieved at less than 10% in respect to the peak area of the total molecular weight distribution of the resin.

Specific examples of the structural unit represented by General Formula (C) are shown below, however the present invention is not limited to these.

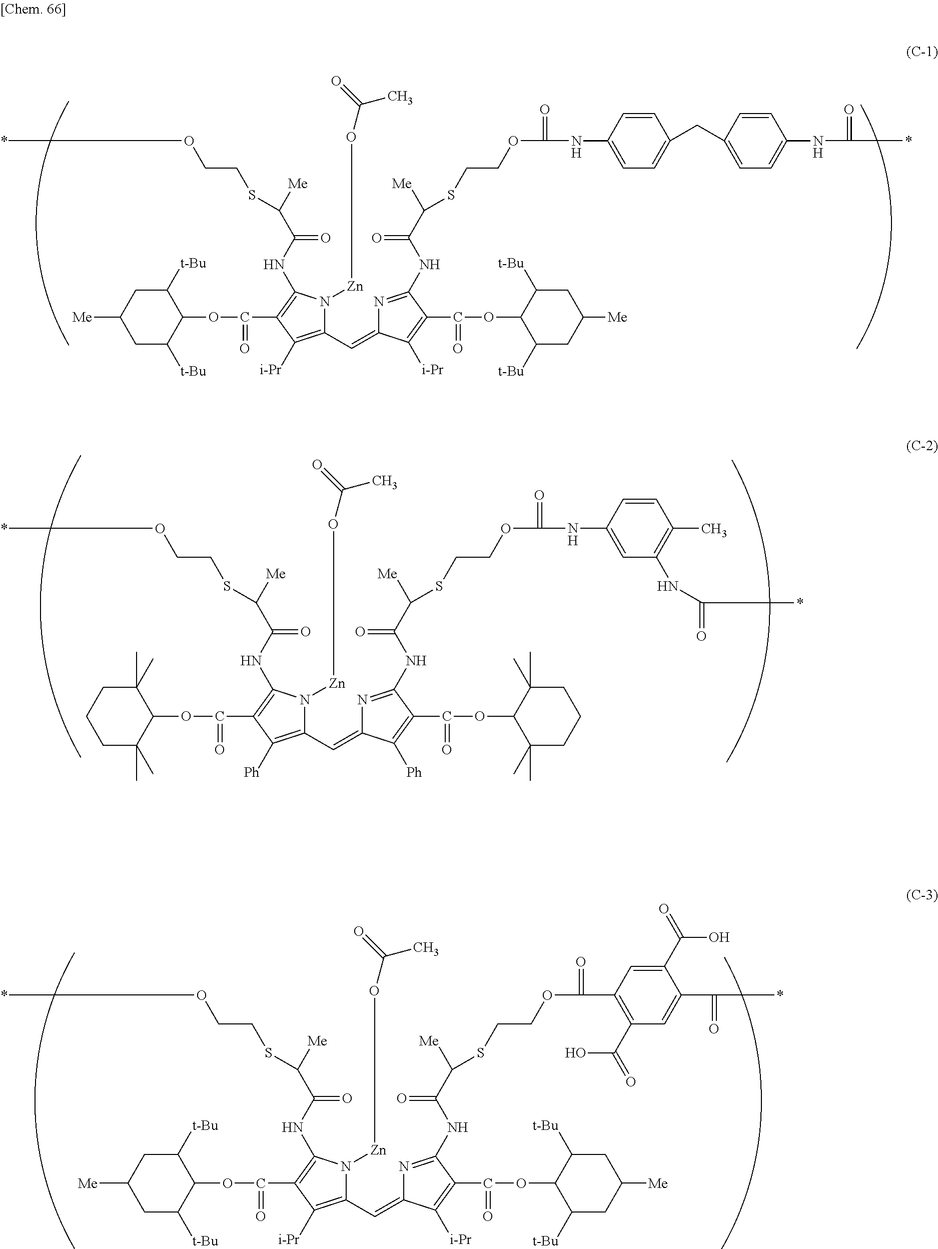

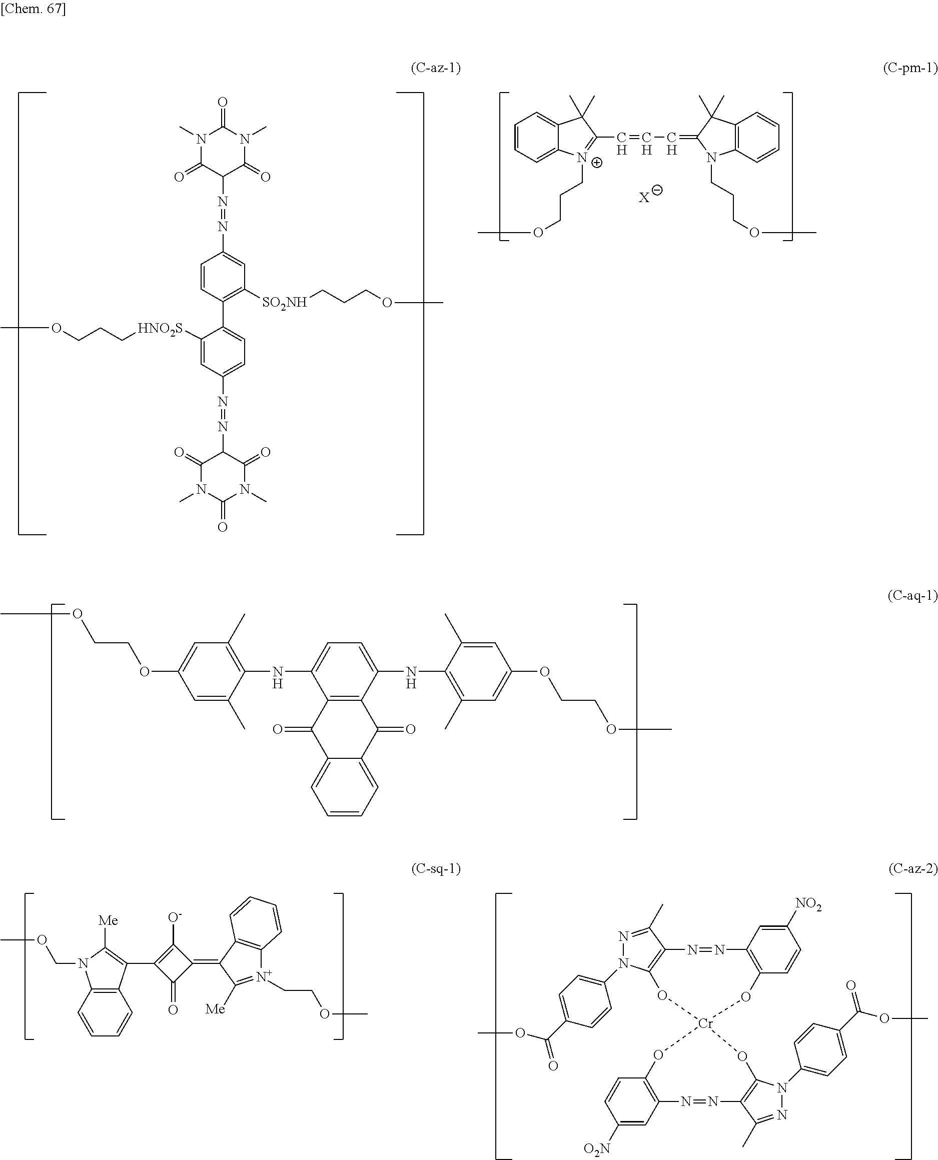

Among the resins which have a dye structure having the structural unit represented by General Formula (A), General Formula (B) and/or General Formula (C), since in the resin having a dye structure having the structural unit represented by General Formula (A) and General Formula (C), the partial structure derived from the dye is bonded by covalent bonding in the molecular structure, the coloring composition which contains the resin which has the dye structure, has excellent heat resistance. Therefore, in a case where the coloring composition is applied to a pattern forming which has a high temperature process, it is effective for color migration suppression of the other adjacent colored patterns, and is therefore preferable. Also the compound represented by General Formula (A) is preferable because it is easy to control the molecular weight of the resin having a dye structure.

(Polymerizable Group Included in Resin (A) Having a Dye Structure)

The resin (A) having a dye structure in the present invention preferably includes a polymerizable group Therefore, even when thinned, it has excellent color loss resistance, heat resistance and developability, and it is possible to form a colored cured film with good pattern formability.

As the polymerizable group, well-known polymerizable groups capable of cross-linking by radical, acid or heat may be used, and for example, groups containing ethylenic unsaturated bonds, cyclic ether groups (epoxy groups, oxetane groups), methylol groups or the like may be exemplified, however, particularly, groups containing ethylenic unsaturated bonds are preferable, (meth)acryloyl groups are more preferable, and (meth)acryloyl groups derived from glycidyl(meth)acrylate, and 3,4-epoxy-cyclohexyl methyl(meth)acrylate are most preferable. The resin (A) having a dye structure may have 2 or more types of polymerizable groups.

As introduction methods of the polymerizable group, (1) an introduction method in which the resin having a dye structure is modified by a polymerizable group containing compound, (2) an introduction method in which a dye monomer and a polymerizable group containing compound are copolymerized may be used. Hereinafter, they will be described in detail.

(1) Introduction Method in which Resin Having a Dye Structure is Modified by Polymerizable Group Containing Compound

As an introduction method by modifying a resin having a dye structure by a polymerizable group containing compound, a well-known method may be used with no particular limitations. For example, (a) a method in which a carboxylic acid included in a resin having a dye structure is reacted with an unsaturated bond containing epoxy compound, (b) a method in which a hydroxyl group or a amino group included in a resin having a dye structure is reacted with an unsaturated bond containing isocyanate compound, or (c) a method in which an epoxy compound included in a resin having a dye structure is reacted with an unsaturated bond containing carboxylic acid compound, is preferable from the viewpoint of preparation.

As the unsaturated bond containing epoxy compound in the method in which the carboxylic acid included in the resin having a dye structure (a) is reacted with the unsaturated bond containing epoxy compound, glycidyl methacrylate, glycidyl acrylate, allyl glycidyl ether, 3,4-epoxy-cyclohexylmethylacrylate, 3,4-epoxy-cyclohexylmethylmethacrylate and the like may be exemplified, however, particularly, glycidyl methacrylate and 3,4-epoxy-cyclohexylmethylmethacrylate are preferable since cross-linking property and storage stability are excellent. For the reaction conditions, well-known conditions may be used.

As the unsaturated bond containing isocyanate compound in (b) the method in which the hydroxyl group or the amino group included in the resin having a dye structure is reacted with the unsaturated bond containing isocyanate compound, 2-isocyanatoethyl methacrylate, 2-isocyanatoethylathacrylate, 1,1-bis(acryloyloxymethyl)ethylisocyanate and the like may be included, however, 2-isocyanatoethyl methacrylate is preferable since cross-linking property and storage stability are excellent. For the reaction conditions, well-known conditions may be used.

As the unsaturated bond containing carboxylic acid compound in (c) the method in which the epoxy compound included in the resin having a dye structure is reacted with the unsaturated bond containing carboxylic acid compound is not particularly limited and any carboxylic compound having well-known (meth)acryloyloxy groups may be used, however, methacrylic acid and acrylic acid are preferable, and particularly, methacrylic acid is preferable since cross-linking property and storage stability are excellent. For the reaction conditions, well-known conditions may be used.

(2) Method in which Dye Monomer and Polymerizable Group Containing Compound is Copolymerized and Introduced

(2) The method in which the dye monomer and the polymerizable group containing compound is copolymerized and introduced is not particularly limited and well-known methods may be used, however, (d) a method in which a dye monomer capable of radical polymerization is copolymerized with a polymerizable group containing compound capable of radical polymerization, (e) a method in which a dye monomer capable of polyaddition is copolymerized with a polymerizable group containing compound capable of polyaddition, is preferable.

As the polymerizable group containing compound capable of radical polymerization (d) the method in which a dye monomer capable of radical polymerization is copolymerized with a polymerizable group containing compound capable of radical polymerization, particularly, an allyl group containing compound (for example, allyl(meth)acrylate and the like), an epoxy group containing compound (for example, glycidyl(meth)acrylate), 3,4-epoxy-cyclohexylmethyl(meth)acrylate and the like), an oxetane group containing compound (for example, 3-methyl-3-oxetanylmethyl(meth)acrylate and the like), a methylol group containing compound (for example, N-(hydroxymethyl)acrylamide and the like) may be included and particularly, an epoxy compound and an oxetane compound are preferable. For the reaction conditions, well-known conditions may be used.

As the polymerizable group containing compound capable of polyaddition in (e) the method in which a dye monomer capable of polyaddition is copolymerized with a polymerizable group containing compound capable of polyaddition, an unsaturated bond containing diol compound (for example, 2,3-dihydroxypropyl(meth)acrylate and the like) may be included. For the reaction conditions, well-known conditions may be used.

As the method for introducing a polymerizable group, the method in which the carboxylic acid included in the resin having a dye structure is reacted with the unsaturated bond containing epoxy compound is the most preferable.

As the amount of the polymerizable group included in the resin (A) having a dye structure, 0.1 to 2.0 mmol with regard to 1 g of the resin (A) having a dye structure is preferable, 0.2 to 1.5 mmol is more preferable, and 0.3 to 1.0 mmol is the most preferable.

As the method for introducing the polymerizable group, the method in which the carboxylic acid included in the resin having a dye structure is reacted with the unsaturated bond containing epoxy compound is the most preferable.

As the structural unit having the polymerizable group, specific examples shown below may be included. However, the present invention is not limited to these.

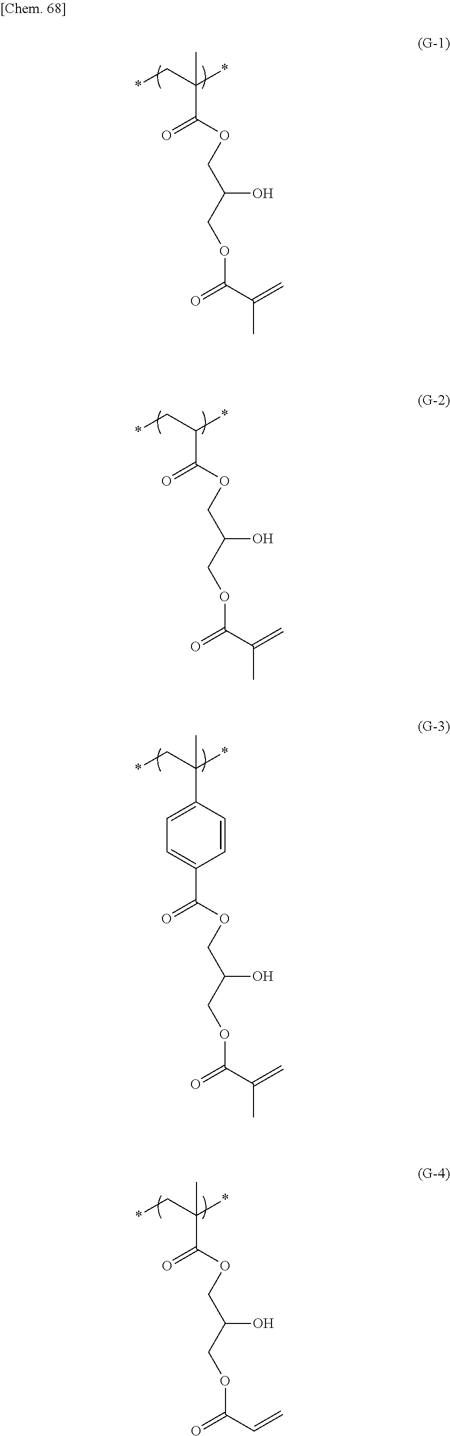

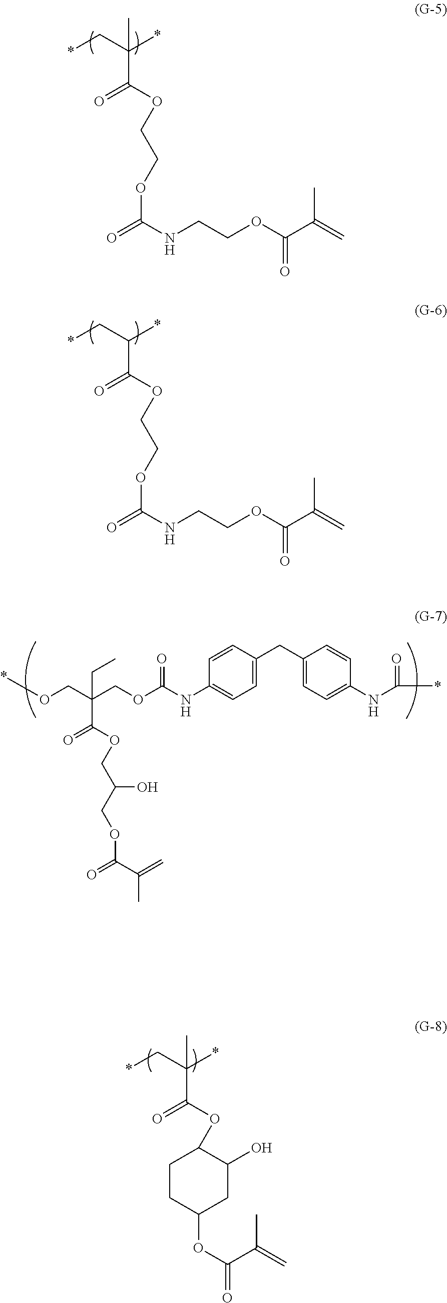

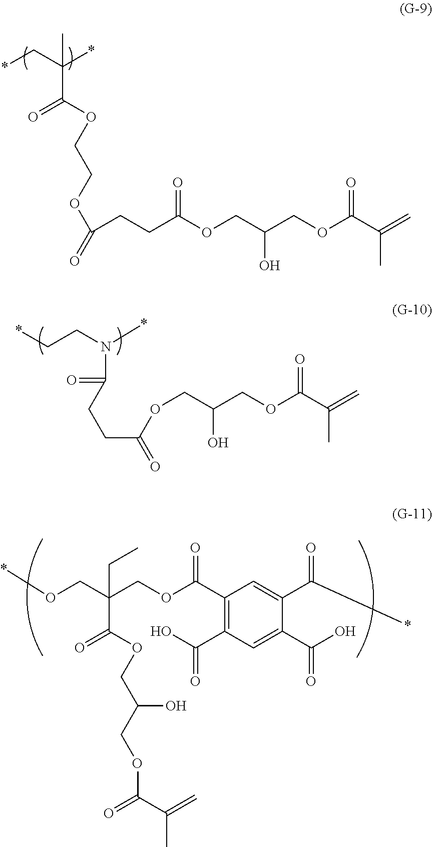

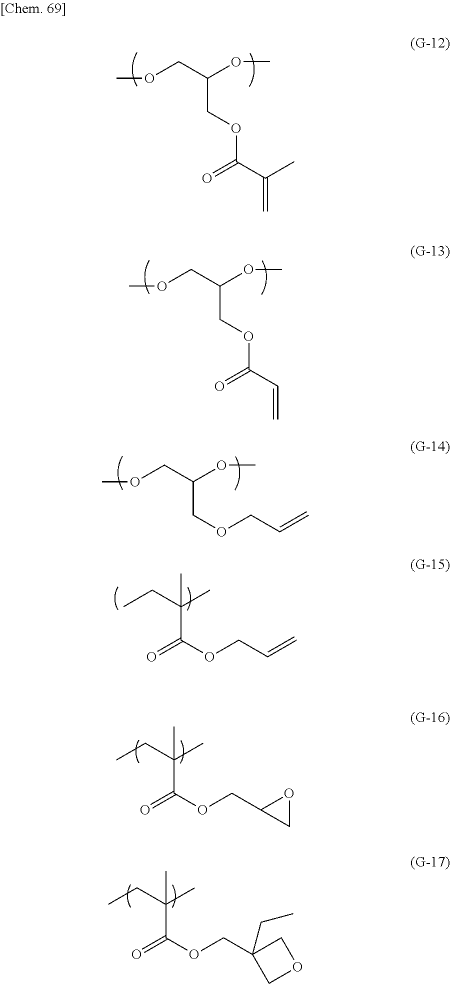

Among the above described specific examples, from a viewpoint of the substrate adhesion and the surface roughness, a dye monomer which has an ethylenic unsaturated bond is preferable, and among these, a methacryloyl group, an acryloyl group, a styryl group, or a vinyloxy group is preferable, and a methacryloyl group is most preferable.

Other Functional Group Included in Resin (A) Having a Dye Structure

The resin (A) having a dye structure in the present invention may include another functional group. As the other functional groups, an alkali-soluble group such as carboxylate, sulfonate, phosphate, and phenolic hydroxyl group and the like is preferable. As the alkali-soluble group, carboxylate is the most preferable.

As a method for introducing the alkali-soluble group to the resin having a dye structure, a method in which the alkali-soluble group is introduced to the dye monomer in advance, and a monomer other than the dye monomer having the alkali-soluble group ((meth)acrylic acid, a caprolactone modified product of acrylic acid, a succinic anhydride modified product of 2-hydroxyethyl(meth)acrylate, a phthalic anhydride modified product of 2-hydroxyethyl(meth)acrylate, a 1,2-cyclohexanedicarboxylic anhydride modified product of 2-hydroxyethyl(meth)acrylate, a carboxylic acid contained monomer such as styrene carboxylic acid, itaconic acid, maleic acid, norbonenecarboxylic acid or the like, a phosphoric acid contained monomer such as acid phosphooxyethylmethacrylate and vinyl phosphonic acid, and a sulfonic acid contained monomer such as vinyl sulfonic acid and 2-acrylamide-2-methylsulfonic acid) are copolymerized is included, however, the use of both methods is the most preferable.

As the amount of the alkaline-soluble group (acid value) included in the resin (A) having a dye structure, 0.3 mmol 1 to 2.0 mmol with regard to 1 g of the resin (A) having a dye structure is preferable, 0.4 mmol 1 to 1.5 mmol is more preferable, and 0.5 mmol 1 to 1.0 mmol is the most preferable. In the present invention, the acid value of the resin having a dye structure may, for example, be calculated from the average content of an alkaline-soluble group (acid group) in the resin having a dye structure. Also, by changing the content of the repeating unit (structural unit) containing an acid group which configures a resin having a dye structure, a resin which has a desired acid value may be obtained.

As the other functional groups included in the resin (A) having a dye structure, a development promoting group such as lactone, an acid anhydride, an amide, —COCH₂CO—, or a cyano group, an adjusting group with a hydrophilic or hydrophobic property such as an alkyl group with long chain and a ring structure, an aralkyl group, an aryl group, a polyalkylene oxide group, a hydroxyl group, a maleimide group, or an amino group or the like may be included and is appropriately introduced. As the method for introducing, a method in which the other functional groups are introduced to the dye monomer in advance and a method in which the monomer having the functional group is copolymerized.

As the repeating unit having other functional groups included in the resin (A) having a dye structure, specific examples shown below are represented, however the present invention is not limited to this.

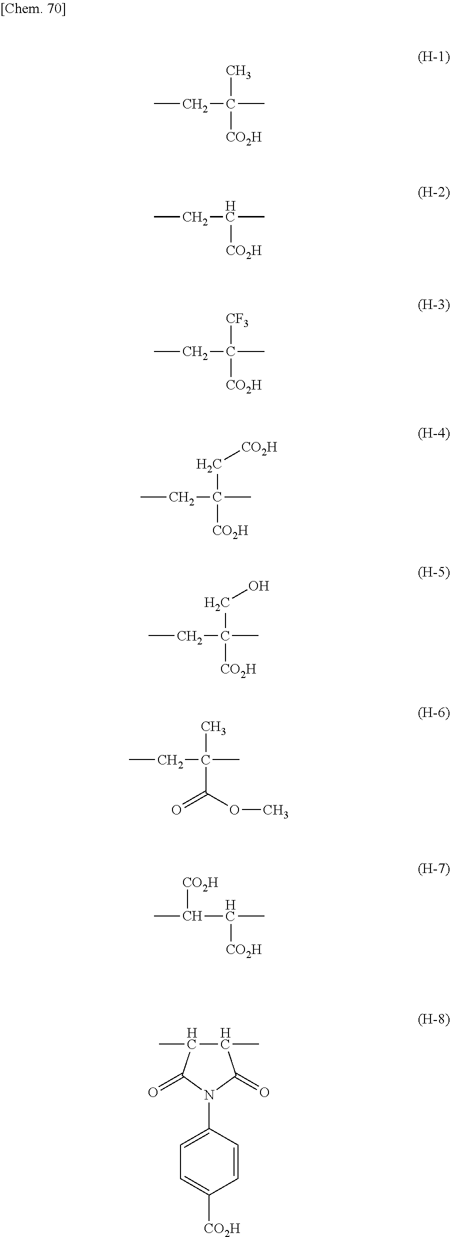

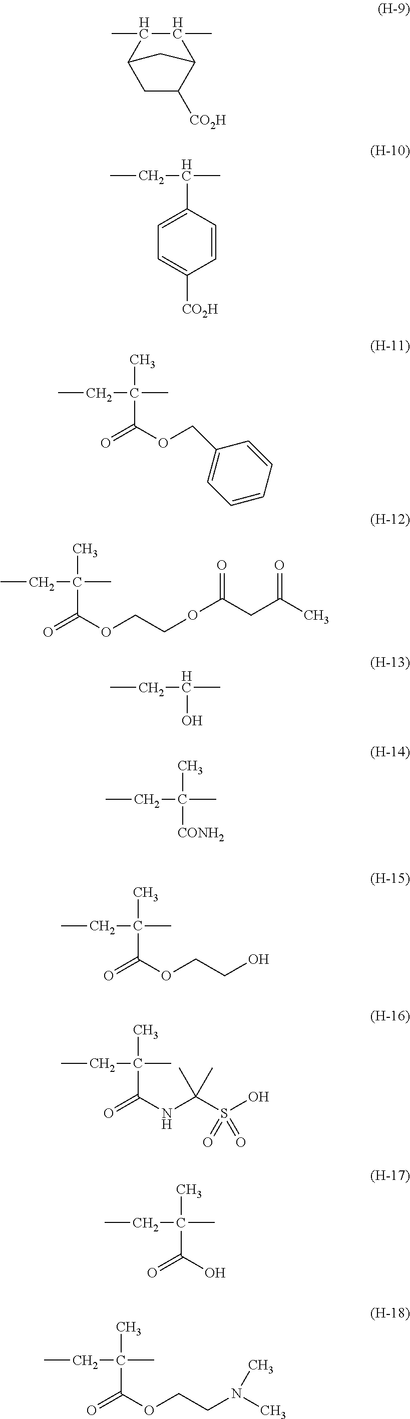

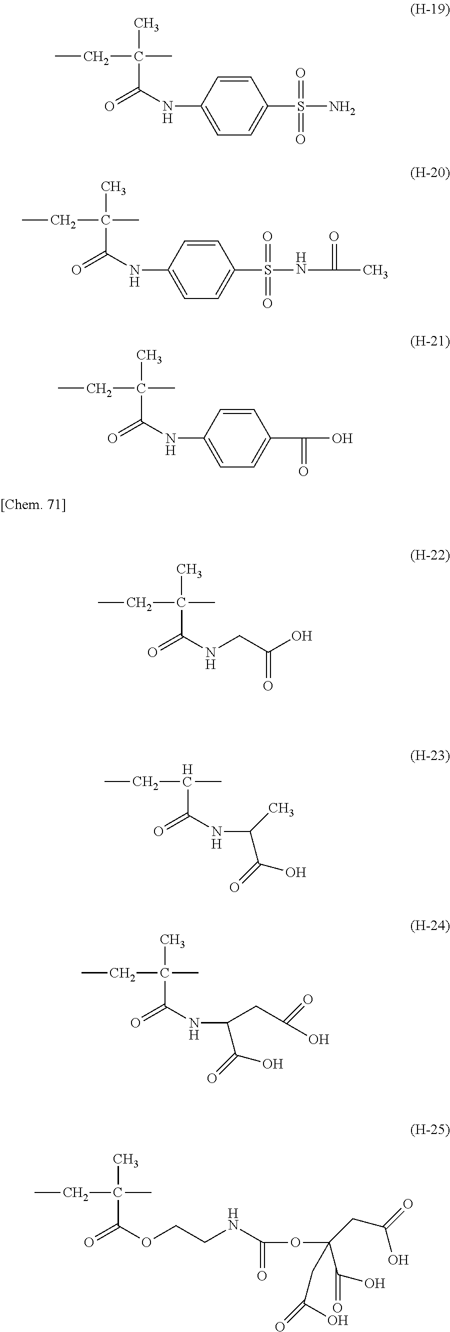

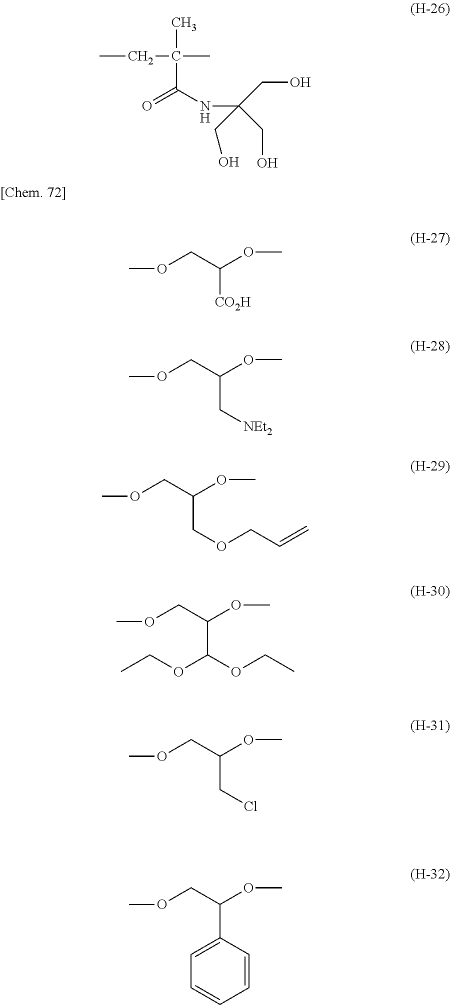

The Tg of the resin (A) having a dye structure according to the present invention is preferably 50° C. or higher, and is further preferably 100° C. or higher. Also the 5% weight loss temperature according to thermogravimetric analysis (TGA measurement) is preferably 120° C. or higher, more preferably 150° C. or higher, and even more preferably 200° C. By setting Tg and the 5% weight loss temperature in these regions, when the coloring composition of the present invention is applied to the production of color filters and the like, it is possible to reduce a density change caused by the heating process.

Also, the extinction coefficient (Hereinafter denoted as ε′. ε′=ε/average molecular weight, unit: L/g cm) per unit weight of the resin having a dye structure according to the present invention is preferably 30 or more, more preferably 60 or more, and even more preferably 100 or more. By being within this range, applying the coloring composition of the present invention, in a case where a color filter is produced, a color filter with good color reproduction may be produced.

The molar extinction coefficient of the resin (A) having a dye structure used in the coloring composition of the present invention, from a viewpoint of coloring power, is preferably as high as possible.

The resin (A) having a dye structure according to the present invention is preferably a compound which is soluable in the below organic solvents.

As the organic solvent, esters (for example, 3-ethoxypropionic acid methyl, 3-ethoxypropionic acid ethyl, ethyl lactate, butyl acetate, 3-methoxypropionic acid methyl, and the like), ethers (for example, methyl cellosolve acetate, ethyl cellosolve acetate, propylene glycol monomethyl ether, propylene glycol monomethyl ether acetate, and the like), ketones (for example, methyl ethyl ketone, cyclohexanone, 2-heptanone, 3-heptanone), and aromatic hydrocarbons (for example, toluene, xylene and the like) may be exemplified and in regard to these solvents (25° C.), the resin (A) having a dye structure according to the present invention is preferably soluble from 1 mass % to 50 mass %, more preferably from 5 mass % to 40 mass %, and even more preferably from 10 mass % to 30 mass %. By setting the solubility in this region, when the coloring composition of the present invention is applied to the production of color filters and the like, it is possible to obtain a favourable coating surface and to reduce a decrease in density caused by the elusion after coating another color.

In the coloring composition of the present invention, one type of the resin having a dye structure may be used, and two or more types may also be used together.

The content of the resin having a dye structure in the coloring composition of the present invention is set with the content ratio with the pigment (B) described below in consideration.

As the mass ratio (resin (A) having a dye structure/pigment) of the resin having a dye structure in regard to the pigment, 0.1 to 5 is preferable, 0.2 to 2 is more preferable, and 0.3 to 1 is even more preferable.

[(B) Pigment]

The coloring composition of the present invention preferably contains a pigment.

As the pigment used in the present invention, various inorganic pigments or organic pigments which are well-known may be used. It is preferable that the pigment have a high transmission.

As the inorganic pigment, metal compound such as metallic oxides and metallic complex salts may be exemplified, specifically, metallic oxides of iron, cobalt, aluminum, cadmium, lead, copper, titanium, magnesium, chromium, zinc, antimony, and the like and complex oxides of the above metals may be exemplified.

As organic pigments, for example,

C.I. pigment yellow 11, 24, 31, 53, 83, 93, 99, 108, 109, 110, 138, 139, 147, 150, 151, 154, 155, 167, 180, 185, 199;
C.I. pigment orange 36, 38, 43, 71;
C.I. pigment red 81, 105, 122, 149, 150, 155, 171, 175, 176, 177, 209, 220, 224, 242, 254, 255, 264, 270;
C.I. pigment violet 19, 23, 32, 39;
C.I. pigment blue 1, 2, 15, 15:1, 15:3, 15:6, 16, 22, 60, 66;
C.I. pigment green 7, 36, 37, 58;
C.I. pigment brown 25, 28;
C.I. pigment black 1, 7;
and the like may be exemplified.

In the present invention, as pigments which may be preferably used, the following may be exemplified. However, the present invention is not limited to these.

C.I. pigment yellow 11, 24, 108, 109, 110, 138, 139, 150, 151, 154, 167, 180, 185,

C.I. pigment orange 36, 71,
C.I. pigment red 122, 150, 171, 175, 177, 209, 224, 242, 254, 255, 264,
C.I. pigment violet 19, 23, 32,
C.I. pigment blue 15:1, 15:3, 15:6, 16, 22, 60, 66,
C.I. pigment green 7, 36, 37, 58,
C.I. pigment black 1, 7.

These organic pigments may be used individually, or as a combination in order to raise the spectral adjustment or the color purity. Specific examples of the mixtures are shown below. For example, as a red pigment, a mixture or the like of at least one type of anthraquinone pigments, perylene pigments, or diketopyrrolopyrrole pigments, and disazo yellow pigments, isoindoline yellow pigments, quinophthalone yellow pigments, or perylene red pigments may be used. For example, as the anthraquinone pigment, C.I. pigment red 177 may be exemplified, as the perylene pigment, C.I. pigment red 155 and C.I. pigment red 224 may be exemplified, as the diketopyrrolopyrrole pigment, C.I. pigment red 254 may be exemplified, and from a viewpoint of color separation, a mixture with C.I. pigment yellow 139 is preferable. Also, the mass ratio between a red pigment and a yellow pigment is preferably from 100:5 to 100:50. At 100:4 or less, it becomes difficult to suppress light transmission from 400 nm to 500 nm, and at 100:51 or more, the main wavelength becomes biased toward short wavelengths and there are cases in which the chromatic resolution power may not be raised. In particular, as the above mass ratio, a range from 100:10 to 100:30 is optimal. Furthermore, when the red pigments are combined with each other, adjustment corresponding to a desired spectrum becomes possible.

Also, as the green pigment, a halogenated phthalocyanine pigment may be used independently, or in a mixture with a disazo yellow pigment, a quinophthalone yellow pigment, an azomethine yellow pigment, or an isoindoline yellow pigment. For example, as an example of this, a combination of C.I. pigment green 7, 36, 37, and C.I. pigment yellow 83, C.I. pigment yellow 138, C.I. pigment yellow 139, C.I. pigment yellow 150, C.I. pigment yellow 180, or C.I. pigment yellow 185 is preferable. The mass ratio between a green pigment and a yellow pigment is preferably from 100:5 to 100:150. As the above mass ratio, a range from 100:30 to 100:120 is particularly preferable.

As the blue pigment, a phthalocyanine pigment may be used independently, or in a mixture with a dioxazine violet pigment. For example, a combination of C.I. pigment blue 15:6 and C.I. pigment violet 23 is preferable. The mass ratio between a blue pigment and a violet pigment is preferably from 100:0 to 100:100, and is more preferably 100:10 or less.

Also, as the pigment for the black matrix, carbon, titanium black, iron oxide, titanium oxide may be used individually or as a mixture thereof, and a combination of carbon and titanium black is preferable. Also, the mass ratio between carbon and titanium black is preferably a range of from 100:0 to 100:60.

The primary particle diameter of the pigment is, when used for a color filter, from a viewpoint of color uneveness and contrast, preferably 100 nm or less, and from a viewpoint of dispersion stability, preferably 5 nm or more. As the primary particle diameter of the pigment, from 5 to 75 nm is more preferable, from 5 to 55 nm is even more preferable, and from 5 to 35 nm is particularly preferable. The specific resin of the present invention may exhibit an effect particularly in a range of from 5 to 35 nm.

The primary particle diameter of the pigment may be measured using a well-known method such as an electron microscope.

Among these, as a pigment, a pigment selected from anthraquinones, diketopyrrolopyrroles, phthalocyanines, quinophthalones, isoindolines, azomethines, and dioxazines is preferable. In particular, C.I. pigment red 177 (anthraquinone), C.I. pigment red 254 (diketopyrrolopyrrole), C.I. pigment green 7, 36, 58, C.I. pigment blue 15:6 (phthalocyanine), C.I. pigment yellow 138 (quinophthalone), C.I. pigment yellow 139, 185 (isoindoline), C.I. pigment yellow 150 (azomethine), and C.I. pigment violet 23 (dioxazine) are most preferable.

Dispersing Agent

The coloring composition of the present invention may contain a pigment dispersing agent.

As the pigment dispersing agent which may be used in the present invention, a polymer dispersing agent (for example, polyamide amine and salts thereof, polycarboxylic acid and salts thereof, high molecular weight unsaturated acid esters, modified polyurethanes, modified polyesters, modified poly(meth)acrylates, (meth)acrylic copolymers, and naphthalene sulfonic acid formalin condensates), a surfactant such as polyoxyethylene alkyl phosphate ester, polyoxyethylene alkylamine, and alkanolamine, and a pigment derivative may be exemplified.

The polymer dispersing agents may be further classified from the configuration thereof as a linear polymer, a terminal modified polymer, a graft polymer, and a block polymer.

As the terminal modified polymer which has an anchor portion in the pigment surface, for example, the polymer which has a phosphate group on a terminal thereof disclosed in JP1991-112992A (JP-H03-112992A), JP2003-533455A, or the like, the polymer which has a sulfonate group on a terminal thereof disclosed in JP2002-273191A, the polymer which has a partial skeleton or a complex ring of an organic dye disclosed in JP1997-77994A (JP-H09-77994A), or the like may be exemplified. Also, a polymer, in which two or more anchor portions (acid groups, basic groups, partial skeletons of organic dye, hetero rings, or the like) to a pigment surface are introduced in the polymer terminal disclosed in JP2007-277514A, has excellent dispersion stability and is preferable.

As a graft polymer which has an anchor portion in the pigment surface, for example, polyester dispersion agents and the like may be exemplified, and specifically, reaction products of poly (lower alkyleneimine) and polyester disclosed in JP1979-37082A (JP-S54-37082A), JP1996-507960A (JP-H08-507960A), JP2009-258668A, and the like, reaction products of polyallylamine and polyester disclosed in JP1997-169821A (JP09-169821A), copolymers of macromonomers and nitrogen atom monomers disclosed in JP1998-339949 (JP-H10-339949), JP2004-37986, and WO2010/110491A, graft polymers which have partial skeletons and complex rings of the organic dyes described in JP2003-238837A, JP2008-9426A, JP2008-81732A, and the like, and copolymers and the like of macromonomers and acid group containing monomers disclosed in JP2010-106268A and the like may be exemplified. In particular, the amphoteric dispersing resin which has a basic group and an acid group disclosed in JP2009-203462A is particularly preferable from a viewpoint of the dispersibility and the dispersing stability of a pigment dispersoid, and the developability exhibited by a coloring composition which uses the pigment dispersoid.

As the macromonomer used when manufacturing a graft polymer which has an anchor portion in the pigment surface using radical polymerization, a well-known macromonomer may be used, the macromonomers manufactured by Toagosei Chemical Industry Co., Ltd. AA-6 (polymethylmethacrylate in which the terminal group is a methacryloyl group), AS-6 (polystyrene in which a terminal group is a methacryloyl groups), AN-6S (a copolymer of styrene and acrylonitrile in which a terminal group is a methacryloyl group), AB-6 (polybutyl acrylate in which a terminal group is a methacryloyl group), Placcel FM5 manufactured by Daicel Chemical Ind., Ltd. (ε-caprolactone 5 molar equivalent additive of 2-hydroxyethyl methacrylate), FA10L (ε-caprolactone 10 molar equivalent additive of 2-hydroxyethyl acrylate), and the polyester macromonomer or the like disclosed in JP1990-272009A (JP-H02-272009A) may be disclosed. Among these, in particular, polyester macromonomers with excellent flexibility and pro-solvent properties are particularly preferable from a viewpoint of the dispersibility and the dispersing stability of a pigment dispersoid, and the developability exhibited by a coloring composition which used the pigment dispersoid, furthermore, a polyester macromonomer represented by the polyester macromonomer disclosed in JP1990-272009A (JP-H02-272009A) is most preferable.

As the block polymer which has an anchor portion in the pigment surface, the block polymer disclosed in JP2003-49110A, JP2009-52010A, or the like is preferable.

The pigment dispersing agent which can be used in the present invention is possible to obtain as a commercial product, and as a specific example, Kusumoto Chemicals, Ltd. manufactured “DA-7301”, BYKChemie manufactured “Disperbyk-101 (polyamideamine phosphate), 107 (carboxylic acid ester), 110 (copolymers including acid groups), 130 (polyamide), 161, 162, 163, 164, 165, 166, 170 (high molecular weight copolymer)”, “BYK-P104, P105 (high molecular weight saturated polycarbonate), EFKA manufactured “EFKA4047, 4050 to 4010 to 4165 (polyurethanes), EFKA4330 to 4340 (block copolymers), 4400 to 4402 (modified polyacrylate), 5010 (polyesteramides), 5765 (high molecular weight polycarboxylates), 6220 (fatty acid polyester), 6745 (phthalocyanine derivatives), 6750 (azo pigment derivatives)”, Ajinomoto Fine-Techno Co., Inc. manufactured “AJISPER PB821, PB822, PB880, PB881”, Kyoeisha Chemical Co., Ltd manufactured “FLOWLEN TG-710 (urethane oligomer), “Polyflow No. 50E, No. 300 (acryl copolymer)”, Kusumoto Chemicals, Ltd. manufactured “Disparlon KS-860, 873 SN, 874, #2150 (aliphatic polyvalent carboxylic acid), #7004 (polyether-ester), DA-703-50, DA-705, DA-725”, Kao Corporation manufactured “DEMOL RN, N (naphthalene sulfonic acid formalin polycondensate), MS, C, SN-B (aromatic sulfonic acid formalin polycondensate)”, “homogenol L-18 (high molecular weight polycarboxylic acid)”, “EMULGEN 920, 930, 935, 985 (polyoxyethylene nonylphenyl ether)”, “ASETAMIN 86 (stearylamine acetate)”, Lubrizol Corporation manufactured “Solsperse 5000 (phthalocyanine derivative), 22000 (azo pigment derivative), 13240 (polyesteramine), 3000, 17000, 27000 (polymer which has a functional portion in the terminal portions), 24000, 28000, 32000, 38500 (graft polymer)”, Nikko Chemicals Co., Ltd. “NIKKOR T106 (polyoxyethylene sorbitan monooleate), MYS-IEX (polyoxyethylene monostearate), Kawaken Fine Chemicals Co., Ltd. manufactured Hinoact T-8000E or the like, Shin-Etsu Chemical Co., Ltd. manufactured, organosiloxane polymer KP341, Yusho Co., Ltd. manufactured “W001: cation surfactant”, nonion surfactants such as polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty ester, anion surfactants such as “W004, W005, W017”, Morishita Industries manufactured “EFKA-46, EFKA-47, EFKA-47EA, EFKA polymer 100, EFKA polymer 400, EFKA polymer 401, EFKA polymer 450”, Sannopco Co., Ltd. manufactured polymer dispersing agents such as “Dispersuade 6, Dispersuade 8, Dispersuade 15, Dispersuade 9100”, ADEKA Corporation manufactured “Adeka Pluronic L31, F38, L42, L44, L61, L64, F68, L72, P95, F77, P84, F87, P94, L101, P103, F108, L121, P-123”, and Sanyo Chemical Industries Ltd. manufactured “Ionet (product name) S-20” and the like may be exemplified.

These pigment dispersion agents may be used individually and may also be used in a combination of two or more types. In the present invention, in particular, it is preferable to use a combination of the pigment derivative and the polymer dispersing agent. Also, as the pigment dispersing agent of the present invention, an alkaline soluble resin may be used together with a terminal modified polymer, a graft polymer, and a block polymer which have an anchor portion in the pigment surface. As the alkaline soluble resin, a resin in which a (meth)acrylic acid copolymer, an itaconic acid copolymer, a crotonic acid copolymer, a maleic acid copolymer, a partially esterified maleic acid copolymer and the like, and a acidic cellulose derivative having carboxylic acid in a side chain or a polymer having a hydroxyl group is modified by an acidic anhydride may be exemplified, however, in particular, a (meth)acrylic acid copolymer is preferable. Also, an alkaline soluble resin containing the N-substituted maleimide monomer copolymer disclosed in JP1998-300922A (JP-H10-300922A), the ether dimer copolymer disclosed in JP2004-300204A, or the polymerizable group disclosed in JP1995-319161A (JP-H07-319161A) is preferable.

As the content of the pigment dispersing agent in the coloring composition, in regard to 100 parts by mass of pigment, 1 parts by mass to 80 parts by mass is preferable, 5 parts by mass to 70 parts by mass is more preferable, and 10 parts by mass to 60 parts by mass is even more preferable.

Specifically, in a case where a polymer distributing agent is used, the content thereof is, in regard to 100 parts by mass of pigment, by mass conversion a range of 5 parts to 100 parts is preferable, and a range of 10 parts to 80 parts is more preferable.

Also, in a case where a pigment derivative is used with this, the content of the pigment derivative is, in regard to 100 parts by mass of pigment, by mass conversion a range of 1 part to 30 parts is preferable, a range of 3 parts to 20 parts is more preferable, and a range of 5 parts to 15 parts is particularly preferable.

In the coloring composition, in a case where, together with the pigment as a coloring agent, a pigment dispersion agent is also used, from a viewpoint of curing sensitivity and color density, the total content of the coloring agent and the dispersing agent is, in regard to the total solid portion which configures the coloring composition, preferably from 50 mass % to 90 mass %, more preferably from 55 mass % to 85 mass %, and even more preferably from 60 mass % to 80 mass %.

(C) Polymerizable Compound

The coloring composition of the present invention preferably contains a polymerizable compound.

Well-known polymerizable compounds capable of cross-linking by radical, acid or heat, may be used, and for example, polymerizable compounds which include ethylenic unsaturated bonds, cyclic ether (epoxy, oxetane), methanol or the like may be exemplified. The polymerizable compound is appropriately selected from the compound having at least one, preferably two or more terminal ethylenic unsaturated bonds from a viewpoint of sensitivity. Among these, the multifunctional polymerizable compound of tetrafunctional or more is preferable, and of penta-functional or higher multifunctional polymerizable compound is more preferable.

This group of compounds is widely known in the related industry field and these may be used without particular limitation in the present invention. These may be any chemical form of, for example, a monomer, a prepolymer, that is, a dimer, a trimer, and an oligomer, or a mixture thereof and a polymer thereof and the like. The polymerizable compound in the present invention may be used either alone or as a combination of two or more.

More specifically, as examples of the monomer and the prepolymer, unsaturated carboxylic acids (for example, acrylic acid, methacrylic acid, itaconic acid, crotonic acid, isocrotonic acid, maleic acid and the like) or esters thereof, amides thereof, and polymers thereof may be included and preferably, esters of unsaturated carboxylic acids and aliphatic multivalent alcohol compounds and amides of unsaturated carboxylic acids and an aliphatic multivalent amine compounds and polymers thereof are included. Also, addition reaction products of unsaturated carboxylic acid esters or amides having nucleophilic substituents such as a hydroxyl group, an amino group, a mercapto group or the like and monofunctional or multifunctional isocyanates or epoxies, or dehydration condensation reaction with monofunctional or multifunctional carboxylic acids or the like is suitably used. In addition, addition reaction products of unsaturated carboxylate esters or amides having electrophilic substituents such as an isocyanate group or an epoxy group or the like and monofunctional or multifunctional alcohols, amines or thiols, or substituted reaction products of unsaturated carboxylate esters or amides having dissociating substituents such as a halogen group or a tosyloxy group and monofunctional or multifunctional alcohols, amines or thiols are also suitably used. Moreover, as other examples, the use of a compound group substituted with a vinyl benzene derivative such as unsaturated phosphonic acid, styrene or the like, vinyl ether, allyl ether or the like instead of the unsaturated carboxylic acids is possible.

As the specific examples such as these, compounds disclosed in paragraph number [0095] to [0108] of JP2009-288705A may also be suitably used in the present invention.

Furthermore, as the polymerizable compound, a compound having at least one ethylene group capable of polyaddition and having an ethylenic unsaturated group with the boiling point of 100° C. or more under atmospheric pressure is also preferable. As the examples, monofunctional acrylate or methacrylate such as polyethylene glycol mono(meth)acrylate, polypropylene glycol mono(meth)acrylate, phenoxyethyl(meth)acrylate; multifunctional acrylate or methacrylate such as polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol(meth)acrylate, trimethylolpropane tri(acryloyloxypropyl)ether, tri(acryloyloxypropyl)isocyanurate, converted (meth)acrylate after adding ethylene oxide or propylene oxide to polyfunctional alcohols such as glycerin or trimethylolethane, urethane(meth)acrylates such as those disclosed in each of JP1973-41708B (JP-S48-41708B), JP1975-6034B (JP-S50-6034B), and JP1976-37193A (JP-S51-37193A), polyester acrylates such as those disclosed in each of JP1973-64183A (JP-S48-64183A), JP1974-43191B (JP-S49-43191B), and JP1977-30490B (JP-S52-30490B), and epoxyacrylates which are products of epoxy resin and (meth)acrylate and these mixtures may be included.

Multifunctional (meth)acrylate obtained from the reaction of a cyclic ether group such as glycidyl(meth)acrylate and a compound having an ethylenic unsaturated group with multifunctional carboxylic acid may also be included.

Also, as a preferable polymerizable compound, compounds having a fluorene ring and a difunctional or more ethylenic unsaturated group which is disclosed in specification of JP2010-160418A, JP2010-129825A, JP4364216B, and the like or cardo resin may also be used.

Also as the compound having an ethylenic unsaturated group with the boiling point of 100° C. or more under atmospheric pressure and having at least one ethylene group capable of polyaddition, compounds disclosed in paragraph numbers [0254] to [0257] of JP2008-292970A are also suitable.

In addition to the above, radical polymerizable monomers represented by following General Formulae (MO-1) to (MO-5) is also suitably used. Also, in the Formula, when T is an oxyalkylene group, the end of the carbon atom side is bonded to R.

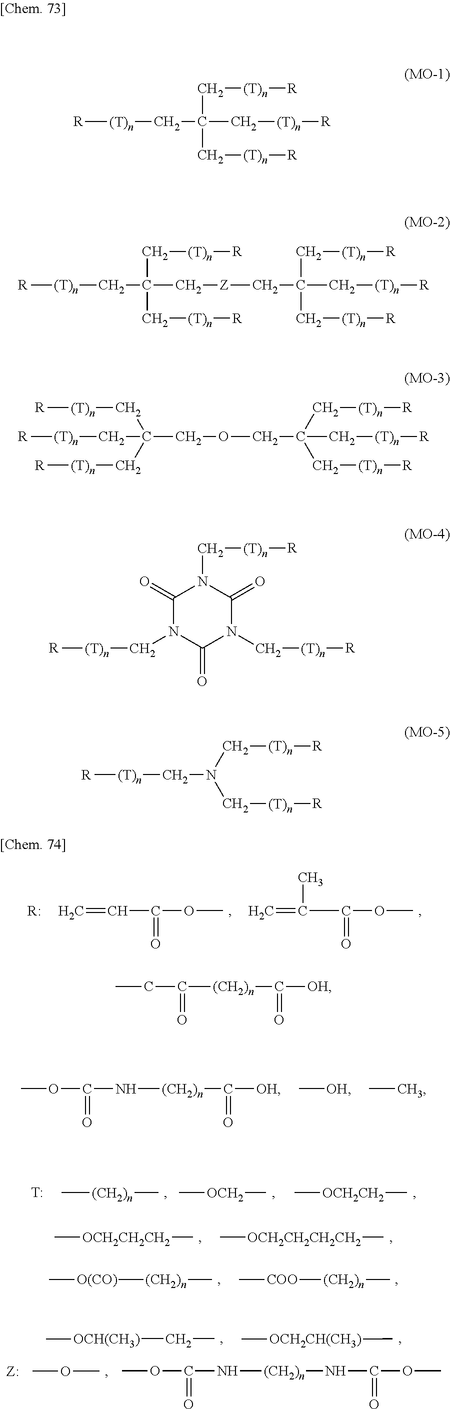

In the above General Formula, n is 0 to 14 and m is 1 to 8. R and T which are present in plural numbers within one molecule may be the same as or different from each other, respectively.

In each of the polymerizable compounds represented by following General Formulae (MO-1) to (MO-5), at least one R presented in the plural numbers represents a group represented by —OC(═O)CH═CH₂ or —OC(═O)C(CH₃)═CH₂.

As specific examples of the polymerizable compounds represented by following General Formulae (MO-1) to (MO-5), compounds disclosed in paragraph number [0248] to paragraph number [0251] of JP2007-269779A may be suitably used in the present invention.

Also, the converted (meth)acrylate compound after adding ethylene oxide or propylene oxide to the polyfunctional alcohols disclosed as General Formulae (1) and (2) with specific examples in JP1998-62986A (JP-H10-62986A) may also be used as the polymerizable compound.

Among these, as the polymerizable compound, dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd.), and a structure in which these (meth)acryloyl group is through an ethylene glycol or a propylene glycol remnant are preferable. Oligomer types of these may be used. Hereinafter, the preferable aspects of the polymerizable compounds are shown.

The polymerizable compound may have an acidic group such as a carboxyl group, a sulfonate group, or a phosphate group as a multifunctional monomer. If the ethylenic compound has an unreacted carboxyl group as in the case of the mixture as above, this may be used as it is, however, as necessary, an acidic group may be introduced by reacting a non-aromatic carboxylic anhydride with a hydroxyl group of the ethylenic compound described above. In this case, as specific examples of the non-aromatic carboxylic anhydride used, tetrahydrophthalic anhydride, alkylated tetrahydrophthalic anhydride, hexahydrophthalic anhydride, alkylated hexahydrophthalic anhydride, succinic anhydride, maleic anhydride and the like may be included.

In the present invention, the monomer having an acidic group is an ester of aliphatic polyhydroxy compound with unsaturated carboxylic acid and a multifunctional monomer made to have an acidic group by reacting an unreacted hydroxyl group of aliphatic polyhydroxy compound with a non-aromatic carboxylic anhydride is preferable.

In this ester, the aliphatic polyhydroxy compound being pentaerythritol and/or dipentaerythritol is particularly preferable. As commercially available products, for example, M-510 and M-520 as polybasic modified acryl oligomers manufactured by Toagosei Co., Ltd. may be included.

These monomers may be used alone, however, may be used as a combination of two or more since it is difficult to use a single compound in the manufacturing. Also, if necessary, a multifunctional monomer which does not have an acidic group and a multifunctional monomer which has an acidic group may be used together as the monomer.

The acid value of the multifunctional monomer which has an acidic group is preferably 0.1 mgKOH/g to 40 mgKOH/g and particularly preferably 5 mgKOH/g to 30 mgKOH/g. If the acid value of the multifunctional monomer is excessively low, developing dissolution characteristics becomes worse and if excessively high, preparation or handling becomes difficult, therefore photopolymerization performance gets becomes low and a curing property such as surface smoothness of the pixel becomes inferior. Therefore, when two or more multifunctional monomers of different acid groups are used together, or when the multifunctional monomer which does not have an acidic group is used together, it is preferable that the acid value as the total multifunctional monomer be adjusted to be within the ranges described above.

As the polymerizable monomer, containing a multifunctional monomer having a caprolactone structure is also a preferable aspect.

The multifunctional monomer having a caprolactone structure is not particularly limited as long as a caprolactone structure is included within the molecule, however, s-caprolactone modified multifunctional (meth)acrylate obtained from esterification of a multivalent alcohol such as trimethylolethane, ditrimethylolethane, trimethylolpropane, ditrimethylolpropane, and pentaerythritol, dipentaerythritol, tripentaerythritol, glycerine, diglycerol, trimethylolmelamine or the like with (meth)acrylic acid and ε-caprolactone may be included. Among these, a multifunctional monomer having a caprolactone structure represented by following General Formula (Z-1) is preferable.

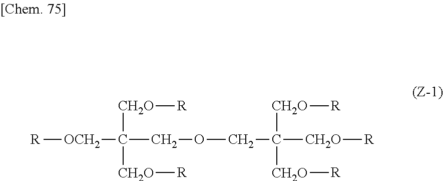

In General Formula (Z-1), all of six Rs are groups represented by following General Formula (Z-2), or 1 to 5 of six Rs are groups represented by following General Formula (Z-2) and the remainder is a group represented by following General Formula (Z-3).

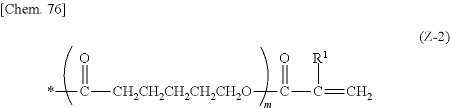

In General Formula (Z-2), R¹ represents a hydrogen atom or a methyl group, m represents a number of 1 or 2, and “*” represents a linking arm.

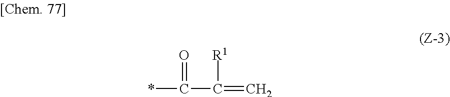

In General Formula (Z-3), R¹ represents a hydrogen atom or a methyl group and “*” represents a linking arm.

As this multifunctional monomer having a caprolactone structure, for example, DPCA-20 (a compound in Formula (1) to (3) in which m=1, the number of groups represented by Formula (2)=2, and R¹s are all hydrogen atoms), DPCA-30 (a compound in the same Formula in which m=1, the number of groups represented by Formula (2)=3, and R¹s are all hydrogen atoms), DPCA-60 (a compound in the same Formula in which m=1, the number of groups represented by Formula (2)=6, and R¹s are all hydrogen atoms), and DPCA-120 (a compound in the same Formula in which m=2, the number of groups represented by Formula (2)=6, and R¹s are all hydrogen atoms), all of which are commercially available products as KAYARAD DPCA series from Nippon Kayaku Co., Ltd. and the like may be included.

In the present invention, the multifunctional monomer having a caprolactone structure may be used either alone or as a combination or two or more

Also, as the specific monomer in the present invention, at least one type selected from the group of compounds represented by the below General Formulas (Z-4) or (Z-5) is preferable.

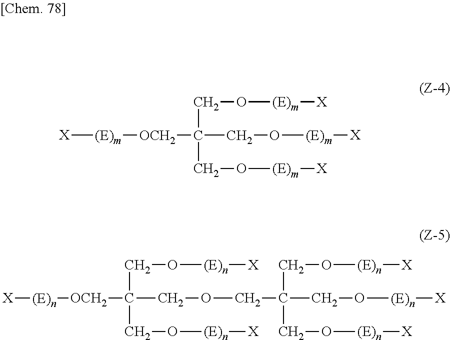

In General Formula (Z-4) or (Z-5), Es, each independently, represent —((CH₂)yCH₂O)— or —((CH₂)yCH(CH₃)O)—, ys, each independently, represent an integer of 0 to 10, Xs, each independently, represent an acryloyl group, a methacryloyl group, a hydrogen atom or a carboxyl group.

In General Formula (Z-4), the sum of the acryloyl group and the methacryloyl group is 3 or 4, ms, each independently, represent an integer of 0 to 10, and the sum of each m is an integer of 0 to 40. However, if the sum of each m is 0, any one of the Xs is a carboxyl group.

In General Formula (Z-5), the sum of the acryloyl group and the methacryloyl group is 5 or 6, ns, each independently, represent an integer of 0 to 10, and the sum of each n is an integer of 0 to 60. However, if the sum of each m is 0, any one of the Xs is a carboxyl group.

In General Formula (Z-4), m is preferably an integer of 0 to 6 and more preferably an integer of 0 to 4. Also, the sum of each m is preferably an integer of 2 to 40, more preferably an integer of 2 to 16, and particularly preferably an integer of 4 to 8.

In General Formula (Z-5), n is preferably an integer of 0 to 6 and more preferably an integer of 0 to 4.

Also, the sum of each n is preferably an integer of 3 to 60, more preferably an integer of 3 to 24, and particularly preferably an integer of 6 to 12.

Furthermore, in —((CH₂)yCH₂O)— or —((CH₂)yCH(CH₃)O)— in General Formula (Z-4) or (Z-5), a form in which the end of the oxygen atom side is bonded to X is preferable.

The compounds represented by General Formula (Z-4) or General Formula (Z-5) may be used either alone or as a combination of two or more. Particularly, in General Formula (Z-5), a form in which all of the 6 Xs are acryloyl groups is preferable.

Also, as the total content in the polymerizable compounds of the compounds represented by General Formula (Z-4) or General Formula (Z-5), 20 mass % or more is preferable, and 50 mass % or more is more preferable.

The compounds represented by General Formula (Z-4) or General Formula (Z-5) may be synthesized from a step in which a ring-opening skeleton is bonded by a ring-opening addition of ethylene oxide or propylene oxide to pentaerythritol or dipentaerythritol and a step in which a (meth)acryloyl group is introduced at the hydroxyl group which is the end of the ring-opening skeleton by for example, reacting with (meth)acryloyl chloride, all of which are conventionally well-known steps.

Each step is a well-known step and those skilled in the related art may easily synthesize the compounds represented by General Formula (Z-4) or General Formula (Z-5).

Among the compounds represented by General Formula (Z-4) or General Formula (Z-5), a pentaerythritol derivative and/or a dipentaerythritol derivative is more preferable.

Specifically, the compounds represented by following Formulae (a) to (f) (hereinafter, also referred to as “Example Compounds (a) to (f)”) may be included, and among these, Example Compounds (a), (b), (e), and (f) are preferable.

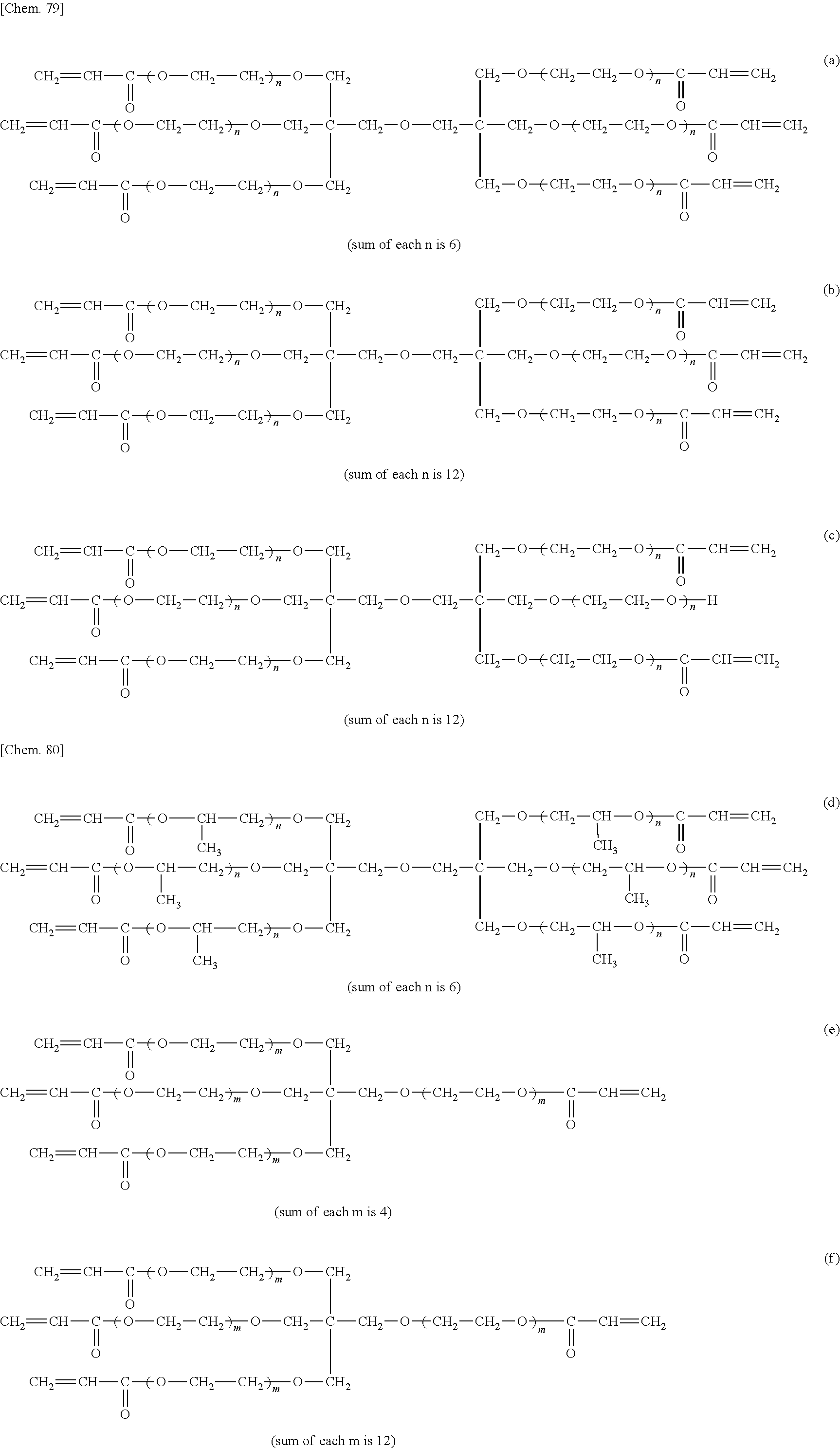

As commercially available products of the polymerizable compounds represented by General Formula (Z-4) or General Formula (Z-5), SR-494 which is a tetrafunctional acrylate having four ethylene oxy chains manufactured by Sartomer Company, Inc., DPCA-60 which is a hexafunctional acrylate having six pentylene oxy chains manufactured by Nippon Kayaku Co., Ltd., and TPA-330 which is a trifunctional acrylate having three isobutylene oxy chains and the like may be included.

Also, as the polymerizable compound, urethane compositions which have urethane acrylates such as those disclosed in JP1973-41708A (JP-S48-41708A), JP1976-37193A (JP-S51-37193A), JP1990-32293A (JP-H02-32293A), and JP1990-16765A (JP-H02-16765A), or ethylene oxide skeletons of JP1996-49860A (JP-S58-49860A), JP1981-17654A (JP-S56-17654A), JP1987-39417A (JP-S62-39417A), and JP1987-39418A (JP-S62-39418A) are also favorable. Furthermore, as the polymerizable compound, by using addition-polymerizable compounds which have an amino structure or a sulfide structure in the molecule disclosed in JP1988-277653A (JP-S63-277653A), JP1988-360909A (JP-S63-360909A), and JP1989-105238A (JP-H01-105238A), a curable composition with extremely excellent exposure speed may be obtained.

As a commercial product of the polymerizable compound, urethane oligomer-UAS-10, UAB-140 (manufactured by Sanyo—Kokusaku Pulp Co., Ltd), UA-7200 (manufactured by Shin-Nakamura Chemical Co., Ltd), DPHA-40H (manufactured by Nippon Kayaku Co., Ltd), UA-306H, UA-306T, UA-306I, AH-600, T-600, AI-600 (manufactured by Kyoeisha Chemical Co., Ltd) and the like may be exemplified.

In regard to these polymerizable compounds, the configuration thereof, as to whether to use in isolation or a use together, the specifics of the usage method of the addition amount and the like, may be configured arbitrarily in accordance with the final function plans of the coloring composition. For example, from a viewpoint of sensitivity, a configuration in which the unsaturated group content per molecule is large is preferable, and in most cases it is preferable to difunctional or more. Also, from the viewpoint of increasing the strength of the coloring curable film, a trifunctional or more polymerizable compound is favorable, and furthermore, by using a polymerizable compound of a different number of functional groups or different polymerizable groups (for example, acrylate esters, methacrylate esters, styrene compounds, or vinyl ether compounds) together therewith, a method of adjusting both of sensitivity and strength is valid. Furthermore, using trifunctional or more polymerizable compounds together which have different ethylene oxide chain lengths is preferable due to the point that the developability of the coloring composition may be adjusted, and excellent pattern formability may be obtained.

Also, in regard to the compatibility and dispersibility of the other components contained in the coloring composition (for example, photopolymerization initiators, dispersoids, alkaline soluble resins, and the like), the selection and usage method of the polymerizable compound is an important factor, for example, it may be possible to improve the compatibility by using a low purity compound or 2 or more types of compound together. Also, it is also possible to select a specific configuration form a viewpoint of improving the adherence to a hard surface such as the support.

The content of the polymerizable compound in the coloring composition of the present invention, in relation to the total solids of the coloring composition, is preferably from 0.1 mass % to 90 mass %, more preferably from 1.0 mass % to 50 mass %, and is particularly preferably from 2.0 mass % to 30 mass %.

[(D) Photopolymerization Initiator]

The coloring composition of the present invention, from a viewpoint of further improvement to sensitivity, preferably contains a photopolymerization initiator.

The photopolymerization initiator is not particularly limited as long as it has a function of initiating the polymerization of the polymerizable compound and may be appropriately selected among well-known photopolymerization initiators. For example, having a photosensitivity for visible light from the ultraviolet region is preferable. Also, an activating agent which generates active radicals by generating a certain action with a photoexcited sensitizer may be used or an initiator such as that which initiates a cation polymerization depending on the type of monomer may be used.

Also, it is preferable that the photopolymerization initiator contain at least one type of compound which has a molecular extinction coefficient of at least approximately 50 within the range of approximately 300 nm to 800 nm (330 nm to 500 nm is more preferable).

As the polymerization initiator, for example, a halogenated hydrocarbon derivative (for example, those having a triazine skeleton, those having an oxadiazole skeleton, or the like), an acylphosphine compound such as acylphosphine oxide, hexaarylbiimidazole, an oxime compound such as an oxime derivative, organic peroxide, a thio compound, a ketone compound, an aromatic onium salt, keto oxime ether, an aminoacetophenone compound, hydroxyacetophenone or the like may be exemplified.

Also, a compound selected from the group consisting of a trihalomethyltriazine compound, a benzyldimethylketal compound, an α-hydroxyketone compound, an α-aminoketone compound, an acyl phosphine compound, a phosphine oxide compound, a metallocene compound, an oxime compound, a triallylimidazole dimer, an onium compound, a benzothiazole compound, a benzophenone compound, an acetophenone compound and a derivative thereof, a cyclopentadiene-benzene-iron complex and a salt thereof, a halomethyloxadiazole compound, a 3-aryl substituted coumarin compound is preferable from the viewpoint of exposure sensitivity.

A trihalomethyltriazine compound, an α-aminoketone compound, an acyl phosphine compound, a phosphine oxide compound, an oxime compound, a triallylimidazole dimer, an onium compound, a benzophenone compound, an acetophenone compound is more preferable and at least one type of compound selected from the group consisting of a trihalomethyltriazine compound, an α-aminoketone compound, an oxime compound, a triallylimidazole dimer, a benzophenone compound is the most preferable.

In particular, when the coloring composition of the present invention is used in the production of the color filter of the solid state imaging device, from a viewpoint of forming a fine pattern in a sharp shape, it is preferable to, along with curability, develop a non-exposed portion without residues. From this point of view, using an oxime compound as the polymerization initiator is particularly preferable. Particularly, when a fine pattern is formed in a solid state imaging device, stepper exposure is used for the curing exposure, however, the exposure device is sometimes damaged by halogen, and an adding amount of the polymerization initiator needs to be suppressed to be low, therefore, considering this, in order to form a fine pattern such as a solid state imaging device, using an oxime compound as the photopolymerization initiator (D) is the most preferable.

As the halogenated hydrocarbon derivative having the triazine skeleton, for example, compounds disclosed in Wakabayashi et al., Bull. Chem. Soc. Japan, 42, 2924 (1969), compounds disclosed in GB1388492B, compounds disclosed in JP1978-133428B (JP-553-133428B), compounds disclosed in DE3337024B, compounds disclosed in F. C Schaefer et al., J. Org. Chem.; 29, 1527 (1964), compounds disclosed in JP1987-58241B (JP-562-58241B), compounds disclosed in JP1993-281728B (JP-H05-281728B), compounds disclosed in JP1993-34920B (JP-H05-34920B), compounds disclosed in U.S. Pat. No. 4,212,976A or the like may be included.

As the compounds disclosed in U.S. Pat. No. 4,212,976A, for example, a compound having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole; 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloro-methyl-5-(1-naphthyl)-1,3,4-oxadiazole, 2-trichloromethyl-5-(4-n-butoxystyryl)-1,3,4-oxadiazole, 2-tribromomethyl-5-styryl-1,3,4-oxadiazole and the like) or the like may be included.

Also, as the photopolymerization initiator in addition to the above, an acridine derivative (for example, 9-phenylacridine, 1,7-bis(9,9′-acridinyl)heptane and the like), N-phenylglycine and the like, a polyhalogen compound (for example, carbon tetrabromide, phenyl tribromomethylsulfone, phenyl trichloromethylketone and the like), coumarins (for example, 3-(2-benzofuranoyl)-7-diethylamino coumarin, 3-(2-benzofuranoyl)-7-(1-pyrrolidinyl)coumarin, 3-benzoyl-7-diethylamino coumarin, 3-(2-methoxybenzoyl)-7-diethylamino coumarin, 3-(4-dimethylaminobenzoyl)-7-diethylamino coumarin, 3,3′-carbonylbis(5,7-di-n-propoxy coumarin), 3,3′-carbonylbis(7-diethylamino coumarin), 3-benzoyl-7-methoxy coumarin, 3-(2-furoyl)-7-diethylamino coumarin, 3-(4-diethylaminocinnamoyl)-7-diethylamino coumarin, 7-methoxy-3-(3-pyridylcarbonyl)coumarin, 3-benzoyl-5,7-dipropoxy coumarin, 7-benzotriazol-2-yl coumarin, also, coumarin compounds disclosed in JP1993-19475A (JP-H05-19475A), JP1995-271028A (JP-H07-271028A), JP2002-363206A, JP2002-363207A, JP2002-363208A, JP2002-363209A, or the like, and the like), acyl phosphine oxides (for example, bis(2,4,6-trimethylbenzoyl)-phenylphosphine oxide, bis(2,6-dimethoxybenzoyl)-2,4,4-trimethylpentylphenylphosphine oxide, Lucirin TPO and the like), metallocenes (for example, bis(η5-2,4-cyclopentadien-1-yl)-bis(2,6-difluoro-3-(1H-pyrrol-1-yl)-phenyl)titanium, η5-cyclopentadienyl-η6-cumenyl-iron(1+)-hexafluoro phosphate(1−) and the like), or compounds disclosed in JP1978-133428A (JP-S53-133428A), JP1982-1819B (JP-S57-1819B), JP1982-6096B (JP-S57-6096B), or U.S. Pat. No. 3,615,455A may be included.

As the ketone compounds, for example, benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone tetracarboxylic acid or tetramethyl ester thereof, or 4,4′-bis(dialkylamino)benzophenones (for example, 4,4′-bis(dimethylamino)benzophenone, 4,4′-bisdicyclohexylamino)benzophenone, 4,4′-bis(diethylamino)benzophenone, 4,4′-bis(dihydroxyethylamino)benzophenone, 4-methoxy-4′-dimethylamino benzophenone, 4,4′-dimethoxybenzophenone, 4-dimethylaminobenzophenone, 4-dimethylaminoacetophenone, benzyl, anthraquinone, 2-t-butyl anthraquinone, 2-methyl anthraquinone, phenanthraquinone, xanthone, thioxanthone, 2-chlorothioxanthone, 2,4-diethylthioxanthone, fluorenone, 2-benzyl-dimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin, benzoin ethers (for example, benzoin methyl ether, benzoin ethyl ether, benzoin propyl ether, benzoin isopropyl ether, benzoin phenyl ether, benzyl dimethyl ketal), acridone, chloroacridone, N-methylacridone, N-butylacridone, N-butylchloroacridone or the like may be included.

As the photopolymerization initiator, a hydroxyacetophenone compound, an aminoacetophenone compound and an acyl phosphine compound may also be suitably used. More specifically, aminoacetophenone-based initiators disclosed in JP1998-291969A (JP-H10-291969A) and acyl phosphine oxide based initiators disclosed in JP4225898B may be used.

As the hydroxyacetophenone-based initiator, IRGACURE-184, DAROCUR-1173, IRGACURE-500, IRGACURE-2959, and IRGACURE-127 (trade names: all manufactured by BASF Group) may be used. As the aminoacetophenone-based initiator, IRGACURE-907, IRGACURE-369, and IRGACURE-379 (trade names: all manufactured by BASF Group), all of which are commercially available products, may be used. Compounds disclosed in JP2009-191179A of which absorption wavelength is matched to a long wave light source such as 405 nm or 365 nm may also be used. Also, as the acyl phosphine-based initiator, IRGACURE-819 or DAROCUR-TPO (trade names: all manufactured by BASF Group), all of which are commercially available products, may be used.

As the photopolymerization initiator, the oxime compound may more preferably be included. As specific examples of the oxime initiator, compounds disclosed in JP2001-233842A, compounds disclosed in JP2000-80068A, or compounds disclosed in JP2006-342166A may be used.

As the oxime compound such as an oxime derivative suitably used as the photopolymerization initiator in the present invention, for example, 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenensulfonyloxy)iminobutan-2-one, 2-ethoxycarbonyloxyimino-1-phenylpropan-1-one and the like may be included.

As the oxime ester compound, compounds disclosed in J. C. S. Perkin II (1979) pp. 1653 to 1660, J. C. S. Perkin II (1979) pp. 156 to 162, Journal of Photopolymer Science and Technology (1995) pp. 202 to 232, or JP2000-66385A, compounds disclosed in each of JP2000-80068A, JP2004-534797A and JP2006-342166A, or the like may be included.

Among the commercially available products, IRGACURE-OXE 01 (manufactured by BASF Group) or IRGACURE-OXE 02 (manufactured by BASF Group) is also suitably used.

Also, as an oxime compound in addition to the one disclosed above, compounds disclosed in JP2009-519904A in which the oxime is bonded to N position of the carbozole, compounds disclosed in U.S. Pat. No. 7,626,957B in which a heterosubstituent is introduced to the benzophenone portion, the compound disclosed in JP2010-15025A and US2009292039A in which a nitro group is introduced to the dye portion, a ketooxime-based compound disclosed in WO2009/131189A, compounds disclosed in U.S. Pat. No. 7,556,910B in which a triazine skeleton and an oxime skeleton are included within the same molecule, the compound disclosed in JP2009-221114A having a maximum absorption at 405 nm and a satisfactory sensitivity for g-ray light source or the like may be included.

Preferably, also, a cyclic oxime compound disclosed in JP2007-231000A and JP2007-322744A may be suitably used. Among the cyclic oxime compounds, particularly, cyclic oxime compounds condensed to carbazole dyes disclosed in JP2010-32985A and JP2010-185072A are preferable from the viewpoint of high sensitivity due to high light-absorbance.

Furthermore, compounds disclosed in JP2009-242469A having unsaturated bonds at specific sites of the oxime compound may achieve high sensitivity by generating active radicals from polymerization inert radicals and may also be suitably used.

The most preferably, oxime compounds having specific substituents disclosed in JP2007-269779A or oxime compounds having thioaryl groups disclosed in JP2009-191061A may be included.

Specifically, as the oxime polymerization initiator, compounds represented by following General Formula (OX-1) are preferable. Also, an N—O bond of the oxime compound may be an (E) isomer of the oxime compound, (Z) isomer of the oxime compound, or a mixture of (E) isomer and (Z) isomer.

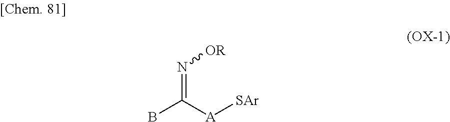

In General Formula (OX-1), R and B, each independently, represent a monovalent substituent, A represents a divalent organic group and Ar represents an aryl group.

In General Formula (OX-1), as the monovalent substituent represented by R, a monovalent non-metallic atomic group is preferable.

As the monovalent non-metallic atomic group, an alkyl group, an aryl group, an acyl group, an alkoxycarbonyl group, an aryloxycarbonyl group, a heterocyclic group, an alkyl thiocarbonyl group, an aryl thiocarbonyl group or the like may be included. These groups may also have one or more substituents. The substituents described above may also be substituted with other substituents.

As the substituent, a halogen atom, an aryloxy group, an alkoxycarbonyl group or an aryloxycarbonyl group, an acyloxy group, an acyl group, an alkyl group, aryl group, or the like may be included.

As the alkyl group, an alkyl group with 1 to 30 carbon atoms is preferable and specifically, a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, a cyclopentyl group, a cyclohexyl group, a trifluoromethyl group, a 2-ethylhexyl group, a phenacyl group, a 1-naphthoylmethyl group, 2-naphthoylmethyl group, a 4-methylsulfanylphenacyl group, a 4-phenylsulfanylphenacyl group, the 4-dimethylaminophenacyl group, 4-cyanophenacyl group, 4-methylphenacyl group, 2-methylphenacyl group, 3-fluorophenacyl group, 3-trifluoromethylphenacyl group, and 3-nitrophenacyl group may be exemplified.

As the aryl group, an aryl group with 6 to 30 carbon atoms is preferable and specifically, a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quaterphenyl group, an o-tolyl group, a m-tolyl group, a p-tolyl group, a xylyl group, o-cumenyl group, a m-cumenyl group and a p-cumenyl group, a mesityl group, a pentalenyl group, a binaphthalenyl group, a ternaphthalenyl group, a quaternaphthalenyl group, a heptalenyl group, a biphenylenyl group, an indacenyl group, a fluoranthenyl group, an acenaphthylenyl group, an aseantrilenyl group, a phenalenyl group, a fluorenyl group, an anthryl group, a bianthracenyl group, a teranthracenyl group, a quateranthracenyl group, an anthraquinolyl group, a phenanthryl group, a triphenylenyl group, a pyrenyl group, a chrysenyl group, a naphthacenyl group, a pureiadenyl group, a picenyl group, a perylenyl group, a pentaphenyl group, a pentacenyl group, a tetraperylenyl group, a hexaphenyl group, a hexacenyl group, a rubycenyl group, a coronenyl group, a trinaphthalenyl group, a heptaphenyl group, a heptacenyl group, a pirantrenyl group, an obalenyl group may be exemplified.

As the acyl group, an acyl group with 2 to 20 carbon atoms is preferable and specifically, an acetyl group, a propanoyl group, a butanoyl group, a trifluoroacetyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group, and a 4-methoxybenzoyl group may be exemplified.

As the alkoxycarbonyl, an alkoxycarbonyl group with 2 to 20 carbon atoms is preferable and specifically, a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group, and a trifluoromethyloxycarbonyl group may be exemplified.

As the aryloxycarbonyl group, specifically, a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, a 3-cyanophenyloxycarbonyl group, a 3-nitrophenyloxycarbonyl group, 4-fluorophenyloxycarbonyl group, a 4-cyanophenyloxycarbonyl group, and 4-methoxyphenyloxycarbonyl group may be exemplified.

As the heterocyclic group which may have substituents, an aromatic or aliphatic heterocyclic ring including a nitrogen atom, an oxygen atom, a sulfur atom, or a phosphorous atom is preferable.

Specifically, a thienyl group, a benzo[b]thienyl group, a naphtho[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolizinyl group, an isoindolyl group, an 3H-indolyl group, an indolyl group, an 1H-indazolyl group, a purinyl group, a 4H-quinolizinyl group, an isoquinolyl group, a quinolyl group, a phthalazinyl group, a naphthyridinyl group, a quinoxalinyl group, a quinazolinyl group, a cinnolinyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenazinyl group, a phenalxazinyl group, an isothiazolyl group, a phenothiazinyl group, an isoxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolinyl group, an isoindolinyl group, a quinuclidinyl group, a morpholinyl group, and a thioxanthyl group may be exemplified.

As the alkylthiocarbonyl group, specifically, a methylthiocarbonyl group, a propylthiocarbonyl group, a butylthiocarbonyl group, a hexylthiocarbonyl group, an octylthiocarbonyl group, a decylthiocarbonyl group, an octadecylthiocarbonyl group, and a trifluoromethylthiocarbonyl group may be exemplified

As the arylthiocarbonyl group, specifically, a 1-naphthylthiocarbonyl group, a 2-naphthylthiocarbonyl group, a 4-methylsulfanylphenylthiocarbonyl group, a 4-phenylsulfanyl phenylthiocarbonyl group, 4-dimethylaminophenylthiocarbonyl group, a 4-diethylaminophenylthiocarbonyl group, a 2-chlorophenylthiocarbonyl group, a 2-methylphenylthiocarbonyl group, a 2-methoxyphenylthiocarbonyl group, a 2-butoxyphenylthiocarbonyl group, a 3-chlorophenylthiocarbonyl group, a 3-trifluoromethylphenylthiocarbonyl group, a 3-cyanophenylthiocarbonyl group, a 3-nitrophenylthiocarbonyl group, a 4-fluorophenylthiocarbonyl group, a 4-cyanophenylthiocarbonyl group, and 4-methoxyphenylthiocarbonyl group may be included

In General Formula (OX-1), as the monovalent group represented by B, an aryl group, a heterocyclic group, an arylcarbonyl group, or a heterocyclic carbonyl group may be represented. These monovalents may also have one or more substituents. As the substituents, substituents described above may be exemplified. The substituents described above may also be substituted with other substituents.

Among these, the structure shown below is particularly preferable.

In the structure below, Y, X and n are respectively the same as Y, X, and n in General Formula (OX-2) described later, and so are the preferable examples.

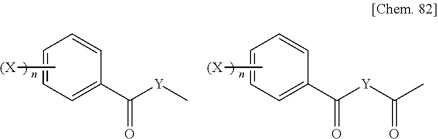

In Formula (OX-1), as the divalent organic group represented by A, an alkylene group with 1 to 12 carbon atoms, a cycloalkylene group, or an alkynylene group may be included. These groups may also have one or more substituents. As the substituents, substituents described above may be exemplified. The substituents described above may also be substituted with other substituents.

Among these, as A in Formula (OX-1), an unsubstituted alkylene group, an alkylene group substituted with an alkyl group (for example, a methyl group, an ethyl group, a tert-butyl group, or a dodecyl group), an alkylene group substituted with an alkenyl group (for example, a vinyl group or an allyl group), and an alkylene group substituted with an aryl group (for example, a phenyl group, a p-tolyl group, a xylyl group a cumenyl group, a naphthyl group, an anthryl group, a phenanthryl group, or a styryl group) are preferable from the viewpoint of increasing sensitivity and suppressing coloring due to an heating over time.

In Formula (OX-1), as the aryl group represented by Ar, an aryl group with 6 to 30 carbon atoms is preferable, and also, the aryl group may have substituents. As the substituents, the same substituents introduced to the substituted aryl group described above in specific examples of the aryl groups which may have substituents may be exemplified.

Among these, a substituted or unsubstituted phenyl group is preferable from the viewpoint of increasing sensitivity and suppressing coloring due to an heating over time.

In Formula (OX-1), the “SAr” structure, formed by Ar in Formula (OX-1) with S which is adjacent thereto, is preferably a structure shown below from the viewpoint of sensitivity. Also, Me represents a methyl group and Et represents an ethyl group.

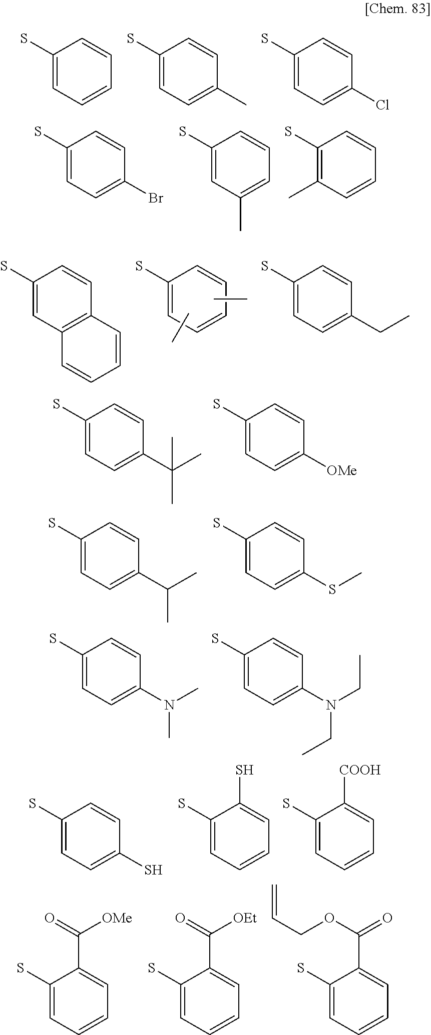

The oxime compound is preferably a compound represented by following General Formula (OX-2).

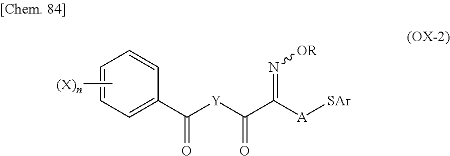

In General Formula (OX-2), R and X, each independently, represent a monovalent substituent, A and Y, each independently, represent a divalent organic group, Ar represents an aryl group, and n is an integer of 0 to 5. R, A and Ar in General Formula (OX-2) are the same as R, A and Ar in General Formula (OX-1), respectively, and so are the preferable examples.

In General Formula (OX-2), as the monovalent group represented by X, an alkyl group, an aryl group, an alkoxy group, an aryloxy group, an acyloxy group, an acyl group, an alkoxycarbonyl group, an amino group, a heterocyclic group, or a halogen atom may be included. Furthermore, these monovalents may have one or more substituents. As the substituents, substituents described above may be exemplified. The substituents described above may also be substituted with other substituents

Among these, as X in General Formula (OX-2), an alkyl group is preferable from the viewpoint of solvent solubility and absorption efficiency improvement in a long wavelength region.

Furthermore, n in General Formula (OX-2) represents an integer of 0 to 5, and an integer of 0 to 2 is preferable.

In Formula (OX-2), as the divalent organic group represented by Y, a structure shown below may be included. Also, in the group shown below, “*” represents, in Formula (OX-2), a bonding site with the carbon atom which is adjacent to Y.

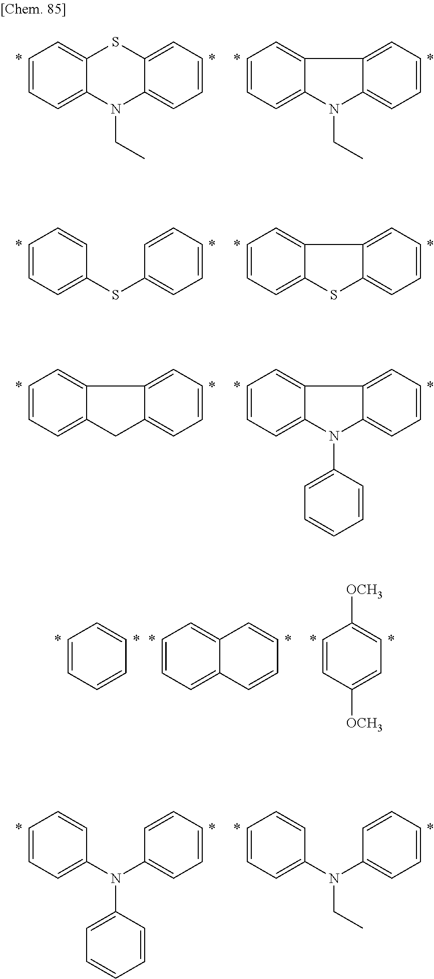

Among these, the structure shown below is preferable from the viewpoint of high sensitivity.

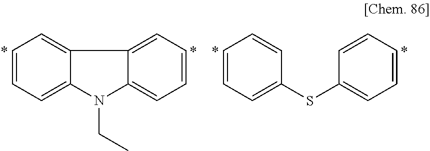

Also, the oxime compound is preferably a compound represented by following General Formula (OX-3) or (OX-4).

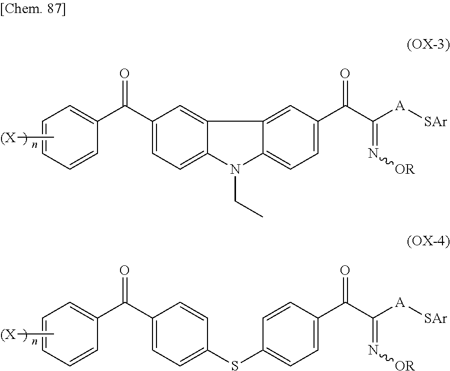

In General Formula (OX-3) or (OX-4), R and X, each independently, represent a monovalent substituent, A represents a divalent organic group, Ar represents an aryl group, and n is an integer of 0 to 5.)

R, X, A, Ar and n in Formula (OX-3) or (OX-4) are the same as R, X, A, Ar and n in General Formula (OX-2), respectively, and so are the preferable examples.

Specific examples (C-4) to (C-13) of the oxime compounds suitably used are shown below, however, the present invention is not limited to these.

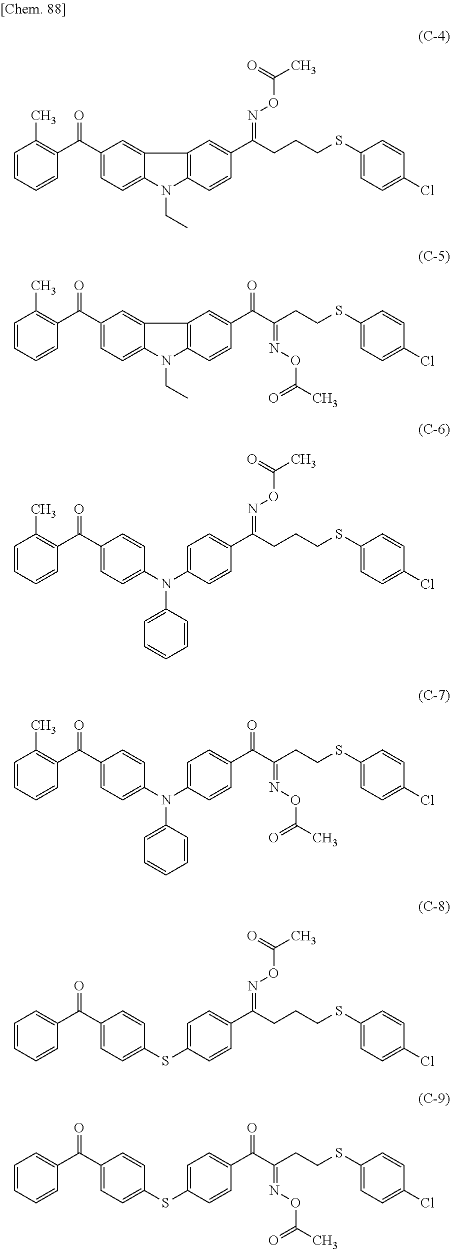 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCCSc1ccc(Cl)cc1)c1ccc(N(c2ccccc2)c2ccc(C(=O)c3ccccc3C)cc2)cc1 ; CC(=O)O/N=C(\CCSc1ccc(Cl)cc1)C(=O)c1ccc(N(c2ccccc2)c2ccc(C(=O)c3ccccc3C)cc2)cc1 ; CC(=O)O/N=C(\CCCSc1ccc(Cl)cc1)c1ccc(Sc2ccc(C(=O)c3ccccc3)cc2)cc1 ; CC(=O)O/N=C(\CCSc1ccc(Cl)cc1)C(=O)c1ccc(Sc2ccc(C(=O)c3ccccc3)cc2)cc1]

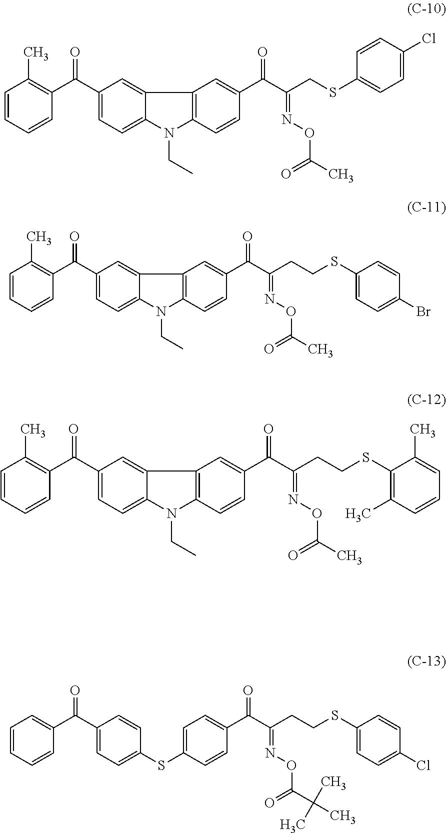 [SMILES: CCn1c2ccc(C(=O)/C(CSc3ccc(Cl)cc3)=N/OC(C)=O)cc2c2cc(C(=O)c3ccccc3C)ccc21 ; CCn1c2ccc(C(=O)/C(CCSc3ccc(Br)cc3)=N/OC(C)=O)cc2c2cc(C(=O)c3ccccc3C)ccc21 ; CCn1c2ccc(C(=O)/C(CCSc3c(C)cccc3C)=N/OC(C)=O)cc2c2cc(C(=O)c3ccccc3C)ccc21 ; CC(C)(C)C(=O)O/N=C(\CCSc1ccc(Cl)cc1)C(=O)c1ccc(Sc2ccc(C(=O)c3ccccc3)cc2)cc1]

The oxime compound has a maximum absorption wavelength in the wavelength range of 350 nm to 500 nm, the compound having the absorption wavelength in the wavelength range of 360 nm to 480 nm is preferable, and the compound having high absorbance at 365 nm and 405 nm is particularly preferable.

The molar extinction coefficient of the oxime compound at 365 nm or 405 nm is preferably 1000 to 300000, more preferably 2000 to 300000, and particularly preferably 5000 to 200000 from the viewpoint of sensitivity.

The molar extinction coefficient of the compound may be measured by well-known methods, however, specifically, measuring with, for example, an ultraviolet-visible spectrophotometer (Cary-5 spectrophotometer manufactured by Varian Medical Systems, Inc.) using ethyl acetate solvent at a concentration of 0.01 g/L is preferable.

The polymerization initiator used in the present invention may be used as a combination of two or more as necessary.

The content of (D) the photopolymerization initiator contained in the coloring composition of the present invention is preferably greater than or equal to 0.1 mass % and less than or equal to 50 mass % with regard to the total solids of the coloring composition, more preferably greater than or equal to 0.5 mass % and less than or equal to 30 mass %, and even more preferably greater than or equal to 1 mass % and less than or equal to 20 mass %. In this range, more favorable sensitivity and pattern forming property may be obtained.

[(E) Alkali Soluble Resin]

The coloring composition of the present invention preferably further contains (E) an alkali-soluble resin.

The alkali-soluble resin is a linear organic high molecular weight polymer and may be appropriately selected from alkali-soluble resins having at least one group facilitating an alkali-soluble property in the molecule (preferably, a molecule having an acrylic-based copolymer or a styrene-based copolymer as the main chain). From the viewpoint of heat resistance, a polyhydroxystyrene-based resin, a polysiloxane-based resin, an acrylic-based resin, an acrylamide-based resin, or an acrylic/acrylamide copolymer resin is preferable, and an acrylic-based resin, an acrylamide-based resin, or an acrylic/acrylamide copolymer resin is preferable from the viewpoint of a developability control. As the group facilitating an alkali-soluble property (hereinafter, also refer to as an acid group), for example, a carboxyl group, a phosphate group, a sulfonate group, a phenolic hydroxyl group may be exemplified, those which can be developed by a weak alkali aqueous solution soluble in organic solvent are preferable, and (meth)acrylic acid may be exemplified as a particularly preferable group. These acid groups may be just one type, or two or more types.

As the monomer capable of imparting the acid group after the polymerization, for example, a monomer having a hydroxyl group such as 2-hydroxyethyl(meth)acrylate, a monomer having an epoxy group such as glycidyl(meth)acrylate, a monomer having an isocyanate group such as 2-isocyanatoethyl(meth)acrylate or the like may be included. The monomer to introduce these acid groups may be just one type, or two or more types. In order to introduce an acid group to an alkali soluble resin, for example, a monomer having an acid group and/or a monomer capable of imparting an acid group after the polymerization (hereinafter, sometimes refer to as “a monomer to introduce an acid group”) may be polymerized as a monomer component.

Also, when the monomer capable of imparting an acid group after the polymerization is used as a monomer component and the acid group is introduced, a process to impart the acid group after the polymerization as described later is necessary.

For the manufacture of the alkaline soluble resin, methods by, for example, well-known radical polymerization methods may be applied. Polymerization conditions such as temperature, pressure, types of radical initiator and the amount thereof, or types of solvent when the alkaline soluble resin is manufactured by the radical polymerization method may be set easily by those skilled in the related art and the conditions may be set experimentally.

As a linear organic high molecular weight polymer which is used as the alkaline soluble resin, a polymer having carboxylic acid in a side chain is preferable, and those in which an acidic anhydride is added to a methacrylic acid copolymer, an acrylic acid copolymer, an itaconic acid copolymer, a crotonic acid copolymer, a maleic acid copolymer, a partially esterified maleic acid copolymer, an alkali-soluble phenol resin such as a novolac type resin or the like, and an acidic cellulose derivative having carboxylic acid in a side chain, a polymer having a hydroxyl group may be included. Particularly, a copolymer of (meth)acrylic acid and other monomer copolymerizable with (meth)acrylic acid is suitable as the alkaline soluble resin. As the other monomer copolymerizable with (meth)acrylic acid, an alkyl(meth)acrylate, an aryl(meth)acrylate, a vinyl compound and the like may be included. As the alkyl(meth)acrylate and the aryl(meth)acrylate, methyl(meth)acrylate, ethyl(meth)acrylate, propyl(meth)acrylate, butyl(meth)acrylate, isobutyl(meth)acrylate, pentyl(meth)acrylate, hexyl(meth)acrylate, octyl(meth)acrylate, phenyl(meth)acrylate, benzyl(meth)acrylate, tolyl(meth)acrylate, naphthyl(meth)acrylate, cyclohexyl(meth)acrylate or the like, as the vinyl compound, styrene, α-methyl styrene, vinyl toluene, glycidyl methacrylate, acrylonitrile, vinyl acetate, N-vinyl pyrrolidone, tetrahydrofurfuryl methacrylate, polystyrene macromonomer, poly methyl methacrylate macromonomer or the like, and as the N-substituted maleimide monomer disclosed in JP1998-300922A (JP-H10-300922A), N-phenyl maleimide, N-cyclohexylmaleimide or the like may be included. Also, this other monomer copolymerizable with (meth)acrylic acid may be just one type, or two or more types.

The alkaline soluble resin preferably includes a Polymer (a) formed by polymerizing the monomer component which has compounds represented by following General Formula (ED) (hereinafter, also referred to as “ether dimer”).

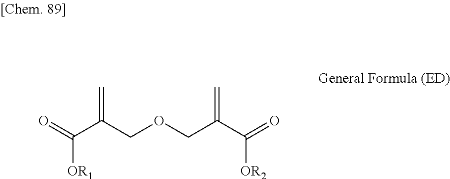

In General Formula (ED), R¹ and R², each independently, represent a hydrogen atom or a hydrocarbon group with 1 to 25 carbon atoms which may have substituents.

Therefore, in the coloring composition of the present invention, a cured coating film with extremely excellent not only heat resistance but also transparency may be formed. In General Formula (ED) which shows the ether dimer, the hydrocarbon group with 1 to 25 carbon atoms which may have substituents represented by R¹ and R² is not particularly limited, however, for example, a linear or branched alkyl group such as methyl, ethyl, n-propyl, isopropyl, n-butyl, isobutyl, t-butyl, t-amyl, stearyl, lauryl, or 2-ethylhexyl, an aryl group such as phenyl; an alicyclic group such as cyclohexyl, t-butylcyclohexyl, dicyclopentadienyl, tricyclodecanyl, isobornyl, adamantyl or 2-methyl-2-adamantyl; an alkyl group substituted with an alkoxy group such as 1-methoxyethyl, 1-ethoxyethyl, an alkyl group substituted with an aryl group such as benzyl; or the like may be included. Among these, a substituent of primary or secondary carbon such as methyl, ethyl, cyclohexyl, or benzyl which is difficult to be dissociated by acid or heat is particularly preferable from the viewpoint of heat resistance.

Specific examples of the ether dimer, for example, dimethyl-2,2′-[oxybis(methylene)]bis-2-propenoate, diethyl-2,2′-[oxybis(styrene)]bis-2-propenoate, di(n-propyl)-2,2′-[oxybis(styrene)]bis-2-propenoate, di(isopropyl)-2,2′-[oxybis(styrene)]bis-2-propenoate, di(n-butyl)-2,2′-[oxybis(styrene)]bis-2-propenoate, di(isobutyl)-2,2′-[oxybis(styrene)]bis-2-propenoate, di(t-butyl)-2,2′-[oxybis(styrene)]bis-2-propenoate, di(t-amyl)-2,2′-[oxybis(styrene)]bis-2-propenoate, di(stearyl)-2,2′-[oxybis(styrene)]bis-2-propenoate, di(lauryl)-2,2′-[oxybis(methylene)]bis-2-propenoate, di(2-ethylhexyl)-2,2′-[oxybis(methylene)]bis-2-propenoate, di(1-methoxyethyl)-2,2′-[oxybis(methyl ene)]bis-2-propenoate, di(1-ethoxyethyl)-2,2′-[oxybis(methylene)]bis-2-propenoate, dibenzyl-2,2-[oxybis(styrene)]bis-2-propenoate, diphenyl-2,2′-[oxybis(styrene)]bis-2-propenoate, dicyclohexyl-2,2′-[oxybis(styrene)]bis-2-propenoate, di(t-butylcyclohexyl)-2,2′-[oxybis(styrene)]bis-2-propenoate, di(dicyclopentadienyl)-2,2′-[oxybis(styrene)]bis-2-propenoate, di(tricyclodecanyl)-2,2′-[oxybis(styrene)]bis-2-propenoate, di(isobornyl)-2,2′-[oxybis(styrene)]bis-2-propenoate, diadamantyl-2,2′-[oxybis(methylene)]bis-2-propenoate, di(2-methyl-2-adamantyl)-2,2′-[oxybis(styrene)]bis-2-propenoate or the like may be included. Among these, dimethyl-2,2′-[oxybis(methylene)]bis-2-propenoate, diethyl-2,2′-[oxybis(methylene)]bis-2-propenoate, dicyclohexyl-2,2′-[oxybis(methylene)]bis-2-propenoate, or dibenzyl-2,2′-[oxybis(styrene)]bis-2-propenoate, is preferable. These ether dimers may be just one type, or two or more types. The structure derived from the compound shown in General Formula (ED) may copolymerize another monomer.

In order to improve the cross-linking efficiency of the coloring composition of the present invention, an alkaline soluble resin having the polymerizable group may also be used. As the alkaline soluble resin having the polymerizable group, an alkaline soluble resin including an allyl group, a (meth)acrylic group, an allyloxy alkyl group or the like in a side chain and the like is useful. As examples of the polymer including the polymerizable group described above, Dianal NR series (manufactured by Mitsubishi Rayon Co., Ltd.), Photomer 6173 (COOH containing polyurethane acrylic oligomer, manufactured by Diamond Shamrock Co., Ltd.), Viscoat R-264, KS resist 106 (all manufactured by Osaka Organic Chemical Industry Ltd.), Cyclomer P series, Placcel CF 200 series (all manufactured by Daicel Chemical Ind., Ltd.), Ebecryl 3800 (manufactured by Daicel-UCB Co., Ltd.) and the like may be exemplified. As the alkaline soluble resin having these polymerizable groups, a resin obtained by base treating a urethane modified polymerizable double bond containing acrylic resin obtained by reacting an isocyanate group with a OH group in advance, leaving one unreacted isocyanate group, and also reacting a compound including a (meth)acryloyl group with an acrylic resin including a carboxyl group, an unsaturated group containing acrylic resin obtained by reacting an acrylic resin including a carboxyl group with a compound having both an epoxy group and a polymerizable double bond within the molecule, an acid pendant type epoxy acrylate resin, a polymerizable double bond containing acrylic resin in which an acrylic resin including a OH group and a dibasic acid anhydride having a polymerizable double bond are reacted, a resin in which an acrylic resin including a OH group and a compound having an isocyanate and a polymerizable group are reacted, the resin having an ester group which has a dissociating group such as a halogen atom or a sulfonate group at an α-position or a β-position in a side chain disclosed in JP2002-229207A and JP2003-335814A, or the like is preferable.

As the alkaline soluble resin, particularly, a benzyl(meth)acrylate/(meth)acrylic acid copolymer or a multicomponent copolymer consisting of benzyl(meth)acrylate/(meth)acrylic acid/other monomer is suitable. In addition, a copolymer in which 2-hydroxyethylmetacrylate is copolymerized, or a 2-hydroxypropyl(meth)acrylate/poly styrene macromonomer/benzyl methacrylate/methacrylic acid copolymer, a 2-hydroxy-3-phenoxy propyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrate/methacrylic acid copolymer or the like disclosed in JP1995-140654A (JP-H07-140654A) may be exemplified, and particularly preferably, a copolymer or the like of methacrylate benzyl/methacrylate may be exemplified.

The acid value of the alkaline soluble resin is preferably 30 mgKOH/g to 200 mgKOH/g, more preferably 50 mgKOH/g to 150 mgKOH/g, and the most preferably 70 mgKOH/g to 120 mgKOH/g.

Also, weight average molecular weight (Mw) of the alkaline soluble resin is preferably 2000 to 50000, more preferably 5000 to 30000, and the most preferably 7000 to 20000.

As the content of the alkaline soluble resin in the coloring composition, 1 mass % to 15 mass % with regard to the total solids of the coloring composition is preferable, 2 mass % to 12 mass % is more preferable, and 3 mass % to 10 mass % is even more preferable.

[Other Components]

The coloring composition of the present invention may further include, in addition to each of the above described components, other components such as organic solvent and cross-linking agent within a scope of not impairing the effect of the invention.

(Organic Solvent)

The coloring composition of the present invention may include an organic solvent. The organic solvent is basically not particularly limited as long as the solubility of each component or the coating property of the coloring composition is satisfactory, however, it is particularly preferable that the organic solvent be selected considering the solubility, the coating property and the safety of the ultraviolet ray absorbing agent, the alkaline soluble resin, the dispersing agent, and the like. It is also preferable that at least two types of organic solvent be included to prepare the coloring composition of the present invention.

As the organic solvent, as esters, for example, ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, alkyl oxyacetates (for example: methyl oxyacetates, ethyl oxyacetates, butyl oxyacetates (for example, methyl methoxyacetate, ethyl methoxyacetate, butyl methoxyacetate, methyl ethoxyacetate, ethyl ethoxyacetate and the like)), alkyl 3-oxypropionates (for example: methyl 3-oxypropionates, ethyl 3-oxypropionates and the like (for example, methyl 3-methoxypropionate, ethyl 3-methoxypropionate, methyl 3-ethoxypropionate, ethyl 3-ethoxypropionate and the like)), alkyl 2-oxypropionates (for example: methyl 2-oxypropionates, ethyl 2-oxypropionates, propyl 2-oxypropionates and the like (for example, methyl 2-methoxypropionate, ethyl 2-methoxypropionate, propyl 2-methoxypropionate, methyl 2-ethoxypropionate, ethyl 2-ethoxypropionate)), methyl 2-oxy-2-methylpropionates and ethyl 2-oxy-2-methylpropionates (for example, methyl 2-methoxy-2-methylpropionate and ethyl 2-ethoxy-2-methylpropionate and the like), methyl pyruvate, ethyl pyruvate, propyl pyruvate, methyl acetoacetate, ethyl acetoacetate, methyl 2-oxobutanoate, ethyl 2-oxobutanoate and the like, and, as ethers, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol mono-propyl ether acetate, and, as ketones, for example, methyl ethyl ketone, cyclohexanone, 2-heptanone, 3-heptanone and the like, and, as aromatic hydrocarbons, for example, toluene, xylene and the like may be suitably included.

This organic solvent is preferably used as a combination of two or more from the viewpoint of improvement of the solubility and the shape of the coated surface of the alkaline soluble resin and an ultraviolet absorber. In this case, it is preferable that a mixed solution consisting of two or more types selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether, and propylene glycol methyl ether acetate.

As the content of the organic solvent in the coloring composition, from the viewpoint of a coating property, the amount of the total solids concentration of the composition to be 5 to 80 mass % is preferable, 5 to 60 mass % is more preferable, 10 to 50 mass % is particularly preferable.

(Crosslinking Agent)

Using the cross-linking agent to supplement the coloring composition of the present invention, it is possible to further harden the colored cured film formed by curing the coloring composition.

As the cross-linking agent, as long as film curing may be performed using a cross-linking reaction, there are no particular limitations, for example, a phenyl compound, a naphthyl compound or a hydroxyanthracene compound which is substituted by at least one substituent selected from an (a) epoxy resin, a (b) methylol group, an alkoxymethyl group, and an acyloxymethyl group, and substituted by at least one substituent selected from a melamine compound, a guanamine compound, a glycol lauryl compound or a urea compound, a (c) methylol group, an alkoxymethyl group, and an acyloxymethyl group may be exemplified. Among these, a multifunctional epoxy resin is preferable.

In regard to the details of specific examples of the cross-linking agent, the disclosures of paragraphs [0134] to [0147] of JP2004-295116A may be referred to.

(Polymerization Inhibitor)

In the coloring composition of the present invention, it is preferable that a small amount of a polymerization inhibitor be added in order to prevent unnecessary thermal polymerization of the polymerizable compound while the coloring composition is prepared or stored.

As the polymerization inhibitor which can be used in the present invention, hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), cerium(I) salt of N-nitroso phenylhydroxylamine, or the like may be included.

An addition amount of the polymerization inhibitor is preferably approximately 0.01 mass % to approximately 5 mass % with regard to the mass of the total coloring composition.

(Surfactant)

Various surfactants may be added to the coloring composition of the present invention from the viewpoint of further improving coating properties. As the surfactant, various surfactants such as fluorine-based surfactants, nonionic surfactants, cationic surfactants, anionic surfactants, or silicone-based surfactants may be used.

Particularly, in the coloring composition of the present invention, by containing the fluorine-based surfactant, uniformity of the coating thickness or a liquid saving property may be further improved since the property of liquid (liquidity, in particular) is further improved when prepared as a coating liquid.

In other words, when the film is formed using a coating liquid in which the coloring composition containing the fluorine-based surfactant is applied, a wetting property to the coated surface is improved since interfacial tension between the coated surface and the coating liquid is lowered, thereby a coating property to the coated surface is improved. As a result, it is effective in that the film of uniform thickness with small thickness variation is suitably formed even when the thin film of approximately several μm is formed using a small amount of liquid amount.

As fluorine content in the fluorine-based surfactant, 3 mass % to 40 mass % is suitable, 5 mass % to 30 mass % is more preferable, and 7 mass % to 25 mass % is particularly preferable. The fluorine-based surfactant with the fluorine content within this range is effective in terms of uniformity of the thickness of coated film or a liquid saving property and solubility in the coloring composition is also satisfactory.

As the fluorine-based surfactant, for example, Megaface F171, the same F172, the same F173, the same F176, the same F177, the same F141, the same F142, the same F143, the same F144, the same R30, the same F437, the same F475, the same F479, the same F482, the same F554, the same F780, or the same F781 (hereinbefore, manufactured by DIC Corporation), Fluorad FC430, the same FC431, or the same FC171 (hereinbefore, manufactured by Sumitomo 3M Limited), Surflon S-382, the same SC-101, the same SC-103, the same SC-104, the same SC-105, the same SC1068, the same SC-381, the same SC-383, the same S393, or the same KH-40 (hereinbefore, manufactured by Asahi Glass, Co., Ltd.), or the like may be included.

As the nonionic surfactant, specifically, glycerol, trimethylolpropane, trimethylolethane, and ethoxylates and propoxylates thereof (for example, glycerol propoxylate, glycerin ethoxylate, and the like.), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, or sorbitan fatty acid esters (Pluronic L10, L31, L61, L62, 10R5, 17R2, 25R2, Tetronic 304, 701, 704, 901, 904, 150R1 manufactured by BASF), Solsperse 20000 (manufactured by Lubrizol Japan Limited) or the like may be included.

As the cationic surfactant, specifically, a phthalocyanine derivative (trade name: EFKA-745, manufactured by Morishita Co., Ltd.), an organosiloxane polymer KP341 (manufactured by Shin-Etsu Chemical Co., Ltd.), a (meth)acrylic acid-based (co)polymer Polyflow. No. 75, No. 90, or No. 95 (manufactured by Kyoeisha Chemical Co., Ltd.), W001 (manufactured by Yusho Co. Ltd.,) or the like may be included.

As the anionic surfactant, specifically, W004, W005, or W017 (manufactured by Yusho Co. Ltd.,) or the like may be included.

As the silicone-based surfactant, for example, the Dow Corning Toray Co., Ltd. manufactured “Toray Silicone DC3PA”, “Toray Silicone SH7PA”, “Toray Silicone DC11PA”, “Toray Silicone SH21PA”, “Toray Silicone SH28PA”, “Toray Silicone SH29PA”, “Toray Silicone SH30PA”, or “Toray Silicone SH8400”, the Momentive Performance Materials, Inc. manufactured “TSF-4440”, “TSF-4300”, “TSF-4445”, “TSF-4460”, or “TSF-4452”, the Shin-Etsu Silicone Co., Ltd. manufactured “KP341”, “KF6001”, or “KF6002”, the BYK-Chemie manufactured “BYK307”, “BYK323” or “BYK330” or the like may be exemplified.

The surfactant may either use alone or as a combination of two or more.

An addition amount of the surfactant is preferably 0.001 mass % to 2.0 mass %, more preferably 0.005 mass % to 1.0 mass % with regard to the total mass of the coloring composition.

(Other Additives)

In the coloring composition, as necessary, various additives, for example, a filler, an adherence promoter, an antioxidant, an ultraviolet absorber, an anti dispersing agent, and the like may be mixed. As these additives, those disclosed in paragraphs [0155] to [0156] of JP2004-295116A may be exemplified.

In the coloring composition of the present invention, the sensitizer or the photostabilizer disclosed in paragraph [0078] of JP2004-295116A, and the thermal polymerization inhibitor disclosed in paragraph [0081] of the same document may be contained therein.

(Organic Carboxylic Acids, Organic Carboxylic Acid Anhydride)

The coloring composition of the present invention may contain an organic carboxylate of a molecular weight of 1000 or less, and/or an organic carboxylate anhydride.

As the organic carboxylate, specifically, an aliphatic carboxylic acid or an aromatic carboxylic acid may be exemplified. As the aliphatic carboxylate acid, for example, monocarboxylic acid such as formic acid, acetic acid, propionic acid, butyric acid, valeric acid, pivalic acid, caproic acid, glycolic acid, acrylic acid, and methacrylic acid, dicarboxylic acids such as oxalic acid, malonic acid, succinic acid, glutaric acid, adipic acid, pimelic acid, cyclohexanedicarboxylic acid, cyclohexene dicarboxylic acid, itaconic acid, citraconic acid, maleic acid, and fumaric acid, tricarboxylic acids such as tricarballylic acid and aconitic acid may be exemplified. Also, as the aromatic carboxylate, for example, carboxylates in which carboxyl groups are directly bonded to phenyl groups such as benzoic acid and phthalic acid, and carboxylates in which the carboxyl groups are bonded via carbon bonding from the phenyl groups may be exemplified. Among these, particularly those of a molecular weight of 600 or less, especially those of a molecular weight of from 50 to 500, specifically, for example, maleic acid, malonic acid, succinic acid, and itaconic acid are preferable.

As the organic carboxylate anhydride, for example, an aliphatic carboxylate anhydride or an aromatic carboxylate anhydride may be exemplified specifically, for example, aliphatic carboxylic acid anhydrides such as acetic anhydride, trichloroacetic anhydride, trifluoroacetic anhydride, tetrahydrophthalic anhydride, succinic anhydride, maleic anhydride, citraconic anhydride, itaconic anhydride, glutaric acid anhydride, anhydrous 1,2-cyclohexene dicarboxylic acid, n-octadecyl succinic anhydride acid, and anhydrous 5-norbornene-2,3-dicarboxylic acid may be exemplified. As the aromatic carboxylate anhydride, for example, an anhydrous phthalic acid, a trimellitic acid anhydride, a pyromellitic acid anhydride, an anhydrous phthalic acid or the like may be exemplified. Among these, particularly those of a molecular weight of 600 or less, especially those of a molecular weight of from 50 to 500, specifically, for example, maleic anhydride, succinic anhydride, citraconic anhydride, and itaconic anhydride are preferable.

The addition amount of these organic carboxylates and/or organic carboxylate anhydrides is normally, among the total solids, in a range of from 0.01 to 10 weight %, preferably from 0.03 to 5 weight %, and more preferably from 0.05 to 3 weight %.

The residue of undissolved portions of the coloring composition may be further reduced while maintaining high pattern adherence by adding these organic carboxylates of a molecular weight of 1000 or less and/or organic carboxylate anhydrides.

[Preparation Method of Coloring Composition]

The coloring composition of the present invention is prepared by mixing the previously described components.

Also, when preparing the coloring composition, each component which configures the coloring composition may be mixed in a batch, and may also be mixed successively after dissolving and dispersing each component in a solvent. Also, the introduction order or the operation conditions when mixing are not particularly restricted. For example, all components may be simultaneously dissolved and dispersed in a solvent to prepare the composition, and, as necessary, each component may be set appropriately to 2 or more solvents or dispersion liquids, and when using them (when coating), they are mixed and may be prepared as the composition.

(Filter Filtration)

The coloring composition of the present invention is preferably filtered using a filter for the purpose of removing foreign substances or reducing defects.

As the filter used for the filter filtering, any filter may be used without particular limitation as long as it is a filter which has been used hitherto for the purpose of filtering and the like.

As examples of the material of the filter, fluorine resins such as PTFE (polytetrafluoroethylene); polyamide resins such as nylon-6 and nylon-6,6, polyolefin resins (including high density and ultra high molecular weight) such as polyethylene and polypropylene (PP) may be exemplified. Among these materials, polypropylene (including high-density polyprolylene) is preferable.

As diameter of the filter pore, there are no particular limitations, however for example, it may be approximately from 0.01 to 20.0 approximately from 0.01 to 5 μm is preferable, and approximately from 0.01 to 2.0 μm is more preferable.

By maintaining the diameter within this range, fine foreign substances which inhibit the preparation of uniform and smooth coloring composition in a follow-up processes can be reliably filtered.

Here, the pore diameter of the filter may refer to the nominal value of the filter manufacturer. The commercially available filters may be selected among various filters provided by, for example, Pall Corporation, Advantec Toyo Kaisha, Ltd., Nihon Entegris K.K. (former Mykrolis Corporation), Kitz Microfilter Corporation or the like.

In the filter filtering, two types or more of filters may be used in combination.

For example, first, filtering is performed using the first filter, next, filtering is performed using the second filter which has a different pore diameter to that of the first filter.

In that case, filtering in a first filter and filtering in a second filter may be respectively carried out just once, or twice or more.

As a second filter, a filter formed with the same material of the first filter described above may be used.

Since the coloring composition of the present invention may form a colored cured film with excellent heat resistance and color properties such as color hue, color isolation, and color uneveness, it may be used in order to favorably form the colored layer of a color filter. Also, the coloring composition of the present invention may be used favorably for colored pattern formation of color filters and the like used in image display devices such as solid state imaging devices (CCD, CMOS and the like), or liquid crystal displays (LCD). Furthermore, it may also be used favorably for the purpose of creating printing inks, ink jet inks, coatings and the like. Among these, it may be used favorably for the purpose of making a color filter of an solid state imaging device such as a CCD and a CMOS.

<Manufacturing Method of Color Filter>

The manufacturing method of the color filter of the present invention has a step of forming a colored layer by applying the coloring composition onto the support, a step of pattern exposing (via a mask, as necessary) the colored layer, and a step of developing and removing an unexposed portion to form a colored pattern.

Furthermore, as necessary, a step of baking the colored layer (a prebaking step) and a step of baking the developed colored layer (post baking) may be provided.

Below, sometimes the pattern formation step is performed according to these steps.

The manufacturing method of the color filter of the present invention may favorably apply the formation of the colored pattern (pixel) which has a color filter, and the color filter of the present invention may be favorably obtained using the above manufacturing method.

Below, the solid state imaging device color filter is sometimes referred to as simply a “color filter”.

[Colored Layer Forming Step]

In the colored layer forming step, the colored layer is formed by applying the coloring composition of the present invention onto the support.

As the support which may be used in the present step, for example, a solid state imaging device substrate in which a solid state imaging device (light receiving element) is provided on the substrate (for example, a silicon substrate) of which a CCD (Charged Coupled Device) or a CMOS (Complimentary Metal-Oxide Semiconductor) is provided may be used.

The colored pattern of the present invention may be formed on the imaging device formation surface side (front surface) of the solid state imaging device substrate, and may also be formed on the imaging device non-formation surface side (rear surface).

A light-shielding film may be provided between the colored patterns in the solid state imaging device, or on the rear side of the solid state imaging device substrate.

Also, on the support, as necessary, an undercoat layer may be prepared in order to improve adhesion with the upper layer, to prevent the substance spread, or to flatten the substrate surface.

As the method for applying the coloring composition of the present invention on the support, various coating methods such as slit coating, ink jet method, spin coating, cast coating, roll coating, a screen printing method or the like may be applied.

Drying of the colored layer coated on the support (pre-bake) may be carried out at 50° C. to 140° C. for 10 seconds to 300 seconds using a hot plate, an oven or the like.

[Exposing Step]

In the exposing step, the colored layer formed in the colored layer forming step is, for example, pattern exposed via a mask having a predetermined mask pattern by using an exposure device such as a stepper. In this manner, the colored cured film is obtained.

As the radiation (light) which can be used in exposure, particularly, ultraviolet such as g ray, or i ray is preferably used (i ray is particularly preferable). The dose of irradiation (exposure amount) is preferably 30 mJ/cm² to 1500 mJ/cm², more preferably is 50 mJ/cm² to 1000 mJ/cm², the most preferably 80 mJ/cm² to 500 mJ/cm².

The film thickness of the colored cured film is preferably 1.0 μm or less, more preferably from 0.1 μm to 0.9 μm, and even more preferably from 0.2 μm to 0.8 μm.

By setting the film thickness to 1.0 μm or less, high resolution and high adherence may be obtained, therefore this is preferable.

[Pattern Forming Step]

Subsequently, by performing an alkali developing step, the colored layer of the portion yet to be irradiated with light in the exposure step is eluted to alkali aqueous solution and only the light cured portion remains.

As the developing liquid, an organic alkali developing liquid which causes no damage to underlying imaging device circuits and the like is preferable. The developing temperature is normally 20° C. to 30° C., and the developing time was 20 to 90 seconds. In order to further remove residue, in recent years, there are cases where this is performed for from 120 seconds to 180 seconds. Furthermore, in order to further improve removability of residue, the developer is shaken off every 60 seconds, and a step where developer is newly supplied is sometimes repeated several times.

As the alkali agent used in the developer, for example, an organic alkali compound such as aqueous ammonia, ethylamine, diethylamine, dimethylethanolamine, tetramethylammonium hydroxide, tetraethylammonium hydroxide, choline, pyrrole, piperidine or 1,8-diazabicyclo-[5,4,0]-7-undecene may be exemplified, and an alkaline aqueous solution diluted with pure water so that concentration of these alkali agents is to be 0.001 mass % to 10 mass % and preferably to be 0.01 mass % to 1 mass % is used preferably as the developing liquid.

Furthermore, an inorganic alkaline may be used in the developer, and as the inorganic alkaline, for example, sodium hydroxide, potassium hydroxide, sodium carbonate, sodium hydrogen carbonate, sodium silicate, sodium meta silicate, and the like are preferable.

Also, when the developing liquid made of these alkaline aqueous solutions is used, after the development in general, washing (rinsing) with pure water is performed.

Subsequently, it is preferable to perform heating processing (post bake) after performing drying. If colored patterns of many colors are to be formed, the cured film may be manufactured by sequentially repeating the step for each color. In this manner, the color filter is obtained.

The post-bake is a heating process after the development in order to complete the curing, and normally a heat curing process of 100° C. to 240° C., preferably from 200° C. to 240° C., is performed.

This post bake process is performed continuously or in batches using a heating means such as a hot plate or a convection oven (heat circulation dryer) high frequency heater so as to meet the above conditions.

Furthermore, the manufacturing method of the present invention, as necessary, as a step other than those described above, as the manufacturing method of a solid state imaging device color filter, a well-known step may be used. For example, after the colored layer forming step, the exposing step, and the pattern formation step described above are performed, as necessary a curing step may be included in which the colored pattern which is formed is cured using heating and/or exposure.

Also, when the coloring composition according to the present invention is used, for example, there are cases in which contamination and the like occurs due to clogging of the of nozzle and piping portion of the coating equipment discharge unit or adherence, precipitation, or drying of the coloring composition or the pigment to within the coating device. In this case, in order to efficiently clean contamination brought about by the coloring composition of the present invention, it is preferable to use the solvent according to the present composition as the cleaning liquid. Furthermore, cleaning liquids disclosed in JP1995-128867A (JP-H07-128867A), JP1995-146562A (JP-H07-146562A), JP1996-278637A (JP-H08-278637A), JP2000-273370A, JP2006-85140A, JP2006-291191A, JP2007-2101A, JP2007-2102A, or JP2007-281523A may also be suitably used for removal by cleaning of the coloring composition according to the present invention.

Among these, alkylene glycol monoalkyl ether carboxylate and alkylene glycol monoalkyl ether are preferable.

These solvents may be used either alone or as a combination of two or more. When two or more are mixed, it is preferable to mix a solvent having a hydroxyl group and a solvent having no hydroxyl group. The mass ratio of the solvent having a hydroxyl group and the solvent having no hydroxyl group is 1/99 to 99/1, preferably 10/90 to 90/10, and more preferably 20/80 to 80/20. A mixed solvent of propylene glycol monomethyl ether acetate (PGMEA) and propylene glycol monomethyl ether (PGME) with the ratio of 60/40 is particularly preferable. Furthermore, in order to improve the transmittance of the cleaning liquid in regard to the contaminant, the surfactant according to the present composition may be added to the cleaning liquid.

The color filter for a solid state imaging device of the present invention, since the coloring composition of the present invention is used, as well as being able to perform exposure with an excellent exposure margin, the formed colored pattern (coloring pixel) has excellent heat resistance. Also, when forming the colored pattern of many colors, even in a case where a heating process is undergone after post heating and the like, color migration of neighboring patterns is effectively suppressed, therefore the color filter of the present invention has excellent color properties such as color hue, color isolation and color unevenness.

The color filter for a solid state imaging device of the present invention may be used suitably in a solid state imaging device such as a CCD or a CMOS, and in particular, is suitable for a high resolution CCD, CMOS or the like with more than one million pixels. The solid state imaging device color filter of the present invention may be used, for example, as a color filter disposed between a light receiving unit of each pixel consisting of a CCD or a CMOS, and a micro-lens for light concentration.

Furthermore, as the film thickness of the colored pattern (coloring pixel) in the solid state imaging device color filter, 2.0 μm or less is preferable, and 1.0 μm or less is more preferable.

Also, as the size (pattern width) of the colored pattern (coloring pixel), 2.5 μm or less is preferable, 2.0 μm or less is more preferable, and 1.7 μm or less is particularly preferable.

<Solid State Imaging Device>

A solid state imaging device in the present invention is provided with the color filter for an solid state imaging device of the present invention already described. The configuration of the solid state imaging device in the present invention is a configuration provided with the color filter for the solid state imaging device in the present invention and is not particularly limited as long as the configuration functions as the solid state imaging device, however, for example, the configuration such as below may be included.

In the solid state imaging device, a transfer electrode made of a plurality of photodiodes configuring a light receiving area of the solid state imaging device (a CCD image sensor, a CMOS image sensor, or the like) and polysilicon and the like is on the support, a light-shielding film made of a tungsten and the like in which only a light receiving unit of the photodiode is opened is on the photodiode and the transfer electrode, the device protective film made of silicon nitride and the like formed so as to cover the total surface of the light-shielding film and the light receiving unit of the photodiode is on the light-shielding film, and the color filter for the solid state imaging device of the present invention is on the device protective film.

In addition, a configuration having a light concentrating means (for example, a micro-lens or the like, hereinafter the same) below the color filter (the side closer to the support) on the device protective layer, or a configuration having the light concentrating means on the color filter may also be included.

<Image Display Device>

The color filter in the present invention may be used in image display devices such as liquid crystal display devices, organic EL display devices as well as the solid state imaging devices, and is particularly favorable for the purpose of a liquid crystal display device.

When used in a liquid crystal display device, bad alignment of the liquid crystal molecules which accompany a decrease in specific resistance is few, the color tone of the display image is good and display properties are excellent.

For this reason, a liquid crystal display device provided with a color filter of the present invention, may display high quality images in which the color tone of the display image is good, and with excellent display characteristics.

In regard to the definition of display device and details of each display device, they are disclosed in, for example, “Electronic Display Devices (Sasaki Akio Kogyo Chosakai Publishing Co., Ltd. Published 1990)”, “Display Devices (Ibuki Sumiaki SANGYO-TOSHO Publishing Co., Ltd. published)”, and the like. Also, in regard to the liquid crystal display device, for example, it is disclosed in “Next Generation Liquid Crystal Display Technology (edited by Uchida Tatsuo Kogyo Chosakai Publishing Co., Ltd. published 1994)”. There are no particular limitations to the liquid crystal display devices to which the present invention may be applied, for example, the liquid crystal display devices of various types disclosed in the above “Next Generation Liquid Crystal Display Technology” may be applied.

As the color filter of the present invention, a color TFT type of liquid crystal display device may also be used. In regard to the TFT type liquid crystal display device, for example, it is disclosed in “color TFT liquid crystal displays (Kyoritsu Shuppan Co., Ltd. published 1996)”. Furthermore, the present invention may also be applied to a wide electric field drive type such as IPS or pixel division type such as MVA of liquid crystal display device in which the viewing angle is enlarged, or an STN, TN, VA, OCS, FFS, and R-OCB.

Also, the color filter in the present invention may also be used for a bright, high definition COA (Color-filter On Array) type. In a COA type liquid crystal display device, the prescribed properties in regard to the color filter are, in addition to the normal prescribed properties described above, prescribed properties in regard to the inter-layer insulation film, in other words a low permittivity and a dissociation liquid resistance are sometimes required. In the color filter of the present invention, since a resin (A) having a dye structure is used, the color purity, the optical permeability or the like are good and the color tone of the colored pattern (pixel) is excellent, therefore, a COA type liquid crystal display device with a high resolution and excellent long term durability may be provided. Furthermore, in order to satisfy the prescribed property of a low permittivity, a resin membrane may be provided on the color filter layer.

These image displaying types are described, for example, in page 43 and the like of “Latest Trends in EL, PDP and LCD display technology and markets (Toray Research Center Inc. published 2001)”.

The liquid crystal display device which is provided with a color filter in the present invention is configured from various members such as, besides the color filter in the present invention, an electrode substrate, a polarization film, a phase difference film, a backlight, a spacer, and a viewing angle secured film. The color filter of the present invention may be applied to a liquid crystal display device configured by these well-known members. These members are described in, for example, “market of '94 liquid crystal display periphery members and chemicals (Shima Kentaro (Co., Ltd.) CMC published 1994)”, “Present State and Future Prospects of 2003 liquid crystal related Markets (Volume 2) (Omote Ryokichi (Co., Ltd.) Fuji Research Institute, Inc., published 2003)”.

The backlight is described in SID meeting Digest 1380 (2005) (A. Konno Et. Al) and Displays Monthly December issue 2005, pages 18 to 24 (Shima Yasuhiro) and pages 25 to 30 of same (Yagi Takaaki) and the like.

When using the color filter of the present invention in a liquid crystal display device, a high contrast may be expressed when combined with the well-known cold cathode tube three wavelength tube, further, by setting red, green, and blue LED light sources (RGB-LED) as the backlight, a liquid crystal display device may be provided in which the brightness is high, and, the color purity is high and the color reproduction is good.

### EXAMPLES

Hereinafter, the present invention is described in detail using examples. However, the present invention is not limited to these examples as long as it does not depart from the spirit of the present invention. In addition, “parts” and “%” are by mass unless otherwise specified.

### Synthesis Example 1

### Synthesis of Dipyrromethene Containing Resin 1

The synthesis was carried out under the following scheme.

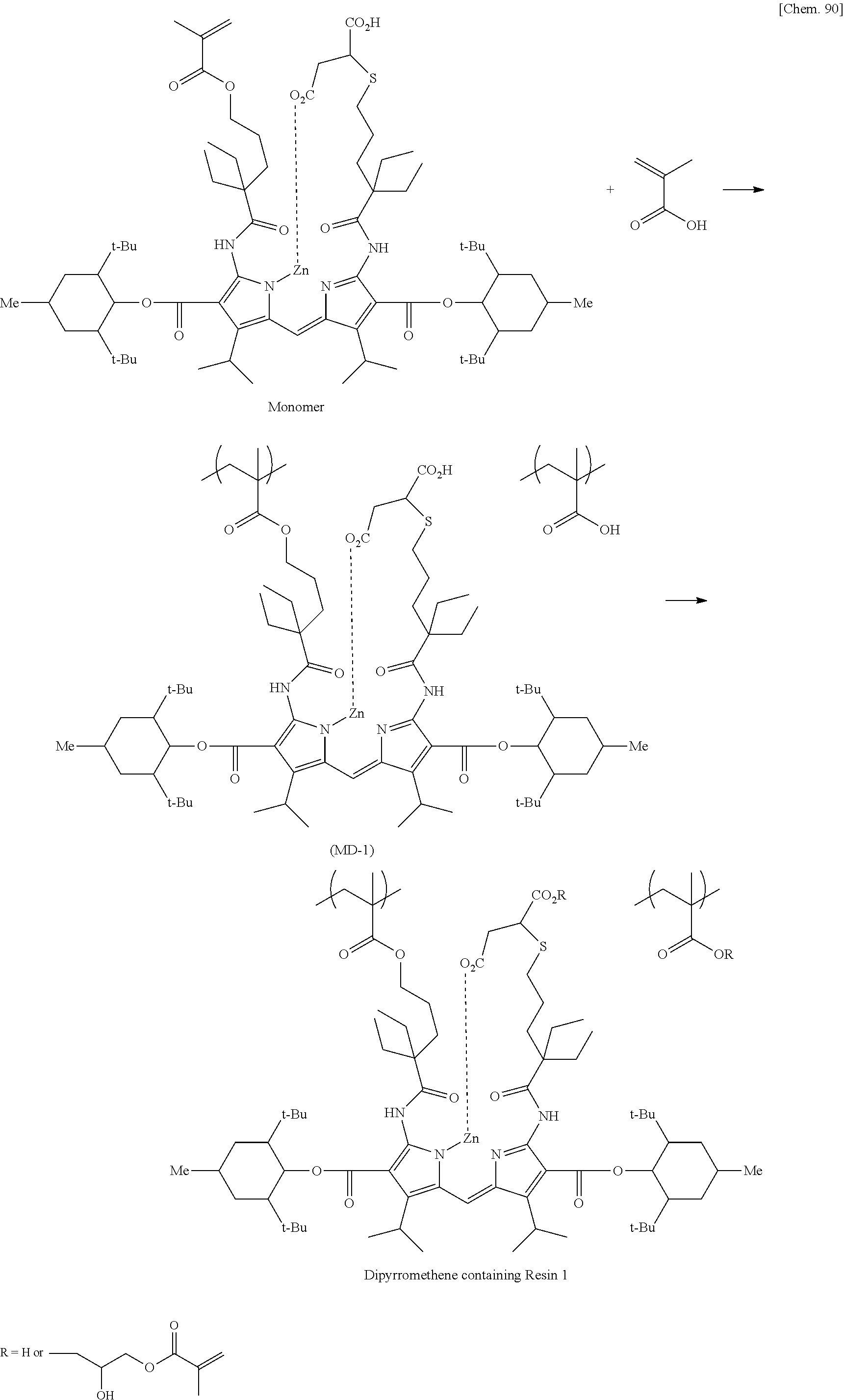

Into 100 mL of three-necked flask, monomer 1 (8.21 g) methacrylic acid (1.08 g) and propylene glycol 1-monomethyl ether 2-acetate (hereinafter, also referred to as “PGMEA”) (23.3 g) were added, followed by heating to 80° C. under a nitrogen atmosphere. To the obtained solution, a mixed solution of monomer 1 (8.21 g), methacrylic acid (1.08 g), dimethyl 2,2′-azobis(isobutyrate) (trade name. V601, manufactured by Wako Pure Chemical Industries, Ltd) (0.9 g), and PGMEA (23.3 g) was added dropwise over 2 hours. Thereafter, stirring was performed for 3 hours followed by heating to 90° C., and stirring was again performed under heating for 2 hours, which was then left to cool to obtain a PGMEA solution of (MD-1). Next, glycidyl methacrylate (1.42 g), tetrabutylammonium bromide (80 mg) and p-methoxyphenol (20 mg) were added to the PGMEA solution of (MD-1), the mixture was heated at 100° C. for 15 hours under an air atmosphere, and loss of glycidyl methacrylate was confirmed. After cooling, methanol/ion-exchange water=50 mL/5 mL was added thereto, and precipitated polymer (low-molecular-weight component) was removed by filtration. The filtrate was added dropwise to a mixed solvent of methanol/ion-exchange water=65 mL/260 mL, and reprecipitating operation by stirring for 0.5 hr at a rotation speed of 180 rpm was performed twice, to obtain 17.6 g of dipyrromethene containing resin 1.

A weight average molecular weight (Mw) of the dipyrromethene containing resin 1 was 6500 when determined by GPC measurement. The ratio of a peak area of components having a molecular weight of 2000 or less to a peak area of total molecular weight distribution of the resin was 2%

The measurement of weight average molecular weight using GPC above was performed under the conditions below, using a polystyrene conversion value as a reference.

Measuring Apparatus: HLC-8120 GPC (manufactured by TOSOH Corporation)

Guard Column: TSKguardcolumn MP (XL) (6.0 mm ID×40 mm L) (manufactured by TOSOH Corporation)
Column: TSKgel Multipore HXL-M (7.8 mm ID×300 mm L)×3 (manufactured by TOSOH Corporation)
Eluent: tetrahydrofuran
Flow rate: Sample pump: 1.0 mL/min, Reference pump: 0.3 mL/min
Temperature: Inlet oven: 40° C., Column oven: 40° C., RI detector: 40° C.
Measuring sample Injection Amount: After diluting 5 mg of sample with 5 mL of tetrahydrofuran followed by filtering with 0.5 μm of PTFE (polytetrafluoroethylene) membrane filter, 100 μL was injected.

Also, according to a titration using 0.1N sodium hydroxide solution, the acid value was 0.72 mmol/g, and according to an NMR measurement, the amount of polymerizable group contained in the resin having a dye structure was confirmed to be 0.63 mmol with respect to 1 g of dipyrromethene containing resin 1.

### Synthesis Example 8

### Synthesis of Dipyrromethene Containing Resin 2

Into 100 mL of three-necked flask, monomer 1 (8.51 g), methacrylic acid (0.35 g) and PGMEA (23.3 g) were added, followed by heating to 80° C. under a nitrogen atmosphere. To the obtained solution, a mixed solution of monomer 1 (8.51 g), methacrylic acid (0.35 g), dimethyl 2,2′-azobis(isobutyrate) (3.33 g), and PGMEA (23.3 g) was added dropwise over 2 hours. Thereafter, stirring was performed for 3 hours followed by heating to 90° C., and stirring was again performed under heating for 2 hours, which was then left to cool to obtain a PGMEA solution of (MD-1). Next, glycidyl methacrylate (2.29 g) and tetrabutylammonium bromide (80 mg) were added to the PGMEA solution of (MD-1), the mixture was heated at 100° C. for 15 hours under an air atmosphere, and loss of glycidyl methacrylate was confirmed. After cooling, the reaction solution was added dropwise to a mixed solvent of methanol/ion-exchange water=130 mL/520 mL, and reprecipitating operation by stirring for 0.5 hr at a rotation speed of 180 rpm was performed once, to obtain 18.7 g of dipyrromethene containing resin 2.

A weight average molecular weight (Mw) of the dipyrromethene containing resin 2 was 7500 when determined by GPC measurement. The ratio of a peak area of components having a molecular weight of 2000 or less to a peak area of total molecular weight distribution of the resin was 8%. Also, according to a titration using 0.1N sodium hydroxide solution, the acid value was 0.71 mmol/g, and according to an NMR measurement, the amount of polymerizable group contained in the resin having a dye structure was confirmed to be 0.64 mmol with respect to 1 g of dipyrromethene containing resin 2.

### Synthesis Examples 2 to 7, and 9 to 16

Synthesis of Dipyrromethene containing Resin 1 in which a ratio of a peak area of components having a molecular weight of 2000 or less to a peak area of total molecular weight distribution of the resin is different from that in Synthesis Example 1

For Synthesis Examples 2 to 7, the procedures were carried out in the same manner as in Synthesis Example 1, except that the reprecipitation conditions (number of times of reprecipitation, solvent amount for reprecipitation and stirring time) in Synthesis Example 1 were changed to values shown in Table 1, so as to obtain a dipyrromethene containing resin 1 in which a ratio of a peak area of components having a molecular weight of 2000 or less to a peak area of total molecular weight distribution of the resin is different from that in Synthesis Example 1.

For Synthesis Examples 9 to 16, the procedures were carried out in the same manner as in Synthesis Example 1 to obtain dipyrromethene containing resins 1 which have a ratio of a peak area of components having a molecular weight of 2000 or less to a peak area of total molecular weight distribution of the resin shown in Table 1.

Properties, reprecipitation conditions (number of times of reprecipitation, solvent amount for reprecipitation and stirring time) and the ratio of a peak area of components having a molecular weight of 2000 or less to a peak area of total molecular weight distribution of the resin, of the dipyrromethene containing resins 1 of Synthesis Examples 2 to 7 and 9 to 16, are shown in Table 1 below together with properties, reprecipitation conditions and the ratio of a peak area of components having a molecular weight of 2000 or less to a peak area of total molecular weight distribution of the resin of the dipyrromethene containing resin 1 of Synthesis Example 1 and the dipyrromethene containing resin 2 of Synthesis Example 8.

TABLE 1

| | | | | | Purification Method | | | Ratio of Peak Area |
|---|---|---|---|---|---|---|---|---|
| | | | | Polymerizable | | Reprecipitation | Reprecipitation | of Components of |
| | Resin which has Dye | | Acid value | Groups | Reprecipitation | Solvent Amount | Stirring Time | Molecular Weight of |
| | Structure | Mw | (mmol/g) | (mmol/g) | Repetitions | (relative ratio) | (relative ratio) | 2000 or Less (%)* |
| Synthesis | Dipyrromethene | 6500 | 0.72 | 0.63 | 2 | 1 | 1 | 2 |
| Example 1 | containing Resin 1 | | | | | | | |
| Synthesis | Dipyrromethene | 6500 | 0.72 | 0.63 | 1 | 2 | 1 | 3 |
| Example 2 | containing Resin 1 | | | | | | | |
| Synthesis | Dipyrromethene | 6500 | 0.72 | 0.63 | 1 | 1 | 2 | 2 |
| Example 3 | containing Resin 1 | | | | | | | |
| Synthesis | Dipyrromethene | 6500 | 0.72 | 0.63 | 3 | 1 | 1 | 2 |
| Example 4 | containing Resin 1 | | | | | | | |
| Synthesis | Dipyrromethene | 6500 | 0.72 | 0.63 | 1 | 3 | 1 | 2 |
| Example 5 | containing Resin 1 | | | | | | | |
| Synthesis | Dipyrromethene | 6500 | 0.72 | 0.63 | 1 | 1 | 3 | 2 |
| Example 6 | containing Resin 1 | | | | | | | |
| Synthesis | Dipyrromethene | 6500 | 0.72 | 0.63 | 2 | 2 | 2 | 1 |
| Example 7 | containing Resin 1 | | | | | | | |
| Synthesis | Dipyrromethene | 7500 | 0.71 | 0.64 | 1 | 2 | 1 | 8 |
| Example 8 | containing Resin 2 | | | | | | | |
| Synthesis | Dipyrromethene | 6500 | 0.72 | 0.63 | 2 | 1 | 1 | 2 |
| Example 9 | containing Resin 1 | | | | | | | |
| Synthesis | Dipyrromethene | 6500 | 0.72 | 0.63 | 2 | 1 | 1 | 3 |
| Example 10 | containing Resin 1 | | | | | | | |
| Synthesis | Dipyrromethene | 6500 | 0.72 | 0.63 | 2 | 1 | 1 | 2 |
| Example 11 | containing Resin 1 | | | | | | | |
| Synthesis | Dipyrromethene | 6500 | 0.72 | 0.63 | 2 | 1 | 1 | 2 |
| Example 12 | containing Resin 1 | | | | | | | |
| Synthesis | Dipyrromethene | 6500 | 0.72 | 0.63 | 2 | 1 | 1 | 3 |
| Example 13 | containing Resin 1 | | | | | | | |
| Synthesis | Dipyrromethene | 6500 | 0.72 | 0.63 | 2 | 1 | 1 | 2 |
| Example 14 | containing Resin 1 | | | | | | | |
| Synthesis | Dipyrromethene | 6500 | 0.72 | 0.63 | 2 | 1 | 1 | 3 |
| Example 15 | containing Resin 1 | | | | | | | |
| Synthesis | Dipyrromethene | 6500 | 0.72 | 0.63 | 2 | 1 | 1 | 4 |
| Example 16 | containing Resin 1 | | | | | | | |

*The ratio in regard to the peak area of the total molecular weight distribution of the resin.

### Synthesis Example 17

### Synthesis of Azo Containing Resin 1

The synthesis was carried out under the scheme shown below.

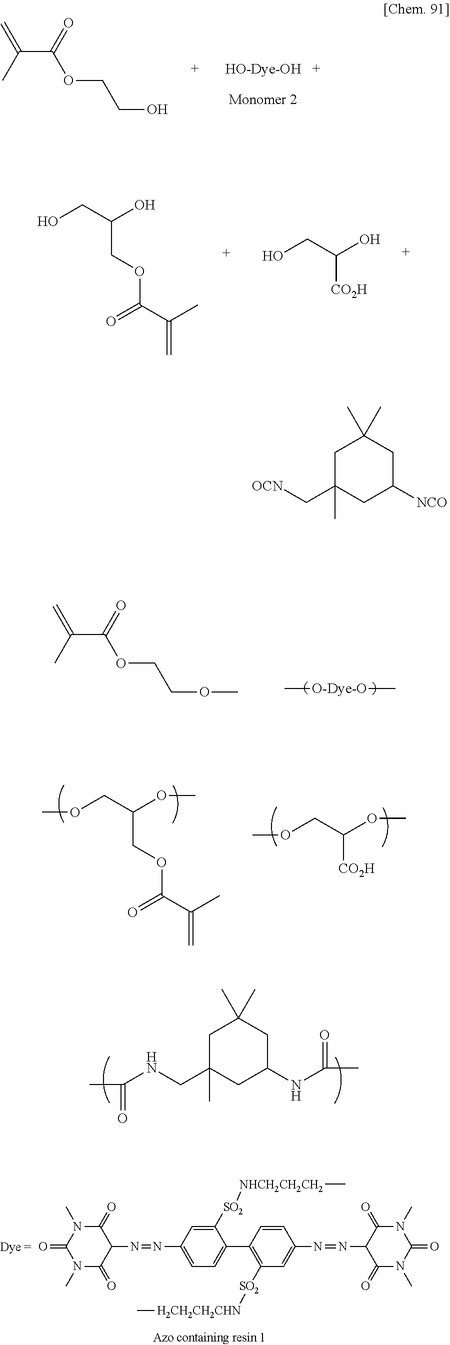

2-hydroxyethyl methacrylate (1.29 g), monomer 2 (9.40 g), 2,3-dihydroxypropyl methacrylate (0.53 g), 1,2-dihydroxy propionate (1.41 g), 2,5-di-tertbutyl-4-methylphenol (9.4 mg, 1000 ppm with respect to monomer 2) and isophorone diisocyanate (7.37 g) were added to PGMEA (46.7 g) and the mixture was heated to 80° C. under nitrogen atmosphere. Then, Neostann U-600 (manufactured by Nitto Kasei Co., Ltd.) (20 mg) was added thereto, the mixture was heated for 10 hours, followed by cooling to obtain a PGMEA 30 mass % solution of azo containing resin 1. Reprecipitation conditions (number of times of reprecipitation, solvent amount for reprecipitation and stiffing time) are shown in Table 2 below.

A weight average molecular weight (Mw) of the azo containing resin 1 was 7100 when determined by GPC measurement. The ratio of a peak area of components having a molecular weight of 2000 or less in regard to a peak area of total molecular weight distribution of the resin was 5%.

Also according to a titration using 0.1N sodium hydroxide solution, the acid value was 0.73 mmol/g, and according to an NMR measurement, the amount of polymerizable group containing in the resin having a dye structure was 0.62 mmol with respect to 1 g of azo containing resin 1

### Synthesis Example 21

### Synthesis of Squarylium Containing Resin

The procedures were carried out in the same manner as in Synthesis Example 17, except that the monomer 2 used in Synthesis Example 17 was replaced to a monomer having a dye structure corresponding to the structure shown later and that the reprecipitation conditions were changed to the conditions as shown in Table 2 below, so as to obtain a squarylium containing resin.

A weight average molecular weight (Mw) of the squarylium containing resin was 7000 when determined by GPC measurement. The ratio of a peak area of components having a molecular weight of 2000 or less to a peak area of total molecular weight distribution of the resin was 2%.

Also, according to a titration using 0.1N sodium hydroxide solution, the acid value was 0.73 mmol/g, and according to an NMR measurement, the amount of polymerizable group containing in the resin having a dye structure was 0.62 mmol with respect to 1 g of squarylium containing resin.

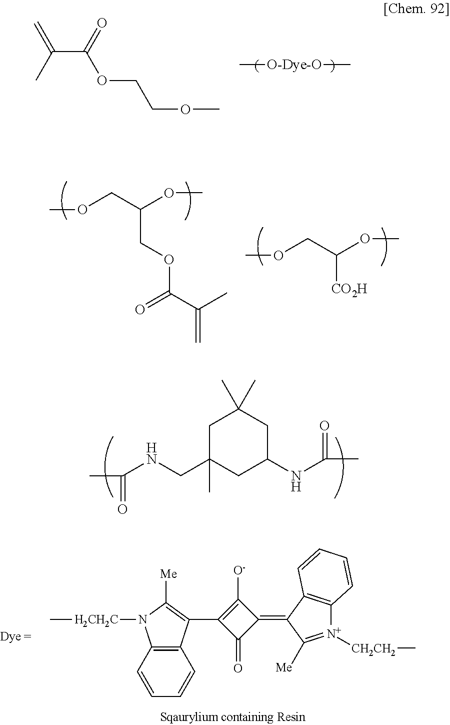

### Synthesis Example 20

### Synthesis of Anthraquinone Containing Resin

The synthesis was carried out under the scheme shown below.

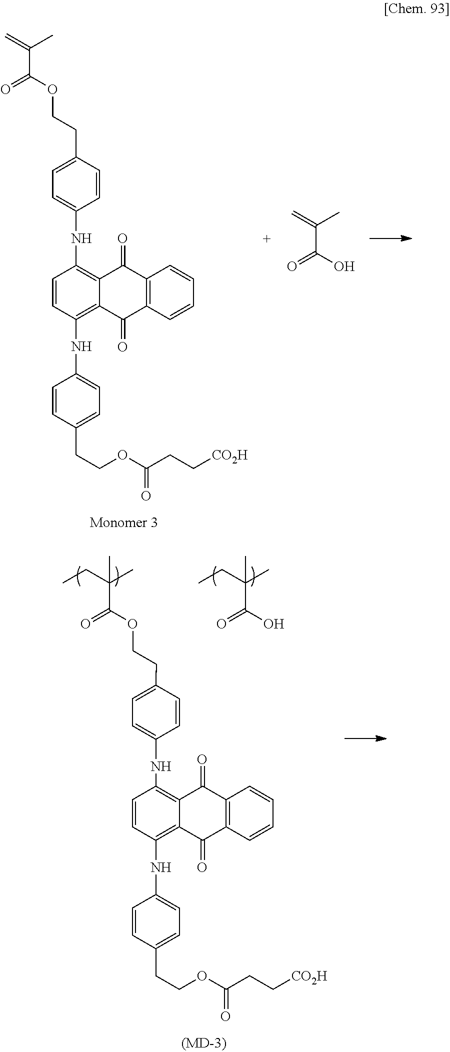

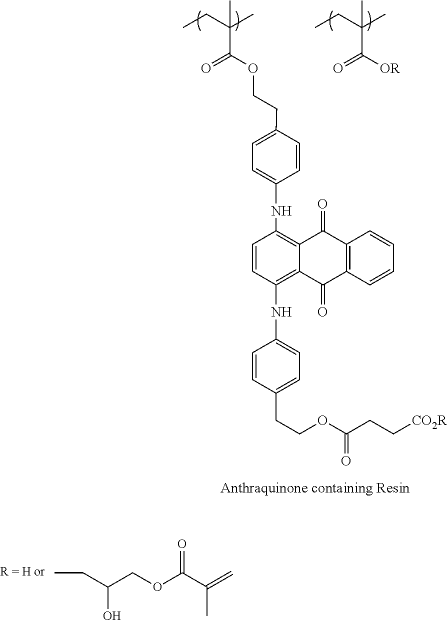

Into 100 mL of three-necked flask, monomer 3 (8.51 g), methacrylic acid (0.35 g and PGMEA (23.3 g) were added, followed by heating to 80° C. under a nitrogen atmosphere. To the solution, a mixed solution of monomer 3 (8.51 g), methacrylic acid (0.35 g), dimethyl 2,2′-azobis(isobutyrate) (3.33 g), and PGMEA (23.3 g) was added dropwise over 2 hours. Thereafter, stirring was performed for 3 hours followed by heating to 90° C., and stirring was performed under heating for 2 hours, which was then left to cool to obtain a PGMEA solution of (MD-3). Next, glycidyl methacrylate (2.29 g) and tetrabutylammonium bromide (80 mg) were added to the PGMEA solution of (MD-3), the mixture was heated at 100° C. for 15 hours under an air atmosphere, and loss of glycidyl methacrylate was confirmed. After cooling, the reaction solution was added dropwise to a mixed solvent of methanol/ion-exchange water=130 mL/520 mL, and reprecipitating operation by stirring for 0.5 hr at a rotation speed of 180 rpm was performed once, to obtain 18.6 g of anthraquinone containing resin.

A weight average molecular weight (Mw) of the anthraquinone containing resin was 7100 when determined by GPC measurement. The ratio of a peak area of components having a molecular weight of 2000 or less to a peak area of total molecular weight distribution of the resin was 2%

Also, according to a titration using 0.1N sodium hydroxide solution, the acid value was 0.72 mmol/g, and according to an NMR measurement, the amount of polymerizable group contained in the resin having a dye structure was confirmed to be 0.63 mmol with respect to 1 g of anthraquinone containing resin

### Synthesis Example 22

### Synthesis of Xanthene Containing Resin

The synthesis was carried out under the scheme shown below.

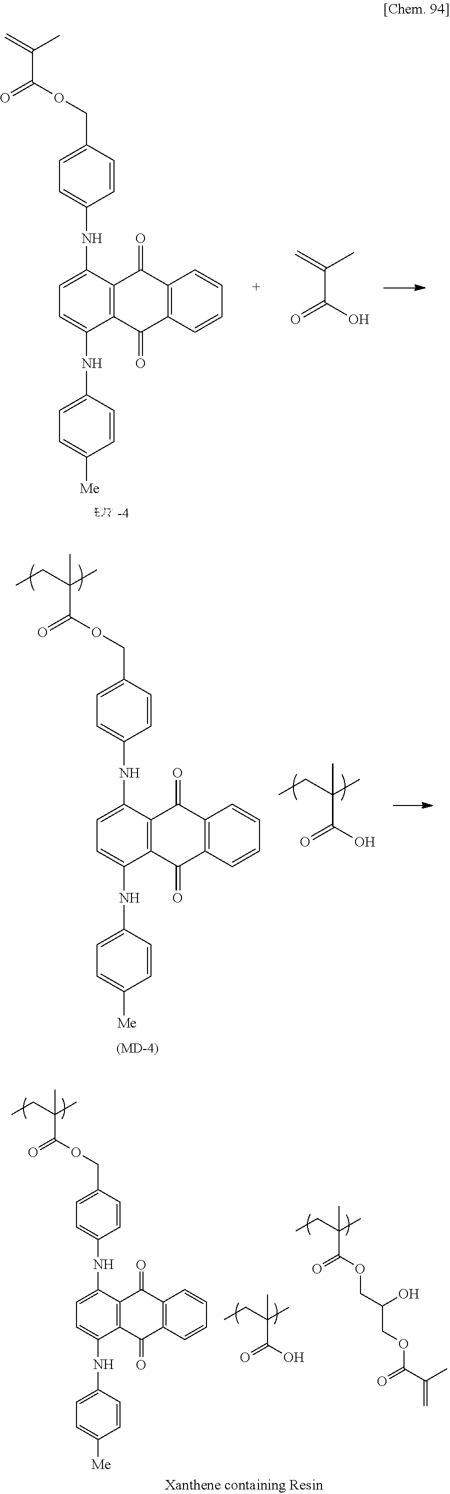

Into 100 mL of three-necked flask, monomer 4 (8.21 g), methacrylic acid (1.08 g) and PGMEA (23.3 g) were added, followed by heating to 80° C. under a nitrogen atmosphere. To the solution, a mixed solution of monomer 4 (8.21 g), methacrylic acid (1.08 g), dimethyl 2,2′-azobis(isobutyrate) (trade name: V601, manufactured by Wako Pure Chemical Industries, Ltd) (15 g), and PGMEA (23.3 g) was added dropwise over 2 hours. Thereafter, stirring was performed for 3 hours followed by heating to 90° C., and then stirring was performed under heating for 2 hours, which was then left to cool to obtain a PGMEA solution of (MD-4). Next, glycidyl methacrylate (1.42 g) and tetrabutylammonium bromide (80 mg) were added to the PGMEA solution of (MD-4), the mixture was heated at 100° C. for 15 hours under an air atmosphere, and loss of glycidyl methacrylate was confirmed. After cooling, the reaction solution was added dropwise to a mixed solvent of methanol/ion-exchange water=65 mL/260 mL, and reprecipitating operation by stirring for 1 hr at a rotation speed of 180 rpm was performed once, to obtain 17.6 g of xanthene containing resin.

A weight average molecular weight (Mw) of the xanthene containing resin was 7200 when determined by GPC measurement. The ratio of a peak area of components having a molecular weight of 2000 or less to a peak area of total molecular weight distribution of the resin was 5%.

Also, according to a titration using 0.1N sodium hydroxide solution, the acid value was 0.75 mmol/g, and according to an NMR measurement, the amount of polymerizable group contained in the xanthene containing resin was 0.60 mmol with respect to 1 g of xanthene containing resin.

### Synthesis Examples 19, 23 to 26, and 18

### Synthesis of Triarylmethane Containing Resin, Quinophthalone Containing Resin, Cyanine Containing Resin, Phthalocyanine Containing Resin, Sub-Phthalocyanine Containing Resin, and Azo Containing Resin 2

The triarylmethane containing resin, the quinophthalone containing resin, the cyanine containing resin, the phthalocyanine containing resin, the sub-phthalocyanine containing resin, and the azo containing resin 2 which are shown below were synthesized in the same manner as in Synthesis Example 22, except that the dye monomer (monomer 4) used in Synthesis Example 22 was changed to the monomers having dye structure which correspond to the structures shown below (where reprecipitation conditions were also changed for Synthesis Example 19).

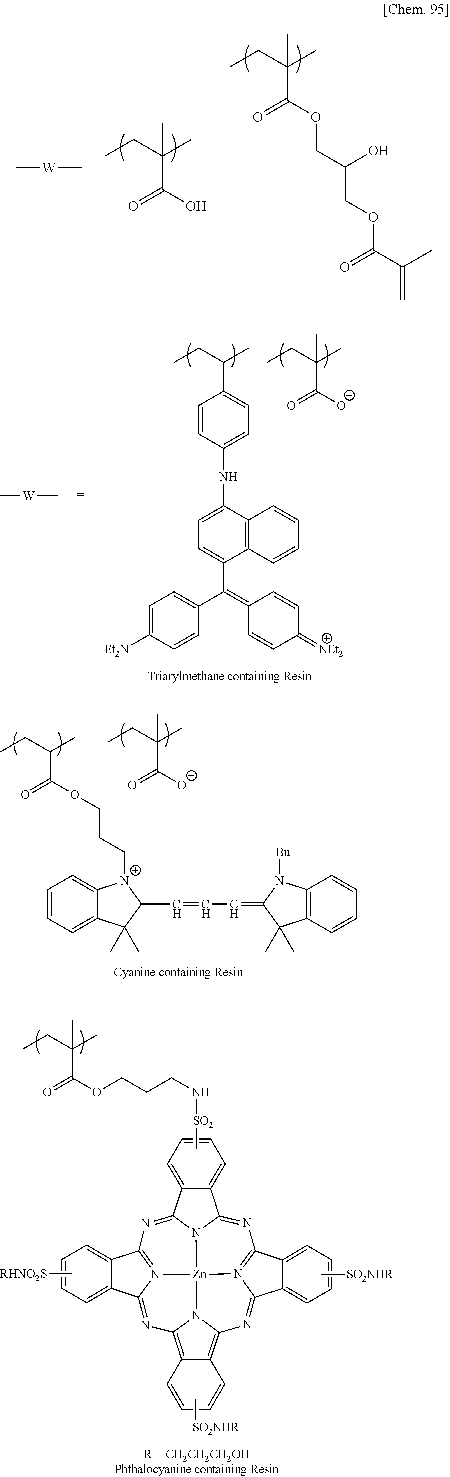

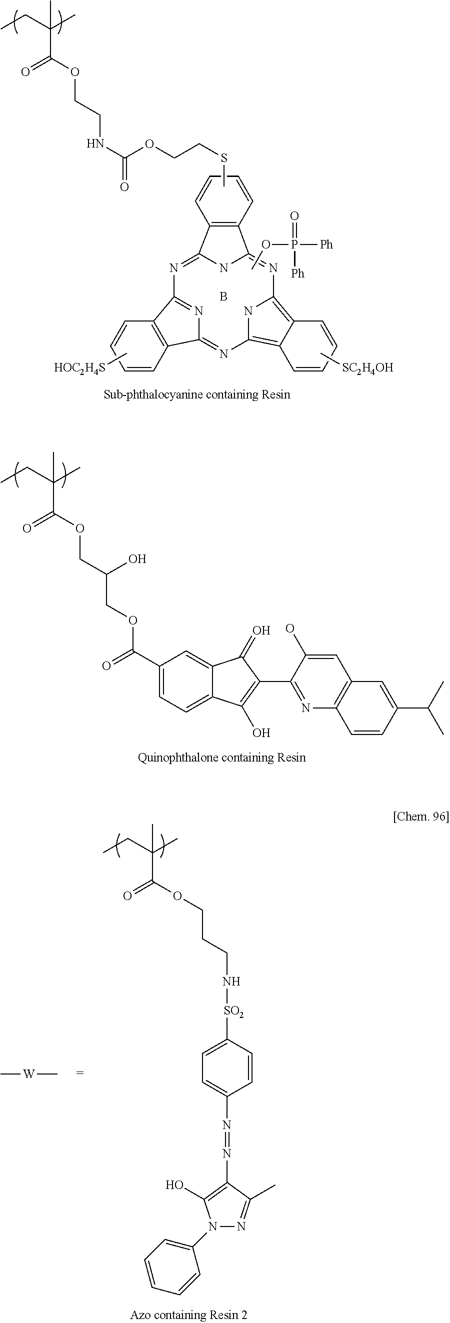

Properties of resins having each dye structure, reprecipitation conditions (number of times of reprecipitation, solvent amount for reprecipitation and stirring time) and the ratio of a peak area of components having a molecular weight of 2000 or less in regard to a peak area of total molecular weight distribution of the resin are shown in Table 2.

### Comparative Synthesis Examples 1 and 2

A dipyrromethene containing resin 1 in which a ratio of a peak area of components having a molecular weight of 2000 or less in regard to a peak area of total molecular weight distribution of the resin is different from that in Synthesis Example 1 was obtained in the same manner as in Synthesis Example 1, except that the reprecipitation conditions (number of times of reprecipitation, solvent amount for reprecipitation and stirring time) used in Synthesis Example 1 were changed to values shown in Table 2.

Properties of the dipyrromethene containing resins 1 of Comparative Synthesis Examples 1 and 2 in which a ratio of a peak area of components having a molecular weight of 2000 or less in regard to a peak area of total molecular weight distribution of the resin is different from that in Synthesis Example 1, reprecipitation conditions and the ratio of a peak area of components having a molecular weight of 2000 or less in regard to a peak area of total molecular weight distribution of the resin are shown in Table 2 below.

### Comparative Synthesis Example 3

An azo containing resin 1 in which a ratio of a peak area of components having a molecular weight of 2000 or less in regard to a peak area of total molecular weight distribution of the resin is different from that in Synthesis Example 17 was obtained in the same manner as in Synthesis Example 17, except that the reprecipitation conditions used in Synthesis Example 17 were changed to values shown in Table 2.

### Comparative Synthesis Example 4

A triarylmethane containing resin in which a ratio of a peak area of components having a molecular weight of 2000 or less in regard to a peak area of total molecular weight distribution of the resin is different from that in Synthesis Example 19 was obtained in the same manner as in Synthesis Example 19, except that the reprecipitation conditions used in Synthesis Example 19 were changed to values shown in Table 2.

### Comparative Synthesis Example 5

An anthraquinone containing resin in which a ratio of a peak area of components having a molecular weight of 2000 or less in regard to a peak area of total molecular weight distribution of the resin is different from that in Synthesis Example 20 was obtained in the same manner as in Synthesis Example 20, except that the reprecipitation conditions used in Synthesis Example 20 were changed to values shown in Table 2.

### Comparative Synthesis Example 6

A squarylium containing resin in which a ratio of a peak area of components having a molecular weight of 2000 or less in regard to a peak area of total molecular weight distribution of the resin is different from that in Synthesis Example 21 was obtained in the same manner as in Synthesis Example 21, except that the reprecipitation conditions used in Synthesis Example 21 were changed to values shown in Table 2.

### Comparative Synthesis Example 7

A xanthene containing resin in which a ratio of a peak area of components having a molecular weight of 2000 or less in regard to a peak area of total molecular weight distribution of the resin is different from that in Synthesis Example 22 was obtained in the same manner as in Synthesis Example 22, except that the reprecipitation conditions used in Synthesis Example 22 were changed to values shown in Table 2.

### Comparative Synthesis Example 8

A quinophthalone containing resin in which a ratio of a peak area of components having a molecular weight of 2000 or less in regard to a peak area of total molecular weight distribution of the resin is different from that in Synthesis Example 23 was obtained in the same manner as in Synthesis Example 23, except that the reprecipitation conditions used in Synthesis Example 23 were changed to values shown in Table 2.

Properties of resins having each dye structure of Comparative Synthesis Examples 1 to 8, reprecipitation conditions (number of times of reprecipitation, solvent amount for reprecipitation and stirring time) and the ratio of a peak area of components having a molecular weight of 2000 or less in regard to a peak area of total molecular weight distribution of the resin are shown in Table 2 below.

TABLE 2

| | | | | | Purification Method | | | Ratio of Peak Area |
|---|---|---|---|---|---|---|---|---|
| | | | | Polymerizable | | Reprecipitation | Reprecipitation | of Components of |
| | Resin which has Dye | | Acid value | Groups | Reprecipitation | Solvent Amount | Stirring Time | Molecular Weight of |
| | Structure | Mw | (mmol/g) | (mmol/g) | Repetitions | (relative ratio) | (relative ratio) | 2000 or Less (%)* |
| Synthesis | Dipyrromethene | 6500 | 0.72 | 0.63 | 2 | 1 | 1 | 2 |
| Example 1 | containing Resin 1 | | | | | | | |
| Synthesis | Dipyrromethene | 6500 | 0.72 | 0.63 | 1 | 2 | 1 | 3 |
| Example 2 | containing Resin 1 | | | | | | | |
| Synthesis | Dipyrromethene | 6500 | 0.72 | 0.63 | 1 | 1 | 2 | 2 |
| Example 3 | containing Resin 1 | | | | | | | |
| Synthesis | Dipyrromethene | 6500 | 0.72 | 0.63 | 3 | 1 | 1 | 2 |
| Example 4 | containing Resin 1 | | | | | | | |
| Synthesis | Dipyrromethene | 6500 | 0.72 | 0.63 | 1 | 3 | 1 | 2 |
| Example 5 | containing Resin 1 | | | | | | | |
| Synthesis | Dipyrromethene | 6500 | 0.72 | 0.63 | 1 | 1 | 3 | 2 |
| Example 6 | containing Resin 1 | | | | | | | |
| Synthesis | Dipyrromethene | 6500 | 0.72 | 0.63 | 2 | 2 | 2 | 1 |
| Example 7 | containing Resin 1 | | | | | | | |
| Synthesis | Dipyrromethene | 7500 | 0.71 | 0.64 | 1 | 2 | 1 | 8 |
| Example 8 | containing Resin 2 | | | | | | | |
| Synthesis | Dipyrromethene | 6500 | 0.72 | 0.63 | 2 | 1 | 1 | 2 |
| Example 9 | containing Resin 1 | | | | | | | |
| Synthesis | Dipyrromethene | 6500 | 0.72 | 0.63 | 2 | 1 | 1 | 3 |
| Example 10 | containing Resin 1 | | | | | | | |
| Synthesis | Dipyrromethene | 6500 | 0.72 | 0.63 | 2 | 1 | 1 | 2 |
| Example 11 | containing Resin 1 | | | | | | | |
| Synthesis | Dipyrromethene | 6500 | 0.72 | 0.63 | 2 | 1 | 1 | 2 |
| Example 12 | containing Resin 1 | | | | | | | |
| Synthesis | Dipyrromethene | 6500 | 0.72 | 0.63 | 2 | 1 | 1 | 3 |
| Example 13 | containing Resin 1 | | | | | | | |
| Synthesis | Dipyrromethene | 6500 | 0.72 | 0.63 | 2 | 1 | 1 | 2 |
| Example 14 | containing Resin 1 | | | | | | | |
| Synthesis | Dipyrromethene | 6500 | 0.72 | 0.63 | 2 | 1 | 1 | 3 |
| Example 15 | containing Resin 1 | | | | | | | |
| Synthesis | Dipyrromethene | 6500 | 0.72 | 0.63 | 2 | 1 | 1 | 4 |
| Example 16 | containing Resin 1 | | | | | | | |
| Synthesis | Azo containing | 7100 | 0.73 | 0.62 | 1 | 2 | 1 | 5 |
| Example 17 | Resin 1 | | | | | | | |
| Synthesis | Azo containing | 7200 | 0.74 | 0.61 | 1 | 1 | 2 | 8 |
| Example 18 | Resin 2 | | | | | | | |
| Synthesis | Triarylmethane | 7300 | 0.75 | 0.6 | 1 | 2 | 1 | 2 |
| Example 19 | containing Resin | | | | | | | |
| Synthesis | Anthraquinone | 7100 | 0.72 | 0.63 | 1 | 2 | 1 | 2 |
| Example 20 | containing Resin | | | | | | | |
| Synthesis | Squarylium | 7000 | 0.73 | 0.62 | 1 | 1 | 2 | 2 |
| Example 21 | containing Resin | | | | | | | |
| Synthesis | Xanthene | 7200 | 0.75 | 0.6 | 1 | 1 | 2 | 5 |
| Example 22 | containing Resin | | | | | | | |
| Synthesis | Quinophthalone | 7400 | 0.74 | 0.61 | 1 | 1 | 2 | 3 |
| Example 23 | containing Resin | | | | | | | |
| Synthesis | Phthalocyanine | 7600 | 0.71 | 0.64 | 1 | 1 | 2 | 3 |
| Example 24 | containing Resin | | | | | | | |
| Synthesis | Cyanine | 7000 | 0.75 | 0.6 | 1 | 1 | 2 | 2 |
| Example 25 | containing Resin | | | | | | | |
| Synthesis | Sub-phthalocyanine | 7500 | 0.71 | 0.63 | 1 | 1 | 2 | 3 |
| Example 26 | containing Resin | | | | | | | |
| Comparative | Dipyrromethene | 6500 | 0.72 | 0.63 | 1 | 1 | 1 | 12 |
| Synthesis | containing Resin 1 | | | | | | | |
| Example 1 | | | | | | | | |
| Comparative | Dipyrromethene | 6500 | 0.72 | 0.63 | 0 | 0 | 0 | 30 |
| Synthesis | containing Resin 1 | | | | | | | |
| Example 2 | | | | | | | | |
| Comparative | Azo containing | 7100 | 0.73 | 0.62 | 1 | 1 | 1 | 15 |
| Synthesis | Resin 1 | | | | | | | |
| Example 3 | | | | | | | | |
| Comparative | Triaryrmethane | 7300 | 0.75 | 0.6 | 1 | 1 | 1 | 15 |
| Synthesis | containing Resin | | | | | | | |
| Example 4 | | | | | | | | |
| Comparative | Anthraquinone | 7100 | 0.72 | 0.63 | 1 | 1 | 1 | 10 |
| Synthesis | containing Resin | | | | | | | |
| Example 5 | | | | | | | | |
| Comparative | Squarylium | 7000 | 0.73 | 0.62 | 1 | 1 | 1 | 11 |
| Synthesis | containing Resin | | | | | | | |
| Example 6 | | | | | | | | |
| Comparative | Xanthene | 7200 | 0.75 | 0.6 | 1 | 1 | 1 | 10 |
| Synthesis | containing Resin | | | | | | | |
| Example 7 | | | | | | | | |
| Comparative | Quinophthalone | 7400 | 0.74 | 0.61 | 1 | 1 | 1 | 11 |
| Synthesis | containing Resin | | | | | | | |
| Example 8 | | | | | | | | |

*The ratio in regard to the peak area of the total molecular weight distribution of the resin.

### Example 1 to Example 26 and Comparative Examples 1 to 8

### 1. Preparation of Coloring Radiation-Sensitive Composition

1-1. Preparation of Pigment Dispersion Liquid for Blue

The pigment dispersion liquid for blue was prepared as follows.

A mixed solution formed from 13.0 parts by mass of C.I. Pigment Blue 15:6 (blue pigment, average particle diameter 55 nm), 5.0 parts by mass of dispersion resin A which is the pigment dispersion agent (the structure below), and 82.0 parts by mass of PGMEA, is mixed and dispersed for 3 hours using a beads mill (zirconia beads of a 0.3 mm diameter), thereby preparing the pigment dispersion liquid. Subsequently, further using a high pressure dispersion apparatus which has a reduced pressure control NANO-3000-10 (manufactured by Japan BEE Co., Ltd.), dispersion processing was performed at a flow rate of 500 g/min under a pressure of 2000 kg/cm³. This dispersion processing was repeated 10 times and the pigment dispersion liquid for blue (C.I. Pigment Blue 15:6 dispersion liquid) was obtained.

In regard to the obtained pigment dispersion liquid for blue, when we measured the particle diameter of the pigment using dynamic light scattering (Microtrac Nanotrac UPA-EX150 (manufactured by Nikkiso Co., Ltd.)), it was 24 nm.

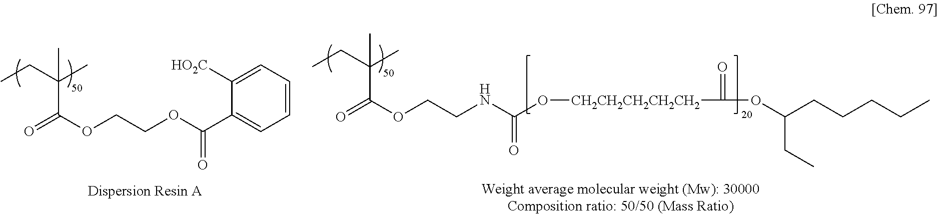

A pigment dispersion liquid for red, a pigment dispersion liquid for green, and a pigment dispersion liquid for yellow were prepared in the same manner as the preparation of the pigment dispersion liquid for blue, except that the C.I. pigment Blue 15:6 which was used as a blue pigment in the above “1-1. Preparation of Pigment Dispersion. Liquid for Blue” was changed to the below pigments.

Pigment for Red A

C.I. pigment red 254 (PR254) (particle diameter 26 nm)

Violet Pigment

C.I. pigment violet 23 (PV23) (particle diameter 27 nm)

Pigment for Green A

C.I. pigment green 36 (PG36) (particle diameter 25 nm)

Pigment for Yellow A

C.I. pigment yellow 139 (PY139) (particle diameter 27 nm)

1-2. Preparation of Coloring Radiation-Sensitive Composition

(1) Coloring Radiation-Sensitive Compositions of Examples 1 to 26 and Comparative Examples 1 to 8

Each of the below components were mixed, dispersed, dissolved, and each coloring radiation-sensitive composition of examples 1 to 26 and comparative examples 1 to 8 were obtained.

| | | |
|---|---|---|
| Cyclohexanone | 1.133 | parts |
| Alkaline soluble resin (K1 or K2:the compound described in table 3) | 0.030 | parts |
| Solsperse 20000 (1% cyclohexane solvent, manufactured by Japan Lubrizol Co., Ltd.) | 0.125 | parts |
| Photopolymerization initiator (the compound of the below structure:the compound | 0.012 | parts |
| described in table 3) | | |
| Coloring agent (the resin having a dye structure:the compound described in table 3) | 0.040 | parts as solids |
| Pigment dispersion liquid described in table 3 (pigment density 13.0%) | 0.615 | parts |
| Dipentaerythritol hexaacrylate | 0.070 | parts |
| (KAYARAD DPHA: manufactured by Nippon Kayaku Co., Ltd.) | | |
| Glycerol propoxylate (1% cyclohexane solvent) | 0.048 | parts |

[Chem. 98] 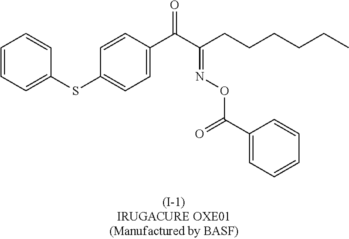 [SMILES: CCCCCC/C(=N\OC(=O)c1ccccc1)C(=O)c1ccc(Sc2ccccc2)cc1] 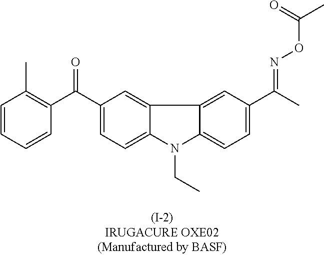 [SMILES: CCn1c2ccc(C(=O)c3ccccc3C)cc2c2cc(/C(C)=N/OC(C)=O)ccc21] 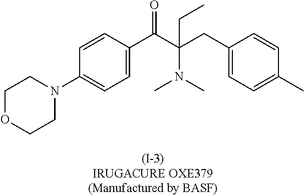 [SMILES: CCC(Cc1ccc(C)cc1)(C(=O)c1ccc(N2CCOCC2)cc1)N(C)C] 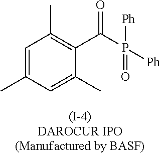 [SMILES: Cc1cc(C)c(C(=O)P(=O)(c2ccccc2)c2ccccc2)c(C)c1] 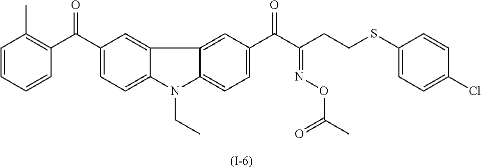 [SMILES: CCn1c2ccc(C(=O)/C(CCSc3ccc(Cl)cc3)=N/OC(C)=O)cc2c2cc(C(=O)c3ccccc3C)ccc21 ; "(I-6)"] 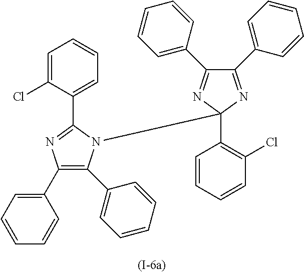 [SMILES: Clc1ccccc1-c1nc(-c2ccccc2)c(-c2ccccc2)n1C1(c2ccccc2Cl)N=C(c2ccccc2)C(c2ccccc2)=N1] 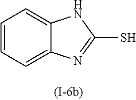
(I-6):(I-6a)/(I-6b) = 20/10 (Mass ratio) 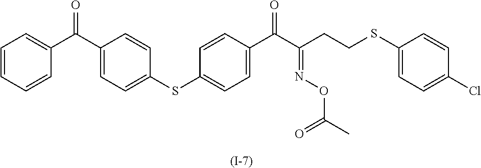 [SMILES: CC(=O)O/N=C(\CCSc1ccc(Cl)cc1)C(=O)c1ccc(Sc2ccc(C(=O)c3ccccc3)cc2)cc1 ; "(I-7)"] 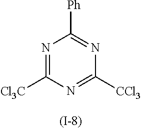
[Chem. 99]

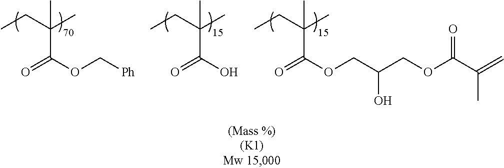

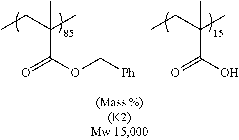

### 2 Performance Evaluation

2-1. Developability

The coloring radiation-sensitive compositions of examples 1 to 26 and comparative examples 1 to 8 are coated onto the silicon wafer using a spincoat method, then a photosensitive colored layer of a film thickness of 1 μm was obtained by heating for 2 minutes at 100° C. on a hotplate.

Exposure was performed on the photosensitive colored layer at an exposure amount of 200 mJ/cm² and a wavelength of 365 nm by using an i-beam stepper FPA-3000i5+ (manufactured by Canon Co., Ltd) via a mask pattern where each of square pixels having sides of 1.1 μm are arranged in a region of 4 mm×3 mm on substrate.

Paddle developing was performed on the colored layer after exposure for 60 seconds at 23° C. using an aqueous solvent with 0.3 mass % of tetramethylammonium hydroxide.

Subsequently, spin shower rinsing was performed using water, and water washing was further performed using pure water. Subsequently, a transparent pattern (cured film) of a film thickness of 1 μm was obtained on the silicon wafer by allowing the silicon wafer to dry naturally, blowing water droplets off using high pressure air and performing a post bake using a hotplate for 300 seconds at 200° C.

The obtained transparent pattern was observed at a magnification of 30000 times on the silicon wafer using Critical Dimension SEM (S-7800H, manufactured by Hitachi Co., Ltd.).

In regard to the developing residue, the presence thereof was determined based on the below basis. The results of determination are shown in the table below.

A: No residues were observed on the pixel.

B: Residues were observed to a slight extent, however, it was within an acceptable range.

C. Many residues were observed.

2-2. Color Loss Resistance Evaluation

After dropping each of propylene glycol monomethyl ether acetate (PGMEA), acetone, N-methylpyrrolidone (NMP), photoresist dissociation liquid MS230C (manufactured by Fujifilm Electronics Materials Co., Ltd.), alkaline developing fluid FHD-5 (tetramethylammonium hydroxide (TMAH): 2.38 mass %, manufactured by Fujifilm Electronics Materials Co., Ltd.), onto the photosensitive colored layer in the above “2-1. Developability”, the samples after dropping were left to rest for 120 seconds and rinsed for 10 seconds in running water.

The spectral fluctuations of the transmittance before and after dropping each type of liquid were measured using an MCPD-3000 (manufactured by Otsuka Electronics (Co., Ltd.)), thereby the color difference ΔEab was measured. This means that the smaller ΔEab is, the more excellent the color loss resistance is. The ΔEab which corresponds to the liquid which exhibited the largest ΔEab was determined based on the below basis. The results are shown in the table below.

The color difference ΔEab is 5 or less . . . color loss resistance is good (A)

The color difference ΔEab is more than 5 and 10 or less . . . color loss resistance is an extent which is practically acceptable (B)

The color difference ΔEab is more than 10 . . . color loss resistance is bad (C)

2-3. Heat Resistance

The spectrum of the photosensitive colored layer which was formed in the above “2-1. Developability” was measured, and a transmittance (transmittance A) of 630 nm was measured.

Next, after performing heating processing for 120 seconds using a hotplate at 100° C., the spectrum was measured, and a transmittance (transmittance B) of 630 nm was measured. The percentage (%) was calculated using the difference between the transmittances A and B, and the obtained percentage was used as an indicator to evaluate the heat resistance. This shows that the closer this numerical value is to 0%, the more excellent the heat resistance is. Heat resistance was determined based on the below basis. The results are shown in the table below.

A reduction in the transmittance was not observed . . . heat resistance is good (A)
A reduction in the transmittance was within 3% . . . heat resistance is an extent which is practically acceptable (B)
A reduction in the transmittance was more than 3% . . . heat resistance is bad (C)

TABLE 3

| | | | | | Ratio of | | | | | | |
|---|---|---|---|---|---|---|---|---|---|---|---|
| | | | | | Peak Area of | | | | | | |
| | | | | Polymer- | Components of | | | | | Color | |
| | | | Acid | izable | Molecular | | | Alkaline | | Loss | Heat |
| | Resin Having Dye | | Value | Groups | Weight of 2000 | | Initi- | Soluble | Develop- | Resis- | Resis- |
| | Structure | Mw | (mmol/g) | (mmol/g) | or Less (%)* | Pigment | ator | Resin | ability | tance | tance |
| Example 1 | synthesis example 1 | 6500 | 0.72 | 0.63 | 2 | PB15:6 | I-1 | K1 | A | A | A |
| | dipyrromethene | | | | | | | | | | |
| | containing resin 1 | | | | | | | | | | |
| Example 2 | synthesis example 2 | 6500 | 0.72 | 0.63 | 3 | PB15:6 | I-1 | K1 | A | A | A |
| | dipyrromethene | | | | | | | | | | |
| | containing resin 1 | | | | | | | | | | |
| Example 3 | synthesis example 3 | 6500 | 0.72 | 0.63 | 2 | PB15:6 | I-1 | K1 | A | A | A |
| | dipyrromethene | | | | | | | | | | |
| | containing resin 1 | | | | | | | | | | |
| Example 4 | synthesis example 4 | 6500 | 0.72 | 0.63 | 2 | PB15:6 | I-1 | K1 | A | A | A |
| | dipyrromethene | | | | | | | | | | |
| | containing resin 1 | | | | | | | | | | |
| Example 5 | synthesis example 5 | 6500 | 0.72 | 0.63 | 2 | PB15:6 | I-1 | K1 | A | A | A |
| | dipyrromethene | | | | | | | | | | |
| | containing resin 1 | | | | | | | | | | |
| Example 6 | synthesis example 6 | 6500 | 0.72 | 0.63 | 2 | PB15:6 | I-1 | K1 | A | A | A |
| | dipyrromethene | | | | | | | | | | |
| | containing resin 1 | | | | | | | | | | |
| Example 7 | synthesis example 7 | 6500 | 0.72 | 0.63 | 1 | PB15:6 | I-1 | K1 | A | A | A |
| | dipyrromethene | | | | | | | | | | |
| | containing resin 1 | | | | | | | | | | |
| Example 8 | synthesis example 8 | 7500 | 0.71 | 0.64 | 8 | PB15:6 | I-1 | K1 | B | B | A |
| | dipyrromethene | | | | | | | | | | |
| | containing resin 2 | | | | | | | | | | |
| Example 9 | synthesis example 9 | 6500 | 0.72 | 0.63 | 2 | PB15:6 | I-2 | K1 | A | A | A |
| | dipyrromethene | | | | | | | | | | |
| | containing resin 1 | | | | | | | | | | |
| Example 10 | synthesis example 10 | 6500 | 0.72 | 0.63 | 3 | PB15:6 | I-3 | K1 | A | A | A |
| | dipyrromethene | | | | | | | | | | |
| | containing resin 1 | | | | | | | | | | |
| Example 11 | synthesis example 11 | 6500 | 0.72 | 0.63 | 2 | PB15:6 | I-4 | K1 | A | A | A |
| | dipyrromethene | | | | | | | | | | |
| | containing resin 1 | | | | | | | | | | |
| Example 12 | synthesis example 12 | 6500 | 0.72 | 0.63 | 2 | PB15:6 | I-5 | K1 | A | A | A |
| | dipyrromethene | | | | | | | | | | |
| | containing resin 1 | | | | | | | | | | |
| Example 13 | synthesis example 13 | 6500 | 0.72 | 0.63 | 3 | PB15:6 | I-6 | K1 | A | A | A |
| | dipyrromethene | | | | | | | | | | |
| | containing resin 1 | | | | | | | | | | |
| Example 14 | synthesis example 14 | 6500 | 0.72 | 0.63 | 2 | PB15:6 | I-7 | K1 | A | A | A |
| | dipyrromethene | | | | | | | | | | |
| | containing resin 1 | | | | | | | | | | |
| Example 15 | synthesis example 15 | 6500 | 0.72 | 0.63 | 3 | PB15:6 | I-8 | K1 | A | A | A |
| | dipyrromethene | | | | | | | | | | |
| | containing resin 1 | | | | | | | | | | |
| Example 16 | synthesis example 16 | 6500 | 0.72 | 0.63 | 4 | PB15:6 | I-1 | K2 | A | A | A |
| | dipyrromethene | | | | | | | | | | |
| | containing resin 1 | | | | | | | | | | |
| Example 17 | synthesis example 17 | 7100 | 0.73 | 0.62 | 5 | PR254 | I-1 | K1 | A | B | A |
| | azo containing resin 1 | | | | | | | | | | |
| Example 18 | synthesis example 18 | 7200 | 0.74 | 0.61 | 8 | PR254 | I-1 | K1 | B | B | A |
| | azo containing resin 2 | | | | | | | | | | |
| Example 19 | synthesis example 19 | 7300 | 0.75 | 0.6 | 2 | PB15:6 | I-1 | K1 | A | A | A |
| | triarylmethane | | | | | | | | | | |
| | containing resin | | | | | | | | | | |
| Example 20 | synthesis example 20 | 7100 | 0.72 | 0.63 | 2 | PY139 | I-1 | K1 | A | A | A |
| | anthraquinone | | | | | | | | | | |
| | containing resin | | | | | | | | | | |
| Example 21 | synthesis example 21 | 7000 | 0.73 | 0.62 | 2 | PB15:6 | I-1 | K1 | A | A | A |
| | squarylium containing | | | | | | | | | | |
| | resin | | | | | | | | | | |
| Example 22 | synthesis example 22 | 7200 | 0.75 | 0.6 | 5 | PB15:6 | I-1 | K1 | A | B | A |
| | xanthene containing resin | | | | | | | | | | |
| Example 23 | synthesis example 23 | 7400 | 0.74 | 0.61 | 3 | PG36 | I-1 | K1 | A | A | A |
| | quinophthalone | | | | | | | | | | |
| | containing resin | | | | | | | | | | |
| Example 24 | synthesis example 24 | 7600 | 0.71 | 0.64 | 3 | PV23 | I-1 | K1 | A | A | A |
| | phthalocyanine | | | | | | | | | | |
| | containing resin | | | | | | | | | | |
| Example 25 | synthesis example 25 | 7000 | 0.75 | 0.6 | 2 | PR254 | I-1 | K1 | A | A | A |
| | cyanine containing resin | | | | | | | | | | |
| Example 26 | synthesis example 26 | 7500 | 0.71 | 0.63 | 3 | PV23 | I-1 | K1 | A | A | A |
| | sub-phthalocyanine | | | | | | | | | | |
| | containing resin | | | | | | | | | | |
| Comparative | comparative synthesis | 6500 | 0.72 | 0.63 | 12 | PB15:6 | I-1 | K1 | B | C | B |
| Example 1 | example 1 dipyrromethene | | | | | | | | | | |
| | containing resin 1 | | | | | | | | | | |
| Comparative | comparative synthesis | 6500 | 0.72 | 0.63 | 30 | PB15:6 | I-1 | K1 | C | C | C |
| Example 2 | example 2 dipyrromethene | | | | | | | | | | |
| | containing resin 1 | | | | | | | | | | |
| Comparative | comparative synthesis | 7100 | 0.73 | 0.62 | 15 | PR254 | I-1 | K1 | C | C | B |
| Example 3 | example 3 azo | | | | | | | | | | |
| | containing resin 1 | | | | | | | | | | |
| Comparative | comparative synthesis | 7300 | 0.75 | 0.6 | 15 | PB15:6 | I-1 | K1 | B | C | B |
| Example 4 | example 4 triarylmethane | | | | | | | | | | |
| | containing resin | | | | | | | | | | |
| Comparative | comparative synthesis | 7100 | 0.72 | 0.63 | 10 | PY139 | I-1 | K1 | B | C | B |
| Example 5 | example 5 anlhraquinone | | | | | | | | | | |
| | containing resin | | | | | | | | | | |
| Comparative | comparative synthesis | 7000 | 0.73 | 0.62 | 11 | PB15:6 | I-1 | K1 | B | C | B |
| Example 6 | example 6 squaryliuin | | | | | | | | | | |
| | containing resin | | | | | | | | | | |
| Comparative | comparative synthesis | 7200 | 0.75 | 0.6 | 10 | PB15:6 | I-1 | K1 | B | C | B |
| Example 7 | example 7 xanthene | | | | | | | | | | |
| | containing resin | | | | | | | | | | |
| Comparative | comparative synthesis | 7400 | 0.74 | 0.61 | 11 | PG36 | I-1 | K1 | B | C | B |
| Example 8 | example 8 quinophthalone | | | | | | | | | | |
| | containing resin | | | | | | | | | | |

As is clear from the results shown in table 3, it may be understood that comparative examples 1 to 8 in which a resin was used in which a ratio of the peak area of the component having a molecular weight of 2000 or less is 10% or more in regard to the peak area of the total molecular weight distribution of the resin have poor color loss resistance. Also, when the ratio of the peak area of the component having a molecular weight of 2000 or less further increases, it may be understood that not only the color loss resistance, but also the developability and heat resistance deteriorate (for example, see comparative example 2).

Meanwhile, it may be understood that all of developability, color loss resistance and heat resistance of examples 1 to 26, in which a resin is used in which a ratio of the peak area of the component having a molecular weight of 2000 or less is less than 10% in regard to the peak area of the total molecular weight distribution of the resin, are of a practical, acceptable degree or more.

### Example 27

### Manufacturing of Full-Color Color Filter for Solid State Imaging Device

Using the coloring radiation-sensitive composition for green which was prepared in example 23, the green pixel was formed in a 1.2×1.2 μm island bayer pattern, next, using the coloring radiation-sensitive composition for red which was prepared in example 25, the red pixel was formed in a 1.2×1.2 μm island pattern, and furthermore, using coloring radiation-sensitive composition for blue which was prepared in example 1 in the remaining lattices, the blue pixel was formed in a 1.2×1.2 μm island pattern, thereby a color filter for the light-shielding portion solid state imaging device was manufactured.

Evaluation

When the obtained full-color color filter for a solid state imaging device was incorporated into the solid state imaging device, it was confirmed that the solid state imaging device had a high resolution and excellent color isolation.

What is claimed is:

1. A coloring composition which includes a resin (A) having a dye structure,
wherein a peak area occupied by a component having a molecular weight of 2000 or less is below 10% in respect to a peak area of a total molecular weight distribution of the resin (A) which is measured using gel permeation chromatography.

2. The coloring composition according to claim 1,
wherein a weight average molecular weight of the resin (A) is from 4000 to 15000.

3. The coloring composition according to claim 1, further comprising a pigment (B).

4. The coloring composition according to claim 3,
wherein the pigment (B) is an anthraquinone pigment, a diketopyrrolopyrrole pigment, a phthalocyanine pigment, a quinophthalone pigment, an isoindoline pigment, an azomethine pigment, or a dioxazine pigment.

5. The coloring composition according to claim 1, further comprising a polymerizable compound (C), and a photopolymerization initiator (D).

6. The coloring composition according to claim 5,
wherein the photopolymerization initiator (D) is an oxime initiator.

7. The coloring composition according to claim 1, further comprising an alkaline soluble resin (E).

8. The coloring composition according to claim 1,
wherein the dye structure of the resin (A) is a structure derived from a dye selected from a dipyrromethene dye, an azo dye, an anthraquinone dye, a triphenylmethane dye, a xanthene dye, a cyanine dye, a squarylium dye, a quinophthalone dye, a phthalocyanine dye, and a sub-phthalocyanine dye.

9. The coloring composition according to claim 1,
wherein the resin (A) further has a polymerizable group.

10. The coloring composition according to claim 9,
wherein the polymerizable group is a polymerizable group selected from a group consisting of a group that includes an ethylenic unsaturated bond, an epoxy group, an oxetane group, and a methylol group.

11. The coloring composition according to claim 1,
wherein the resin (A) is a resin obtained by subjecting a monomer, which has an ethylenic unsaturated bond and a dye structure, to a radical polymerization reaction.

12. The coloring composition according to claim 1,
wherein the resin (A) further has an alkaline soluble group.

13. The coloring composition according to claim 1,
wherein an acid value of the resin (A) is from 0.5 mmol/g to 1.0 mmol/g.

14. The coloring composition according to claim 1,
wherein the coloring composition is used to form a colored layer of a color filter.

15. A colored cured film obtained by curing the coloring composition according to claim 1.

16. A color filter which is provided with the colored cured film according to claim 15.

17. A manufacturing method of a color filter comprising:
forming a colored layer by coating the coloring composition according to claim 11 onto a support,
performing pattern exposure on the colored layer, and
developing the colored layer after exposure to form a colored pattern.

18. A solid state imaging device provided with the color filter according to claim 16.

19. A solid state imaging device provided with the color filter obtained using the manufacturing method of a color filter according to claim 17.
